(19) United States
(12) Patent Application Publication
(10) Pub. No.: US 2025/0194356 A1
(43) Pub. Date: Jun. 12, 2025

(54) DISPLAY PANEL AND DISPLAY DEVICE

(71) Applicants: Visionox Technology Inc., Kunshan (CN); Hefei Visionox Technology Co., Ltd., Hefei (CN)

(72) Inventors: Deqiang ZHANG, Kunshan (CN); Chung-chun LEE, Kunshan (CN); Yiming XIAO, Kunshan (CN); Fengying XU, Kunshan (CN); Xiujian ZHU, Kunshan (CN); Rubo XING, Kunshan (CN)

(73) Assignees: Visionox Technology Inc., Kunshan (CN); Hefei Visionox Technology Co., Ltd., Hefei (CN)

(21) Appl. No.: 19/059,347

(22) Filed: Feb. 21, 2025

Related U.S. Application Data
(63) Continuation of application No. PCT/CN2023/134518, filed on Nov. 27, 2023.

(30) Foreign Application Priority Data
Mar. 31, 2023 (CN) 202310356240.4
Apr. 9, 2023 (CN) 202310369642.8
Apr. 9, 2023 (CN) 202310369659.3
Apr. 9, 2023 (CN) 202310392090.2
Jun. 26, 2023 (CN) 202310759370.2
Jul. 12, 2023 (CN) 202310853873.6
Jul. 12, 2023 (CN) 202310854721.8
Jul. 13, 2023 (CN) 202310855866.X
Sep. 28, 2023 (CN) 202311275756.2

(51) Int. Cl. H10K 59/122; H10K 59/80

(52) U.S. Cl. CPC H10K 59/122; H10K 59/873

(57) ABSTRACT

The present application provides a display panel and a display device, the display panel includes an isolation structure including a partition portion, a display functional layer including a plurality of light-emitting devices and a first encapsulation layer located on the substrate. The partition portion includes a first end portion and a second end portion. In a regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin.

### CROSS-REFERENCE TO RELATED APPLICATIONS

The present application is a continuation application of International Application No. PCT/CN2023/134518, filed on Nov. 27, 2023, which claims priority to the Chinese Patent Application 202310855866.X, filed on Jul. 13, 2023, the Chinese Patent Application 202310356240.4, filed on Mar. 31, 2023, the Chinese Patent Application 202311275756.2, filed on Sep. 28, 2023, the Chinese Patent Application 202310392090.2, filed on Apr. 9, 2023, the Chinese Patent Application 202310759370.2, filed on Jun. 26, 2023, the Chinese Patent Application 202310369642.8, filed on Apr. 9, 2023, the Chinese Patent Application 202310854721.8, filed on Jul. 12, 2023, the Chinese Patent Application 202310369659.3, filed on Apr. 9, 2023, the Chinese Patent Application 202310853873.6, filed on Jul. 12, 2023, all of which are hereby incorporated by reference in there entireties.

### FIELD

The present application relates to the field of display technologies, and in particular, to a display panel and a display device.

### BACKGROUND

An Organic Light-Emitting Diode (OLED) is an organic thin-film electroluminescent device, which has advantages of low power consumption, high brightness, wide viewing angle, high contrast, flexible display and the like, and is greatly concerned by people and widely used in electronic display products.

However, current electronic display products are limited to a design of its own structure, facing a need to further increase the pixel density.

### SUMMARY

According to a first aspect, the present application provides a display panel, which includes a substrate, a display functional layer and an isolation structure. The display functional layer includes a plurality of light-emitting devices, each of the plurality of light-emitting devices includes a first electrode, a light-emitting functional layer, and a second electrode that are sequentially stacked on the substrate, the light-emitting functional layer includes an effective functional region, and the light-emitting functional layer includes a first functional layer. The isolation structure is located on the substrate and surrounds the light-emitting functional layer. The isolation structure includes a partition portion, the partition portion includes a first end portion facing the substrate and a second end portion facing away from the substrate, an orthographic projection, on a plane where the substrate is located, of the effective functional region of the light-emitting functional layer is located outside an orthographic projection, on the plane where the substrate is located, of the second end portion of the isolation structure, and an orthographic projection, on the plane where the substrate is located, of an edge of the first functional layer is located outside an orthographic projection, on the plane where the substrate is located, of the first end portion, and is located within the orthographic projection, on the plane where the sub strate is located, of the second end portion on a plane where the substrate is located. On a cross-section perpendicular to the substrate and on a same side of the isolation structure, an acute angle formed by intersecting a straight line determined by the edge of the first functional layer and an edge of the second end portion with the plane where the substrate is located is a second inclination angle, and a tangent value of an acute angle formed by intersecting a straight line determined by an edge of the effective functional region and the edge of the second end portion with the plane where the substrate is located is not greater than a tangent value of the second inclination angle, and a ratio of a height difference between an edge of the first end portion and the edge of the second end portion along a direction perpendicular to the plane where the substrate is located and a distance between the edge of the first end portion and the edge of the second end portion along a direction parallel to the plane where the substrate is located is not greater than the tangent value of the second inclination angle. Such as, a film thickness of a portion, located in the effective functional region, of the first functional layer is uniform.

In the foregoing solution, a first vapor deposition angle is determined through a boundary of the effective functional region and a height of the second end portion (the edge thereof), an extension position of the edge of the first functional layer is determined according to a height of the first vapor deposition angle and a height of the second end portion, a distance between the extension position and the second end portion can be inferred based on a principle that the first functional layer is separated by the partition portion, and an optional range of the position of the edge of the second end portion can be inferred, consequently, a relationship between the edge of the effective functional region, the edge of the first functional layer, a width of the isolation structure (a position of the edge of the first end portion and the edge of the second end portion), a height of the isolation structure (a height difference of the edge of the first end portion and the edge of the second end portion) and a vapor deposition angle can be constructed, in combination with an optional width range (with a lower limit value) of the first end portion, an optional width range (with a maximum width) of a main effective functional region can be reversely deduced, and an optional width range (with a maximum width) of a main light-emitting region can be deduced, and a maximum design width of the main light-emitting region can be obtained under a specific pixel density design requirement, to ensure a design area of the main light-emitting region under an actual process (a width of the main light-emitting region under the design area can be equal to the maximum design width or slightly smaller than the maximum design width), and an arrangement density of the light-emitting device can be improved while a situation that the first functional layer is separated by the partition part is maintained.

In one embodiment of the present application, the isolation structure defines a plurality of first openings, the light-emitting functional layer and the second electrode are located in a first opening of the plurality of first openings, the partition portion includes a conductive portion, the second electrode is connected with the conductive portion of the partition portion, an orthographic projection, on the plane where the substrate is located, of the first end portion, facing the substrate, of the partition portion is within an orthographic projection, on the plane where the substrate is located, of the second end portion, facing away from the substrate, of the partition portion.

In one embodiment of the present application, on the cross-section perpendicular to the substrate and on the same side of the isolation structure, an acute angle formed by intersecting a straight line determined by an edge of the second electrode and the edge of the second end portion with the plane where the substrate is located is a first inclination angle, first inclination angle is less than the second inclination angle, an acute angle formed by intersecting a straight line determined by the edge of the effective functional region and the edge of the second end portion with the plane where the substrate is located is less than or equal to the first inclination angle. For example, a film thickness of a portion, located in the effective functional region, of the second electrode is uniform.

In the foregoing solution, a minimum design size of a distance between the edge of the effective functional region and the edge of the second end portion in a transverse direction can be obtained under a condition that the film thickness of the second electrode and all the film layers of the light-emitting functional layer in the effective functional region is uniformly distributed, and a minimum distance between adjacent effective functional regions can be obtained, and the arrangement density (equivalent to the pixel density) of the light-emitting device is improved while the situation that the first functional layer is separated by the partition part is maintained.

In one embodiment of the present application, on the cross-section perpendicular to the substrate and on the same side of the isolation structure, an acute angle formed by intersecting a straight line determined by the edge of the first end portion (for example, an edge of a surface facing the surface) and the edge of the second end portion with the plane where the substrate is located is not less than the first inclination angle and is not greater than the second inclination angle.

In the foregoing solution, a minimum design size of a distance between the edge of the first end portion and the edge of the second end portion in a transverse direction may be obtained, and the minimum distance between the adjacent effective functional regions can be further obtained, and the arrangement density of the light-emitting device (equivalent to the pixel density) is improved while the situation that the first functional layer is separated by the partition part is maintained.

For example, an acute angle formed by intersecting a straight line determined by the edge of the first end portion and the edge of the second end portion with the plane where the substrate is located is greater than a first inclination angle, and the second electrode overlaps and contacts at least a portion of a side surface of the first end portion.

In the foregoing solution, the second electrode in lap-joint to the first end portion of the isolation structure can be ensured, and an overlapping portion of the second electrode and the isolation structure has a relatively large thickness to avoid poor contact or excessive resistance at a lap joint.

In one embodiment of the present application, an acute angle formed by intersecting a straight line of the edge of the effective functional region and the edge of the second end portion with the plane where the substrate is equal to the first inclination angle, and an acute angle formed by intersecting a straight line of the edge of the first end portion and the edge of the second end portion with the plane where the substrate is equal to the second inclination angle.

In the foregoing solution, in a case where it is ensured that the film thickness of each of the film layers, in the effective functional region, of the light-emitting device is uniformly distributed, the distance between the edge of the effective functional region and the edge of the second end portion in the transverse direction, and the distance between the edge of the first end portion and the edge of the second end portion in the transverse direction are all designed to be a minimum size, thereby the distance between adjacent effective functional regions is minimized to the greatest extend, and the minimum distance between adjacent effective functional regions can be obtained, and the arrangement density (equivalent to the pixel density) of the light-emitting device is maximized while the situation that the first functional layer is separated by the partition part is maintained.

In one embodiment of the present application, the isolation structure is an integral structure. For example, further, along a direction perpendicular to the substrate, a cross-sectional profile of a portion, located between two adjacent sub-pixels, of the partition portion is an inverted trapezoid, a top edge of the inverted trapezoid is located between the substrate and a bottom edge of the inverted trapezoid, an edge of a surface, facing the substrate, of the first end portion is the edge of the first end portion, and an edge of a surface, facing away from the substrate, of the second end portion is the edge of the second end portion.

In another specific embodiment of the present application, the partition portion includes a supporting portion and a blocking portion sequentially stacked on the substrate, the supporting portion forms the first end portion, and the blocking portion forms the second end portion. For example, further, along the direction perpendicular to the substrate, a cross-sectional profile of a portion, located between two adjacent sub-pixels, of the supporting portion is a regular trapezoid, the isolation structure is located at a top edge of the supporting portion, and an edge of a surface, facing the substrate, of the supporting portion is the edge of the first end portion. For example, further, along the direction perpendicular to the substrate, a cross-sectional profile of a portion, located between two adjacent sub-pixels, of the blocking portion is a regular trapezoid, and an edge of a surface, facing the supporting portion, of the blocking portion is the edge of the second end portion.

In one embodiment of the present application, the light-emitting functional layer further includes a light-emitting layer and a second functional layer, the first functional layer, the light-emitting layer and the second functional layer are located between the first electrode and the second electrode and sequentially stacked on the first electrode, and the orthographic projection, on the plane where the substrate is located, of the edge of any of the light-emitting layer and the second functional layer is located between an orthographic projection, on the plane where the substrate is located, of an edge of the first functional layer and the orthographic projection, on the plane where the substrate is located, of the edge of the second electrode.

In one embodiment of the present application, the display panel may further include a pixel defining layer, the pixel defining layer is located between the isolation structure and a layer where the first electrode is located, and covers a gap between adjacent first electrodes. The pixel defining layer defines a second opening, the light-emitting functional layer covers the second opening, the second opening corresponds to and communicates with the first opening, and an orthographic projection, on the plane where the substrate is located, of the second opening is located within an orthographic projection, on the plane where the substrate is located, of the first opening corresponding to the second opening.

In the foregoing solution, by designing the pixel defining layer, a risk that the first electrode overlaps with the isolation structure adjacent to the first electrode (for example, the conductive first end portion) can be eliminated, and the first electrode has a larger design size to ensure a design area of the effective functional region.

For example, a cross-sectional profile of a portion, located between two adjacent sub-pixels, of the pixel defining layer is a regular trapezoid along a direction perpendicular to the substrate, and an acute angle formed by intersecting a straight line determined by an edge, facing away from the surface, of the pixel defining layer and the edge of the second end portion with the plane where the substrate is located is equal to a second inclination angle on the same side of the isolation structure.

In the foregoing solution, the second electrode may have a relatively large film thickness on a sidewall (with a slope) of the pixel defining layer, to prevent the second electrode from poor film extension due to a segment difference.

For example, a cross-sectional profile of a portion, located between two adjacent sub-pixels, of the pixel defining layer is a regular trapezoid along the direction perpendicular to the substrate, and an acute angle formed by intersecting a straight line determined by an edge, facing the surface, of the pixel defining layer and the edge of the second end portion with the plane where the substrate is located is equal to a first inclination angle on the same side of the isolation structure.

In the foregoing solution, a boundary of the second opening of the pixel defining layer coincides with a boundary of the effective functional region, and the light-emitting region of the light-emitting device coincides with the effective functional region, and the light-emitting portion of the light-emitting region can have a maximum light-emitting efficiency, thereby improving a light-emitting uniformity; correspondingly, the design may obtain a range where the boundary of the pixel defining layer may extend while ensuring a maximum light-emitting efficiency of the light-emitting device, to obtain a maximum design width of the pixel defining layer (a width of a portion between two adjacent first openings), thereby facilitating a planning of a width of the pixel gap (a gap of the light-emitting region of adjacent light-emitting device).

In one embodiment of the present application, an orthographic projection, on the plane where the substrate is located, of a gap between adjacent first electrodes coincides with an orthographic projection, on the plane where the substrate is located, of a surface, facing the substrate, of the first end portion. In this way, a minimum design width of the first end portion of the isolation structure can be obtained, and the minimum distance between the adjacent effective functional regions can be obtained, and the arrangement density (equivalent to the pixel density) of the light-emitting device is improved while the situation that the first functional layer is separated by the partition part is maintained.

In another specific embodiment of the present application, an orthographic projection, on the plane where the substrate is located, of a gap between adjacent first electrodes is located within an orthographic projection, on the plane where the substrate is located, of a surface, facing the substrate, of the first end portion. In this way, it can be ensured that the first end portion of the isolation structure can completely cover a groove existing on a surface of the pixel definition layer due to the gap between the first electrodes, to ensure a preparation yield of the isolation structure.

In one embodiment of the present application, a portion, covering the gap of the first electrode, of the pixel defining layer is conformal with the gap of the first electrode, and the pixel defining layer is an inorganic material film layer. In this way, the pixel defining layer has a smaller thickness, which can ensure a continuity of the second electrode at an opening of the pixel defining layer, and can prevent a height of the isolation structure from being too high (affecting a gap size of the effective functional region) due to excessive thickness of the pixel defining layer, thereby further improving the pixel density of the display panel or the design area of the effective functional region (related to a light-emitting area, aperture ratio and the like of a pixel).

According to a second aspect, the present application provides a display panel, which includes a substrate, and an isolation structure, a display functional layer, and a first encapsulation layer located on the substrate. The isolation structure is located on the substrate and has a first end portion and a second end portion, the second end portion is located on a side, away from the substrate, of the first end portion, an orthographic projection, on a plane where the substrate is located, of the first end portion is located within an orthographic projection, on a plane where the substrate is located, of the second end portion, and the isolation structure defines a plurality of first openings. The display functional layer is located on the substrate and includes a plurality of light-emitting devices, where the plurality of light-emitting devices correspond to the plurality of first openings respectively, each light-emitting device of the plurality of light-emitting devices is located in a first opening, corresponding to the light-emitting device, of the plurality of first openings, the light-emitting device includes a first electrode, a light-emitting functional layer, and a second electrode stacked on the substrate, and the first opening is configured limit he light-emitting device corresponding to the first opening. The first encapsulation layer is located on a side, away from the substrate, of the display functional layer. An orthographic projection, on a plane where the substrate is located, of a part of an edge portion of each one of at least one of film layers of the light-emitting device is located within the orthographic projection, on the plane where the substrate is located, of the second end portion.

In one embodiment, a thickness of an edge portion of each of at least one of the film layers of the light-emitting device gradually decreases along a direction from a middle portion of the light-emitting device to an edge of the light-emitting device.

In the foregoing solution, the thickness of the edge portion of each of at least one of the film layers of the light-emitting device is gradually decreases, which representing that the at least one of the film layers are formed by evaporation through the isolation structure, a thickness of the light-emitting device at an edge of the second end portion is smaller than a thickness at the middle portion of the second end portion, and the height of the isolation structure can be designed to ensure an encapsulation effect of the first encapsulation layer while enabling the isolation structure to have a relatively small height to further reduce a width of a portion, between adjacent first openings, of the isolation structure, thereby increasing the aperture ratio, the pixel density and the like of the display panel.

In one embodiment, the display panel includes a plurality of sub-pixels, each sub-pixel of the plurality of sub-pixels includes two opposite long sides and two opposite short sides, at least one sub-pixel only has an edge portion with a gradually decreasing thickness in the direction from a middle portion of the light-emitting device to a corresponding edge at the short side, and the long edge does not have an edge portion gradually decreasing in the direction from the middle portion of the light-emitting device to a corresponding edge.

In one embodiment of the present application, along a direction perpendicular to the plane where the substrate is located, a distance from the edge of the second end portion to an edge of the first end portion is a first height; in a regular cross-section of the light-emitting device, a distance between a position of a surface, facing the substrate, of the first encapsulation layer that located on a straight line passing through the edge of the second end portion and perpendicular to the plane where the substrate is located and the edge of the first end portion along the direction perpendicular to the plane where the substrate is located is a partition association height, and a difference between the first height and the partition association height is not less than an encapsulation safety margin.

Along the direction perpendicular to the plane where the substrate is located, a distance from the edge of the second end portion to the edge of the first end portion is a first height, a distance between the first encapsulation layer and the first electrode is a second height at an intermediate position of the light-emitting device. A product of the second height and a first thickness coefficient is a first numerical value, and a difference between the first height and the first numerical value is not less than an encapsulation safety margin.

In the foregoing solution, an encapsulation degree of the first encapsulation layer can be controlled by adjusting the difference between the encapsulation safety margin and the difference between the first height and the first numerical value, to ensure that the first encapsulation layer has a basic encapsulation effect while balancing a relationship between the encapsulation effect of the first encapsulation layer and the height of the isolation structure, and in a case of meeting different encapsulation requirements, a minimum width of a portion, between the adjacent first openings, of the isolation structure can be obtained to further improve the aperture ratio, pixel density, and the like of the display panel.

In one embodiment, the first thickness coefficient is greater than or equal to M and less than 1, and M∈[0.3, 0.5) or M∈[0.5, 0.7];

In one embodiment, the first thickness coefficient is equal to M.

In one embodiment, M is a ratio of the partition association height to the second height;

In one embodiment, the first thickness coefficient is greater than or equal to 0.5 and less than 1.

In one embodiment of the present application, the first encapsulation layer has a second thickness at an intermediate position of the light-emitting device, the first encapsulation layer covers the light-emitting device and a side surface of a part of the second end portion, and the encapsulation safety margin is equal to a product of the second thickness and the second thickness coefficient. The encapsulation safety margin is set based on a need to protect relevant film layers such as light-emitting devices, and the basic encapsulation effect of the first encapsulation layer can be guaranteed.

In one embodiment, the first encapsulation layer is formed with a closed chamber on a side surface of the isolation structure, and the second thickness coefficient is 0.2 to 2.

In one embodiment, the second thickness coefficient is 0.25 to 1.2; further in one embodiment, the second thickness coefficient is 0.3 to 0.8;

In one embodiment, the display panel includes a plurality of sub-pixels, each sub-pixel of the plurality of sub-pixels includes two opposite long sides and two opposite short sides, at least one sub-pixel only has an edge portion with a gradually decreasing thickness in the direction from a middle portion of the light-emitting device to a corresponding edge at the short side, and the long edge does not have an edge portion gradually decreasing in the direction from a middle portion of the light-emitting device to a corresponding edge.

In one embodiment of the present application, a distance between an orthographic projection, on the plane where the substrate is located, of the edge of the second end portion and an orthographic projection, on the plane where the substrate is located, of the edge of the first end portion is a first width, in the regular cross-section of the light-emitting device, an acute angle formed by intersecting a straight line passing through the edge of the second electrode and the edge of the second end portion with the plane where the substrate is located is a first inclination angle, the first width is less than a product of the first height and a cotangent value of the first inclination angle. The first inclination angle may represent a vapor deposition angle of the second electrode during vapor deposition formation, and by controlling a numerical relationship between the first width, the first height and the vapor deposition angle, it can be ensured that an edge of the second electrode can be overlapped on the isolation structure (for example, the first end portion thereof), to ensure that the second electrode of the light-emitting device can be connected to an external circuit (for example, a common electrode line or other pixel-driving circuits) through the isolation structure.

In one embodiment, the second electrode has an upturned tail portion overlapping a side surface of the first end portion.

In one embodiment, in the regular cross-section of the light-emitting device, an acute angle formed by intersecting a straight line of an edge of the light-emitting functional layer and the edge of the second end portion with the plane where the substrate is located is an inclination angle of the light-emitting functional layer, and the inclination angle of the light-emitting functional layer is greater than the first inclination angle.

In one embodiment, the first width is greater than a product of the first height and a cotangent value of the inclination angle of the light-emitting functional layer.

In one embodiment, the light-emitting functional layer includes a first functional layer, in the regular cross-section of the light-emitting device, an acute angle formed by intersecting a straight line passing through an edge of the first functional layer and the edge of the second end portion with the plane where the substrate is located is a second inclination angle, and the second inclination angle is greater than the inclination angle of the light-emitting functional layer. Design in this way, a spacing between the edge of the first functional layer and the isolation structure is larger compared to the edge of the entire light-emitting functional layer, and the first functional layer can be avoided from being connected together through the isolation structure, thereby a problem that light-emitting efficiency of the display panel is reduced due to current leakage is avoided.

In one embodiment, the light-emitting functional layer further includes a light-emitting layer and a second functional layer, and the light-emitting layer and the second functional layer cover the edge of the first functional layer. Design in this way may prevent the first functional layer from crossing over the light-emitting layer and the second functional layer and directly connecting to the second electrode to ensure the light-emitting effect of the light-emitting device.

In one embodiment, in the regular cross-section of the light-emitting device, a thickness of the second electrode at a position passing through an edge of the first electrode and perpendicular to the plane where the substrate is located is less than a thickness of a portion of the second electrode corresponding to the intermediate position of the light-emitting device.

In one embodiment of the present application, the orthographic projection, on the plane of the substrate, of the edge of the second end portion is located between an orthographic projection, on the plane of the substrate, of the edge of the first electrode and the orthographic projection, on the plane of the substrate, of the edge of the first end portion. Design in this way, the edge of the first electrode does not extend to the edge of the second end portion, not to increase a height of a surface of the light-emitting device at the edge due to a provision of the first electrode, to reserve sufficient space for the first encapsulation layer to have good encapsulation effect, and accordingly, an overall design height of the isolation structure can be permitted to be lowered, and a width of a portion, between the adjacent first openings, of the isolation structure can be further reduced.

In one embodiment, on the regular cross-section of the light-emitting device, a distance between the orthographic projection, on the plane where the substrate is located, of the edge of the first electrode and the orthographic projection, on the plane where the substrate is located, of the edge of the second end portion is less than: a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in a direction perpendicular to the plane where the substrate is located.

In the foregoing solution, it can be ensured that the first electrode has a large enough area, and a first electrode exists in any region where film thickness of the light-emitting functional layer is uniform (for example, the effective functional region), thereby increasing an area of the uniformly light-emitting region of the light-emitting device (in which the film thickness of the light-emitting functional layer is uniform) to increase the aperture rate of the display panel; furthermore, the solution provides sufficient margin for the alignment accuracy of the first electrode and the isolation structure, and even if there is an deviation in a position of the first electrode and the isolation structure, it can also be ensured that the area and position of the uniformly light-emitting region of the light-emitting device are not affected.

In one embodiment, on the regular cross-section of the light-emitting device, the product of a cotangent value of an acute angle at which a connecting line between an edge of the light-emitting functional layer and the edge of the second end portion intersects the plane where the substrate is located and a distance between the intermediate portion of a lower surface of the light-emitting functional layer and the edge of the second end portion in the direction perpendicular to the plane where the substrate is located is less than or equal to: the distance between the orthographic projection, on the plane where the substrate is located, of the edge of the first electrode and the orthographic projection, on the plane where the substrate is located, of the edge of the second end portion.

In the foregoing solution, the film thickness of the light-emitting functional layer is uniform in a region of the light-emitting device where the first electrode is distributed, and wavelengths of the light emitted from the light-emitting region of the light-emitting device can be ensured to be consistent, to eliminate a problem of stray light with different colors in the light-emitting device.

In one embodiment of the present application, the display panel further includes a pixel defining layer, the pixel defining layer is located on the first electrode and located on a side, facing the substrate, of the partition portion, the pixel defining layer defines a plurality of second openings, the first electrode is exposed from the plurality of second openings, and the edge of the first end portion is located in an upper surface of the pixel defining layer.

In the foregoing solution, the first electrode may have a large area by providing the pixel defining layer, and there is no need to consider the problem of the alignment accuracy of the first electrode and the isolation structure in a preparation process.

In one embodiment, on the regular cross-section of the light-emitting device, a distance between an orthographic projection, on the plane where the substrate is located, of an edge of a portion, exposed from a second opening, of the first electrode and the orthographic projection, on the plane where the substrate is located, of the edge of the second end portion is less than: a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in a direction perpendicular to the plane where the substrate is located.

In the foregoing solution, a first electrode exists in any region where film thickness of the light-emitting functional layer is uniform (for example, the effective functional region), thereby increasing an area of the uniformly light-emitting region of the light-emitting device (in which the film thickness of the light-emitting functional layer is uniform) to increase the aperture rate of the display panel.

In one embodiment, on the regular cross-section of the light-emitting device, the product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located is less than or equal to: a distance between an orthographic projection, on the plane where the substrate is located, of an edge of a portion, exposed from the plurality of second openings, of the first electrode and the orthographic projection, on the plane where the substrate is located, of the edge of the second end portion.

In the foregoing solution, the film thickness of the light-emitting functional layer is uniform in a region of the light-emitting device where the first electrode is distributed, and wavelengths of the light emitted from the light-emitting region of the light-emitting device can be ensured to be consistent, to eliminate a problem of stray light with different colors in the light-emitting device.

In one embodiment, the pixel defining layer is an inorganic layer, a portion, covering a gap of the first electrode disposed adjacently, of the pixel defining layer has a groove conformal with the gap, and a surface, facing the substrate, of the first end portion covers the groove.

In the foregoing solution, the inorganic pixel-defining layer may have a smaller thickness and a smaller segment difference exists at an edge of the pixel-defining layer to improve a continuity of the second electrode at that edge of the pixel-defining layer; furthermore, the solution can reduce an extent to which a height of the isolation structure is increased as a result of a provision of the pixel-defining layer; furthermore, the first end portion completely covers the groove, thereby an influence of the groove on the isolation structure is eliminated, to ensure that heights of edges at everywhere of the edge of the first end portion are the same.

In one embodiment, the distance between an intermediate portion of a lower surface of the light-emitting functional layer and the edge of the second end portion in the direction perpendicular to the plane where the substrate is located is equal to: a sum of the first height and a thickness of the pixel defining layer.

In one embodiment of the present application, the display panel further includes a protective layer, the protective layer is an insulation layer, the protective layer includes a plurality of protective units, and each protective unit of the plurality of protective units is located between the first electrode and the first end portion.

In the foregoing solution, in a process of preparing the isolation structure, the first electrode can be protected through the protective layer, to prevent the first electrode from side etching, thereby improving the yield of the light-emitting device.

In one embodiment, the protective unit covers a sidewall of the first electrode and is spaced apart from the first end portion of the isolation structure; or the protective unit covers the sidewall of the first electrode and a sidewall of the first end portion.

In the foregoing solution, a bonding strength of the protective unit and the substrate is higher, and the first electrode is sandwiched between the protective unit and the substrate, thereby further reducing a risk that the first electrode falls off the substrate.

In one embodiment, a straight line perpendicular to a plane where the substrate is located and passing through an edge of the second end portion passes through the protective unit.

In one embodiment, an interval is provided between the protective unit and the first end portion of the isolation structure, along a direction perpendicular to the plane where the substrate is located, a distance between the edge of the second end portion and an edge of the first end portion in the direction perpendicular to the plane where the substrate is located is a first height, in a regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin;
or,
along a direction perpendicular to a plane where the substrate is located, a distance from an edge of the second end portion to an edge of the first end portion is a first height, a distance between the first encapsulation layer and the first electrode is a second height at an intermediate position of the light-emitting device, a product of the second height and a first thickness coefficient is a first numerical value, a sum of the first numerical value and a thickness of the protective unit is a second numerical value, and a difference between the first height and the second numerical value is not less than an encapsulation safety margin; in one embodiment, the first thickness coefficient is greater than or equal to M and less than 1 and M∈[0.3, 0.5) or M∈[0.5, 0.7], further in one embodiment, M is a ratio of the partition association height to the second height, and further in one embodiment, the first thickness coefficient is equal to M;
or,
the protective layer covers a sidewall of the first electrode and a part of a sidewall of the first end portion, along a direction perpendicular to a plane where the substrate is located, a distance between an edge of the second end portion and an edge of the first end portion in the direction perpendicular to the plane where the substrate is located is a first height, in the regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin;
or,
along the direction perpendicular to a plane where the substrate is located, a distance from an edge of the second end portion to an edge of the first end portion is a first height, a distance between the first encapsulation layer and the first electrode is a second height at an intermediate position of the light-emitting device, a product of the second height and the first thickness coefficient is a first numerical value, and a difference between the first height and the first numerical value is not less than an encapsulation security margin. In one embodiment, the first thickness coefficient is greater than or equal to M and less than 1 and M∈[0.3, 0.5) or M∈[0.5, 0.7], further in one embodiment, M is a ratio of the partition association height to the second height, and further in one embodiment, the first thickness coefficient is equal to M.

In one embodiment, on the regular cross-section of the light-emitting device, a distance between an orthographic projection, on the plane where the substrate is located, of an edge of a portion, exposed from the protective layer, of the first electrode and an orthographic projection, on the plane where the substrate is located, of an edge of the second end portion is less than: a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located.

In the foregoing solution, by adjusting an coverage area of the protective unit of the protective layer to the first electrode, a first electrode may exists in any region where film thickness of the light-emitting functional layer is uniform (for example, the effective functional region), thereby increasing an area of the uniformly light-emitting region of the light-emitting device (in which the film thickness of the light-emitting functional layer is uniform) to increase the aperture rate of the display panel; furthermore, the solution provides sufficient margin for the alignment accuracy of the first electrode and the isolation structure, and even if there is an deviation in a position of the first electrode and the isolation structure, it can also be ensured that the area and position of the uniformly light-emitting region of the light-emitting device are not affected.

In one embodiment, on the regular cross-section of the light-emitting device, the product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located is less than or equal to: a distance between an orthographic projection, on the plane where the substrate is located, of an edge of a portion, exposed from the protective layer, of the first electrode and an orthographic projection, on the plane where the substrate is located, of the edge of the second end portion.

In the foregoing solution, the film thickness of the light-emitting functional layer is uniform in a region of the light-emitting device where the first electrode is distributed, and wavelengths of light emitted from the light-emitting region of the light-emitting device can be ensured to be consistent, to eliminate a problem of stray light with different colors in the light-emitting device.

In one embodiment, the first end portion includes a connecting portion facing a side of the substrate, and the connecting portion and the first electrode are in same layer and made of same material. In the foregoing solution, a connecting portion can be prepared synchronously during a preparation of the first electrode to reduce a thickness requirement of the isolation structure; furthermore, the isolation structure and the substrate are connected by the connecting portion to reduce a risk that the isolation structure falls off the substrate.

In one embodiment, an interval is provided between the protective unit and the first end portion of the isolation structure, the substrate includes a first planarization layer and a second planarization layer facing a side of the isolation structure, the second planarization layer is located between the first planarization layer and the isolation structure, and is located between the first planarization layer and the first electrode, the first planarization layer is an organic layer, and the second planarization layer is an inorganic layer. In the foregoing solution, the second planarization layer is an inorganic layer, which can increase a bonding strength of the substrate and the isolation structure as well as the first electrode, thereby reducing a risk that the first electrode and the isolation structure falls off the substrate.

In one embodiment of the present application, the display panel further includes at least one optical functional layer, the optical functional layer is located on a side, away from the substrate, of the light-emitting functional layer and includes a plurality of optical functional units.

In one embodiment, on the regular cross-section of the light-emitting device, an acute angle at which a connecting line from an edge of each of the plurality of optical functional units to the edge of the second end portion intersects the plane where the substrate is located is greater than or equal to an acute angle at which a connecting line from the edge of the light-emitting functional layer to the edge of the second end portion intersects the plane where the substrate is located.

In the foregoing solution, a portion of the optical functional unit that have a uniform thickness covers a portion of the light-emitting functional layer that have a uniform thickness, to make lights emitted by the light-emitting device pass through a portion of the optical functional unit that have a uniform thickness as much as possible, to improve display effect of the display panel.

In one embodiment, the optical functional unit is located between the light-emitting functional layer and the first encapsulation layer, at least one of the plurality of first openings is internally provided with the optical functional unit, an orthographic projection, on the plane where the substrate is located, of a part of an edge portion of the optical functional unit is located within the orthographic projection, on the plane where the substrate is located, of the second end portion, and a thickness of the edge portion of the optical functional unit gradually decreases in the direction from the middle portion of the light-emitting device to a corresponding edge.

In the foregoing solution, the thickness of the edge portion of at least one of the film layer of the optical functional unit is gradually reduced, which representing that the at least one of the film layer are formed by evaporation through the isolation structure, and a thickness of the optical functional unit at the edge of the second end portion is smaller than a thickness at the middle portion of the second end portion, and a height of the isolation structure can be designed, and the height of the isolation structure can be designed to ensure an encapsulation effect of the first encapsulation layer while enabling the isolation structure to have a relatively small height to further reduce a width of a portion, between adjacent first openings, of the isolation structure, thereby increasing the aperture ratio, the pixel density and the like of the display panel.

In one embodiment, a type of the optical functional unit is configured to include at least one type of a color conversion unit, an optical extraction unit, an optical regulating unit, a filling unit and a filter unit; or, the type of the optical functional unit is configured to include at least two different types of the color conversion unit, the optical extraction unit, the optical regulating unit, the filling unit and the filter unit;

In the foregoing solution, in a case that the optical functional unit includes the color conversion unit, the light-emitting device of the display panel can be configured to emit light of same color, and each light-emitting device can be synchronously prepared to simplify a preparation process of the display panel.

In one embodiment of the present application, the partition portion includes a supporting portion and a blocking portion stacked on the substrate, the supporting portion forms the first end portion, and the blocking portion forms the second end portion.

In one embodiment, the first encapsulation layer is in contact with a surface of the blocking portion, and material of the first encapsulation layer is same as material of the barrier portion.

In one embodiment of the present application, a dividing hole with a grid shape is provided in the supporting portion, the dividing hole divides the supporting portion into a plurality of sub-supporting portions, the blocking portion covers and fills the dividing hole, the supporting portion is of a conductive structure, the blocking portion is of an insulating structure, and the second electrode is connected with a sub-supporting portion corresponding to the second electrode.

In the foregoing solution, a conductive portion of the partition portion is divided into the plurality of sub-supporting portions by the dividing the hole, and the second electrodes of the light-emitting device are independent of each other, and the second electrode of each light-emitting device can be driven independently.

In one embodiment of the present application, in a situation that the partition portion includes a supporting portion and a blocking portion stacked on the substrate, on the regular cross-section of the light-emitting device, the blocking portion has an inclined sidewall, a difference between an acute angle at which a connecting line between the edge of the second electrode and the edge of the second end portion intersects the plane where the substrate is located and an acute angle at which a sidewall of the blocking portion intersects the plane where the substrate is located is not less than a preset angle.

In one embodiment of the present application, the first end portion and the second end portion of the partition portion are of an integral structure, and in a direction perpendicular to the plane where the substrate is located, a cross-sectional profile of a portion of the partition portion located between two adjacent sub-pixels is an inverted trapezoid, an edge of a bottom of the inverted trapezoidal is the edge of the second end portion, and an edge of a top of the inverted trapezoidal is the edge of the first end portion.

In one embodiment of the present application, a distance between edges of portions that the first electrode contact with the light-emitting functional layer corresponding to the first electrode of adjacent light-emitting devices is a pixel pitch, the pixel pitch is 2000 to 18000 nanometers, and a pixel density of the display panel is 90 PPI to 7400 PPI.

According to a third aspect, the present application provides a display panel, which includes a substrate, and an isolation structure, a display functional layer and at least one a first encapsulation layer stacked on the substrate. The isolation structure is located on the substrate and includes a first end portion and a second end portion, the second end portion is located on a side, away from the substrate, of the first end portion, an orthographic projection, on a plane where the substrate is located, of the first end portion is located within an orthographic projection, on the plane where the substrate is located, of the second end portion, and the isolation structure defines a plurality of first openings. The display functional layer is located on the substrate and includes a plurality of light-emitting devices, the plurality of light-emitting devices correspond to the plurality of first openings respectively, each light-emitting device of the plurality of light-emitting devices is located in a first opening, corresponding to the light-emitting device, of the plurality of first openings, the light-emitting device includes a first electrode, a light-emitting functional layer and a second electrode stacked on the substrate, and the first opening is configured to limit the light-emitting device corresponding to the first opening. The first encapsulation layer is located on a side, away from the substrate, of the display functional layer. The display functional layer is located on a side, away from the substrate, of light-emitting functional layer and includes a plurality of optical functional units. An orthographic projection, on the plane where the substrate is located, of a part of an edge portion of each of at least one of film layers of the light-emitting device is located within an orthographic projection, on the plane where the substrate is located, of the second end portion.

In one embodiment, along a direction from a middle portion of the light-emitting device to a corresponding edge, a thickness of the edge portion of each of at least one of film layers of the light-emitting device gradually decreases.

In one embodiment of the present application, the optical functional unit is located between the light-emitting functional layer and the first encapsulation layer, at least one of the plurality of first openings is internally provided with the optical functional unit,

In one embodiment, the optical functional unit is located between the light-emitting functional layer and the first encapsulation layer, an orthographic projection, on the plane where the substrate is located, of a part of an edge portion of the optical functional unit is located within the orthographic projection, on the plane where the substrate is located, of the second end portion, and a thickness of the edge portion of the optical functional unit gradually decreases along the direction from the middle portion of the light-emitting device to a corresponding edge.

In one embodiment of the present application, a distance from an edge of the second end portion to an edge of the first end portion is a first height along a direction perpendicular to a plane where the substrate is located; in a regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin.

In one embodiment of the present application, the distance from the edge of the second end portion to the edge of the first end portion is the first height along a direction perpendicular to a plane where the substrate is located, a distance between the first encapsulation layer and the first electrode is a second height at an intermediate position of the light-emitting device, a product of the second height and a first thickness coefficient is a first numerical value, and a difference between the first height and the first numerical value is not less than the encapsulation safety margin.

In one embodiment, the first thickness coefficient is greater than or equal to M and less than 1, and M∈[0.3, 0.5) or M∈[0.5, 0.7], further in one embodiment, M is a ratio of the partition association height to the second height, further preferably, the first thickness coefficient is equal to M.

In one embodiment of the present application, at the intermediate position of the light-emitting device, the first encapsulation layer has a second thickness, the first encapsulation layer covers the light-emitting device and a side surface of a part of the second end portion, and the encapsulation safety margin is equal to a product of the second thickness and the second thickness coefficient.

In one embodiment, the first encapsulation layer is formed with a closed chamber on a side surface of the isolation structure, the second thickness coefficient is 0.2 to 2,

In one embodiment, the second thickness coefficient is 0.25 to 1.2, further in one embodiment, the second thickness coefficient is 0.3 to 0.8.

In one embodiment, the display panel includes a plurality of sub-pixels, each sub-pixel of the plurality of sub-pixels includes two opposite long sides and two opposite short sides, at least one sub-pixel only has an edge portion with a gradually decreasing thickness in the direction from a middle portion of the light-emitting device to a corresponding edge at the short side, and the long edge does not have an edge portion gradually decreasing in the direction from a middle portion of the light-emitting device to a corresponding edge.

In one embodiment of the present application, a distance between an orthographic projection, on the plane where the substrate is located, of the edge of the second end portion and an orthographic projection, on the plane where the substrate is located, of the edge of the first end portion is a first width. In the regular cross-section of the light-emitting device, an acute angle formed by intersecting a straight line passing through an edge of the second electrode and the edge of the second end portion with the plane where the substrate is located is a first inclination angle, the first width is less than a product of the first height and a cotangent value of the first inclination angle.

In one embodiment, the second electrode has an upturned tail portion overlapping a side surface of the first end portion;

In one embodiment, in the regular cross-section of the light-emitting device, an acute angle formed by intersecting a straight line of an edge of the light-emitting functional layer and the edge of the second end portion with the plane where the substrate is located is an inclination angle of the light-emitting functional layer, and the inclination angle of the light-emitting functional layer is greater than the first inclination angle.

In one embodiment, the first width is greater than a product of the first height and a cotangent value of the inclination angle of the light-emitting functional layer.

In one embodiment, the light-emitting functional layer includes a first functional layer, in the regular cross-section of the light-emitting device, an acute angle formed by intersecting a straight line passing through an edge of the first functional layer and the edge of the second end portion with the plane where the substrate is located is a second inclination angle, and the second inclination angle is greater than the inclination angle of the light-emitting functional layer.

In one embodiment, the light-emitting functional layer further includes a light-emitting layer and a second functional layer, and the light-emitting layer and the second functional layer cover the edge of the first functional layer.

In one embodiment, in the regular cross-section of the light-emitting device, a thickness of the second electrode at a position passing through an edge of the first electrode and perpendicular to the plane where the substrate is located is less than a thickness of a portion of the second electrode corresponding to the intermediate position of the light-emitting device.

In one embodiment of the present application, an orthographic projection, on the plane where the substrate is located, of the second end portion is located between an orthographic projection, on the plane where the substrate is located, of the edge of the first electrode and an orthographic projection, on the plane where the substrate is located, of an edge of the first end portion.

In one embodiment, on the regular cross-section of the light-emitting device, a distance between the orthographic projection, on the plane where the substrate is located, of the edge of the first electrode and the orthographic projection, on the plane where the substrate is located, of the edge of the second end portion is less than: a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in a direction perpendicular to the plane where the substrate is located.

In one embodiment, on the regular cross-section of the light-emitting device, the product of the cotangent value of the acute angle at which the connecting line between an edge of the light-emitting functional layer and the edge of the second end portion intersects the plane where the substrate is located and the distance between the intermediate portion of the lower surface of the light-emitting functional layer and the edge of the second end portion in the direction perpendicular to the plane where the substrate is located is less than or equal to: the distance between the orthographic projection, on the plane where the substrate is located, of the edge of the first electrode and the orthographic projection, on the plane where the substrate is located, of the edge of the second end portion.

In one embodiment of the present application, the display panel further includes a pixel defining layer, the pixel defining layer is located on the first electrode and located on a side, facing the substrate, of the partition portion, the pixel defining layer defines a plurality of second openings, the first electrode is exposed from the plurality of second openings, and the edge of the first end portion is located in an upper surface of the pixel defining layer.

In one embodiment, on the regular cross-section of the light-emitting device, a distance between an orthographic projection, on the plane where the substrate is located, of an edge of a portion, exposed from the plurality of second openings, of the first electrode and the orthographic projection, on the plane where the substrate is located, of the edge of the second end portion is less than: a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in a direction perpendicular to the plane where the substrate is located.

In one embodiment, on the regular cross-section of the light-emitting device, the product of the cotangent value of the acute angle at which the connecting line between the edge of the light-emitting functional layer and the edge of the second end portion intersects the plane where the substrate is located and the distance between the intermediate portion of the lower surface of the light-emitting functional layer and the edge of the second end portion in the direction perpendicular to the plane where the substrate is located is less than or equal to: the distance between the orthographic projection, on the plane where the substrate is located, of the edge of a portion, exposed from the plurality of second openings, of the first electrode and the orthographic projection, on the plane where the substrate is located, of the edge of the second end portion.

In one embodiment, the pixel defining layer is an inorganic layer, a portion, covering a gap of the first electrode disposed adjacently, of the pixel defining layer has a groove conformal with the gap, and a surface, facing the substrate, of the first end portion covers the groove.

In one embodiment, the distance between the intermediate portion of the lower surface of the light-emitting functional layer and the edge of the second end portion in the direction perpendicular to the plane where the substrate is located is equal to: a sum of the first height and a thickness of the pixel defining layer.

In one embodiment of the present application, the display panel further includes a protective layer, the protective layer is an insulation layer, the protective layer includes a plurality of protective units, and each protective unit of the plurality of protective units is located between the first electrode and the first end portion.

In one embodiment, the protective unit covers a sidewall of the first electrode and is spaced apart from the first end portion of the isolation structure; or the protective unit covers the sidewall of the first electrode and a sidewall of the first end portion.

In one embodiment, a straight line perpendicular to a plane where the substrate is located and passing through an edge of the second end portion passes through the protective unit.

In one embodiment, an interval is provided between the protective unit and the first end portion of the isolation structure, along a direction perpendicular to the plane where the substrate is located, a distance between the edge of the second end portion and an edge of the first end portion in the direction perpendicular to the plane where the substrate is located is a first height, in a regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin;
or,
along a direction perpendicular to a plane where the substrate is located, a distance from an edge of the second end portion to an edge of the first end portion is a first height, a distance between the first encapsulation layer and the first electrode is a second height at an intermediate position of the light-emitting device, a product of the second height and a first thickness coefficient is a first numerical value, a sum of the first numerical value and a thickness of the protective unit is a second numerical value, and a difference between the first height and the second numerical value is not less than an encapsulation safety margin; in one embodiment, the first thickness coefficient is greater than or equal to M and less than 1 and M∈[0.3, 0.5) or M∈[0.5, 0.7], further in one embodiment, M is a ratio of the partition association height to the second height, and further in one embodiment, the first thickness coefficient is equal to M;
or,
the protective layer covers a sidewall of the first electrode and a part of a sidewall of the first end portion, along a direction perpendicular to a plane where the substrate is located, a distance between an edge of the second end portion and an edge of the first end portion in the direction perpendicular to the plane where the substrate is located is a first height, in the regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin;
or,
along a direction perpendicular to a plane where the substrate is located, a distance from an edge of the second end portion to an edge of the first end portion is a first height, a distance between the first encapsulation layer and the first electrode is a second height at an intermediate position of the light-emitting device, a product of the second height and the first thickness coefficient is a first numerical value, and a difference between the first height and the first numerical value is not less than an encapsulation security margin; in one embodiment, the first thickness coefficient is greater than or equal to M and less than 1 and M∈[0.3, 0.5) or M∈[0.5, 0.7], further in one embodiment, M is a ratio of the partition association height to the second height, and further in one embodiment, the first thickness coefficient is equal to M.

In one embodiment, on the regular cross-section of the light-emitting device, a distance between an orthographic projection, on the plane where the substrate is located, of an edge of a portion, exposed from the protective layer, of the first electrode and an orthographic projection, on the plane where the substrate is located, of an edge of the second end portion is less than: a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located.

In one embodiment, on the regular cross-section of the light-emitting device, the product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located is less than or equal to: a distance between an orthographic projection, on the plane where the substrate is located, of an edge of a portion, exposed from the protective layer, of the first electrode and an orthographic projection, on the plane where the substrate is located, of the edge of the second end portion.

In one embodiment, the first end portion includes a connecting portion facing a side of the substrate, and the connecting portion and the first electrode are in same layer and made of same material.

In one embodiment, an interval is provided between the protective unit and the first end portion of the isolation structure, the substrate includes a first planarization layer and a second planarization layer facing a side of the isolation structure, the second planarization layer is located between the first planarization layer and the isolation structure, and is located between the first planarization layer and the first electrode, the first planarization layer is an organic layer, and the second planarization layer is an inorganic layer.

In one embodiment of the present application, the optical functional unit is located between the second electrode and the first encapsulation layer, the second height includes a thickness of a portion of the optical functional unit corresponding to an intermediate position of the light-emitting device.

In one embodiment, on the regular cross-section of the light-emitting device, an acute angle at which a connecting line between an edge of the optical functional unit to the edge of the second end portion intersects the plane where the substrate is located is greater than or equal to an acute angle at which a connecting line between an edge of the light-emitting functional layer to the edge of the second end portion intersects the plane where the substrate is located.

In one embodiment, the display panel further includes a pixel defining layer, the pixel defining layer is located on the first electrode and located on a side, facing the substrate, of the partition portion, the pixel defining layer defines a plurality of second openings, the first electrode is exposed from the plurality of second openings, and the edge of the first end portion is located in an upper surface of the pixel defining layer, on the regular cross-section of the light-emitting device, a product of a cotangent value of an acute angle at which a connecting line between the edge of the optical functional unit and the edge of the second end portion intersects the plane where the substrate is located and a distance between a middle portion of the lower surface of the optical functional unit and the edge of the second end portion in the direction perpendicular to the plane where the substrate is located is less than or equal to: a distance between an orthographic projection, on the plane where the substrate is located, of an edge of the first electrode and the orthographic projection, on the plane where the substrate is located, of the edge of the second end portion.

In one embodiment, a distance between the middle portion of the lower surface of the optical functional unit and the edge of the second end portion in the direction perpendicular to the plane where the substrate is located is equal to: a difference of a sum of the first height and a thickness of the pixel defining layer and a distance between the middle portion of the lower surface of the optical functional unit and a middle portion of the first electrode in the direction perpendicular to the plane where the substrate is located.

In one embodiment, a type of the optical functional unit is configured to include at least one type of a color conversion unit, an optical extraction unit, an optical regulating unit, a filling unit and a filter unit. Or, the type of the optical functional unit is configured to include at least two different types of the color conversion unit, the optical extraction unit, the optical regulating unit, the filling unit and the filter unit.

In one embodiment, the optical functional unit is configured to include the color conversion unit, the optical extraction unit, the optical regulating unit, the filling unit and the light filter unit, where the color conversion unit and the filling unit correspond to different light-emitting devices and are arranged side by side, the light filtering unit is located on a side, away from the substrate, of the color conversion unit corresponding to the light filtering unit or located on a side, away from the substrate, of the filling unit corresponding to the light filtering unit, the optical regulating unit is located on a side, away from the substrate, of the optical extraction unit corresponding to the optical regulating unit, and the color conversion unit is located on a side, close to the substrate, of the optical extraction unit corresponding to the color conversion unit or on a side, away from the substrate, of the optical regulating unit corresponding to the color conversion unit.

In one embodiment of the present application, each of the plurality of optical functional units is located on a side, away from the substrate, of the first encapsulation layer.

In one embodiment, the display panel further includes a second encapsulation layer located on the side, away from the substrate, of the first encapsulation layer, and the second encapsulation layer is an organic encapsulation layer and includes a multiplexing unit multiplexed as a color conversion unit.

In one embodiment, the display panel further includes a second encapsulation layer located on the side, away from the substrate, of the first encapsulation layer, the second encapsulation layer is an organic encapsulation layer, and the color conversion unit is located between the first encapsulation layer and the second encapsulation layer.

In one embodiment of the present application, the light-emitting functional layer of the light-emitting device is configured to emit light of a first color. The optical functional unit includes the color conversion unit, the color conversion unit includes a first color conversion unit and/or a second color conversion unit, the first color conversion unit is configured to convert the first color light into a second color light, the second color conversion unit is configured to convert the first color light into a third color light, and wavelengths of the first color light, the second color light, and the third color light are sequentially increased.

In one embodiment, the first color light, the second color light and the third color light emit blue light, green light and red light respectively, material of the first color conversion unit includes a G quantum dot material, and material of the second color conversion unit includes an R quantum dot material.

In one embodiment, the light-emitting functional layer is a stacked structure.

In one embodiment, a light-emitting type of the light-emitting functional layer is fluorescent or phosphorescence.

In one embodiment, the color conversion unit is located on a side, away from the substrate, of the second electrode.

In one embodiment, there is an interval between an edge of the color conversion unit and the isolation structure.

In one embodiment of the present application, the light-emitting functional layer of the light-emitting device includes at least two light-emitting layers, at least one of the at least two light-emitting layers is configured to emit a first color light, at least one of the at least two light-emitting layers is configured to emit a second color light, the color conversion unit includes a first color conversion unit and/or a second color conversion unit, the first color conversion unit is configured to convert the first color light into a second color light, and the second color conversion unit is configured to convert the first color light into a third color light, where wavelengths of the first color light, the second color light, and the third color light are sequentially increased, or the wavelengths of the first color light, the third color light, and the second color light are sequentially increased.

In one embodiment, the first color light, the second color light and the third color light are respectively blue light, green light and red light, material of the first color conversion unit includes a G quantum dot material, and material of the second color conversion unit includes an R quantum dot material.

In one embodiment, the first color light, the second color light and the third color light emit blue light, red light and green light respectively, the material of the first color conversion unit includes an R quantum dot material, and the material of the second color conversion unit includes a G quantum dot material.

In one embodiment, a light-emitting type of the light-emitting functional layer is fluorescent or phosphorescent.

In one embodiment, the quantum dot material includes perovskite quantum dots and/or II-VI group semiconductor quantum dots; in one embodiment, the perovskite quantum dots include at least one of CsPbX₃ and CH₃NH₃PbX₃, where X is a halogen atom.

Further in one embodiment, the halogen atom includes at least one type of F, Cl, Br and I.

Further in one embodiment, the II-VI group semiconductor quantum dots include at least one type of CdSe/ZnS, ZnCdSe/ZnSe/ZnS, CdZnSe/CdZnS/ZnS, CdSe/CdZnSe/ZnS, CdZnSe/ZnS, InP@ZnSeS, ZnSe/ZnS, InP/ZnSe/ZnS, ZnSeTe/ZnSe/ZnSeS/ZnS, ZnSeTe/ZnSe/ZnS, and ZnSe/ZnS.

In one embodiment, a thickness of a film layer of the color conversion unit is 500 to 10000 nanometers, further in one embodiment, the thickness of the film layer of the color conversion unit is 600 to 3000 nanometers, and still further in one embodiment, the thickness of the film layer of the color conversion unit is 800 to 1200 nanometers.

In one embodiment of the present application, the optical functional unit is configured to include at least the filling unit and the color conversion unit, where the color conversion unit includes a red color conversion unit disposed on a side, away from the substrate, of the light-emitting functional layer of the light-emitting device emitting red light and a green color conversion unit disposed on a side, away from the substrate, of the light-emitting functional layer of the light-emitting device emitting green light, and the filling unit is disposed on a side, away from the substrate, of the light-emitting functional layer of the light-emitting device emitting blue light.

In one embodiment of the present application, the optical functional unit is configured to include at least the optical extraction unit, the optical extraction unit is located between the light-emitting device corresponding to the optical extraction unit and the color conversion unit corresponding to the optical extraction unit or located on a side, away from the substrate, of the color conversion unit.

In one embodiment, the optical extraction unit includes a first extraction sub-layer. Or, the optical extraction unit includes a first extraction sub-layer, a second extraction sub-layer located on a side, facing the substrate, of the first extraction sub-layer, and a third extraction sub-layer located on a side, facing away from the substrate, of the first extraction sub-layer, and a refractive index of the second extraction sub-layer and a refractive index of the third extraction sub-layer are both less than a refractive index of the first extraction sub-layer.

In one embodiment, the refractive index of the first extraction sub-layer is 2.0 to 2.3, and further in one embodiment, the refractive index of the first extraction sub-layer is 2.1 to 2.2.

In one embodiment, a thickness of the first extraction sub-layer is 45 to 75 nanometers, and further in one embodiment, the thickness of the first extraction sub-layer is 55 to 65 nanometers.

In one embodiment, the refractive index of the second extraction sub-layer and/or the refractive index of the third extraction sub-layer is 1.4 to 1.8, and further in one embodiment, the refractive index of the second extraction sub-layer and/or the refractive index of the third extraction sub-layer is 1.5 to 1.6.

In one embodiment, a thickness of the second extraction sub-layer and/or a thickness of the third extraction sub-layer is 7 to 30 nanometers, and further in one embodiment, the thickness of the second extraction sub-layer and/or the thickness of the third extraction sub-layer is 10 to 20 nanometers.

In one embodiment of the present application, the optical functional unit is configured to include at least an optical regulating unit located on a side, away from the substrate, of an optical extraction unit corresponding to the optical regulating unit.

In one embodiment, the optical regulating unit is located between the optical extraction unit corresponding to the optical regulating unit and a color conversion unit corresponding to the optical regulating unit.

In one embodiment, material of the optical regulating unit includes a LiF material.

In one embodiment, a thickness of the optical regulating unit is 65 to 100 nanometers, and further in one embodiment, the thickness of the optical regulating unit is 75 to 85 nanometers.

In one embodiment of the present application, the partition portion includes a supporting portion and a blocking portion stacked on the substrate, the supporting portion forms the first end portion, and the blocking portion forms the second end portion.

In one embodiment, the first encapsulation layer is in contact with a surface of the blocking portion, and material of the first encapsulation layer is same as material of the barrier portion.

In one embodiment of the present application, a dividing hole with a grid shape is provided in the supporting portion, the dividing hole divides the supporting portion into a plurality of sub-supporting portions, the blocking portion covers and fills the dividing hole, the supporting portion is of a conductive structure, the blocking portion is of an insulating structure, and the second electrode is connected with a sub-supporting portion corresponding to the second electrode.

In one embodiment of the present application, the partition portion includes a supporting portion and a blocking portion stacked on the substrate, on the regular cross-section of the light-emitting device, the blocking portion has an inclined sidewall, a difference between an acute angle at which a connecting line between the edge of the second electrode and the edge of the second end portion intersects the plane where the substrate is located and an acute angle at which a sidewall of the blocking portion intersects the plane where the substrate is located is not less than a preset angle.

In one embodiment of the present application, the first end portion and the second end portion of the partition portion are of an integral structure, and in the direction perpendicular to the plane where the substrate is located, a cross-sectional profile of a portion, located between two adjacent sub-pixels, of the partition portion, is an inverted trapezoid, an edge of a bottom of the inverted trapezoidal is the edge of the second end portion, and an edge of a top of the inverted trapezoidal is the edge of the first end portion.

In one embodiment of the present application, the optical functional unit is configured to include at least the filter unit and the color conversion unit, the filter unit is located on a side, away from the substrate, of the color conversion unit corresponding to the filter unit, and a shielding portion is disposed between adjacent filter units.

In one embodiment, the filter unit is located between the color conversion unit corresponding to the filter unit and the first encapsulation layer, and a part of the isolation structure is multiplexed as the shielding portion.

In one embodiment of the present application, a distance between edges of portions that the first electrode contact with a light-emitting functional layer corresponding to the first electrode of adjacent light-emitting devices is a pixel pitch, the pixel pitch is 2000 to 18000 nanometers, and a pixel density of the display panel is 90 PPI to 7400 PPI.

According to a fourth aspect, the present application provides a display panel, which includes a substrate, and an isolation structure, a display functional layer, and a first encapsulation layer located on the substrate. The isolation structure is located on the substrate and has a first end portion and a second end portion, the second end portion is located on a side, away from the substrate, of the first end portion, an orthographic projection, on a plane where the substrate is located, of the first end portion is located within an orthographic projection, on a plane where the substrate is located, of the second end portion, and the isolation structure defines a plurality of first openings. The display functional layer is located on the substrate and includes a plurality of light-emitting devices, where the plurality of light-emitting devices correspond to the plurality of first openings respectively, each light-emitting device of the plurality of light-emitting devices is located in a first opening, corresponding to the light-emitting device, of the plurality of first openings, the light-emitting device includes a first electrode, a light-emitting functional layer, and a second electrode stacked on the substrate, and the first opening is configured limit he light-emitting device corresponding to the first opening. The first encapsulation layer is located on a side, away from the substrate, of the display functional layer, a distance from an edge of the second end portion to an edge of the first end portion is a first height along a direction perpendicular to a plane where the substrate is located; in a regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin.

In one embodiment of the present application, a distance between the first encapsulation layer and the first electrode is a second height at an intermediate position of the light-emitting device, a product of the second height and a first thickness coefficient is a first numerical value, and a difference between the first height and the first numerical value is not less than the encapsulation safety margin. In one embodiment, the first thickness coefficient is greater than or equal to M and less than 1, and M∈[0.3, 0.5) or M∈[0.5, 0.7], further in one embodiment, M is a ratio of the partition association height to the second height, further in one embodiment, the first thickness coefficient is equal to M.

In one embodiment of the present application, at the intermediate position of the light-emitting device, the first encapsulation layer has a second thickness. The first encapsulation layer covers the light-emitting device and a side surface of a part of the second end portion, and the encapsulation safety margin is equal to a product of the second thickness and the second thickness coefficient.

In one embodiment, the second thickness coefficient is 0.2 to 2. Further in one embodiment, the second thickness coefficient is 0.25 to 1.2. Still further in one embodiment, the second thickness coefficient is 0.3 to 0.8.

In one embodiment of the present application, a distance between an orthographic projection, on the plane where the substrate is located, of the edge of the second end portion and an orthographic projection, on the plane where the substrate is located, of the edge of the first end portion is a first width, in the regular cross-section of the light-emitting device, an acute angle formed by intersecting a straight line passing through an edge of the second electrode and the edge of the second end portion with the plane where the substrate is located is a first inclination angle, and the first width is less than a product of the first height and a cotangent value of the first inclination angle.

In one embodiment, in the regular cross-section of the light-emitting device, an acute angle formed by intersecting a straight line of an edge of the light-emitting functional layer and the edge of the second end portion with the plane where the substrate is located is an inclination angle of the light-emitting functional layer, and the inclination angle of the light-emitting functional layer is greater than the first inclination angle.

In one embodiment, the first width is greater than a product of the first height and a cotangent value of the inclination angle of the light-emitting functional layer.

In one embodiment, the light-emitting functional layer includes a first functional layer, in the regular cross-section of the light-emitting device, an acute angle formed by intersecting a straight line passing through an edge of the first functional layer and the edge of the second end portion with the plane where the substrate is located is a second inclination angle, and the second inclination angle is greater than the inclination angle of the light-emitting functional layer.

In one embodiment, the light-emitting functional layer further includes a light-emitting layer and a second functional layer, and the light-emitting layer and the second functional layer cover the edge of the first functional layer.

In one embodiment, in the regular cross-section of the light-emitting device, a thickness of the second electrode at a position passing through an edge of the first electrode and perpendicular to the plane where the substrate is located is less than a thickness of a portion of the second electrode corresponding to the intermediate position of the light-emitting device.

In one embodiment of the present application, the orthographic projection, on the plane where the substrate is located, of the edge of the second end portion is located between an orthographic projection, on the plane where the substrate is located, of an edge of the first electrode and the orthographic projection, on the plane where the substrate is located, of the edge of the first end portion.

In one embodiment, on the regular cross-section of the light-emitting device, a distance between the orthographic projection, on the plane where the substrate is located, of the edge of the first electrode and the orthographic projection, on the plane where the substrate is located, of the edge of the second end portion is less than: a product of a cotangent value of an acute angle at which a connecting line between the edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located;

In one embodiment, on the regular cross-section of the light-emitting device, the product of the cotangent value of the acute angle at which the connecting line between the edge of the light-emitting functional layer and the edge of the second end portion intersects the plane where the substrate is located and the distance between the intermediate portion of the lower surface of the light-emitting functional layer and the edge of the second end portion in the direction perpendicular to the plane where the substrate is located is less than or equal to: the distance between the orthographic projection, on the plane where the substrate is located, of the edge of the first electrode and the orthographic projection, on the plane where the substrate is located, of the edge of the second end portion.

In one embodiment of the present application, the display panel further includes a pixel defining layer, the pixel defining layer is located on the first electrode and located on a side, facing the substrate, of the partition portion, the pixel defining layer defines a plurality of second openings, the first electrode is exposed from the plurality of second openings, and the edge of the first end portion is located in an upper surface of the pixel defining layer.

In one embodiment, on the regular cross-section of the light-emitting device, a distance between an orthographic projection, on the plane where the substrate is located, of an edge of a portion, exposed from the plurality of second openings, of the first electrode and the orthographic projection, on the plane where the substrate is located, of the edge of the second end portion is less than: a product of a cotangent value of an acute angle at which a connecting line between the edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located.

In one embodiment, on the regular cross-section of the light-emitting device, the product of the cotangent value of the acute angle at which the connecting line between the edge of the light-emitting functional layer and the edge of the second end portion intersects the plane where the substrate is located and the distance between the intermediate portion of the lower surface of the light-emitting functional layer and the edge of the second end portion in the direction perpendicular to the plane where the substrate is located is less than or equal to: the distance between the orthographic projection, on the plane where the substrate is located, of the edge of the portion, exposed from the plurality of second openings, of the first electrode and the orthographic projection, on the plane where the substrate is located, of the edge of the second end portion.

In one embodiment, the pixel defining layer is an inorganic layer, a portion, covering a gap of the first electrode disposed adjacently, of the pixel defining layer has a groove conformal with the gap, and a surface, facing the substrate, of the first end portion covers the groove.

In one embodiment, a distance between an intermediate portion of a lower surface of the light-emitting functional layer and the edge of the second end portion in the direction perpendicular to the plane where the substrate is located is equal to: a sum of the first height and a thickness of the pixel defining layer.

In one embodiment of the present application, the partition portion includes a supporting portion and a blocking portion stacked on the substrate, the supporting portion forms the first end portion, and the blocking portion forms the second end portion.

In one embodiment, the first encapsulation layer is in contact with a surface of the blocking portion, and material of the first encapsulation layer is same as material of the barrier portion.

In one embodiment of the present application, the dividing hole with a grid shape is provided in the supporting portion, the dividing hole divides the supporting portion into a plurality of sub-supporting portions, the blocking portion covers and fills the dividing hole, the supporting portion is of a conductive structure, the blocking portion is of an insulating structure, and the second electrode is connected with a sub-supporting portion corresponding to the second electrode.

In one embodiment of the present application, the partition portion includes a supporting portion and a blocking portion stacked on the substrate, on the regular cross-section of the light-emitting device, the blocking portion has an inclined sidewall, a difference between an acute angle at which a connecting line between the edge of the second electrode and the edge of the second end portion intersects the plane where the substrate is located and an acute angle at which a sidewall of the blocking portion intersects the plane where the substrate is located is not less than a preset angle.

In one embodiment of the present application, the first end portion and the second end portion of the partition portion are of an integral structure, and in the direction perpendicular to the plane where the substrate is located, a cross-sectional profile of a portion, located between two adjacent sub-pixels, of the partition portion is an inverted trapezoid, an edge of a bottom of the inverted trapezoidal is the edge of the second end portion, and an edge of a top of the inverted trapezoidal is the edge of the first end portion.

In one embodiment of the present application, a distance between edges of portions that the first electrode contact with the light-emitting functional layer corresponding to the first electrode of adjacent light-emitting devices is a pixel pitch, the pixel pitch is 2000 to 18000 nanometers, and a pixel density of the display panel is 90 PPI to 7400 PPI.

According to a fifth aspect, the present application provides a display panel, which includes a substrate, and an isolation structure and a display functional layer located on the substrate, where the isolation structure includes a first end portion and a second end portion, the second end portion is located on a side, away from the substrate, of the first end portion, the isolation structure defines a plurality of first openings, the display functional layer includes a plurality of light-emitting devices, where the plurality of light-emitting devices correspond to the plurality of first openings respectively, each light-emitting device of the plurality of light-emitting devices is located in a first opening, corresponding to the light-emitting device, of the plurality of first openings, the light-emitting device includes a first electrode, a light-emitting functional layer and a second electrode stacked on the substrate, an orthographic projection, on a plane where the substrate is located, of the light-emitting functional layer is located outside an orthographic projection, on the plane where the substrate is located, of the first end portion and located within an orthographic projection, on the plane where the substrate is located, of the second end portion, a distance between edges of portions that the first electrode contact with the light-emitting functional layer corresponding to the first electrode of adjacent light-emitting devices is a pixel pitch, and the pixel pitch is 2000 to 18000 nanometers.

In one embodiment of the present application, on a regular cross-section of the light-emitting device, a cross-sectional profile of a portion, located between two adjacent sub-pixels, of a partition portion is an inverted trapezoid, an edge of a bottom of the inverted trapezoidal is an edge of the second end portion, and an edge of a top of the inverted trapezoidal is an edge of the first end portion, where, a width of a top of the inverted trapezoidal is 1500 to 16000 nanometers.

In one embodiment of the present application, the partition portion includes a supporting portion and a blocking portion stacked on the substrate, the supporting portion forms the first end portion, the blocking portion forms the second end portion, on the regular cross-section of the light-emitting device, a cross-sectional profile of a portion, located between two adjacent sub-pixels, of the supporting portion and the blocking portion is a regular trapezoid, the edge of the second end portion is an edge, facing a surface of the substrate, of the blocking portion, the edge of the first end portion is an edge, facing the surface of the substrate, of the supporting portion, a width of a bottom of the regular trapezoid corresponding to the supporting portion is 1258 to 17000 nanometers, and a width of a top of the trapezoid corresponding to the supporting portion is 880 to 15000 nanometers.

In one embodiment of the present application, the display panel includes a plurality of pixels, each of the pixels includes a plurality of sub-pixels with different wavelengths of emergent light, the plurality of sub-pixels of the plurality of pixels include a plurality of first sub-pixels, a plurality of second sub-pixels and a plurality of third sub-pixels, and the plurality of first sub-pixels, the plurality of second sub-pixels and the plurality of third sub-pixels respectively include different light-emitting devices.

In one embodiment, a number ratio of the plurality of first sub-pixels, the plurality of second sub-pixels and the plurality of third sub-pixels is 1:1:1.

In one embodiment, each of the plurality of pixels is arranged in a first pixel arrangement manner in which a first sub-pixel, a second sub-pixel, and a third sub-pixel are arranged in parallel; or, each of the plurality of pixels is arranged in a second pixel arrangement manner in which the second sub-pixel and the third sub-pixel are arranged in a column/row and are arranged parallel to the first sub-pixel.

In one embodiment, the larger the pixel density, the smaller the pixel pitch, and/or the smaller an average width of the sub-pixels.

In one embodiment of the present application, the partition portion of the isolation structure is in direct contact with the substrate, an edge of the first spacing is the edge of the portion of the first electrode in contact with the light-emitting functional layer in a same light-emitting device, a distance between an orthographic projection, on the plane where the substrate is located, of the edge of the second end portion and an orthographic projection, on the plane where the substrate is located, of the edge of the first end portion is a first width, a distance between an edge of a portion of the first electrode in contact with the light-emitting functional layer in the same light-emitting device and an orthographic projection, on the plane where the substrate is located, of the edge of the second end portion is a first spacing. In this case, the pixel pitch is 2000 to 2200 nanometers, the first spacing is 0 to 1017 nanometers, and the first width is 148 to 417 nanometers; or the pixel pitch is 2200 to 2500 nanometers, the first spacing is 0 to 1050 nanometers, and the first width is 166 to 450 nanometers; or the pixel spacing is 2500 to 3200 nanometers, the first spacing is 0 to 1090 nanometers, and the first width is 185 to 490 nanometers; or the pixel spacing is 3200 to 4000 nanometers, the first spacing is 0 to 1130 nanometers, and the first width is 203 to 530 nanometers; or the pixel spacing is 4000 to 6000 nanometers, the first spacing is 0 to 1170 nanometers, and the first width is 221 to 570 nanometers; or the pixel pitch is 6000 to 9000 nanometers, the first spacing is 0 to 1210 nanometers, and the first width is 240 to 610 nanometers; or the pixel pitch is 9000 to 13000 nanometers, the first spacing is 0 to 1300 nanometers, and the first width is 259 to 700 nanometers; or the pixel pitch is 13000 to 18000 nanometers, the first spacing is 0 to 1410 nanometers, and the first width is 277 to 810 nanometers.

For example, on the regular cross-section of the light-emitting device, a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in a direction perpendicular to the plane where the substrate is located is less than or equal to: a distance between an orthographic projection, on the plane where the substrate is located, of an edge of the first electrode and the orthographic projection, on the plane where the substrate is located, of the edge of the second end portion. For example, the pixel pitch is 2000 to 2200 nanometers, and the first spacing is 148 to 567 nanometers; or the pixel pitch is 2200 to 2500 nanometers, and the first spacing is 166 to 650 nanometers; or the pixel pitch is 2500 to 3200 nanometers, and the first spacing is 185 to 740 nanometers; or the pixel pitch is 3200 to 4000 nanometers, and the first spacing is 203 to 830 nanometers; or the pixel pitch is 4000 to 6000 nanometers, and the first spacing is 221 to 920 nanometers; or the pixel pitch is 6000 to 9000 nanometers, and the first spacing is 240 to 1010 nanometers; or the pixel pitch is 9000 to 13000 nanometers, and the first spacing is 259 to 1150 nanometers; or the pixel pitch is 13000 to 18000 nanometers, and the first spacing is 277 to 1310 nanometers.

For further example, a distance from the edge of the second end portion to the edge of the first end portion is a first height along the direction perpendicular to the plane where the substrate is located, and the first height is 400 to 2200 nanometers. In one embodiment, the pixel pitch is 2000 to 2200 nanometers, and the first height is 400 to 800 nanometers; or the pixel pitch is 2200 to 2500 nanometers, and the first height is 450 to 850 nanometers; or the pixel pitch is 2500 to 3200 nanometers, and the first height is 500 to 900 nanometers; or the pixel pitch is 3200 to 4000 nanometers, and the first height is 550 to 950 nanometers; or the pixel pitch is 4000 to 6000 nanometers, and the first height is 600 to 1000 nanometers; or the pixel pitch is 6000 to 9000 nanometers, and the first height is 650 to 1100 nanometers; or the pixel pitch is 9000 to 13000 nanometers, and the first height is 700 to 1200 nanometers; or the pixel pitch is 13000 to 18000 nanometers, and the first height is 750 to 2200 nanometers.

For example, on the regular cross-section of the light-emitting device, the distance between the orthographic projection, on the plane where the substrate is located, of the edge of the first electrode and the orthographic projection, on the plane where the substrate is located, of the edge of the second end portion is less than: the product of the cotangent value of the acute angle at which the connecting line between the edge of the light-emitting functional layer and the edge of the second end portion intersects the plane where the substrate is located and the distance between the intermediate portion of the lower surface of the light-emitting functional layer and the edge of the second end portion in the direction perpendicular to the plane where the substrate is located. In this case, the pixel pitch is 2000 to 2200 nanometers, the first spacing is 0 to 415 nanometers, and the first width is 148 to 417 nanometers; or the pixel pitch is 2200 to 2500 nanometers, the first spacing is 0 to 446 nanometers, and the first width is 166 to 450 nanometers; or the pixel pitch is 2500 to 3200 nanometers, the first spacing is 0 to 484 nanometers, and the first width is 185 to 490 nanometers; or the pixel pitch is 3200 to 4000 nanometers, the first spacing is 0 to 522 nanometers, and the first width is 203 to 530 nanometers; or the pixel pitch is 4000 to 6000 nanometers, the first spacing is 0 to 560 nanometers, and the first width is 221 to 570 nanometers; or the pixel pitch is 6000 to 9000 nanometers, the first spacing is 0 to 598 nanometers, and the first width is 240 to 610 nanometers; or the pixel pitch is 9000 to 13000 nanometers, the first spacing is 0 to 685 nanometers, and the first width is 259 to 700 nanometers; or the pixel pitch is 13000 to 18000 nanometers, the first spacing is 0 to 790 nanometers, and the first width is 277 to 810 nanometers.

In one embodiment, the display panel further includes at least one optical functional layer, where the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases, and for every two adjacent first electrodes, a pixel pitch between edges of a portion of the first electrode in contact with the light-emitting functional layer in a same light-emitting device is 2074 to 18000 nanometers.

In one embodiment of the present application, the display panel further includes a pixel defining layer, the pixel defining layer is located on the first electrode and located on a side, facing the substrate, of the partition portion and defines a second opening, the pixel defining layer covers an edge of the first electrode, the second opening exposes the first electrode, and an edge of the second opening coincides with an edge of a portion of the first electrode in contact with the light-emitting functional layer in a same light-emitting device, where a distance between an orthographic projection, on the plane where the substrate is located, of the edge of the second end portion and an orthographic projection, on the plane where the substrate is located, of the edge of the first end portion is a first width, a distance between an edge of a portion of the first electrode in contact with the light-emitting functional layer in the same light-emitting device and an orthographic projection, on the plane where the substrate is located, of the edge of the second end portion is a first spacing. For example, the pixel pitch is 2200 to 2500 nanometers, the first spacing is 0 to 1050 nanometers, and the first width is 148 to 450 nanometers; or the pixel pitch is 2500 to 3200 nanometers, the first spacing is 0 to 1090 nanometers, and the first width is 185 to 490 nanometers; or the pixel pitch is 3200 to 4000 nanometers, the first spacing is 0 to 1130 nanometers, and the first width is 203 to 530 nanometers; or the pixel pitch is 4000 to 6000 nanometers, the first spacing is 0 to 1170 nanometers, and the first width is 221 to 570 nanometers; or the pixel pitch is 6000 to 9000 nanometers, the first spacing is 0 to 1210 nanometers, and the first width is 240 to 610 nanometers; or the pixel spacing is 9000 to 13000 nanometers, the first spacing is 0 to 1300 nanometers, and the first width is 259 to 700 nanometers; or the pixel pitch is 13000 to 18000 nanometers, the first spacing is 0 to 1410 nanometers, and the first width is 277 to 810 nanometers.

In one embodiment, on the regular cross-section of the light-emitting device, a product of a cotangent value of an acute angle at which a connecting line between an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located is less than or equal to: a distance between an orthographic projection, on the plane where the substrate is located, of an edge of a portion, exposed from the plurality of second openings, of the first electrode and the orthographic projection, on the plane where the substrate is located, of the edge of the second end portion. For example, the pixel pitch is 2200 to 2500 nanometers, the first spacing is 148 to 650 nanometers, and the first width is 148 to 450 nanometers; or the pixel pitch is 2500 to 3200 nanometers, the first spacing is 185 to 740 nanometers, and the first width is 185 to 490 nanometers; or the pixel pitch is 3200 to 4000 nanometers, the first spacing is 203 to 830 nanometers, and the first width is 203 to 530 nanometers; or the pixel pitch is 4000 to 6000 nanometers, the first spacing is 221 to 920 nanometers, and the first width is 221 to 570 nanometers; or the pixel pitch is 6000 to 9000 nanometers, the first spacing is 240 to 1010 nanometers, and the first width is 240 to 610 nanometers; or the pixel pitch is 9000 to 13000 nanometers, the first spacing is 259 to 1150 nanometers, and the first width is 259 to 700 nanometers; or the pixel pitch is 13000 to 18000 nanometers, the first spacing is 277 to 1310 nanometers, and the first width is 277 to 810 nanometers.

For example, a distance from the edge of the second end portion to the edge of the first end portion is a first height along the direction perpendicular to the plane where the substrate is located, and the first height is 400 to 2200 nanometers. In one embodiment, the pixel pitch is 2200 to 2500 nanometers, and the first height is 400 to 850 nanometers; or the pixel pitch is 2500 to 3200 nanometers, and the first height is 500 to 900 nanometers; or the pixel pitch is 3200 to 4000 nanometers, and the first height is 550 to 950 nanometers; or the pixel pitch is 4000 to 6000 nanometers, and the first height is 600 to 1000 nanometers; or the pixel pitch is 6000 to 9000 nanometers, and the first height is 650 to 1100 nanometers; or the pixel pitch is 9000 to 13000 nanometers, and the first height is 700 to 1200 nanometers; or the pixel pitch is 13000 to 18000 nanometers, and the first height is 750 to 2200 nanometers.

In one embodiment, on the regular cross-section of the light-emitting device, the distance between the orthographic projection, on the plane where the substrate is located, of the edge of the portion, exposed from the plurality of second openings, of the first electrode and the orthographic projection, on the plane where the substrate is located, of the edge of the second end portion is less than: the product of the cotangent value of the acute angle at which the connecting line between the edge of the light-emitting functional layer and the edge of the second end portion intersects the plane where the substrate is located and the distance between the intermediate portion of the lower surface of the light-emitting functional layer and the edge of the second end portion in the direction perpendicular to the plane where the substrate is located. For example, the pixel pitch is 2200 to 2500 nanometers, the first spacing is 0 to 446 nanometers, and the first width is 148 to 450 nanometers; or the pixel pitch is 2500 to 3200 nanometers, the first spacing is 0 to 484 nanometers, and the first width is 185 to 490 nanometers; or the pixel pitch is 3200 to 4000 nanometers, the first spacing is 0 to 522 nanometers, and the first width is 203 to 530 nanometers; or the pixel pitch is 4000 to 6000 nanometers, the first spacing is 0 to 560 nanometers, and the first width is 221 to 570 nanometers; or the pixel pitch is 6000 to 9000 nanometers, the first spacing is 0 to 598 nanometers, and the first width is 240 to 610 nanometers; or the pixel pitch is 9000 to 13000 nanometers, the first spacing is 0 to 685 nanometers, and the first width is 259 to 700 nanometers; or the pixel pitch is 13000 to 18000 nanometers, the first spacing is 0 to 790 nanometers, and the first width is 277 to 810 nanometers.

In one embodiment of the present application, the display panel further includes at least one optical functional layer, the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases, and for every two adjacent first electrodes, a pixel pitch between edges of a portion of the first electrode in contact with the light-emitting functional layer in a same light-emitting device is 2274 to 18000 nanometers.

According to a sixth aspect, the present application provides a display panel, which includes a substrate, and an isolation structure and a display functional layer located on the substrate, where the isolation structure includes a first end portion and a second end portion, the second end portion is located on a side, away from the substrate, of the first end portion, the isolation structure defines a plurality of first openings, the display functional layer includes a plurality of light-emitting devices, where the plurality of light-emitting devices correspond to the plurality of first openings respectively, each light-emitting device of the plurality of light-emitting devices is located in a first opening, corresponding to the light-emitting device, of the plurality of first openings, the light-emitting device includes a first electrode, a light-emitting functional layer and a second electrode stacked on the substrate, an orthographic projection, on a plane where the substrate is located, of the light-emitting functional layer is located outside an orthographic projection, on the plane where the substrate is located, of the first end portion and located within an orthographic projection, on the plane where the substrate is located, of the second end portion, a pixel density of the display panel is 90 PPI to 7400 PPI.

In one embodiment of the sixth aspect of the present application, a thickness of an edge portion of each of at least one of the film layers of the light-emitting device gradually decreases along a direction from a middle portion of the light-emitting device to an edge of the light-emitting device.

In one embodiment of the sixth aspect of the present application, a pixel pitch between edges of portions that the first electrode in contact with a corresponding light-emitting functional layer of adjacent light-emitting devices is 2000 to 18000 nanometers.

In one embodiment of the sixth aspect of the present application, in a regular cross-section of the light-emitting device, a cross-sectional profile of a portion, located between two adjacent sub-pixels, of a partition portion is an inverted trapezoid, an edge of a bottom of the inverted trapezoid is an edge of the second end portion, and an edge of a top of the inverted trapezoid is an edge of the first end portion.

In one embodiment of the sixth aspect of the present application, the partition portion includes a supporting portion and a blocking portion stacked on the substrate, the supporting portion forms the first end portion, the blocking portion forms the second end portion, on a regular cross-section of the light-emitting device, a cross-sectional profile of a portion, located between two adjacent sub-pixels, of the supporting portion and the blocking portion is a regular trapezoid, the edge of the second end portion is an edge of a surface, facing the surface of the substrate, of the blocking portion, and the edge of the first end portion is an edge of a surface, facing the surface of the substrate, of the supporting portion.

In one embodiment of the sixth aspect of the present application, the display panel includes a plurality of pixels, each of the pixels includes a plurality of sub-pixels with different wavelengths of emergent light, the plurality of sub-pixels of the plurality of pixels include a plurality of first sub-pixels, a plurality of second sub-pixels and a plurality of third sub-pixels, and the plurality of first sub-pixels, the plurality of second sub-pixels and the plurality of third sub-pixels respectively include different light-emitting devices.

In one embodiment, a number ratio of the plurality of first sub-pixels, the plurality of second sub-pixels and the plurality of third sub-pixels is 1:1:1.

In one embodiment, each of the plurality of pixels is arranged in a first pixel arrangement manner in which a first sub-pixel, a second sub-pixel, and a third sub-pixel are arranged in parallel; or, each of the plurality of pixels is arranged in a second pixel arrangement manner in which the second sub-pixel and the third sub-pixel are arranged in a column/row and are arranged parallel to the first sub-pixel.

In one embodiment of the sixth aspect of the present application, a pixel density of the display panel is 90 to 5200 PPI. In one embodiment, the pixel pitch is 2000 to 2200 nanometers, and the pixel density of the display panel is 117 to 5200 PPI; or the pixel pitch is 2200 to 2500 nanometers, and the pixel density of the display panel is 117 to 4792 PPI; or the pixel pitch is 2500 to 3200 nanometers, and the pixel density of the display panel is 115 to 4305 PPI; or the pixel pitch is 3200 to 4000 nanometers, and the pixel density of the display panel is 115 to 3479 PPI; or the pixel pitch is 4000 to 6000 nanometers, and the pixel density of the display panel is 111 to 2854 PPI; or the pixel pitch is 6000 to 9000 nanometers, and the pixel density of the display panel is 107 to 1969 PPI; or the pixel pitch is 9000 to 13000 nanometers, and the pixel density of the display panel is 102 to 1344 PPI; or the pixel pitch is 13000 to 18000 nanometers, and the pixel density of the display panel is 90 to 944 PPI.

In one embodiment of the sixth aspect of the present application, the plurality of sub-pixels in a pixel are arranged in a first pixel arrangement manner, and the pixel density of the display panel is 170 to 3456 PPI. In one embodiment, the pixel pitch is 2000 to 2200 nanometers, and the pixel density of the display panel is 2545 to 3456 PPI; or the pixel pitch is 2200 to 2500 nanometers, and the pixel density of the display panel is 2171 to 3143 PPI; or the pixel pitch is 2500 to 3200 nanometers, and the pixel density of the display panel is 1577 to 2765 PPI; or the pixel pitch is 3200 to 4000 nanometers, and the pixel density of the display panel is 1063 to 2160 PPI; or the pixel pitch is 4000 to 6000 nanometers, and the pixel density of the display panel is 529 to 1728 PPI; or the pixel pitch is 6000 to 9000 nanometers, and the pixel density of the display panel is 353 to 1152 PPI; or the pixel pitch is 9000 to 13000 nanometers, and the pixel density of the display panel is 244 to 768 PPI; or the pixel pitch is 13000 to 18000 nanometers, and the pixel density of the display panel is 170 to 531 PPI.

In one embodiment of the sixth aspect of the present application, the plurality of sub-pixels in a pixel are arranged in a second pixel arrangement manner, and the pixel density of the display panel is 260 to 5200 PPI. In one embodiment, the pixel pitch is 2000 to 2200 nanometers, and the pixel density of the display panel is 3818 to 5200 PPI; or the pixel pitch is 2200 to 2500 nanometers, and the pixel density of the display panel is 3256 to 4714 PPI; or the pixel pitch is 2500 to 3200 nanometers, and the pixel density of the display panel is 2366 to 4147 PPI; or the pixel pitch is 3200 to 4000 nanometers, and the pixel density of the display panel is 1594 to 3240 PPI; or the pixel pitch is 4000 to 6000 nanometers, and the pixel density of the display panel is 794 to 2592 PPI; or the pixel pitch is 6000 to 9000 nanometers, and the pixel density of the display panel is 529 to 1728 PPI; or the pixel pitch is 9000 to 13000 nanometers, and the pixel density of the display panel is 366 to 1152 PPI; or the pixel pitch is 13000 to 18000 nanometers, and the pixel density of the display panel is 260 to 797 PPI.

In one embodiment of the sixth aspect of the present application, the display panel further includes at least one optical functional layer, where the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases, and for every two adjacent first electrodes, a pixel pitch between edges of a portion of the first electrode in contact with the light-emitting functional layer in a same light-emitting device is 2074 to 18000 nanometers, and a pixel density of the display panel is 90 to 5000 PPI.

In one embodiment of the sixth aspect of the present application, the display panel further includes a pixel defining layer, where the pixel defining layer is located on the first electrode and located on a side, facing the substrate, of the partition portion and defines a second opening, the pixel defining layer covers an edge of the first electrode, the second opening exposes the first electrode, and an edge of the second opening coincides with an edge of a portion of the first electrode in contact with the light-emitting functional layer in a same light-emitting device, a distance between an orthographic projection, on a plane where the substrate is located, of the edge of the second end portion and an orthographic projection, on the plane where the substrate is located, of the edge of the first end portion is a first width, a distance between the edge of the portion of the first electrode in contact with the light-emitting functional layer in the same light-emitting device and the orthographic projection, on the plane where the substrate is located, of the edge of the second end portion is a first spacing, the plurality of sub-pixels in a pixel are arranged in a first pixel arrangement manner, and the pixel density of the display panel is 170 to 3143 PPI. For example, the pixel pitch is 2200 to 2500 nanometers, and the pixel density of the display panel is 2171 to 3143 PPI; or the pixel pitch is 2500 to 3200 nanometers, and the pixel density of the display panel is 1577 to 2765 PPI; or the pixel pitch is 3200 to 4000 nanometers, and the pixel density of the display panel is 1063 to 2160 PPI; or the pixel pitch is 4000 to 6000 nanometers, and the pixel density of the display panel is 529 to 1728 PPI; or the pixel pitch is 6000 to 9000 nanometers, and the pixel density of the display panel is 353 to 1152 PPI; or the pixel pitch is 9000 to 13000 nanometers, and the pixel density of the display panel is 244 to 768 PPI; or the pixel pitch is 13000 to 18000 nanometers, and the pixel density of the display panel is 170 to 531 PPI.

In one embodiment of the sixth aspect of the present application, the display panel further includes a pixel defining layer, where the pixel defining layer is located on the first electrode and located on a side, facing the substrate, of the partition portion and defines a second opening, the pixel defining layer covers an edge of the first electrode, the second opening exposes the first electrode, and an edge of the second opening coincides with an edge of a portion of the first electrode in contact with the light-emitting functional layer in a same light-emitting device, a distance between an orthographic projection, on a plane where the substrate is located, of the edge of the second end portion and an orthographic projection, on the plane where the substrate is located, of the edge of the first end portion is a first width, a distance between the edge of the portion of the first electrode in contact with the light-emitting functional layer in the same light-emitting device and the orthographic projection, on the plane where the substrate is located, of the edge of the second end portion is a first spacing, the plurality of sub-pixels in a pixel are arranged in a second pixel arrangement manner, and the pixel density of the display panel is 260 to 4714 PPI. For example, the pixel pitch is 2200 to 2500 nanometers, and the pixel density of the display panel is 3256 to 4714 PPI; or the pixel pitch is 2500 to 3200 nanometers, and the pixel density of the display panel is 2366 to 4147 PPI; or the pixel pitch is 3200 to 4000 nanometers, and the pixel density of the display panel is 1594 to 3240 PPI; or the pixel pitch is 4000 to 6000 nanometers, and the pixel density of the display panel is 794 to 2592 PPI; or the pixel pitch is 6000 to 9000 nanometers, and the pixel density of the display panel is 529 to 1728 PPI; or the pixel pitch is 9000 to 13000 nanometers, and the pixel density of the display panel is 366 to 1152 PPI; or the pixel pitch is 13000 to 18000 nanometers, and the pixel density of the display panel is 260 to 797 PPI.

For example, the pixel pitch is 2000 to 2200 nanometers, and an average value of a width of a first sub-pixel, a width of a second sub-pixel and a width of a third sub-pixel is 450 to 1326 nanometers; or the pixel pitch is 2200 to 2500 nanometers, and the average value of the width of the first sub-pixel, the width of the second sub-pixel and the width of the third sub-pixel is 494 to 1700 nanometers; or the pixel pitch is 2500 to 3200 nanometers, and the average value of the width of the first sub-pixel, the width of the second sub-pixel and the width of the third sub-pixel is 563 to 2868 nanometers; or the pixel pitch is 3200 to 4000 nanometers, and the average value of the width of the first sub-pixel, the width of the second sub-pixel and the width of the third sub-pixel is 720 to 4767 nanometers; or the pixel pitch is 4000 to 6000 nanometers, and the average value of the width of the first sub-pixel, the width of the second sub-pixel and the width of the third sub-pixel is 900 to 11995 nanometers; or the pixel pitch is 6000 to 9000 nanometers, and the average value of the width of the first sub-pixel, the width of the second sub-pixel and the width of the third sub-pixel is 1350 to 18008 nanometers; or the pixel pitch is 9000 to 13000 nanometers, and the average value of the width of the first sub-pixel, the width of the second sub-pixel and the width of the third sub-pixel is 2025 to 25699 nanometers; or the pixel pitch is 13000 to 18000 nanometers, and the average value of the width of the first sub-pixel, the width of the second sub-pixel, and the width of the third sub-pixel is 4050 to 35846 nanometers.

In one embodiment, based on the above data, an aperture ratio of the display panel is 6 to 60%.

In one embodiment of the sixth aspect of the present application, the display panel further includes at least one optical functional layer, where the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases, and for every two adjacent first electrodes, a pixel pitch between edges of a portion of the first electrode in contact with the light-emitting functional layer in same light-emitting device is 2274 to 18000 nanometers, and a pixel density of the display panel is 90 to 4560 PPI.

In one embodiment of the sixth aspect of the present application, the display panel includes the plurality of pixels, where each of the plurality pixels includes a first sub-pixel, a second sub-pixel and a third sub-pixel with wavelengths of emergent light sequentially decreased, the first sub-pixel, the second sub-pixel and the third sub-pixel respectively include different light-emitting devices and are arranged in a plurality of rows and a plurality of columns, the first sub-pixel and the third sub-pixel are arranged in a same row of the plurality of rows and a same column of the plurality of columns, and the same row and the same column are different with a row and a column where the second sub-pixel located, in the same row and the same column where the first sub-pixel and the third sub-pixel are arranged, the first sub-pixel and the third sub-pixel are alternately arranged, the row where the first sub-pixel is arranged and the row where the second sub-pixel is arranged are alternately arranged, the column where the first sub-pixel is arranged and the column where the second sub-pixel is arranged are alternately arranged, each second sub-pixel is surrounded by two first sub-pixels and two third sub-pixels, a quadrangle formed by connecting centroids of the two first sub-pixels and the two third sub-pixels surrounding same second sub-pixel has at least two opposite edges that are parallel. In one embodiment, the pixel density of the display panel is 200-7400 PPI. In one embodiment, the pixel pitch is 2000 to 2200 nanometers, and the pixel density of the display panel is 249 to 7400 PPI; or the pixel pitch is 2200 to 2500 nanometers, and the pixel density of the display panel is 248 to 6778 PPI; or the pixel pitch is 2500 to 3200 nanometers, and the pixel density of the display panel is 245 to 6088 PPI; or the pixel pitch is 3200 to 4000 nanometers, and the pixel density of the display panel is 243 to 4921 PPI; or the pixel pitch is 4000 to 6000 nanometers, and the pixel density of the display panel is 236 to 4036 PPI; or the pixel pitch is 6000 to 9000 nanometers, and the pixel density of the display panel is 227 to 2785 PPI; or the pixel pitch is 9000 to 13000 nanometers, and the pixel density of the display panel is 216 to 1901 PPI; or the pixel pitch is 13000 to 16500 nanometers, and the pixel density of the display panel is 208 to 1335 PPI; or the pixel pitch is 16500 to 18000 nanometers, and the pixel density of the display panel is 200 to 1060 PPI.

In one embodiment of the sixth aspect of the present application, a centroid of the surrounded second sub-pixel is staggered with an intersection point of two diagonal lines of the quadrangle corresponding to the surrounded second sub-pixel, or the centroid of the surrounded second sub-pixel and the intersection point of the two diagonal lines of the quadrangle are overlapped. In one embodiment, the pixel pitch is 2000 to 2200 nanometers, and the pixel density of the display panel is 1600 to 3000 PPI; or the pixel pitch is 2200 to 2500 nanometers, and the pixel density of the display panel is 1400 to 2700 PPI; or the pixel pitch is 2500 to 3200 nanometers, and the pixel density of the display panel is 1200 to 2400 PPI; or the pixel pitch is 3200 to 4000 nanometers, and the pixel density of the display panel is 1000 to 2100 PPI; or the pixel pitch is 4000 to 6000 nanometers, and the pixel density of the display panel is 800 to 1800 PPI; or the pixel pitch is 6000 to 9000 nanometers, and the pixel density of the display panel is 600 to 1500 PPI; or the pixel pitch is 9000 to 13000 nanometers, and the pixel density of the display panel is 400 to 1200 PPI; or the pixel pitch is 13000 to 16500 nanometers, and the pixel density of the display panel is 300 to 900 PPI; or the pixel pitch is 16500 to 18000 nanometers, and the pixel density of the display panel is 200 to 800 PPI.

According to a seventh aspect, the present application provides a display panel, which may include the display panel above-mentioned in any one of the first aspect to the sixth aspect.

### BRIEF DESCRIPTION OF THE DRAWINGS

FIG. 1 is a schematic diagram of a planar structure of a display panel according to an embodiment of the present application.

FIG. 2 is a partial enlarged schematic diagram of an S region of the display panel shown in FIG. 1.

FIG. 3 is a cross-sectional view of a partial structure of a region where a sub-pixel is located of the display panel shown in FIG. 1 and FIG. 2 under a design, which may correspond to a cross-section of FIG. 2 along M1-N1.

FIG. 4 is a cross-sectional view of a partial structure of a region where a sub-pixel is located of the display panel shown in FIG. 1 and FIG. 2 under another design, which may correspond to a cross-section of FIG. 2 along M1-N1.

FIG. 5 is a cross-sectional view of a partial structure of a partial region of a display panel according to an embodiment of the present application.

FIG. 6 is a cross-sectional view of a partial structure of a partial region of a display panel according to an embodiment of the present application.

FIG. 7 is a cross-sectional view of a partial structure of a partial region of a display panel according to an embodiment of the present application.

FIG. 8A is a cross-sectional view of a partial structure of a partial region of a display panel according to an embodiment of the present application.

FIG. 8B is a cross-sectional view of a partial structure of a partial region of a display panel according to an embodiment of the present application.

FIG. 9 is a cross-sectional view of a partial structure of a partial region of a display panel according to an embodiment of the present application.

FIG. 10 to FIG. 13 are diagrams of a manufacturing process of the display panel shown in FIG. 9.

FIG. 14 is an enlarged schematic diagram of a partial structure of a display panel according to an embodiment of the present application, and a schematic diagram of a cross-sectional view of the display panel along M2-N2 may be shown in FIG. 3 or FIG. 4.

FIG. 15 is an enlarged schematic diagram of a partial structure of a display panel according to an embodiment of the present application, and a schematic diagram of a cross-sectional view of the display panel along M3-N3 may be shown in FIG. 3 or FIG. 4.

FIG. 16 is a cross-sectional view of a partial structure of a partial region of a display panel according to an embodiment of the present application.

FIG. 17 is a cross-sectional view of a partial structure of a partial region of a display panel according to an embodiment of the present application.

FIG. 18 is a cross-sectional view of a partial structure of a partial region of a display panel according to an embodiment of the present application.

FIG. 19 is a cross-sectional view of a partial structure of a partial region of a display panel according to an embodiment of the present application.

FIG. 20 is a cross-sectional view of a partial structure of a partial region of a display panel according to an embodiment of the present application.

FIG. 21A is a cross-sectional view of a partial structure of a partial region of a display panel according to an embodiment of the present application.

FIG. 21B is a cross-sectional view of a partial structure of a partial region of a display panel according to an embodiment of the present application.

FIG. 21C is a cross-sectional view of a partial structure of a partial region of a display panel according to an embodiment of the present application.

FIG. 22 is a cross-sectional view of a partial structure of a partial region of a display panel according to an embodiment of the present application.

FIG. 23A is a cross-sectional view of a partial structure of a partial region of a display panel according to an embodiment of the present application.

FIG. 23B is a cross-sectional view of a partial structure of a partial region of a display panel according to an embodiment of the present application.

FIG. 23C is a cross-sectional view of a partial structure of a partial region of a display panel according to an embodiment of the present application.

FIG. 24 is a cross-sectional view of a partial structure of a partial region of a display panel according to an embodiment of the present application.

FIG. 25 is a cross-sectional view of a partial structure of a partial region of a display panel according to an embodiment of the present application.

FIG. 26A is a cross-sectional view of a partial structure of a partial region of a display panel according to an embodiment of the present application.

FIG. 26B is a cross-sectional view of a partial structure of a partial region of a display panel according to an embodiment of the present application.

FIG. 27 is a cross-sectional view of a partial structure of a partial region of a display panel according to an embodiment of the present application.

FIG. 28A is a cross-sectional view of a partial structure of a partial region of a display panel according to an embodiment of the present application.

FIG. 28B is a cross-sectional view of a partial structure of a partial region of a display panel according to an embodiment of the present application.

FIG. 29 is a cross-sectional view of a partial structure of a partial region of a display panel according to an embodiment of the present application.

FIG. 30 is a cross-sectional view of a partial structure of a partial region of a display panel according to an embodiment of the present application.

FIG. 31 is a cross-sectional view of a partial structure of a partial region of a display panel according to an embodiment of the present application.

FIG. 32 is a cross-sectional view of a partial structure of a partial region of a display panel according to an embodiment of the present application.

FIG. 33 is a cross-sectional view of a partial structure of a partial region of a display panel according to an embodiment of the present application.

FIG. 34A is a cross-sectional view of a partial structure of a partial region of a display panel according to an embodiment of the present application.

FIG. 34B is a cross-sectional view of a partial structure of a partial region of a display panel according to an embodiment of the present application.

FIG. 35A is a cross-sectional view of a partial structure of a partial region of a display panel according to an embodiment of the present application.

FIG. 35B is a cross-sectional view of a partial structure of a partial region of a display panel according to an embodiment of the present application.

FIG. 36 is a cross-sectional view of a partial structure of a partial region of a display panel according to an embodiment of the present application.

FIG. 37 is an enlarged diagram of a partial structure of a pixel of a display panel according to an embodiment of the present application.

FIG. 38 is a cross-sectional view of a partial structure of a partial region of a display panel according to an embodiment of the present application.

FIG. 39 is a cross-sectional view of a partial structure of a partial region of a display panel according to an embodiment of the present application.

FIG. 40 is a cross-sectional view of a partial structure of a partial region of a display panel according to an embodiment of the present application.

FIG. 41 is a cross-sectional view of a partial structure of a partial region of a display panel according to an embodiment of the present application.

FIG. 42 is a cross-sectional view of a partial structure of a partial region of a display panel according to an embodiment of the present application.

FIG. 43 is a cross-sectional view of a partial structure of a partial region of a display panel according to an embodiment of the present application.

FIG. 44 is a schematic diagram of a relationship between pixel density and pixel pitch in a display panel in a pixel arrangement manner according to an embodiment of the present application.

FIG. 45 is a schematic diagram of a relationship between pixel density and pixel pitch in a display panel in another pixel arrangement manner according to an embodiment of the present application.

FIG. 46 is an enlarged diagram of a partial structure of another pixel of a display panel according to an embodiment of the present application, a schematic diagram of the display panel along M4-N4 may be shown in FIG. 3 or FIG. 4.

FIG. 47 is a schematic diagram of a relationship between pixel density and pixel pitch in a display panel in the pixel arrangement manner shown in FIG. 46.

FIG. 48 is a cross-sectional view of a substrate in a display panel according to an embodiment of the present application, which shows a cross-sectional view of a first type of thin film transistor included in a pixel driving circuit in one form.

FIG. 49 is a cross-sectional view of a substrate in a display panel according to an embodiment of the present application, which shows a cross-sectional view of a first type of thin film transistor and a second type of thin film transistor included in a pixel driving circuit.

FIG. 50 is a cross-sectional view of a substrate in a display panel according to an embodiment of the present application, which shows a cross-sectional view of a first type of thin film transistor included in a pixel driving circuit in another form.

FIG. 51 is a partial enlarged schematic diagram of an S region of the display panel shown in FIG. 1 in a pixel arrangement manner.

FIG. 52 is a cross-sectional view of the display panel shown in FIG. 51 along M5-N5.

FIG. 53 is a partial enlarged schematic diagram of an S region of the display panel shown in FIG. 1 in another pixel arrangement manner.

FIG. 54 is a cross-sectional view of the display panel shown in FIG. 53 along M6-N6 under a structural design.

FIG. 55 is a cross-sectional view of the display panel shown in FIG. 53 along M6-N6 under another structural design.

### BRIEF DESCRIPTION OF THE DRAWINGS

100—substrate; 200—light-emitting device; 210—first electrode; 220—light-emitting functional layer; 221—first functional layer; 222—light-emitting layer; 223—second functional layer; 202—effective functional region; 230—second electrode; 300—isolation structure; 301—first opening; 302—second opening; 310—first end portion (supporting portion); 311—sub-supporting portion; 320—second end portion (blocking portion); 330—pixel defining layer; 340—connecting portion; 400—color conversion layer; 410—color conversion unit; 510—first encapsulation layer; 520—second encapsulation layer; 530—third encapsulation layer; 500—photoresist pattern; 600—filling layer; 710—optical extraction layer; 711—optical extraction unit; 720—optical regulating layer; 721—optical regulating unit; 810—blocking portion; 820—filter unit; 910—protective layer; 911—protective unit.

### DETAILED DESCRIPTIONS OF THE EMBODIMENTS

The embodiments of the present application will be clearly and completely described below with reference to the accompanying drawings in the embodiments of the present application.

In a display product, some of functional film layers in a light-emitting device may be formed by vapor deposition method, and there are a plurality of functional film layers in each light-emitting device and materials of some of the functional film layers (for example, the light-emitting layer) in the light-emitting device emitting different light rays are different, and when the functional film layers are vapor-deposited by using a mask (for example, FMM, Fine Metal Mask), multiple alignments need to be performed. In order to resolve a problem of position offset caused by an alignment precision error, a sufficient space (and a safety margin related to an alignment error) needs to be reserved between different light-emitting devices to ensure that a position of an actual light-emitting region of the light-emitting device can have a certain overlap rate with a design position (a design area), which is equivalent to compressing the design area of the light-emitting region of the light-emitting device, and a light-emitting area of the light-emitting device is limited, and an arrangement density of the light-emitting device (corresponding to a sub-pixel) cannot be further increased, thereby it is difficult to further improve a pixel density of a display panel.

In the present application, isolation structure is provided at a gap of the light-emitting device to isolate the functional film layers of adjacent light-emitting devices, in this way, in a vapor deposition process of the plurality of functional film layers, only whole surface of the display panel needs to be vapor-deposited, and an area where the light-emitting device is located does not need to be vapor-deposited by means of a mask to form the functional film layers. Therefore, the vapor deposition process using the isolation structure does not need to consider a problem of alignment precision during a vapor deposition, and the gap of the light-emitting device can be designed to be smaller in size to increase the pixel density (a principle thereof can be referred to related descriptions in embodiments related to FIG. 10 to FIG. 13).

In the above design, the isolation structure surrounds the light-emitting device, and in the vapor deposition process, in view of a vapor deposition source used for vapor-depositing the functional film layer has a vapor deposition angle, a height, a width, and the like of the isolation structure may affect a distribution of a vapor-deposited film layer. A light-emitting efficiency of the light-emitting region of the light-emitting device is related to a vapor deposition quality of the functional film layers, because of an existence of the vapor deposition angle during the vapor deposition and a shielding of a vapor deposition material by the isolation structure, a thickness of the functional film layer may be gradually decreases in an edge region of the functional film layer (such as a first functional layer, a light-emitting layer, a second light-emitting layer, and a second electrode), thereby affecting the light-emitting efficiency. Therefore, a portion, having a uniform thickness, of the functional film layer is distributed in the light-emitting region as much as possible, to ensure that any position of the light-emitting region of the light-emitting device has a relatively high light-emitting efficiency, and the light-emitting region integrally emits light uniformly, therefore, in practice, a portion, having a uniform thickness, of the functional film layer (an effective functional region described below) limits a design boundary (not necessarily overlapping) of the light-emitting region, that is, a boundary of the effective functional region may be obtained first to further determine a main light-emitting region of the light-emitting region (the light-emitting efficiency is uniform, and a light with better quality may be emitted).

It should be noted that a range of the effective functional region is limited by the light-emitting functional layer, and the light-emitting region and the main light-emitting region of the display device are limited by the light-emitting functional layer and the first electrode. For example, taking the light-emitting functional layer to define the effective functional region as an example, a region where a portion, having a uniform thickness, of the light-emitting functional layer is located is an effective functional region; a region where the first electrode and the light-emitting functional layer in the light-emitting device are in contact corresponds to the light-emitting region of the light-emitting device; and in the light-emitting device, a region where the first electrode overlaps and contacts the effective functional region is a main light-emitting region (the region emits light uniformly).

In a case that a size of the light-emitting device and the isolation structure is designed, how to plan parameters such as the height and the width of the isolation structure based on the vapor deposition angle, a distribution position of the functional film layer, and the like, to enable the light-emitting device to have a relatively smaller spacing to increase PPI while maintaining good light-emitting efficiency of the light-emitting device, is an important topic that needs to be studied in a structural design of the display panel.

Furthermore, for the display panel in different display modes and specific function requirements in the display panel, the isolation structure may be modified or other functional structures (such as the color conversion layer in the following embodiments) may be provided based on the isolation structure, in this case, a height, parameters, and the like of the isolation structure need to be adjusted, and when the functional structures are formed by means of the isolation structure, a manufacturing cost can be reduced, related errors are reduced, and the pixel density of a product is improved.

Embodiments of the present application provide a display panel to solve at least some of the above problems. The display panel includes a substrate, a display functional layer and an isolation structure. The display functional layer includes a plurality of light-emitting devices, each light-emitting device of the plurality of light-emitting devices includes a first electrode, a light-emitting functional layer and a second electrode sequentially stacked on the substrate, and the display functional layer includes an effective functional region, a film thickness of a portion, located in the effective functional region, of the first functional layer is uniform. The isolation structure includes a partition portion, the partition portion is located on the substrate and surrounds the light-emitting functional layer. The partition portion includes a first end portion facing the substrate and a second end portion facing away from the substrate, an orthographic projection, on a plane where the substrate is located, of the effective functional region is located outside an orthographic projection, on the plane where the substrate is located, of the second end portion of the isolation structure, an orthographic projection, on the plane where the substrate is located, of an edge of the first functional layer is located outside an orthographic projection, on the plane where the substrate is located, of the first end portion, and located within an orthographic projection, on the plane where the substrate is located, of the second end portion. On a cross-section perpendicular to the substrate and on a same side of the isolation structure, an acute angle formed by intersecting a straight line determined by the edge of the first functional layer and an edge of the second end portion with the plane where the substrate is located is a second inclination angle, a tangent value of an acute angle formed by intersecting a straight line determined by an edge of the effective functional region and the edge of the second end portion with the plane where the substrate is located is not greater than a tangent value of the second inclination angle, and a ratio of a height difference between an edge of the first end portion and the edge of the second end portion along a direction perpendicular to the plane where the substrate is located and a distance between the edge of the first end portion and the edge of the second end portion along a direction parallel to the plane where the substrate is located is not greater than the tangent value of the second inclination angle.

When facing a specific pixel density design requirement, a sum of a width (simply referred to as a sub-pixel width) of a main light-emitting region of the light-emitting device and a gap between adjacent main light-emitting regions may be directly calculated, where the width of the main light-emitting region may be determined based on the effective functional region, that is, if an optional range of a boundary position of the effective functional region can be defined, an optional range of a boundary position of the main light-emitting region can be inferred. Based on the design in the above embodiments of the present application, a first vapor deposition angle is determined through a boundary of the effective functional region and a height of the second end portion (the edge thereof), and an extension position of the edge of the first functional layer is determined according to a height of the first vapor deposition angle and the height of the second end portion, and a distance between the extension position and the second end portion can be inferred based on a principle that the first functional layer is separated by the partition portion, and an optional range of a position the edge of the second end portion can be inferred, thus, relationship between parameters of the edge of the effective functional region, the edge of the first functional layer, the width of the isolation structure (positions of edges of the first end portion and the second end portion) and the height of the isolation structure (a height difference of the edge of the first end portion and the edge of the first second portion), and a vapor deposition angle can be constructed, and in combination with an optional range (including the lower limit value) of a width dimension of the first end portion, an optional width range of the effective functional region can be reversely deduced, and an optional width range (including a maximum width) of the main light-emitting region can be deduced, and under the specific pixel density design requirement, a maximum design width of the main light-emitting region can be obtained to ensure a design area of the main light-emitting region under an actual process (a width of the design area may be equal to the maximum design width or slightly smaller than the maximum design width).

It should be noted that, in a process of preparing the isolation structure, an alignment precision problem may need to be considered, and therefore, a design width of the main light-emitting region may be selected to be slightly smaller than the maximum design width calculated in the foregoing method to provide a security margin for the alignment precision error of the isolation structure; furthermore, according to the above design, it can also be obtained that the boundary of the effective functional region is determined by design parameters of the isolation structure and the vapor deposition angle, and when a position of the isolation structure is fixed, a position of the boundary is not affected by the alignment precision during vapor deposition.

A structure of the display panel in at least one embodiment of the present application will be described in detail below with reference to the accompanying drawings. In addition, in these drawings, a space rectangular coordinate system is established based on the substrate to present a positional relationship of related structures in the display panel more intuitively, and in the space rectangular coordinate system, an X-axis and a Y-axis are parallel to the plane where the substrate is located, and a Z-axis is perpendicular to the plane where the substrate is located. It should be noted that an orientation of “above” and “below” may be determined based on the substrate, for example, a direction, facing a display side (for example, a side of the light-emitting device facing away from the substrate), of the substrate represents the orientation “above”, and a direction, facing away from the display side, of the substrate represents the orientation of “below”. For example, if a first object is located between a second object and the substrate, the second object is located above the first object, and the first object is located below the second object.

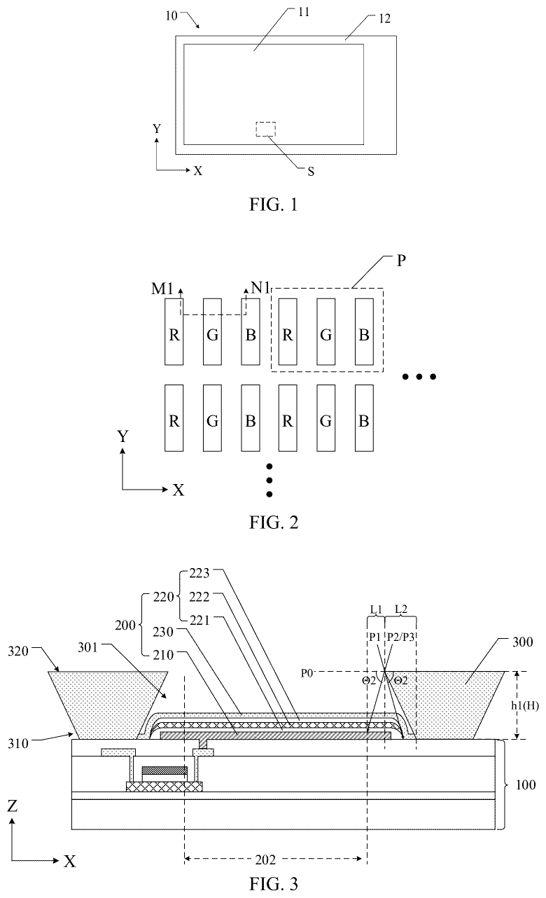

As shown in FIG. 1 to FIG. 3, a planar region of the display panel 10 may be divided into a display region 11 and a frame region 12 surrounding the display region 11, and sub-pixels (which may be referred to as sub-pixels, and so on.) such as R, G, and B may be arranged in the display region 11, a solid structure of a sub-pixel may be the light-emitting device, a pixel P may be formed by adjacent sub-pixels with different colors of emergent light (which may be referred to as a pixel unit, a large pixel, and so on), an arrangement density of the pixel P in the display region 11 represents the display density. It should be noted that, in some embodiments of the present application, some wirings in the bezel region 12 may be arranged in the display region 11, and the bezel region 12 may be designed as a single-sided bezel.

In at least the display region 11, a solid structure of the display panel 10 may include a substrate 100 and a display functional layer and an isolation structure 300 located on the substrate 100, the display functional layer includes a plurality of light-emitting devices 200. Each of the light-emitting devices 200 includes a first electrode 210, a light-emitting functional layer 220, and a second electrode 230 stacked on the substrate 100, the light-emitting functional layer 220 includes an effective functional region 202, and the light-emitting functional layer 220 includes a first functional layer 221.

For example, the light-emitting functional layer may further include a light-emitting layer 222 and a second functional layer 223, and the first functional layer 221, the light-emitting layer 222, and the second functional layer 223 are sequentially stacked on the first electrode 210. The first functional layer 221 may include a hole injection layer, a hole transport layer, an electron blocking layer, and the like. The second functional layer 223 may include an electron injection layer, an electron transport layer, a hole blocking layer, and the like.

In embodiments of the present application, a condition that an influence of a film thickness of the second electrode 230 on a light-emitting efficiency and a light-emitting uniformity of the light-emitting layer is not considered, the “effective functional region” is a region with a uniform thickness of at least one film layer of the light-emitting functional layer, and a type of the “at least one film layer” may be selected according to requirements of an actual process. For example, the “at least one film layer” may be any one or a combination of the first functional layer 221, the light-emitting layer 222, and the second functional layer 223. Specifically, only a thickness of the first functional layer 221 in the effective functional region is uniform, or the thickness of the first functional layer 221 and a thickness of the light-emitting layer 222 in the effective functional region are uniform, or the thicknesses of the first functional layer 221, the thickness of the light-emitting layer 222 and a thickness of the second functional layer 223 in the effective functional region are uniform.

For example, in at least one embodiment of the present application, the first electrode may be set as an anode, and the second electrode may be set as a cathode.

The isolation structure 300 includes a partition portion located on the substrate 100, the partition portion defines a plurality of first openings 301, the light-emitting functional layer 220 and the second electrode 230 are located in each of the plurality of first openings 301, the partition portion includes a conductive portion, and the second electrode 230 is connected to the conductive portion of the partition portion. In this way, an overall structure of the partition portion has a shape of a grid, and the first opening 301 is an opening of the grid. It should be noted that the first opening 301 is a space enclosed by the partition portion, and an edge of the first opening 301 may be determined according to a specified height position (a different distance to the substrate 100), for example, when a width of the first end portion 310 is less than a width of the second end portion 320, an opening width defined by an edge of the first opening 301 at an edge of the first end portion 310 is greater than an opening width defined by an edge of the first opening 301 at an edge of the second end portion 320.

The partition portion is integrally presented to have a shape of “wide top and a narrow bottom”, and the first functional layer 221 is disconnected from other portions formed on the partition portion due to shielding of the isolation structure in a vapor deposition process. For example, an orthographic projection, on the plane where the substrate 100 is located, of the first end portion 310, facing the substrate, of the partition portion is located within an orthographic projection, on the plane where the substrate 100 is located, of the second end portion 320, facing away from the substrate 100, of the partition portion, and an orthographic projection, on the plane where the substrate 100 is located, of an edge of the first functional layer 221 is located outside the orthographic projection, on the plane where the substrate 100 is located, of the first end portion 310, and is located within the orthographic projection, on the plane where the substrate 100 is located, of the second end portion 320, that is, the first functional layer 221 formed by an vapor deposition method is not connected to the conductive portion (for example, the first end portion 310) of the isolation structure 300. On a cross-section perpendicular to the substrate 100 and on a same side of the isolation structure, an acute angle formed by intersecting a straight line P1 determined by the end of the second end portion 320 and the edge of the first functional layer 221 with the plane where the substrate 100 is located (parallel to a straight line P0) is a second inclination angle Θ2. In a case that a boundary of the effective functional region 202 is defined by an edge of a portion with a uniform film thickness of the first functional layer 221, an acute angle determined by a straight line P2 determined by the edge of a portion with a uniform film thickness of the first functional layer 221 and the edge of the second end portion 320 and the straight line P0 is equal to a second inclination angle Θ2, and correspondingly, an acute angle formed by an edge of the effective functional region 202 and the edge of the second end portion 320 and the plane where the substrate 100 is located is also the second inclination angle Θ2.

It should be noted that the plane where the substrate is located is a virtual plane, and corresponds to a surface of a planar structure that can carry the substrate. In the drawings of the present specification, some angles are angles equal in size by means of parallel planes or parallel straight lines of a plane or a straight line, for example, the second inclination angle is shown by a straight line P0 corresponding to a plane parallel to the plane where the substrate is located.

A tangent value of the acute angle formed by the edge of the effective functional region 202 and the edge of the second end portion 320 and the plane where the substrate 100 is located is not greater than a tangent value of the second inclination angle Θ2, and in this relationship, it can be ensured that a film thickness of the first functional layer 221 in the effective functional region 202 is uniform, where, in a “equal” relationship, it is equivalent that the edge of the first functional region 221 defines the boundary of the effective functional region 202.

For example, a ratio of a height difference h1 between the edge of the first end portion 310 and the edge of the second end portion 320 along the direction perpendicular to the plane where the substrate 100 is located to a first width L2 between the edge of the first end portion 310 and the edge of the second end portion 320 along the direction parallel to the plane where the substrate is located is not greater than the tangent value tan Θ2 of the second inclination angle Θ2, that is, L2≥h1/tan Θ2. In this way, in an actual process, a partition effect of the isolation structure on the first functional layer 221 can be ensured, and it that a uniform film thickness of a portion, located in the effective functional region 202, of the first functional layer 221 can be ensured. For example, in a case that the boundary of the effective functional region 202 by the edge of the portion with a uniform film thickness of the first functional layer 221, if L2=h1/tan Θ2, the boundary of the first functional layer 221 just extends to the edge of the first end portion 310, and as a thickness of the film layer decreases gradually, the film thickness of the first functional layer 221 is infinitely close to zero (a resistance is infinite); if L2>h1/2, the first functional layer 221 and the first end portion 310 do not contact with each other and there is a gap between the first functional layer 221 and the first end portion 310, and correspondingly, the isolation structure completely partitions the first functional layer 221.

For example, the second inclination angle Θ2 is actually a vapor deposition angle when the first functional layer 221 is vapor-deposited, and because the first functional layer 221 needs to be spaced apart from the isolation structure, a relatively small design size is required, in view of a case that the larger the vapor deposition angle, the larger a distance between the edge of the first functional layer 221 and the isolation structure, and the first width L2 of the edge of the first end portion 310 and the edge of the second end portion 320 in a transverse direction (for example, a direction parallel to the X-axis) has a relatively small design size, thereby reducing a spacing of the light-emitting device 200. Therefore, in some embodiments, the second inclination angle Θ2 may correspond to the vapor deposition angle of the vapor deposition source as large as possible.

It should be noted that the “vapor deposition angle” is an acute angle formed by a straight line corresponding to a boundary of material radiation range of the vapor deposition source and the plane where the substrate is located, in other words, it may be considered that when a vapor deposition is performed at a certain the vapor deposition angle, a range of a vapor deposition material does not exceed a boundary of the vapor deposition angle corresponding to the vapor deposition material because of a blocking of the isolation structure.

In an embodiment of the present application, the orthographic projection, on the plane where the substrate 100 is located, of the effective functional region 202 is located outside the orthographic projection, on the plane where the substrate 100 is located, of the second end portion 320, and an acute angle formed by the straight line P3 determined by the edge of the effective functional region 202 and the edge of the second end portion 320 and the plane where the substrate 100 is located (parallel to the line P0) is less than or equal to the second inclination angle Θ2. As shown in FIG. 3, that is, a height difference of an outer edge of the first end portion 310 and an outer edge of the second end portion 320 is h1, the distance between the edge of the effective functional region 202 and the edge of the second end portion 320 in the transverse direction (denoted as a second spacing based on following embodiments) is L1, the straight lines P1 and P2 determine a distribution boundary of the vapor deposition material under a blocking of the second end portion 320 when the vapor deposition source is at different positions, and where L1=h1/tan Θ1 is met, an included angle between P3 and P0 is equal to Θ1.

It should be noted that the outer edge of the first end portion 310 may also be referred to as the edge of the first end portion 310, and the outer edge of the second end portion 320 may also be referred to as an edge of the second end portion 320.

It should be noted that, a distance between the outer edge of the second end portion 320 and a boundary of a portion with a uniform thickness of a target film layer in a direction of Z-axis is “H”. For example, for a structure shown in FIG. 3 (for example, a pixel defining layer in following embodiments), if a thickness of the first electrode 210 is ignored, a bottom of the isolation structure and an outer edge of the first functional layer 221 are approximately at same layer, then the formula L1=h1/tan Θ1 may be replaced with L1=h/tan Θ1 If the thickness of the first electrode 210 is calculated, the thickness of the first electrode 210 needs to be subtracted by “H” in the formula L1=h/tan Θ1.

It should be noted that, in a case of L1=h1/tan Θ1, when the first functional layer 221 is vapor-deposited, even if the vapor deposition source is directly aligned with the isolation structure 300 (the vapor deposition angle determined by the straight line P2 and a vapor deposition boundary), the vapor deposition material may still fall into the effective functional region 202, and the first functional layer 221 in the effective functional region 202 can be vapor-deposited at any position and the film thickness is uniform, and in this case, a width of the second spacing L1 is a minimum design width that the uniform film thickness of the first functional layer 221 in the effective functional region 202 can be ensured, and when a gap of the light-emitting device 200 is designed based on the minimum design width, a relatively small gap can be provided between the sub-pixels.

It should be noted that, in the embodiments of the present application, the vapor deposition of the film layer in a certain region is presented as “uniform”, which is a macroscopic representation, and specifically, it is may be that partial regions of a lower surface of a corresponding film layer and an upper surface of a corresponding film layer are all parallel to the plane of the plane where the substrate is located, and correspondingly, a thickness of the film layer in the partial regions is consistent; it may be that the film layer is vapor-deposited at a region parallel to the plane where the substrate is located, and there is no other structure to block the vapor deposition source during an entire vapor deposition process, and the thickness of the film layer in the region is consistent; in a case that a certain film layer is not specifically described, a thickness of the certain film layer referred to refers to the thickness of the certain film layer in such regions.

For the first functional layer, if a boundary of the effective functional region is used as a boundary of a change of a film thickness uniformity of the first functional layer, in the effective functional region, a vapor deposition of the first functional layer is not blocked by the partition portion all the time, but outside the effective functional region, the vapor deposition of the first functional layer is shielded by the partition portion in a certain time period (a relative position of the vapor deposition source and the display panel is changed), and the farther the effective functional region is, the longer the time that the first functional layer is shielded in the vapor deposition process, the smaller the film thickness obtained finally in the vapor deposition process. In this way, the “uniform” of the film layer mentioned in the embodiments of the present application ignores an uneven of the vapor deposition of the film layer itself at a microscopically, the uneven at a microscopically is limited by conditions of the vapor deposition process, and is generally present on an entire film layer.

Furthermore, it should be noted that, in the foregoing embodiment, if only the thickness uniformity of the first functional layer in the effective functional region is considered, the edge of the portion with a uniform film thickness of the first functional layer may be used as the boundary of the effective functional region, and correspondingly, a maximum boundary of a main light-emitting region is also the edge of the portion with a uniform film thickness of the first functional layer

It should be noted that, in the embodiments of the present application, in a case of ensuring that the partition portion have a shape of “wide top and a narrow bottom”, a setting manner of the isolation structure is not limited, and the following embodiments briefly describes several setting manners of the isolation structure.

In some embodiments of the present application, as shown in FIG. 3, an isolation structure is an integral structure, that is, the integral structure may be an independent film layer, and there is no physical interface in the film layer, and at least a first end portion 310 and a second end portion 320 in the isolation structure are two portions in the integral structure. For example, further, along a direction perpendicular to a substrate 100, a cross-sectional profile of a portion, located between two adjacent sub-pixels, of the partition portion is an inverted trapezoid, a top edge of the inverted trapezoid faces the substrate 100, that is, the top edge of the inverted trapezoid is located between the substrate 100 and a bottom edge of the inverted trapezoid, and an edge of a surface, facing the surface of the substrate 100, of the first end portion 310 is an edge of the first end portion 310, and an edge of a surface, facing away from the substrate 100, of the second end portion 320 is an edge of the second end portion 320. In this design, a sidewall of the isolation structure is an inscribed structure, thereby increasing an isolation effect of the isolation structure.

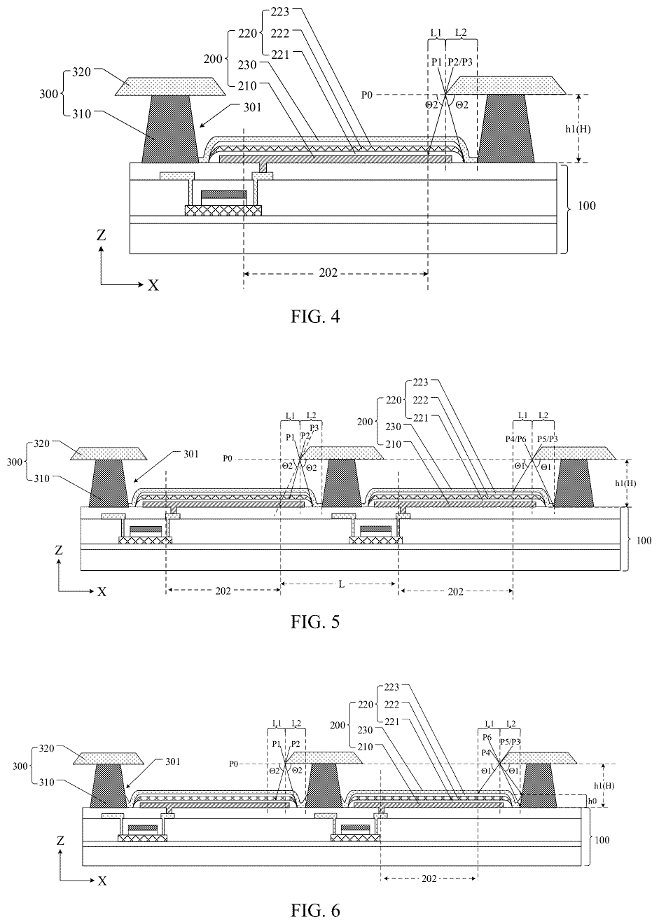

In some other embodiments of the present application, as shown in FIG. 4, a partition portion includes a supporting portion and a blocking portion sequentially stacked on a substrate 100, the supporting portion forms a first end portion 310, the blocking portion forms a second end portion 320. For example, further, along a direction perpendicular to the substrate 100, a cross-sectional profile of a portion, located between two adjacent sub-pixels, of the supporting portion 310 is a regular trapezoid, and the blocking portion 320 is located on a top edge of the supporting portion 310, in this case, an edge of a surface, facing the surface of the substrate 100, of the supporting portion 310 is the edge of the first end portion 310. In this case, a vapor deposition material of the second electrode 230 may be conveniently deposited on a sidewall of the supporting portion 310 to improve a lap joint yield of a second electrode 230 and the supporting portion 310. For example, further, along the direction perpendicular to the substrate 100, a cross-sectional profile of a portion, located between two adjacent sub-pixels, of the blocking portion 320 is a regular trapezoid, and an edge of a surface, facing the supporting portion 310, of the blocking portion 320 is an edge of the second end portion 320.

It should be noted that, in the embodiments of the present application, the regular trapezoidal and the inverted trapezoidal mentioned may be strictly regular trapezoidal and inverted trapezoidal; or may be substantially presented in shape, for example, a top and a bottom thereof are parallel or conformal (a surface of one side is substantially simultaneously raised and lowered along with a surface of another side), and a size of the bottom is greater than a size of the top, and shapes of edges on two sides thereof are substantially axisymmetric; for example, a shape of the top, bottom, and edges on two sides thereof may not be limited to a plane.

In the embodiments of the present application, a vapor deposition angle during a second electrode 230 is vapor-deposited is generally less than a second inclination angle Θ2, thereby ensuring that the second electrode 230 is overlapped with a first end portion 310. In this case, if it is ensured that a film thickness of the second electrode 230 in an effective functional region 202 is uniform, a minimum size of a second spacing L1 needs to be defined.

For example, as shown in FIG. 5, on a cross-section perpendicular to a plane where a substrate 100 is located and on a same side of an isolation structure 300, an acute angle formed by a straight line P4 determined by an edge of a second electrode 230 and an edge of a second end portion 320 and the plane where the substrate 100 is located is a first inclination angle Θ1, the first inclination angle Θ1 is less than a second inclination angle Θ2, an acute angle formed by a straight line P3 determined by an edge of the effective functional region 202 and the edge of the second end portion 320 and the plane where the substrate 100 is located is less than or equal to the first inclination angle Θ1, in this case, an acute angle formed by P3 and P0 has been less than the second inclination angle Θ2, that is, in a case that L2 in FIG. 5 is approximately equal to L2 in FIG. 4, a second spacing L1 in FIG. 5 is greater than the second spacing L1 in FIG. 4.

The first inclination angle Θ1 is actually the vapor deposition angle when the second electrode 230 is vapor-deposited, and when the smaller the vapor deposition angle, the larger an area of a contact surface between the edge of the second electrode 230 and the isolation structure, accordingly, a first width L2 of an edge of the first end portion 310 and the edge of the second end portion 320 in a transverse direction (for example, a direction parallel to the X-axis) may be allowed to be a relatively small size, thereby reducing a spacing between adjacent light-emitting devices 200, and therefore, in some embodiments, the first inclination angle Θ1 may correspond to a minimum vapor deposition angle of a vapor deposition source. An included angle between a straight line P5 and the straight line P0 is the first inclination angle Θ1, that is, a position where the straight line P5 intersects the second electrode 230 is a critical position that whether the thickness of the second electrode 230 starts to be uneven or not, in a case that the acute angle formed by the straight line P3 and the straight line P0 is less than or equal to first inclination angle Θ1, the critical position having an uneven thickness will coincide with a position where the straight line P3 intersects the second electrode 230, or located between the position where the straight line P3 intersects the second electrode 230 and the isolation structure, and a case that a thickness of all film layers in the second electrode 230 and the light-emitting functional layer 220 in the effective functional region 202 are uniformly distributed can be ensured, to obtain a minimum design size of the edge of the effective functional region 202 and the edge of the second end portion 320 in the transverse direction as much as possible, and therefore, a minimum spacing L between adjacent effective functional regions 202 can be obtained as much as possible, and the pixel density is improved while a situation that a first functional layer 221 is separated by the isolation structure 300 is maintained.

In some embodiments of the present application, without considering a contact area between a light-emitting functional layer and an anode (for example, a size of the anode is designed to have sufficient contact area with the light-emitting functional layer), a range of an effective functional region may be defined only through a boundary of a portion having uniform thickness of related film layer (for example, a first functional layer or all film layers) in the light-emitting functional layer. As long as it is ensured that carriers (for example, electrons) can be provided to the light-emitting functional layer, in a case a thickness is sufficient, even if a thickness of the second electrode is uneven, it may be considered that whether a light-emitting efficiency of the light-emitting device is uniformly distributed or not may not be affected by a portion having uneven thickness.

In some other embodiments of the present application, in view of a requirement that a light transmittance of a second electrode is improved, a thickness of the second electrode is limited, and in some solutions, it is necessary to make a thickness of a portion, located in a main light-emitting region, of the second electrode as uniform as possible. For example, if a film thickness of a portion where the second electrode overlaps an effective functional region is to be uniform, a boundary of the effective functional region may be further defined by an edge of a portion having uniform film thickness of the second electrode, in this case, an area of the effective functional region may be smaller than an area of a portion having a uniform film thickness of the light-emitting functional layer (for example, the area of the portion having a uniform film thickness of the light-emitting functional layer and an area of a portion having a uniform film thickness of a first functional layer), in this case, a thickness of the light-emitting functional layer and a thickness of the second electrode in the effective functional region are uniform, and correspondingly, a maximum boundary of a main light-emitting region is also an edge of the portion having a uniform film thickness of the second electrode.

In at least one embodiment of the present application, a vapor deposition angles of a film layer, such as a light-emitting layer, a second functional layer 223, and the like located on a first functional layer 221 are generally less than or equal to a vapor deposition angle of the first functional layer 221, and the film layer located on the first functional layer may cover the first functional layer 221, and the first functional layer 221 is prevented from being directly connected to the second electrode 230. In this case, taking a vapor deposition angle corresponding to the light-emitting layer smaller than the vapor deposition angle of the first functional layer 221 as an example, if a width of a second spacing L1 can ensure that a film thickness of the light-emitting layer in the effective functional region 202 is uniform, the first functional layer 221 may have a uniform film thickness in the effective functional region 202; furthermore, taking an inclination angle corresponding to an edge of the second functional layer 223 is less than an inclination angle corresponding to an edge of other film layers in the light-emitting functional layer as an example, if the width of the second spacing L1 can ensure that a film thickness of the second functional layer 223 in the effective functional region 202 is uniform, other film layers such as the first functional layer 221, the light-emitting layer may have a uniform film thickness in the effective functional region 202.

It should be noted that, in the embodiments of the present application, an inclination angle corresponding to an edge of a film layer is an acute angle formed by intersecting a connecting line between the edge of the film layer and the edge of the second end portion with the plane where the substrate is located.

It should be noted that the light-emitting layer is a main film layer for exciting light in the light-emitting functional layer, and is a basic functional layer of the light-emitting functional layer, and therefore, compared with other film layers, a film quality of the light-emitting layer has a relatively large influence on a light-emitting efficiency of a light-emitting device. Therefore, in an actual process, it is necessary to at least ensure that the film thickness of the light-emitting layer in the effective functional region is uniform, that is, an edge of a portion having a uniform film thickness of the light-emitting layer may be used as a boundary of the effective functional region. In this case, an area of the effective functional region may not be greater than an area of a portion having a uniform film thickness of the first functional layer 221.

It should be noted that, when a vapor deposition angle corresponding to the light-emitting layer is less than or equal to the vapor deposition angle of the first functional layer 221, a minimum limit (a minimum area) of a boundary of the light-emitting layer is a boundary of the first functional layer 221, that is, a boundary corresponding to a maximum area of the effective functional region may still be a boundary of the portion having a uniform film thickness of the first functional region 221, and therefore, at least when a limit value of a pixel density is calculated, a position of the effective functional region may still be defined by a position of the portion having a uniform film thickness of the first functional region 221.

It should be noted that, in the embodiments of the present application, a boundary the portion having a uniform film thickness of the light-emitting layer may be used as a boundary of a main light-emitting region of a light-emitting device. For example, when the vapor deposition angle corresponding to the light-emitting layer is equal to the vapor deposition angle of the first functional layer 221, a boundary of the main light-emitting region, the boundary of the effective functional region, the boundary of the portion having a uniform film thickness of the light-emitting layer, and a boundary of the portion having a uniform film thickness of the first functional layer 221 coincide; or, when the vapor deposition angle corresponding to the light-emitting layer is less than the vapor deposition angle of the first functional layer 221, the boundary of the portion having a uniform film thickness of the light-emitting layer is the boundary of the main light-emitting region of the light-emitting device, and the boundary of the portion having a uniform film thickness of the first functional layer 221 is the boundary of the effective functional region.

In at least one embodiment of the present application, a light-emitting layer 222, a second functional layer 223, and the like do not need to have good contact with an isolation structure or should avoid contact with the isolation structure, and therefore vapor deposition angles of the light-emitting layer 222, the second functional layer 223, and the like are generally greater than a vapor deposition angle of the second electrode 230. In this case, if a width of a second spacing L1 can ensure that a film thickness of the second electrode 230 in an effective functional region 202 is uniform, functional layers such as the light-emitting layer 222 and the second functional layer 223 between a first functional layer 221 and the second electrode 230 may have a uniform film thickness in the effective functional region 202, that is, if a boundary of the effective functional region is defined by an edge of a portion having a uniform film thickness of the second electrode 230, a film thickness of each film layer of the light-emitting functional layer in the effective functional region is uniform.

In at least one embodiment of the present application, as shown in FIG. 5, on a cross-section perpendicular to a substrate 100 and on a same side of an isolation structure 300, an acute angle formed by a straight line determined by an edge of a surface, facing the substrate 100, of a first end portion 310 and an edge of a second end portion 320 and a plane where the substrate is located (or straight line P0) is not less than a first inclination angle Θ1 and is not greater than a second inclination angle Θ2), that is, h1/tan Θ1≤L2≤h1/tan Θ2. Therefore, a minimum design size of an edge of the first end portion 310 and an edge of the second end portion 320 in a transverse direction can be obtained as much as possible, and therefore, a minimum spacing between adjacent effective functional regions 202 can be further obtained, and an arrangement density of a light-emitting device is further improved while a situation that a first functional layer 221 is separated by the isolation structure 300 is maintained.

For example, in some embodiments of the present application, as shown in FIG. 5, an acute angle formed by a straight line determined by an edge of a surface, facing a substrate 100, of a first end portion 310 and an edge of a second end portion 320 and a plane where the substrate is located is equal to a first inclination angle Θ1, and the second electrode 230 is just in contact with the first end portion 310, and in this case, it may be considered that the second electrode 230 is electrically connected to the first end portion 310.

For example, in some other embodiments of the present application, as shown in FIG. 6, an acute angle formed by a straight line determined by an edge of a surface, facing a substrate 100, of a first end portion 310 and an edge of a second end portion 320 and a plane where the substrate is located is greater than a first inclination angle Θ1, and the second electrode 230 may climb to a side surface of the first end portion 310, that is, the second electrode 230 and the side surface of the first end portion 310 at least partially overlap and contact, for example, FIG. 6 shows that a climbing height is h0. In this way, the second electrode 230 in lap-joint to the first end portion 310 of the isolation structure 300 can be ensured, and a portion that the second electrode 230 overlaps the isolation structure 300 has a relatively large thickness to avoid poor contact or excessive resistance at a lap joint. It should be noted that in this case, a size of L2 is: L2=(h1−h0)/tan Θ2.

In some embodiments of the present application, a minimum value of L1+L2 may be obtained by comprehensively considering a critical range of L1 and L2, to further reduce an optional minimum size of a sub-pixel gap. For example, referring again to FIG. 5, an acute angle formed by a straight line P3 determined by an edge of an effective functional region 202 and an edge of a second end portion 320 and a plane where a substrate is located (for example, a straight line P0 included) is equal to a first inclination angle Θ1, an acute angle formed by a straight line P6 determined by an edge of a surface, facing the substrate 100, of a first end portion 310 and the edge of the second end portion 320 is equal to a second inclination angle Θ2, that is, L1=H1/tan Θ2, and L2−H1/tan Θ1. In this way, under a condition that a film thickness of each film layer of a light-emitting device is uniform in the effective functional region 202, both a second spacing L1 of an edge of the effective functional region 202 and the edge of the second end portion 320 second end portion 320 in a transverse direction and a first width L2 of an edge of the first end portion 310 and the edge of the second end portion 320 second end portion 320 in the transverse direction are a minimum size, and a distance between adjacent effective functional regions 202 is reduced as much as possible, and an arrangement density (equivalent to a pixel density) of the light-emitting device 200 is maximized while a situation that a first functional layer 221 is separated by an isolation structure 300 is maintained. It should be noted that, in this solution, an edge of the first functional layer 221 is just in contact with the isolation structure (for example, the first end portion 310 included thereof), but at a contact position, a thickness of the first functional layer 221 is theoretically infinitely close to zero, and a resistance of the contact position is infinite, and currents do not enter the isolation structure 300 through the first functional layer 221, that is, the isolation structure 300 actually electrically isolates adjacent first functional layers 221, thereby avoiding a reduction of a light-emitting efficiency of the display panel caused by current leakage.

It should be noted that in the embodiment shown in FIG. 5, a thickness of each film layer in a first electrode 210 and the light-emitting functional layer 220 is ignored in the formula L1=H1/tan Θ2, and the formula L1=H1/tan Θ1 may be replaced with L1=H tan Θ1. If the thickness of the first electrode 210 and the thickness of the light-emitting functional layer 220 are calculated, then the thickness of the first electrode 210 and he thickness of the light-emitting functional layer 220 needs to be subtracted from “H” in the formula L1=H/tan Θ1.

In some embodiments of the present application, as shown in FIG. 6, an isolation structure 300 may be directly disposed on a substrate 100, in this case, a size of a first electrode 210 needs to be prevented from overlapping with the isolation structure 300, to avoid electric leakage and reduce light-emitting efficiency, and in this case, the first electrode 210 defines a boundary of an effective functional region 202, that is, the effective functional region 202 coincides with the first electrode 210.

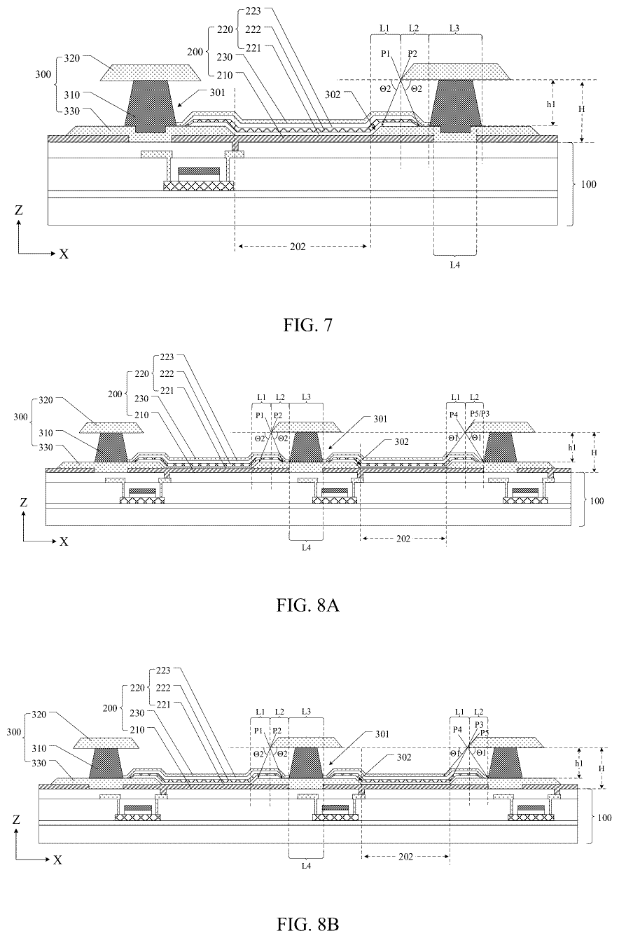

In some other embodiments of the present application, as shown in FIG. 7, the display panel includes a pixel definition layer 330, and the pixel definition layer 330 is located between a layer where an isolation structure (for example, a supporting portion 310) is located and a layer where a first electrode 210 is located to cover a gap between adjacent first electrodes 210 (a region L4). The pixel defining layer 330 defines a second opening 302, a light-emitting functional layer 220 covers the second opening 302, the second opening 302 corresponds to and communicates with a first opening 301, and an orthographic projection, on a plane where a substrate 100 is located, of the second opening 302 is located within an orthographic projection, on the plane where the substrate 100 is located, of the first opening 301 corresponding to the second opening 302. By designing the pixel defining layer 330, a risk that the first electrode 210 overlaps with the isolation structure adjacent to the first electrode 210 (for example, a conductive first end portion 310 thereof) can be eliminated, and the first electrode 210 has a larger design size to ensure a design area of an effective functional region 202.

The pixel defining layer 330 defines an exposed area of the first electrode 210 (the area of a portion for contact with the light-emitting functional layer 220), thereby defining a boundary of a light-emitting region of a light-emitting device 200. It should be noted that, in the light-emitting region, if a thickness of each film layer of the light-emitting functional layer 220 is uneven, a light-emitting efficiency of the light-emitting region is not uniform, and therefore, the light-emitting region of the light-emitting device may be designed in the effective functional region of the light-emitting functional layer 220 or coincide with the effective functional region, thereby ensuring that an entire light-emitting region can emit light uniformly.

It should be noted that, when designing the pixel density of the display panel, above parameters such as L1, L2, and h1 (H) may be synchronously determined when determining a size of the effective functional region (or further a main light-emitting region), and on this basis, a specific position of a boundary of the pixel defining layer 330 is further determined, for example, a minimum boundary of the second opening 302 of the pixel defining layer 330 (a minimum size of the second opening 302) is a boundary of the effective functional region. In this case, when a PPI of the display panel is designed, before the size of the effective functional region and a position of the effective functional region are completed, the specific position (size) of the pixel defining layer 330 may not need to be considered, thereby reducing a number of structures involved in a design, to reduce a design cost of the display panel.

It should be noted that, in some embodiments of the present application, an area of a second opening may be designed to be slightly larger than an area of an effective functional region based on a consideration of a process precision of forming the second opening in a pixel defining layer (for example, a mask alignment precision), that is, an orthographic projection, on a plane where a substrate is located, of the effective functional region is located within an orthographic projection, on the plane where the substrate is located, of the second opening, to set sufficient alignment safety margin, thereby ensuring that a portion, located in the effective functional region, of a light-emitting functional layer can be in contact with a first electrode; or, the area of the second opening can be designed to be smaller than the area of the effective functional region, and a thickness of a portion, located in the second opening, of the light-emitting functional layer can be uniform, and a light-emitting region of a light-emitting device can emit light uniformly.

In some embodiments of the present application, as shown in FIG. 8A, a sidewall of a pixel defining layer 330 may be configured to have an incline with a certain slope, and a boundary of an effective functional region is determined by a boundary of a portion having a uniform film thickness of the second electrode 230 on a same side of an isolation structure 300, that is, it is may be that an edge of a surface, facing a substrate 100, of the pixel defining layer 330 substantially coincides with an edge of the effective functional region, that is, an acute angle formed by the edge of the surface, facing the substrate 100, of the pixel defining layer 330 and an edge of a second end portion 320 is equal to a first inclination angle Θ1. Furthermore, an acute angle formed by a straight line determined by an edge of a surface, facing away from the substrate 100, of the pixel defining layer 330 and an edge of the second end portion 320 and a plane where the substrate 100 is located may be further designed to be equal to a second inclination angle Θ2, that is, a first functional layer 221 starts to have an uneven thickness at the edge of the surface, facing away from the substrate 100, of the pixel defining layer 330. Based on a requirement of the light transmittance, an overall thickness of a second electrode 230 is relatively small, and the second electrode 230 is prone to problems such as too low film thickness, fracture and poor continuity in a region with a large slop. The above design of the present application may enable a second spacing L1 to have a relatively small size, and the sidewall of the pixel defining layer 330 has a relatively small slope, and the second electrode 230 is more easily deposited on the sidewall of the pixel defining layer 330 to have a relatively large film thickness, to prevent the second electrode 230 from being poor film layer continuity or even fracture due to a segment difference.

For example, in some other embodiments of the present application, the structure shown in FIG. 8A may be modified to obtain FIG. 8B, specifically, as shown in FIG. 8B, a boundary of an effective functional region is determined by a boundary of a portion having a uniform film thickness of a light-emitting layer, and an edge of a surface, facing a substrate 100, of a pixel defining layer 330 may be designed to be substantially coincides with a boundary of the effective functional region, that is, an angle between the edge of the surface, facing the substrate 100, of the pixel defining layer 330 and a second end portion 320 (defined between a second inclination angle Θ2 and a first inclination angle Θ1) is equal to an angle formed by a straight line P3 determined by an edge of light-emitting layer and the second end portion 320 and a plane where the substrate 100 is located, in this way, a boundary of a portion having a uniform film thickness of a first functional layer 221 coincides with the edge of the surface, facing the substrate 100, of the pixel defining layer 330 (in this case, vapor deposition angles corresponding to the first functional layer 221 and the light-emitting layer are equal), or are located on a side surface of the pixel defining layer 330 or on a surface facing away from the substrate 100 (in this case, a vapor deposition angle corresponding to the first functional layer 221 is greater a vapor deposition angle corresponding to the light-emitting layer). Furthermore, an acute angle formed by a straight line determined by an edge of a surface, facing away from the substrate 100, of the pixel defining layer 330 and an edge of the second end portion 320 and the plane where the substrate 100 is located may be further designed to be equal to the second inclination angle Θ2, that is, a first functional layer 221 starts to have an uneven thickness at the edge of the surface, facing away from the substrate 100, of the pixel defining layer 330. Based on a requirement of the light transmittance, an overall thickness of a second electrode 230 is relatively small, and the second electrode 230 is prone to problems such as too low film thickness, fracture and poor continuity in a region with a large slop. The above design of the present application may enable a second spacing L1 to have a relatively small size, and the sidewall of the pixel defining layer 330 has a relatively small slope, and the second electrode 230 is more easily deposited on the sidewall of the pixel defining layer 330 to have a relatively large film thickness, to prevent the second electrode 230 from being poor film layer continuity or even fracture due to a segment difference.

For example, in at least one embodiment of the present application, as shown in FIG. 8A, a cross-sectional profile of a portion, located between two adjacent sub-pixels, of a pixel defining layer 330 is a regular trapezoid, on same side of an isolation structure 300, an acute angel formed by a straight line determined by an edge of a surface, facing a substrate 100, of the pixel defining layer 330 and an edge of a second end portion and a plane where the substrate 100 is located is equal to first inclination angle Θ1. A boundary of a second opening 302 of the pixel defining layer 330 coincides with a boundary of an effective functional region, and a light-emitting portion of a light-emitting region can have a maximum light-emitting efficiency, thereby improving a light-emitting uniformity; correspondingly, the design may obtain a range that a boundary of the pixel defining layer 330 may extend while ensuring the maximum light-emitting efficiency of a light-emitting device 200, to obtain a maximum design width of the pixel defining layer 330 (the width of a portion between two adjacent first openings 301), thereby facilitating a planning of a width of a pixel gap (the gap of the light-emitting region of adjacent light-emitting devices 200).

In an embodiment of the present application, a pixel defining layer 330 is mainly used for spacing partition portions of a first electrode 210 and an isolation structure 300, and does not need to limit a light-emitting functional layer 220, and the pixel defining layer 330 can be designed to have a small design thickness, which not only reduces a segment difference at a boundary of the pixel defining layer 330 (a poor film quality will be caused by a too large segment difference), but also facilitates a light-weight and thin design of the display panel. However, the pixel defining layer 330 having a smaller thickness may form a conformal groove at a gap of adjacent first electrodes 210, which may affect a quality of a subsequent film layer.

For example, as shown in FIG. 7, a portion, covering a gap (cooperating with a substrate 100 being presented as a groove shape) a first electrode 210, of a pixel defining layer 330 is conformal with the gap of the first electrode 210 to form a groove. For example, the pixel defining layer 330 is an inorganic material film layer, and the pixel defining layer 330 has a relatively high insulating property while having a relatively thin thickness. For example, material of the pixel defining layer 330 may be silicon oxide, silicon nitride, silicon oxynitride, and the like. A small molecular substance remaining in a process of forming a film by using an organic material is extremely easy to generate miscellaneous gas, and a data appears as a value increase of an out gas, while, a chemical property of the pixel defining layer 330 formed by an inorganic material is more stable, and the pixel defining layer 330 of the present embodiment can improve a stability of the display panel.

For example, a thickness of the pixel defining layer 330 may be 1000 Å to 5000 Å.

It should be noted that the thickness of the pixel defining layer 330 is a thickness of a portion, located between adjacent first electrodes 210, of the pixel defining layer 330, or a thickness of a portion, covering a first electrode 210 (regardless of a portion of a sidewall of the pixel defining layer 330), of a pixel defining layer 330.

In some embodiments of the present application, as shown in FIG. 7, a gap of an orthographic projection, on a plane where a substrate 100 is located, of adjacent first electrodes 210 is located within an orthographic projection, on the plane where the substrate 100 is located, of a surface, facing the substrate 100, of a first end portion 310, that is, a width L4 of the gap of the first electrode 210 is less than a width L3 of the first end portion 310, and the first end portion 310 of an isolation structure may cover a groove on a pixel defining layer 330.

In some other embodiments of the present application, as shown in FIG. 8A, a gap of an orthographic projection, on a plane where a substrate 100 is located, of adjacent first electrodes 210 coincides with an orthographic projection, on the plane where the substrate 100 is located, of a surface, facing the substrate 100, of a first end portion 310, that is, a width L4 of the gap of the first electrode 210 is equal to a width L3 of the first end portion 310. In this way, a minimum design width of the first end portion 310 of an isolation structure 300 may be reduced, thereby reducing a minimum spacing between adjacent effective functional regions 202, and an arrangement density (equivalent to a pixel density) of a light-emitting device 200 is improved while a situation that a first functional layer 221 is separated by the isolation structure 300 is maintained.

For example, the substrate 100 may include a substrate and a driving circuit layer located on the substrate, the driving circuit layer includes a plurality of pixel driving circuits located in a display region, and a display functional layer is located on the driving circuit layer. For example, each of the plurality of pixel driving circuits may include a plurality of transistor TFTs, capacitors, and the like, for example, a plurality of forms such as 2T1C (that is, two transistors (TFTs) and one capacitor (C)), 3T1C, or 7T1C. Each of the plurality of pixel driving circuits is connected to the light-emitting device 200 to control an on-off state and a light-emitting brightness of the light-emitting device 200.

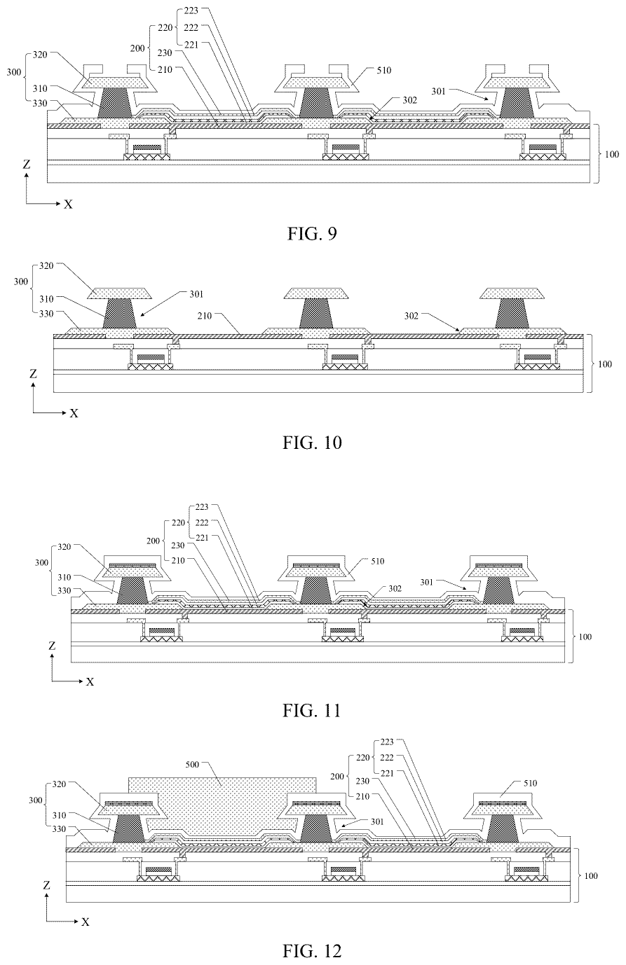

In at least one embodiment of the present application, as shown in FIG. 9, the display panel may further include a first encapsulation layer 510, and the first encapsulation layer 510 at least covers a light-emitting device 200 to protect a film layer of the light-emitting device 200 during a manufacturing process of the display panel. It should be noted that light-emitting devices 200 with different emergent light are independently manufactured, but the film layer (a vapor-deposited coating layer, such as a light-emitting functional layer, and the like) in each light-emitting device 200 is vapor-deposited on an entire surface of the display panel during a vapor deposition process. For example, the light-emitting device 200 is classified as a light-emitting device emitting red light (R), green light (G) and blue light (B), respectively, in a preparation process, the light-emitting device R, the light-emitting device G and the light-emitting device B are sequentially prepared, and when the light-emitting device R is prepared, the light-emitting device R is formed in each first opening 301, and the first encapsulation layer 510 is prepared on the display panel to cover the light-emitting device R, then the first encapsulation layer 510 in part of first openings 301 and a second electrode and the light-emitting functional layer in the light-emitting device R are removed, in this process, the first encapsulation layer 510 is configured to protect the light-emitting device R in other first openings 301, the light-emitting device G and the light-emitting device B are sequentially prepared based on this manner, and finally form the first encapsulation layer 510 as shown in FIG. 9 is formed. The following describes a preparation process of the display panel shown in FIG. 9 with reference to FIG. 10 to FIG. 13.

It should be noted that the first encapsulation layer 510 has an encapsulation effect on the light-emitting device, and therefore may also be referred to as an encapsulation layer (only one film layer is provided) or one film layer of an encapsulation layer (a plurality of encapsulation film layers are provided).

As shown in FIG. 10, providing a substrate 100 and forming a first electrode 210 arranged in an array on the substrate 100; depositing an insulating material film layer (for example, an inorganic material film layer) on the substrate 100 on which the first electrode 210 is formed; forming a supporting portion 310 and a blocking portion 320 on the display panel; and performing a patterning process on the insulating material film layer to form a pixel defining layer 330 (a planar shape is grid-shaped), where the pixel defining layer 330 covers a gap between adjacent first electrodes 210, in this way, the planar shape of the pixel defining layer 330 is grid-shaped.

In an embodiment of the present application, a patterning process may be a photolithography patterning process, for example, the patterning process may include: coating a photoresist on a structural layer to be patterned, exposing the photoresist using a mask plate, developing an exposed photoresist to obtain a photoresist pattern, etching the structural layer using the photoresist pattern (in one embodiment, wet etching or dry etching may be performed), and then optionally removing the photoresist pattern. It should be noted that, in a case that material of the structural layer (for example, a photoresist pattern 500 described below) includes a photoresist, the structural layer may be directly exposed through the mask plate to form a desired pattern.

As shown in FIG. 11, vapor-depositing a light-emitting functional layer and a second electrode on a substrate 100, where a vapor deposition source is vapor-deposited at a first vapor deposition angle (a second inclination angle) to form a first functional layer 221 and is vapor-deposited at a second vapor deposition angle (a first inclination angle) to form a second electrode 230, to form a light-emitting device 200 in each first opening 301 of an isolation structure 300, a vapor deposition in this process does not use a mask plate, so an vapor-deposited material is also deposited on a blocking portion 320; and then depositing to form a first encapsulation layer 510 to cover the light-emitting device 200. For example, a light-emitting layer in a vapor-deposited light-emitting functional layer 220 may correspond to emitting red light, that is, in this stage, each first opening 301 of the isolation structure 300 is formed with a light-emitting device 200 corresponding to emitting red light.

As shown in FIG. 12, as shown in FIG. 12, forming a photoresist (for example, coated) on the substrate 100 on which the first encapsulation layer 510 is formed, and then performing a patterning process to form the photoresist pattern 500, where the photoresist pattern 500 only covers a part of first openings 301.

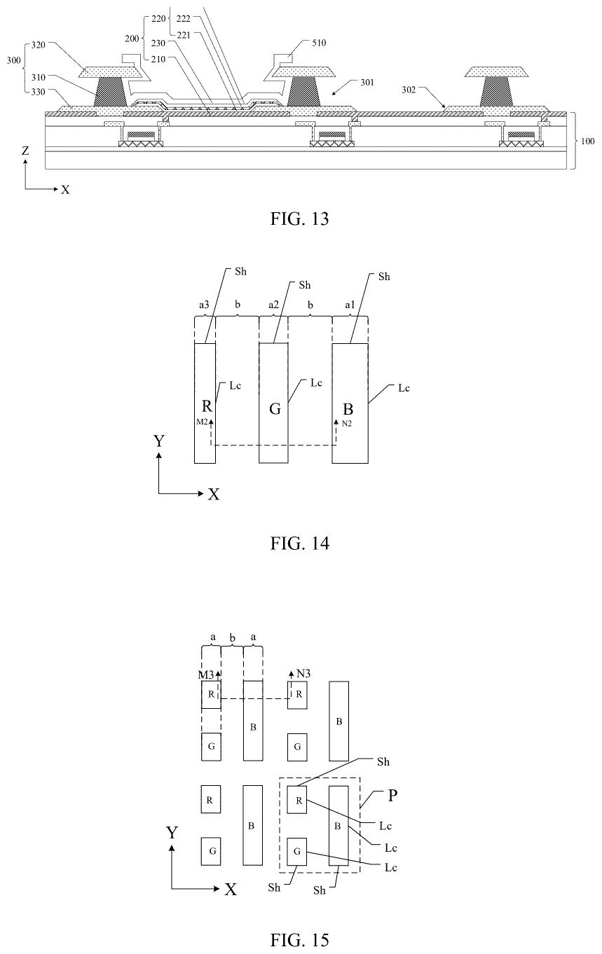

As shown in FIG. 13, etching a surface of the display panel to remove the first encapsulation layer 510, the second electrode 230 and a light-emitting functional layerlight-emitting functional layer 220 not covered by the photoresist pattern 500; and then removing a residual photoresist pattern 500.

Repeating the steps of FIG. 11 to FIG. 13 to respectively form a light-emitting device 200 for emitting green light and a light-emitting device 200 for emitting blue light in other first openings 301, and forming the display panel as shown in FIG. 9.

It should be noted that, in some embodiments of the present application, some film layers in a light-emitting functional layer, such as a light-emitting layer may be prepared in a non-evaporation manner, for example, inkjet printing, and may be specifically selected according to materials of the film layers, for example, in a case where the film layers are polymer materials and are not suitable for evaporation, ink-jet printing may be used.

In a design of the display panel of a current OLED, evaporation of a film layer in a light-emitting device needs to be separately prepared by using a mask (for example, an FMM mask), limited to multiple alignment precision requirements, a large sub-pixel gap (the gap between adjacent light-emitting devices, corresponding to a pixel pitch) needs to be reserved; furthermore, the current OLED needs to limit a light-emitting device by a pixel defining layer having a larger thickness (following embodiments of the present application are not limited to a necessity of limiting the light-emitting device by the pixel defining layer), and the light-emitting device is completely accommodated in an opening of the pixel defining layer, in this case, because a thickness of the pixel defining layer is too large, and in order to increase and make a sidewall of the opening of the pixel defining layer have a larger slope, a space occupied by the sidewall of all pixel defining layers is relatively large, which further increases the sub-pixel gap; in addition, due to a limitation of the alignment precision, a size of the light-emitting device itself is difficult to further shrink. For the display panel of the current OLED, a pixel density based on a FMM technology is difficult to exceed 403 PPI, because a width of a sub-pixel thereof is difficult to be less than 4 μm, more importantly, a minimum gap of the sub-pixel can only reach 17 μm, and it is relatively difficult to achieve 20 μm.

How to improve the pixel density of the display panel to greater than 403 PPI and a specific structure of the display panel in this case will be described in detail below.

In some embodiments of the present application, the display panel includes a substrate, and an isolation structure and a plurality of pixels located on the substrate. The isolation structure has a plurality of first openings, each pixel includes a plurality of sub-pixels with different wavelengths of emergent light (each of the plurality of sub-pixels emits one type of light, different sub-pixels emit light with different wavelengths), the sub-pixel includes a first electrode, a light-emitting functional layer, and a second electrode sequentially stacked on the substrate, a light-emitting layer of the sub-pixel is disposed in a first opening, and the second electrode is connected to the isolation structure. By providing the isolation structure, an arrangement density of the plurality of pixels may be in a range of 90 to 7400 PPI. In the above solution, for a vapor deposition film layer of the sub-pixel, the isolation structure may not need to be vapor-deposited through a mask, and an alignment precision problem during vapor deposition does not need to be considered, and a distance between adjacent sub-pixels can be reduced, and the display panel has a relatively high pixel density; according to different requirements of a specific application scenario, different specific numerical values in a range of 404 to 2000 PPI and 2000 to 7400 PPI may be specifically set, and a numerical value of a range of 90 to 403 PPI according to actual requirements may also be set. For a planar structure of the display panel and a principle of improving the PPI, reference may be made to related descriptions in the foregoing embodiments, and details are not described herein again.

In the embodiments of the present application, there are some options to increase a pixel density, the pixel density may be increased by reducing a sub-pixel width, or reducing a spacing between the sub-pixels, or reducing the sub-pixel width and reducing the spacing between the sub-pixels at a same time, and a structure of the display panel under different options is described in detail below through different embodiments.

In some embodiments of the present application, a pixel density may be increased by reducing only a spacing between sub-pixels. For example, an average width of the sub-pixels may be designed to be no less than 4 micrometers, and a gap of the sub-pixels is designed to be not less than 8 micrometers and not greater than 17 micrometers, and an arrangement density of pixels may be 404 PPI to 1058 PPI, where the arrangement density of the pixels is approximately 706 PPI or 1058 PPI when the average width of the sub-pixels is designed to be 4 micrometers and the gap of the sub-pixels is designed to be 8 micrometers.

For example, a display functional layer includes a plurality of light-emitting devices corresponding to the sub-pixels. In each of the plurality of light-emitting devices, for a type and a positional relationship of each film layer and a positional relationship between each film layer and an isolation structure, refer to related descriptions in the foregoing embodiments related to FIG. 1 to FIG. 3, which is not repeated again herein. In addition, in this embodiment, referring to FIG. 4 again, a distance h1 between an edge of a first end portion 310 and an edge of a second end portion 320 along a direction perpendicular to the substrate 100 is not less than 0.6 μm, a width of the first end portion 310 is not less than 2 μm, a width of the second end portion 320 is not less than 4 μm, and on a same side of an isolation structure 300, a second spacing L1 between an orthographic projection, on a plane where the substrate 100 is located, of an edge of an effective functional region 202 and an orthographic projection, on the plane where the substrate 100 is located, of the edge of the second end portion 320 is not less than 2 μm, and a gap of the sub-pixels is not less than 8 μm. For example, further, a second inclination angle is 40 degrees to 70 degrees.

For example, referring to FIG. 5 again, on a cross-section perpendicular to a substrate 100 and on a same side of an isolation structure 300, an acute angle formed by a straight line P4 determined by an edge of a second electrode 230 and an edge of a second end portion 320 and a plane where the substrate 100 is located is a first inclination angle Θ1, the first inclination angle Θ1 is less than a second inclination angle Θ2, an acute angle formed by a straight line P3 determined by an edge of an effective functional region 202 and the edge of the second end portion 320 and the plane where the substrate 100 is located (for example, a straight line P0) is less than or equal to the first inclination angle Θ1. In this case, the first inclination angle Θ1 may be designed to be 20 degrees to 70 degrees.

For example, referring again to FIG. 5, the acute angle formed by the straight line P3 determined by the edge of the effective functional region 202 and the edge of the second end portion 320 and the plane where the substrate 100 is located (for example, a straight line P0 included thereof) is equal to the first inclination angle Θ1, an acute angle formed by a straight line P6 determined by an edge of a surface, facing the substrate 100, of a first end portion 310 and the edge of the second end portion 320 and the plane where the substrate 100 is located is equal to the second inclination angle Θ2, that is L1=H/tan Θ2 (a film thickness of a first electrode and a light-emitting functional layer is ignored when H is calculated in the formula) and L2=h1/tan Θ1. For example, a width (L3) of the first end portion 310 is 2 μm, a width (2L2+L3) of the second end portion 320 is 4 μm, and on a same side of the isolation structure 300, a second spacing L1 between an orthographic projection, on the plane where the substrate 100 is located, of the edge of the effective functional region 202 and an orthographic projection, on the plane where the substrate 100 is located, of the edge of the second end portion 320 is 2 μm, and a gap of sub-pixels is 8 μm. For example, still further, in each pixel, an average width of the sub-pixels is 4 μm, and the arrangement density of pixels is 706 PPI or 1058 PPI.

It should be noted that, “an average width of the sub-pixels” is a ratio of a sum of widths of the plurality of sub-pixels in each pixel to a number of the sub-pixels. For example, referring to FIG. 2 again, each pixel P includes a first sub-pixel B, a second sub-pixel G, and a third sub-pixel R with wavelengths of emergent light rays are sequentially increased, and the first sub-pixel B, the second sub-pixel G, and the third sub-pixel R emit blue light, green light, and red light respectively. A number ratio of first sub-pixels B, second sub-pixels G, and third sub-pixels R in the display panel in this embodiment is 1:1:1.

For example, in some designs, referring to FIG. 2 again, widths of the first sub-pixel B, the second sub-pixel G, and the third sub-pixel R are both 4 μm.

For example, in some designs, as shown in FIG. 14, a first sub-pixel B, a second sub-pixel G, and a third sub-pixel R are arranged in a plurality of rows, a width direction of the first sub-pixel B, the second sub-pixel G, and the third sub-pixel R is same as a direction of a row (for example, a direction of the X-axis), and the first sub-pixel B, the second sub-pixel G, and the third sub-pixel R in each pixel are sequentially arranged along the direction of the row, a width a1 of the first sub-pixel B, a width a2 of the second sub-pixel G, and a width a3 of the third sub-pixel R are sequentially reduced, the width a1 of the first sub-pixel B is greater than 4 μm, and the width a3 of the third sub-pixel R is less than 4 μm, and the average width (a1+a2+a3)/3 of the first sub-pixel B, the second sub-pixel G, and the third sub-pixel R is 4 μm.

Under the above design, a width of each pixel (including the first sub-pixel B, the second sub-pixel G, and the third sub-pixel R) (which may be referred to as pitch=a1+a2+a3+3b) is 36 μm, and an arrangement density of pixels is 706 PPI, where b=2L1+2L2+L3.

For example, in some other designs, as shown in FIG. 15, the first sub-pixel B, the second sub-pixel G, and the third sub-pixel R are arranged in a plurality of columns, a width direction of the first sub-pixel B, the second sub-pixel G, and the third sub-pixel R is perpendicular to a direction of a column, a column where the second sub-pixel G and the third sub-pixel R are located is different with a column where the first sub-pixel B is located, in columns where the second sub-pixel G and the third sub-pixel R are located, a column where the second sub-pixel G and the third sub-pixel R are located, a column where the first sub-pixel B is located, and a column where the second sub-pixel G is located are alternately arranged, a number of the second sub-pixel G is equal to a number of the third sub-pixels R.

For example, as shown in FIG. 15, a width of the second sub-pixel G and a width of the third sub-pixel R are both 4 μm; or the width of the second sub-pixel G and the width of the third sub-pixel R are sequentially reduced, a width of the first sub-pixel is greater than 4 μm, and the width of the second sub-pixel and the width of the third sub-pixel are equal and less than 4 μm. Under the above design, a width of each pixel P (including the first sub-pixel B, the second sub-pixel G, and the third sub-pixel R) (which may be referred to as pitch=2a+2b) is 24 μm, and an arrangement density of pixels is 1058 PPI, where b=2L1+2L2+L3.

In an embodiment of the present application, a calculation method of PPI may be a ratio of 25.4 millimeters to pitch, for example, under a pixel arrangement manner shown in FIG. 14, if the pitch is 36 μm, the PPI is approximately 706; and if the pitch is 24 μm, the PPIis approximately 1058.

In some embodiments of the present application, a pixel density may be improved by reducing only a width of a sub-pixel. For example, an average width of sub-pixels can be designed to be not less than 2 μm, and a gap of the sub-pixels is designed to be not less than 17 μm, and an arrangement density of pixels can be 404 PPI to 668 PPI, where the arrangement density of the pixels is roughly 446 PPI or 668 PPI when the average width of the sub-pixels is designed to be 2 μm and the gap of the sub-pixels is designed to be 17 μm.

For example, the display panel may further include a substrate and a display functional layer located on the substrate, and the display functional layer includes a plurality of light-emitting devices corresponding to the sub-pixels. In each of the plurality of light-emitting devices, for a type and a positional relationship of each film layer and a positional relationship between each film layer and an isolation structure, refer to related descriptions in the foregoing embodiments related to FIG. 1 to FIG. 3, which is not repeated again herein. In addition, in this embodiment, referring to FIG. 4 again, a distance h1 between an edge of a first end portion 310 and an edge of a second end portion 320 along a direction perpendicular to a substrate 100 is not less than 0.6 μm, a width of the first end portion 310 is not less than 2 μm, a width of the second end portion 320 is not less than 4 μm, and on a same side of an isolation structure 300, a second spacing L1 between an orthographic projection, on a plane where the substrate 100 is located, of an edge of an effective functional region 202 and an orthographic projection, on the plane where the substrate 100 is located, of the edge of the second end portion 320 is not less than 6.5 μm, and a gap of the sub-pixels is not less than 17 μm. For example, further, a second inclination angle is 40 degrees to 70 degrees.

For example, referring to FIG. 5 again, on a cross-section perpendicular to a substrate 100 and on a same side of an isolation structure 300, an acute angle formed by a straight line P4 determined by an edge of a second electrode 230 and an edge of a second end portion 320 and a plane where the substrate 100 is located is a first inclination angle Θ1, the first inclination angle Θ1 is less than a second inclination angle Θ2, an acute angle formed by a straight line P3 determined by an edge of an effective functional region 202 and the edge of the second end portion 320 and the plane where the substrate 100 is located (for example, a straight line P0) is less than or equal to the first inclination angle Θ1. In this case, the first inclination angle Θ1 may be designed to be 20 degrees to 70 degrees.

For example, referring again to FIG. 5, the acute angle formed by the straight line P3 determined by the edge of the effective functional region 202 and the edge of the second end portion 320 and the plane where the substrate 100 is located (for example, a straight line P0 included thereof) is equal to the first inclination angle Θ1, an acute angle formed by a straight line P6 determined by an edge of a surface, facing the substrate 100, of a first end portion 310 and the edge of the second end portion 320 and the plane where the substrate is located is equal to the second inclination angle Θ2, that is L1=H/tan Θ2 (a film thickness of a first electrode and a light-emitting functional layer is ignored when H is calculated in the formula) and L2=h1/tan Θ1. For example, a width of the first end portion 310 is 2 μm, a width of the second end portion 320 is 4 μm, and on the same side of the isolation structure 300, a second spacing L1 between an orthographic projection, on the plane where the substrate 100 is located, of the edge of the effective functional region 202 and an orthographic projection, on the plane where the substrate 100 is located, of the edge of the second end portion 320 is 6.5 μm, and a gap of sub-pixels is 17 μm. For example, in each pixel, an average width of the sub-pixels is 2 μm, and an arrangement density of pixels is 446 PPI or 668 PPI. For example, in a pixel arrangement structure shown in FIG. 2 and FIG. 14, a width of a first sub-pixel B, a width of a second sub-pixel G, and a width of a third sub-pixel R are all 2 μm; or the width of the first sub-pixel B is greater than 2 μm, and the width of the third sub-pixel R is less than 2 μm, and an average width of the first sub-pixel B, the second sub-pixel G, and the third sub-pixel R is 2 μm. Under the above design, a width (which may be referred to as pitch) of each pixel (including the first sub-pixel B, the second sub-pixel G, and the third sub-pixel R) is 57 μm, and the arrangement density of the pixels is 446 PPI. For a design of the average width of the sub-pixels, reference may be made to related descriptions in the foregoing embodiments, and details are not described herein again.

For example, in a pixel arrangement structure shown in FIG. 15, a width of a second sub-pixel G and a width of a third sub-pixel R are both 2 μm; or the width of the second sub-pixel G and the width of the third sub-pixel R are sequentially reduced, a width of a first sub-pixel is greater than 2 μm, and the width of the second sub-pixel G and the width of the third sub-pixel R are equal and less than 2 μm. Under the above design, a width (which may be referred to as pitch) of each pixel P (including the first sub-pixel B, the second sub-pixel G, and the third sub-pixel R) is 38 μm, and an arrangement density of the pixels is 668 PPI. For a design of the average width of the sub-pixels, reference may be made to related descriptions in the foregoing embodiments, and details are not described herein again.

In some embodiments of the present application, a pixel density may be increased by reducing a spacing between sub-pixels and reducing a width of a sub-pixel. For example, an average width of the sub-pixels may be designed to be no less than 2 μm, and a gap of the sub-pixels is designed to be no less than 8 μm and not greater than 17 μm, and an arrangement density of pixels is 404 PPI to 1270 PPI, where the arrangement density of the pixels is approximately 847 PPI or 1270 PPI in a case that the average width of the sub-pixels is designed to be 2 μm and the gap of the sub-pixels is designed to be 8 μm.

For example, the display panel may further include a substrate and a display functional layer located on the substrate, and the display functional layer includes a plurality of light-emitting devices corresponding to the sub-pixels. In each of the plurality of light-emitting devices, for a type and a positional relationship of each film layer and a positional relationship between each film layer and an isolation structure, refer to related descriptions in the foregoing embodiments related to FIG. 1 to FIG. 3, which is not repeated again herein. In addition, in this embodiment, referring to FIG. 4 again, a distance between an edge of a first end portion 310 and an edge of a second end portion 320 along a direction perpendicular to a substrate 100 is not less than 0.6 μm, a width of the first end portion 310 is not less than 2 μm, a width of the second end portion 320 is not less than 4 μm, and on a same side of an isolation structure 300, a distance between an orthographic projection, on a plane where the substrate 100 is located, of an edge of an effective functional region 202 and an orthographic projection, on the plane where the substrate 100 is located, of the edge of the second end portion 320 is not less than 2 μm, and a gap of the sub-pixels is not less than 8 μm. For example, further, a second inclination angle is 40 degrees to 70 degrees.

For example, referring to FIG. 5 again, on a cross-section perpendicular to a substrate 100 and on a same side of an isolation structure 300, an acute angle formed by a straight line P4 determined by an edge of a second electrode 230 and an edge of a second end portion 320 and a plane where the substrate 100 is located is a first inclination angle Θ1, the first inclination angle Θ1 is less than a second inclination angle Θ2, an acute angle formed by a straight line P3 determined by an edge of an effective functional region 202 and the edge of the second end portion 320 and the plane where the substrate 100 is located (for example, a straight line P0) is less than or equal to the first inclination angle Θ1. In this case, the first inclination angle Θ1 may be designed to be 20 degrees to 70 degrees.

For example, referring again to FIG. 5, the acute angle formed by the straight line P3 determined by the edge of the effective functional region 202 and the edge of the second end portion 320 and the plane where the substrate 100 is located (for example, a straight line P0 included thereof) is equal to the first inclination angle Θ1, an acute angle formed by a straight line P6 determined by an edge of a surface, facing the substrate 100, of a first end portion 310 and the edge of the second end portion 320 and the plane where the substrate is located is equal to the second inclination angle Θ2, that is L1=H/tan Θ2 (a film thickness of a first electrode and a light-emitting functional layer is ignored when H is calculated in the formula) and L2=h1/tan Θ1. For example, a width of the first end portion 310 is 2 μm, a width of the second end portion 320 is 4 μm, and on the same side of the isolation structure 300, a distance between an orthographic projection, on the plane where the substrate 100 is located, of the edge of the effective functional region 202 and an orthographic projection, on the plane where the substrate 100 is located, of the edge of the second end portion 320 is 2 μm, and a gap of sub-pixels is 8 μm. For example, still further, in each pixel, an average width of the sub-pixels is 2 μm, and an arrangement density of pixels is 847 PPI or 1270 PPI.

For example, in a pixel arrangement structure shown in FIG. 2 and FIG. 14, a width of a first sub-pixel B, a width of a second sub-pixel G, and a width of a third sub-pixel R are all 2 μm; or the width of the first sub-pixel B is greater than 2 μm, and the width of the third sub-pixel R is less than 2 μm, and an average width of the first sub-pixel B, the second sub-pixel G, and the third sub-pixel R is 2 μm. Under the above design, a width (which may be referred to as pitch) of each pixel (including the first sub-pixel B, the second sub-pixel G, and the third sub-pixel R) is 30 μm, and an arrangement density of the pixels is 847 PPI. For the design of the average width of the sub-pixels, reference may be made to related descriptions in the foregoing embodiments, and details are not described herein again.

For example, in a pixel arrangement structure shown in FIG. 15, a width of a second sub-pixel G and a width of a third sub-pixel R are both 2 μm; or the width of the second sub-pixel G and the width of the third sub-pixel R are sequentially reduced, a width of a first sub-pixel is greater than 2 μm, and the width of the second sub-pixel G and the width of the third sub-pixel R are equal and less than 2 μm. Under the above design, a width (which may be referred to as pitch) of each pixel P (including the first sub-pixel B, the second sub-pixel G, and the third sub-pixel R) is 20 μm, and an arrangement density of the pixels is 1270 PPI. For the design of the average width of the sub-pixels, reference may be made to related descriptions in the foregoing embodiments, and details are not described herein again.

In some embodiments of the present application, a pixel density may be increased by reducing a spacing between sub-pixels and reducing a width of a sub-pixel. For example, an average width of the sub-pixels may be designed to be no less than 1.5 μm, and a gap of the sub-pixels is designed to be no less than 7 μm and not greater than 17 μm, and an arrangement density of pixels is 404 PPI to 1500 PPI, where the arrangement density of the pixels is approximately 1000 PPI or 1500 PPI in a case that the average width of the sub-pixels is designed to be 1.5 μm and the gap of the sub-pixels is designed to be 7 μm.

For example, the display panel may further include a substrate and a display functional layer located on the substrate, and the display functional layer includes a plurality of light-emitting devices corresponding to the sub-pixels. In each of the plurality of light-emitting devices, for a type and a positional relationship of each film layer and a positional relationship between each film layer and an isolation structure, refer to related descriptions in the foregoing embodiments related to FIG. 1 to FIG. 3, which is not repeated again herein. In addition, in this embodiment, referring to FIG. 4 again, a distance between an edge of a first end portion 310 and an edge of a second end portion 320 along a direction perpendicular to a substrate 100 is not less than 0.6 μm, a width of the first end portion 310 is not less than 2 μm, a width of the second end portion 320 is not less than 4 μm, and on a same side of an isolation structure 300, a second spacing L1 between an orthographic projection, on a plane where the substrate 100 is located, of an edge of an effective functional region 202 and an orthographic projection, on the plane where the substrate 100 is located, of the edge of the second end portion 320 is not less than 1.5 μm, and a gap of the sub-pixels is not less than 7 μm. For example, further, a second inclination angle is 40 degrees to 70 degrees.

For example, referring to FIG. 5 again, on a cross-section perpendicular to a substrate 100 and on a same side of an isolation structure 300, an acute angle formed by a straight line P4 determined by an edge of a second electrode 230 and an edge of a second end portion 320 and a plane where the substrate 100 is located is a first inclination angle Θ1, the first inclination angle 1 is less than a second inclination angle Θ2, an acute angle formed by a straight line P3 determined by an edge of an effective functional region 202 and the edge of the second end portion 320 and the plane where the substrate 100 is located (for example, a straight line P0) is less than or equal to the first inclination angle Θ1. In this case, the first inclination angle Θ1 may be designed to be 20 degrees to 70 degrees.

For example, referring again to FIG. 5, the acute angle formed by the straight line P3 determined by the edge of the effective functional region 202 and the edge of the second end portion 320 and the plane where the substrate 100 is located (for example, a straight line P0 included thereof) is equal to the first inclination angle Θ1, an acute angle formed by a straight line P6 determined by an edge of a surface, facing the substrate 100, of a first end portion 310 and the edge of the second end portion 320 and the plane where the substrate is located is equal to the second inclination angle Θ2, that is L1=H/tan Θ2 (a film thickness of a first electrode and a light-emitting functional layer is ignored when H is calculated in the formula) and L2=h1/tan Θ1. For example, a width of the first end portion 310 is 2 μm, a width of the second end portion 320 is 4 μm, and on the same side of the isolation structure 300, a second spacing L1 between an orthographic projection, on the plane where the substrate 100 is located, of the edge of the effective functional region 202 and an orthographic projection, on the plane where the substrate 100 is located, of the edge of the second end portion 320 is 1.5 μm, and a gap of sub-pixels is 7 μm. For example, still further, in each pixel, an average width of the sub-pixels is 1.5 μm, and an arrangement density of pixels is 1000 PPI or 1500 PPI.

For example, in a pixel arrangement structure shown in FIG. 2 and FIG. 14, a width of a first sub-pixel B, a width of a second sub-pixel G, and a width of a third sub-pixel R are all 1.5 μm; or the width of the first sub-pixel B is greater than 1.5 μm, and the width of the third sub-pixel R is less than 1.5 μm, and an average width of the first sub-pixel B, the second sub-pixel G, and the third sub-pixel R is 1.5 μm. Under the above design, a width (which may be referred to as pitch) of each pixel (including the first sub-pixel B, the second sub-pixel G, and the third sub-pixel R) is 25.5 μm, and an arrangement density of the pixels is 1000 PPI. For a design of the average width of the sub-pixels, reference may be made to related descriptions in the foregoing embodiments, and details are not described herein again.

For example, in a pixel arrangement structure shown in FIG. 15, a width of a second sub-pixel G and a width of a third sub-pixel R are both 1.5 μm; or the width of the second sub-pixel G and the width of the third sub-pixel R are sequentially reduced, a width of a first sub-pixel is greater than 1.5 μm, and the width of the second sub-pixel and the width of the third sub-pixel are equal and less than 1.5 μm. Under the above design, a width (which may be referred to as pitch) of each pixel P (including the first sub-pixel B, the second sub-pixel G, and the third sub-pixel R) is 17 μm, and an arrangement density of the pixels is 1500 PPI. For the design of the average width of the sub-pixels, reference may be made to related descriptions in the foregoing embodiments, and details are not described herein again.

For example, in the pixel arrangement structure shown in FIG. 2 and FIG. 14, the width of the first sub-pixel B, the width of the second sub-pixel G, and the width of the third sub-pixel R are all 2 μm; or the width of the first sub-pixel B is greater than 2 μm, and the width of the third sub-pixel R is less than 2 μm, and an average width of the first sub-pixel B, the second sub-pixel G, and the third sub-pixel R is 2 μm. Under the above design, a width (which may be referred to as pitch) of each pixel (including the first sub-pixel B, the second sub-pixel G, and the third sub-pixel R) is 27 μm, and an arrangement density of the pixels is 941 PPI. For the design of the average width of the sub-pixels, reference may be made to related descriptions in the foregoing embodiments, and details are not described herein again.

For example, in a pixel arrangement structure shown in FIG. 15, the width of the second sub-pixel G and the width of the third sub-pixel R are both 2 μm; or the width of the second sub-pixel G and the width of the third sub-pixel R are sequentially reduced, the width of the first sub-pixel is greater than 2 μm, and the width of the second sub-pixel and the width of the third sub-pixel are equal and less than 2 μm. Under the above design, a width (which may be referred to as pitch) of each pixel P (including the first sub-pixel B, the second sub-pixel G, and the third sub-pixel R) is 18 μm, and the arrangement density of the pixels is 1411 PPI. For the design of the average width of the sub-pixels, reference may be made to related descriptions in the foregoing embodiments, and details are not described herein again.

In some embodiments of the present application, a pixel density may be increased by reducing a spacing between sub-pixels and reducing a width of a sub-pixel. For example, an average width of the sub-pixels may be designed to be no less than 1.35 μm, and a gap of the sub-pixels is designed to be no less than 5 μm and not greater than 17 μm, and an arrangement density of pixels is 404 PPI to 2000 PPI, where the arrangement density of the pixels is approximately 1333 PPI or 2000 PPI in a case that the average width of the sub-pixels is designed to be 1.35 μm and the gap of the sub-pixels is designed to be 5 μm.

For example, the display panel may further include a substrate and a display functional layer located on the substrate, and the display functional layer includes a plurality of light-emitting devices corresponding to the sub-pixels. In each of the plurality of light-emitting devices, for a type and a positional relationship of each film layer and a positional relationship between each film layer and an isolation structure, refer to related descriptions in the foregoing embodiments related to FIG. 1 to FIG. 3, which is not repeated again herein. In addition, in this embodiment, referring to FIG. 4 again, a distance between an edge of a first end portion 310 and an edge of a second end portion 320 along a direction perpendicular to a substrate 100 is not less than 0.6 μm, a width of the first end portion 310 is not less than 3.5 μm, a width of the second end portion 320 is not less than 2 μm, and on a same side of an isolation structure 300, a second spacing L1 between an orthographic projection, on a plane where the substrate 100 is located, of an edge of an effective functional region 202 and an orthographic projection, on the plane where the substrate 100 is located, of the edge of the second end portion 320 is not less than 0.75 μm, and a gap of the sub-pixels is not less than 5 μm. For example, further, a second inclination angle is 40 degrees to 70 degrees.

For example, referring to FIG. 5 again, on a cross-section perpendicular to a substrate 100 and on a same side of an isolation structure 300, an acute angle formed by a straight line P4 determined by an edge of a second electrode 230 and an edge of a second end portion 320 and a plane where the substrate 100 is located is a first inclination angle Θ1, the first inclination angle Θ1 is less than a second inclination angle Θ2, an acute angle formed by a straight line P3 determined by an edge of an effective functional region 202 and the edge of the second end portion 320 and the plane where the substrate 100 is located (for example, a straight line P0) is less than or equal to the first inclination angle Θ1. In this case, the first inclination angle Θ1 may be designed to be 20 degrees to 70 degrees.

For example, referring again to FIG. 5, the acute angle formed by the straight line P3 determined by the edge of the effective functional region 202 and the edge of the second end portion 320 and the plane where the substrate 100 is located (for example, a straight line P0 included thereof) is equal to the first inclination angle Θ1, an acute angle formed by a straight line P6 determined by an edge of a surface, facing the substrate 100, of a first end portion 310 and the edge of the second end portion 320 and the plane where the substrate is located is equal to the second inclination angle Θ2, that is L1=H/tan Θ2 (a film thickness of a first electrode and a light-emitting functional layer is ignored when H is calculated in the formula) and L2=h1/tan Θ1. For example, a width of the second end portion 320 is 3.5 μm, a width of the first end portion 310 is 2 μm, and on a same side of the isolation structure 300, a second spacing L1 between an orthographic projection, on the plane where the substrate 100 is located, of the edge of the effective functional region 202 and an orthographic projection, on the plane where the substrate 100 is located, of the edge of the second end portion 320 is 0.75 μm, and a gap of sub-pixels is 5 μm. For example, still further, in each pixel, an average width of the sub-pixels is 1.35 μm, and an arrangement density of pixels is 1333 PPI or 2000 PPI.

For example, in a pixel arrangement structure shown in FIG. 2 and FIG. 14, a width of a first sub-pixel B, a width of a second sub-pixel G, and a width of a third sub-pixel R are all 1.35 μm; or the width of the first sub-pixel B is greater than 1.35 μm, and the width of the third sub-pixel R is less than 1.35 μm, and an average width of the first sub-pixel B, the second sub-pixel G, and the third sub-pixel R is 1.35 μm. Under the above design, a width (which may be referred to as pitch) of each pixel (including the first sub-pixel B, the second sub-pixel G, and the third sub-pixel R) is 19.05 μm, and an arrangement density of the pixels is 1333 PPI. For a design of the average width of the sub-pixels, reference may be made to related descriptions in the foregoing embodiments, and details are not described herein again.

For example, in a pixel arrangement structure shown in FIG. 15, a width of a second sub-pixel G and a width of a third sub-pixel R are both 1.35 μm; or the width of the second sub-pixel G and the width of the third sub-pixel R are sequentially reduced, a width of a first sub-pixel is greater than 1.35 μm, and the width of the second sub-pixel and the width of the third sub-pixel are equal and less than 1.35 μm. Under the above design, a width (which may be referred to as pitch) of each pixel P (including the first sub-pixel B, the second sub-pixel G, and the third sub-pixel R) is 12.7 μm, and an arrangement density of the pixels is 2000 PPI. For the design of the average width of the sub-pixels, reference may be made to related descriptions in the foregoing embodiments, and details are not described herein again.

In some embodiments of the present application, a pixel density may be increased by reducing a spacing between sub-pixels and reducing a width of a sub-pixel. For example, an average width of the sub-pixels may be designed to be no less than 4.8 μm, and a gap of the sub-pixels is designed to be no less than 12 μm and not greater than 17 μm, and an arrangement density of pixels is 404 PPI to 756 PPI, where the arrangement density of the pixels is approximately 504 PPI or 756 PPI in a case that the average width of the sub-pixels is designed to be 4.8 μm and the gap of the sub-pixels is designed to be 7 μm.

For example, the display panel may further include a substrate and a display functional layer located on the substrate, and the display functional layer includes a plurality of light-emitting devices corresponding to the sub-pixels. In each of the plurality of light-emitting devices, for a type and a positional relationship of each film layer and a positional relationship between each film layer and an isolation structure, refer to related descriptions in the foregoing embodiments related to FIG. 1 to FIG. 3, which is not repeated again herein. In addition, in this embodiment, referring to FIG. 4 again, a distance between an edge of a first end portion 310 and an edge of a second end portion 320 along a direction perpendicular to a substrate 100 is not less than 0.6 μm, a width of the first end portion 310 is not less than 2 μm, a width of the second end portion 320 is not less than 4 μm, and on a same side of an isolation structure 300, a second spacing L1 between an orthographic projection, on a plane where the substrate 100 is located, of an edge of an effective functional region 202 and an orthographic projection, on the plane where the substrate 100 is located, of the edge of the second end portion 320 is not less than 4 μm, and a gap of the sub-pixels is not less than 12 μm. For example, further, a second inclination angle is 40 degrees to 70 degrees.

For example, referring to FIG. 5 again, on a cross-section perpendicular to a substrate 100 and on a same side of an isolation structure 300, an acute angle formed by a straight line P4 determined by an edge of a second electrode 230 and an edge of a second end portion 320 and a plane where the substrate 100 is located is a first inclination angle Θ1, the first inclination angle Θ1 is less than a second inclination angle Θ2, an acute angle formed by a straight line P3 determined by an edge of an effective functional region 202 and the edge of the second end portion 320 and the plane where the substrate 100 is located (for example, a straight line P0) is less than or equal to the first inclination angle Θ1. In this case, the first inclination angle Θ1 may be designed to be 20 degrees to 70 degrees.

For example, referring again to FIG. 5, the acute angle formed by the straight line P3 determined by the edge of the effective functional region 202 and the edge of the second end portion 320 and the plane where the substrate 100 is located (for example, a straight line P0 included thereof) is equal to the first inclination angle Θ1, an acute angle formed by a straight line P6 determined by an edge of a surface, facing the substrate 100, of a first end portion 310 and the edge of the second end portion 320 and the plane where the substrate is located is equal to the second inclination angle Θ2, that is L1=H/tan Θ2 (a film thickness of a first electrode and a light-emitting functional layer is ignored when H is calculated in the formula) and L2=h1/tan Θ1. For example, a width of the first end portion 310 is 2 μm, a width of the second end portion 320 is 4 μm, and on the same side of the isolation structure 300, a second spacing L1 between an orthographic projection, on the plane where the substrate 100 is located, of the edge of the effective functional region 202 and an orthographic projection, on the plane where the substrate 100 is located, of the edge of the second end portion 320 is 4 μm, and a gap of sub-pixels is 12 μm. For example, still further, in each pixel, an average width of the sub-pixels is 4.8 μm, and an arrangement density of pixels is 504 PPI or 756 PPI.

For example, in a pixel arrangement structure shown in FIG. 2 and FIG. 14, a width of a first sub-pixel B, a width of a second sub-pixel G, and a width of a third sub-pixel R are all 4.8 μm; or the width of the first sub-pixel B is greater than 4.8 μm, and the width of the third sub-pixel R is less than 4.8 μm, and an average width of the first sub-pixel B, the second sub-pixel G, and the third sub-pixel R is 4.8 μm. Under the above design, a width (which may be referred to as pitch) of each pixel (including the first sub-pixel B, the second sub-pixel G, and the third sub-pixel R) is 50.4 μm, and an arrangement density of the pixels is 504 PPI. For a design of the average width of the sub-pixels, reference may be made to related descriptions in the foregoing embodiments, and details are not described herein again.

For example, in a pixel arrangement structure shown in FIG. 15, a width of a second sub-pixel G and a width of a third sub-pixel R are both 4.8 μm; or the width of the second sub-pixel G and the width of the third sub-pixel R are sequentially reduced, a width of a first sub-pixel is greater than 4.8 μm, and the width of the second sub-pixel and the width of the third sub-pixel are equal and less than 4.8 μm. Under the above design, a width (which may be referred to as pitch) of each pixel P (including the first sub-pixel B, the second sub-pixel G, and the third sub-pixel R) is 33.6 μm, and an arrangement density of the pixels is 756 PPI. For the design of the average width of the sub-pixels, reference may be made to related descriptions in the foregoing embodiments, and details are not described herein again.

In some embodiments of the present application, a pixel density may be increased by reducing a spacing between sub-pixels and reducing a width of a sub-pixel. For example, an average width of the sub-pixels may be designed to be no less than 2.8 μm, and a gap of the sub-pixels is designed to be no less than 10 μm and not greater than 17 μm, and an arrangement density of pixels is 404 PPI to 756 PPI, where the arrangement density of the pixels is approximately 661 PPI or 992 PPI in a case that the average width of the sub-pixels is designed to be 2.8 μm and the gap of the sub-pixels is designed to be 7 μm.

For example, the display panel may further include a substrate and a display functional layer located on the substrate, and the display functional layer includes a plurality of light-emitting devices corresponding to the sub-pixels. In each of the plurality of light-emitting devices, for a type and a positional relationship of each film layer and a positional relationship between each film layer and an isolation structure, refer to related descriptions in the foregoing embodiments related to FIG. 1 to FIG. 3, which is not repeated again herein. In addition, in this embodiment, referring to FIG. 4 again, a distance between an edge of a first end portion 310 and an edge of a second end portion 320 along a direction perpendicular to a substrate 100 is not less than 0.6 μm, a width of the first end portion 310 is not less than 2 μm, a width of the second end portion 320 is not less than 4 μm, and on a same side of an isolation structure 300, a second spacing L1 between an orthographic projection, on a plane where the substrate 100 is located, of an edge of an effective functional region 202 and an orthographic projection, on the plane where the substrate 100 is located, of the edge of the second end portion 320 is not less than 3 μm, and a gap of the sub-pixels is not less than 10 μm. For example, further, a second inclination angle is 40 degrees to 70 degrees.

For example, referring to FIG. 5 again, on a cross-section perpendicular to a substrate 100 and on a same side of an isolation structure 300, an acute angle formed by a straight line P4 determined by an edge of a second electrode 230 and an edge of a second end portion 320 and a plane where the substrate 100 is located is a first inclination angle Θ1, the first inclination angle Θ1 is less than a second inclination angle Θ2, an acute angle formed by a straight line P3 determined by an edge of an effective functional region 202 and the edge of the second end portion 320 and the plane where the substrate 100 is located (for example, a straight line P0) is less than or equal to the first inclination angle Θ1. In this case, the first inclination angle Θ1 may be designed to be 20 degrees to 70 degrees.

For example, referring again to FIG. 5, the acute angle formed by the straight line P3 determined by the edge of the effective functional region 202 and the edge of the second end portion 320 and the plane where the substrate 100 is located (for example, a straight line P0 included thereof) is equal to the first inclination angle Θ1, an acute angle formed by a straight line P6 determined by an edge of a surface, facing the substrate 100, of a first end portion 310 and the edge of the second end portion 320 and the plane where the substrate is located is equal to the second inclination angle Θ2, that is L1=H/tan Θ2 (a film thickness of a first electrode and a light-emitting functional layer is ignored when H is calculated in the formula) and L2=h1/tan Θ1. For example, a width of the first end portion 310 is 2 μm, a width of the second end portion 320 is 4 μm, and on the same side of the isolation structure 300, a second spacing L1 between an orthographic projection, on the plane where the substrate 100 is located, of the edge of the effective functional region 202 and an orthographic projection, on the plane where the substrate 100 is located, of the edge of the second end portion 320 is 3 μm, and a gap of sub-pixels is 10 μm. For example, still further, in each pixel, an average width of the sub-pixels is 2.8 μm, and an arrangement density of pixels is 661 PPI or 992 PPI.

For example, in a pixel arrangement structure shown in FIG. 2 and FIG. 14, a width of a first sub-pixel B, a width of a second sub-pixel G, and a width of a third sub-pixel R are all 2.8 μm; or the width of the first sub-pixel B is greater than 2.8 μm, and the width of the third sub-pixel R is less than 2.8 μm, and an average width of the first sub-pixel B, the second sub-pixel G, and the third sub-pixel R is 2.8 μm. Under the above design, a width (which may be referred to as pitch) of each pixel (including the first sub-pixel B, the second sub-pixel G, and the third sub-pixel R) is 38.4 μm, and an arrangement density of the pixels is 661 PPI. For a design of the average width of the sub-pixels, reference may be made to related descriptions in the foregoing embodiments, and details are not described herein again.

For example, in a pixel arrangement structure shown in FIG. 15, a width of a second sub-pixel G and a width of a third sub-pixel R are both 2.8 μm; or the width of the second sub-pixel G and the width of the third sub-pixel R are sequentially reduced, a width of a first sub-pixel is greater than 2.8 μm, and the width of the second sub-pixel and the width of the third sub-pixel are equal and less than 2.8 μm. Under the above design, a width (which may be referred to as pitch) of each pixel P (including the first sub-pixel B, the second sub-pixel G, and the third sub-pixel R) is 25.6 μm, and an arrangement density of the pixels is 992 PPI. For the design of the average width of the sub-pixels, reference may be made to related descriptions in the foregoing embodiments, and details are not described herein again.

It should be noted that, in the embodiments of the present application, an improvement of a pixel density is based on a condition of a currently existing preparation process, that is, a PPI is further improved under the condition of the currently existing preparation process, such as photolithography precision, alignment precision (for example, alignment precision of photolithography), with a development of technologies, the condition mentioned above may be further improved, and in this case, the pixel density mentioned in the embodiments of the present application may be further improved, for example, a gap of a first electrode and a width of a supporting portion may be further reduced, and a width of a sub-pixel (or an effective function region) may be further reduced.

For example, in an embodiment of the present application, the display panel may include an encapsulation layer covering a display functional layer, and the encapsulation layer may isolate a light-emitting device in the display functional layer and have a planarization function, to provide functional structures such as a touch functional layer, a polarizer, a lens layer, and a cover plate on the encapsulation layer. For example, the encapsulation layer may include a first encapsulation layer (mentioned in the foregoing embodiments), a second encapsulation layer and a third encapsulation layer sequentially stacked on the display functional layer, both the first encapsulation layer and the third encapsulation layer are inorganic film layers, the inorganic film layers have high compactness to isolate water and oxygen, and the second encapsulation layer is an organic encapsulation layer, thereby having a large thickness and a planarization function.

Some basic designs with isolation structures and principles thereof that may increase a pixel density (PPI) of the display panel are generally described above. However, in practical applications, when an isolation structure is provided, the isolation structure may have different design shapes, and there may be other designs in the display panel, for example, the first encapsulation layer described above, an optical functional unit, a protective layer and the like which will be described in the following. Therefore, under a condition of considering different specific designs of the display panel, a minimum size of the width (related to a width of the isolation structure between two first openings) between sub-pixels of the display panel can be explored under a condition that a function of an involved specific structure is ensured, to obtain a design method of how to obtain a maximum pixel density as much as possible under different designs of the display panel, which is specifically as follows.

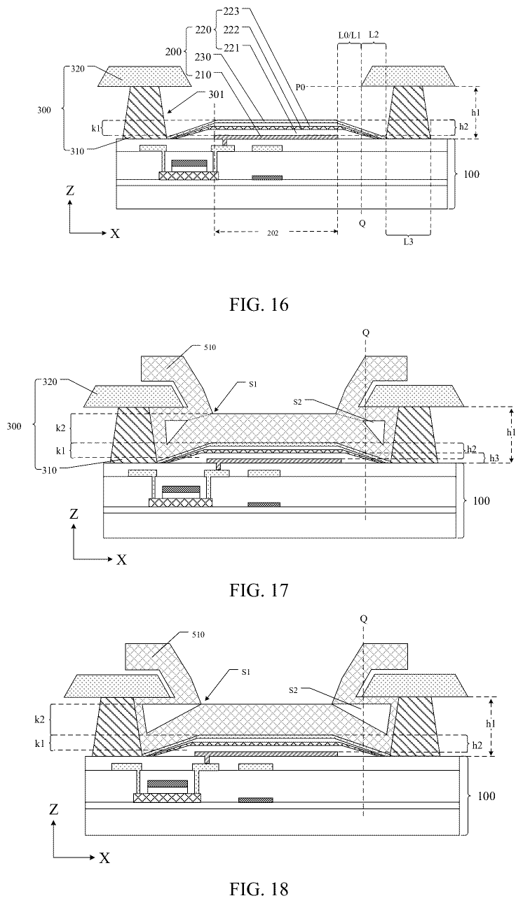

At least one embodiment of the present application provides a display panel, as shown in FIG. 16 and FIG. 17, the display panel includes a substrate 100 and an isolation structure 300 located on the substrate 100, a display functional layer and a first encapsulation layer 510. The isolation structure 300 is located on the substrate 100 and has a first end portion 310 and a second end portion 320, the second end portion 320 is located on a side, away from the substrate 100, of the first end portion 310, an orthographic projection, on a plane where the substrate 100 is located, of the first end portion 310 is located within an orthographic projection, on the plane where the substrate 100 is located, of the second end portion 320, the isolation structure defines a plurality of first openings 301. The display functional layer is located on the substrate 100 and includes a plurality of light-emitting devices 200, where the plurality of light-emitting devices 200 correspond to the plurality of first openings 301 respectively, each light-emitting device 200 of the plurality of light-emitting devices 200 is located in a first opening 301, corresponding to the light-emitting device 200, of the plurality of first openings 301, the light-emitting device 200 includes a first electrode 210, a light-emitting functional layer 220 and a second electrode 230 stacked on the substrate, and the first opening 301 is configured to limit the light-emitting device 200 corresponding to the first opening 301. The first encapsulation layer 501 is located on a side, away from the substrate 100, of the display functional layer. An orthographic projection, on the plane where the substrate 100 is located, of a part of an edge portion of each one of at least one of film layers of the light-emitting device 200 is located within the orthographic projection, on the plane where the substrate 100 is located, of the second end portion 320. For relationships between structures involved in the display panel and functions achieved, reference may be made to related descriptions in the foregoing embodiments, and details are not described herein again.

It should be noted that the each one of at least one of film layers of the light-emitting device 200 may include the light-emitting functional layer mentioned in the foregoing embodiments, or may include the light-emitting functional layer and the second electrode mentioned in the foregoing embodiments. The part of the edge portion of each one of at least one of film layers may refer to a portion with uneven thickness distribution in the each one of at least one of film layers, for example, during an entire vapor deposition process of the film layers, when edge portions of different film layers is formed, a vapor deposition material sprayed from the vapor deposition device may be blocked in different degrees by the isolation structure; and sizes of the edge portions of the different film layers may be different due to different vapor deposition angles and different film layer positions.

For example, as shown in FIG. 16 and FIG. 17, along a direction from a middle portion of a light-emitting device 200 to a corresponding edge, a thickness of an edge portion of each one of at least one of film layers of the light-emitting device 200 gradually decreases. In this way, some of the film layers in the light-emitting device, such as a light-emitting functional layer 220 and a second electrode 230, are formed by performing auxiliary vapor deposition through an isolation structure 300, and the isolation structure may limit a vapor deposition range of a vapor deposition material, and at the edges of the film layers, as a distance from the isolation structure is closer, thicknesses of the film layers becomes smaller and smaller, accordingly, a thickness of the light-emitting device 200 at an edge of a second end portion 320 is smaller than a thickness at the middle portion, accordingly, a height of the isolation structure 300 (for example, a first height described below) can be designed, and the isolation structure 300 has a relatively small height while ensuring an encapsulation effect of the first encapsulation layer 510, to further reduce a width of a portion, between adjacent first openings 301, of the isolation structure 300, thereby improving an aperture ratio, a pixel density, and the like of a display panel.

Please refer to FIG. 14 and FIG. 15, the display panel includes a plurality of sub-pixels, and each sub-pixel of the plurality of sub-pixels includes two opposite long sides Lc and two opposite short sides Sh; at least one sub-pixel only has an edge portion with a gradually decreasing thickness in a direction from a middle portion of the light-emitting device to a corresponding edge at the short sides Sh, while the long sides Lc does not have an edge portion gradually decreasing in the direction from the middle portion of the light-emitting device to the corresponding edge. In this way, an aperture ratio of the display panel can be further improved. In addition, according to requirements, it is may be that at least one sub-pixel only has an edge portion with a gradually decreasing thickness in the direction from the middle portion of the light-emitting device to the corresponding edge at the long sides Lc, while the short sides Lc does not have an edge portion gradually decreasing in the direction from the middle portion of the light-emitting device to the corresponding edge.

In at least one embodiment of the present application, as shown in FIG. 16 and FIG. 17, a distance from an edge of a second end portion 320 to an edge of a first end portion 310 is a first height h1 along a direction perpendicular to a plane where a substrate 100 is located, and a distance between a first encapsulation layer 510 and a first electrode 210 is a second height h2 at an intermediate position of a light-emitting device 200. A product of the second height h2 and a first thickness coefficient k is a first numerical value, and a difference between the first height h1 and the first numerical value is not less than an encapsulation safety margin. Based on the foregoing calculation relationship, when a display panel is designed, a distance between the first electrode 210 and the first encapsulation layer 510 may be determined according to a film layer structure to be disposed between the first electrode 210 and the first encapsulation layer 510 of the light-emitting device, to obtain a smaller value of the first height h1, thereby facilitating finding a smaller width of the isolation structure 300 that can be designed between adjacent first openings 301, to improve an aperture ratio and a PPI of the display panel.

In at least one embodiment of the present application, in a regular cross-section of a light-emitting device, a distance between a position of a surface, facing a substrate 100, of a first encapsulation layer 510 that located on a straight line passing through an edge of a second end portion 320 and perpendicular to a plane where the substrate 100 is located and an edge of a first end portion 310 along a direction perpendicular to the plane where the substrate 100 is located is a partition association height h3 (may be referred to as a third height), a distance between the edge of the second end portion 320 and the edge of the first end portion 310 in the direction perpendicular to the plane where the substrate 100 is located is a first height h1, and a difference between the first height h1 and the partition association height (the third height) h3 is not less than an encapsulation safety margin.

In one embodiment, M is a ratio of the partition association height to a second height. In one embodiment, a first thickness coefficient is greater than or equal to M and less than 1, and M ∈[0.3, 0.5) or M∈[0.5, 0.7]. In one embodiment, the first thickness coefficient is equal to M. In one embodiment, the first thickness coefficient is greater than or equal to 0.5 and less than 1.

It should be noted that a theoretical value of M is 0.5, and due to an influence of factors such as a static electricity, an adsorption performance of an adopted material, a strength of a related material and the like in a process of vapor-depositing of related film layers by means of an isolation structure, the partition association height h3 can deviate from the theoretical value; correspondingly, according to an actual situation, a value of M may be changed within a range of 0.5±0.2, and a specific value may be obtained through experiments or reference experience.

In one embodiment, the first thickness coefficient is equal to 0.5. In this way, the first height h1 is advantageously taken to a small value, thereby facilitating an improvement of a pixel density of the display panel.

It should be noted that the encapsulation safety margin is required for forming the first encapsulation layer capable of meeting functional requirements, and corresponding to a distance between a lower surface, passing through the edge of the second end portion and perpendicular to a straight line of the plane where the substrate is located, of the first encapsulation layer and the edge of the second end portion; that is, the first packaging layer formed on a surface of the isolation structure by means of a space meets requirements of a corresponding encapsulation safety margin can meet a required functional effect, for example, the encapsulation safety margin may be different according to different conditions such as related structures, materials and the like in a subsequent process and product use process, and can be obtained through experiments or experience according to specific conditions. When the encapsulation safety margin need to be determined, if a distance X between the edge, corresponding to a straight line passing through the second end portion and perpendicular to the plane where the substrate is located, of the second end portion and the lower surface of the first encapsulation layer meet the functional requirements and it is determined that there is no value less than a value of X and meets the requirements, it should be determined that the value of X is the encapsulation security margin; and when it is determined that a plurality of values can meet the functional requirements, a minimum value may be used as the encapsulation security margin.

For example, when a color an emitted light of the light emitting device is different, a light-emitting device with largest thickness may be selected as a reference to design parameters such as the first height h1. For example, the light-emitting device with largest thickness may be a light-emitting device emitting red light.

It should be noted that the first encapsulation layer 510 may be formed by chemical vapor deposition, atomic layer deposition, or the like, and if the first height h1 is too small, a thickness of a film layer of the first encapsulation layer 510 formed at a sidewall of the isolation structure is too small, which may result in an inability to effectively protect structures such as corresponding light-emitting devices.

It should be noted that, as shown in FIG. 16, if the first encapsulation layer 510 is directly formed on the light-emitting device 200 after a preparation of the light-emitting device 200 is completed, a design thickness of a vapor deposition film layer (for example, the light-emitting functional layer 220 and the second electrode 230) in the light-emitting device 200 may be equal to the second-height h2, for example, at an intermediate position of the light-emitting device 200, in a whole vapor deposition process, a vapor deposition at the intermediate position does not blocked by the isolation structure 300, and a thickness of the vapor deposition film layer at the intermediate position is the largest, and the thickness of the film layer at the intermediate position is a design thickness of the film layer.

In at least one embodiment of the present application, as shown in FIG. 17, as shown in FIG. 17, in an intermediate position of a light-emitting device 200, a first encapsulation layer 510 has a second thickness k2, and the second thickness k2 is a thickness of a middle portion, covering the light-emitting device, of the first encapsulation layer 510. The first encapsulation layer 510 covers the light-emitting device 200 and a side surfaces of a portion of a second end portion 320, and an encapsulation safety margin is equal to a product of the second thickness k2 and a second thickness coefficient n.

In an example, as shown in FIG. 17, as shown in FIG. 17, at a sidewall of an isolation structure 300, a specific structure corresponding to the isolation structure, a selection of a second thickness coefficient n and a second thickness k2 may cause a first encapsulation layer 510 to enclose an enclosed chamber (at a position of S2).

For example, in another example, as shown in FIG. 18, at a sidewall of an isolation structure 300, a specific structure corresponding to the isolation structure, a selection of a second thickness coefficient n and a second thickness k2 may enable an opening of a chamber of a first encapsulation layer 510 to be just closed.

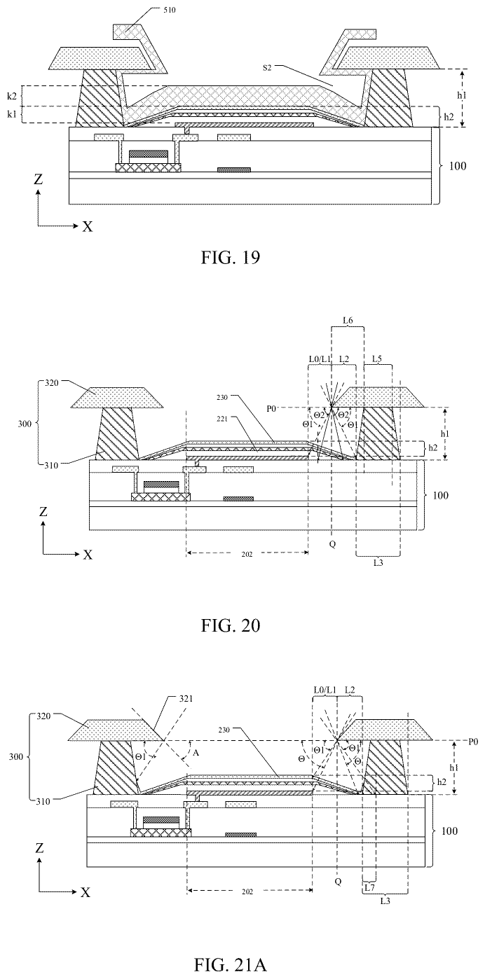

For example, in another example, as shown in FIG. 19, at a sidewall of an isolation structure 300, a specific structure corresponding to the isolation structure, a selection of a second thickness coefficient n, and a second thickness k2 may enable a first encapsulation layer 510 to enclose a chamber having an opening. On a premise of ensuring an encapsulation effect, a value of an encapsulation safety margin is small, and the isolation structure 300 may have a smaller height, and a width between adjacent first openings (see L in FIG. 5) is small, to improve a pixel density of the display panel.

For example, the second thickness coefficient n may be a value of 0.2 to 2; generally, when the second thickness coefficient n may be less than 2, the second thickness coefficient n corresponds to an isolation structure of some structures (such as the isolation structure of the structure shown in FIG. 16), and a closed chamber is formed on a side surface of the isolation structure 300.

For example, the second thickness coefficient n is 0.25 to 1.2. For example, further, the second thickness coefficient n is 0.3 to 0.8. For the isolation structure of some structural forms (such as the isolation structure of the structure shown in FIG. 16), a value of the second thickness coefficient n can be more conducive to ensuring an encapsulation effect, but a size between pixels is not increased; based on this, a numerical value in a range of 0.3 to 0.8 is selected for the second thickness coefficient n to obtain a better comprehensive effect.

In at least one embodiment of the present application, as shown in FIG. 20, a distance between an orthographic projection, on a plane where a substrate 100 is located, of an edge of a second end portion 320 and an orthographic projection, on the plane where the substrate 100 is located, of an edge of a first end portion 310 is a first width L2, in a regular cross-section of a light-emitting device 200, an acute angle formed by intersecting a straight line passing through an edge of a second electrode 230 and the edge of the second end portion 320 with the plane where the substrate 100 is located is a first inclination angle Θ1, the first width L2 is less than a product of a first height h1 and a cotangent value of the first inclination angle Θ1, that is, L2<h1*cot Θ1. The first inclination angle Θ1 may correspond to a vapor deposition angle of the second electrode 230 during a vapor deposition, and by controlling a numerical relationship between the first width L2, the first height h1 and the vapor deposition angle Θ1, it can be ensured that the edge of the second electrode 230 may be overlapped on an isolation structure 300 (for example, the first end portion 310 thereof), thereby ensuring that the second electrode 230 of the light-emitting device 200 is connected to an external circuit (for example, a common electrode line or a pixel driving circuit thereof) through the isolation structure 300.

It should be noted that, if “less than” relationship above-mentioned is replaced by an “equal” relationship, that is, L2=h1*cot Θ1, the second electrode 230 is just in contact with a sidewall of a partition portion, and in the “less than” relationship above-mentioned, the second electrode 230 may have a certain climbing height (for example, an upturned tail portion described below) on a side surface of the partition portion.

It should be noted that, in the embodiments of the present application, an edge of a first end portion is an edge of an outer side closest to a substrate in an exposed portion of the first end portion when a light-emitting functional layer is prepared, or the edge of the first end portion is the edge of the outer side closest to the substrate in the exposed portion of the first end portion after all light-emitting functional layers are removed. An edge of a second end portion is an edge outside the second end portion.

The “regular cross-section of a light-emitting device” may be a cross-section perpendicular to a plane where the substrate is located and parallel to a direction from one first opening to another adjacent first opening, and may be a normal plane perpendicular to the plane where the substrate is located and an edge line of the second end portion.

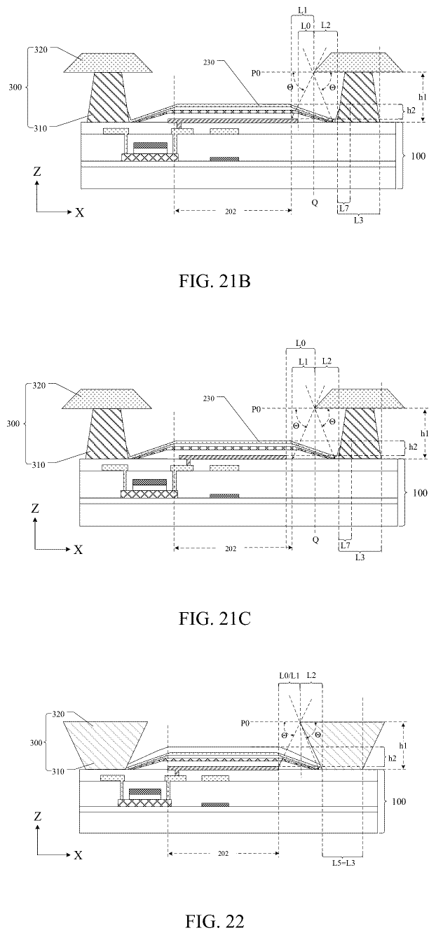

For example, as shown in FIG. 21A, a second electrode 230 has an upturned tail portion overlapping a side surface of a first end portion 310, that is, in a regular cross-section of a light emitting device 200, an acute angle formed by intersecting a straight line passing through an edge of the second electrode 230 with an edge of a second end portion 320 with a plane where a substrate 100 is located is less than an acute angle formed by intersecting a straight line passing through an edge of the first end portion 310 and the edge of the second end portion 320 with the plane where the substrate 100 is located. In this way, in a process of vapor-depositing a conductive material to form the second electrode 230, the conductive material may be vapor-deposited on a sidewall of the first end portion 310 to form the upturned tail portion.

For example, in a structure shown in FIG. 21A, a size of the upturned tail portion may be designed based on size L7, that is: a difference L7 between a product of a cotangent value of an acute angle Θ1 formed by intersecting a straight line determined by an edge of a second electrode 230 and an edge of a second end portion 320 with a plane where a substrate 100 is located and a first height h1 and a first width L2 between an edge of a first end portion 310 and the edge of the second end portion 320 in a direction parallel to the plane where the substrate 100 is located. The size L7 is not less than a safety size, and the safety size may be a preset value, to ensure that the second electrode 230 and an isolation structure 300 have sufficient contact area, to prevent a contact resistance between the second electrode 230 and the isolation structure 300 from being too large. For example, the safety size is related to factors such as material of the second electrode 230 and a magnitude of currents that needs to be carried, and may be specifically obtained through experiments or obtained through experience.

For example, as shown in FIG. 21A, in a regular cross-section of a light-emitting device 200, an acute angle formed by intersecting a straight line passing through an edge of a light-emitting functional layer 220 and the edge of the second end portion 320 with the plane where the substrate 100 is located is an inclination angle of the light-emitting functional layer, and the inclination angle of the light-emitting functional layer is greater than the first inclination angle Θ1, and the second electrode 230 may completely cover the light-emitting functional layer 220, and the edge of the second electrode 230 may be connected with the isolation structure 300.

For example, the first width L2 is greater than a product of the first height h1 and a cotangent value of the inclination angle of the light-emitting functional layer, and the edge of the light-emitting functional layer 220 does not extend to a sidewall of the isolation structure 300, thereby avoiding an electric leakage between a lower side of the light-emitting functional layer 220 and the isolation structure 300 to improve a light-emitting efficiency.

For example, referring to FIG. 16 to FIG. 21A, the light-emitting functional layer 220 includes a first functional layer 221, in a regular cross-section of the light-emitting device 200, an acute angle formed by intersecting a straight line passing through an edge of the first functional layer 221 and the edge of the second end portion 320 with the plane where the substrate 100 is located is a second inclination angle Θ2, and the second inclination angle Θ2 is greater than the inclination angle of the light-emitting functional layer. In the light-emitting device 200, the first functional layer 221 is covered by another film layer (for example, a light-emitting layer, a second functional layer, and the like.) in the light-emitting functional layer 220, and the first functional layer 221 is not directly connected with the second electrode 230; furthermore, compared with the edge of the entire light-emitting functional layer 220, a distance between the edge of the first functional layer 221 and the isolation structure 300 is larger, and the first functional layer 221 can be prevented from being connected together through the isolation structure 300, thereby avoiding an electric leakage between the first functional layer 221 and the isolation structure 300 to improve the light-emitting efficiency.

For example, referring to FIG. 16 to FIG. 21A, the light-emitting functional layer 220 further includes a light-emitting layer 222 and a second functional layer 223, and the light-emitting layer 222 and the second functional layer 223 cover the edge of the first functional layer 221. The design may prevent the first functional layer 221 from directly connecting with the second electrode 230 across the light-emitting layer 222 and the second functional layer 223, to ensure the light-emitting effect of the light-emitting device 200.

In at least one embodiment of the present application, referring to FIG. 16 to FIG. 21A, a second electrode 230 is formed by an isolation structure 300, and therefore, the closer an edge portion of the second electrode 230 is to the isolation structure 300, the smaller a thickness of the second electrode 230.

In a regular cross-section of a light-emitting device 200, a thickness of a position, passing through an edge of a first electrode 210 and perpendicular to a plane where a substrate 100 is located, of the second electrode 230 is less than a thickness of a portion, corresponding to an intermediate position of a light-emitting device 200, of the second electrode 230. In this way, a better overlap between the second electrode 230 and the isolation structure 300 may be implemented by using a smaller first inclination angle Θ1.

In at least one embodiment of the present application, as shown in FIGS. 20 and 21A, an orthographic projection, on a plane where a substrate 100 is located, of an edge of a second end portion 320 is located within an orthographic projection, on the plane where the substrate 100 is located, of an edge of a first electrode 210 and an orthographic projection, on the plane where the substrate 100 is located, of an edge of a first end portion 310. According to the design, the edge of the first electrode 210 does not extend below the second end portion 320, and a height of a surface of the light-emitting device 200 at the edge is not increased due to an arrangement of the first electrode 210, and a first encapsulation layer 510 has a good encapsulation effect, and accordingly, an overall design height of an isolation structure 300 may be reduced, thereby further reducing a width of a portion, between adjacent first openings 301, of the isolation structure 300, and achieving better light-emitting quality.

For example, in some designs, as shown in FIG. 21B, the first electrode 210 shown in FIG. 20 and FIG. 21A may be modified, and a distribution of the first electrode 210 can extend into a second spacing L1, that is, an orthographic projection, on a plane where a substrate 100 is located, of an edge of the first electrode 210 is located between an orthographic projection, on the plane where the substrate 100 is located, of an edge of a second end portion 320 and an orthographic projection, on the plane where the substrate 100 is located, of an edge of a first end portion 310. In this way, on a regular cross-section of a light-emitting device 200, the first spacing L0 between the orthographic projection, on the plane where the substrate 100 is located, of the edge of the first electrode 210 and the orthographic projection, on the plane where the substrate 100 is located, of the edge of the second end portion 320 is less than: a product L1 of a cotangent value of an acute angel (set as Q) formed by intersecting a connecting line between an edge of a light-emitting functional layer 220 and the edge of the second end portion 320 with the plane where the substrate 100 is located and a distance between an intermediate portion of a lower surface, facing the substrate 100, of the light-emitting functional layer 220 and the edge of the second end portion 320 in a direction perpendicular to the plane where the substrate 100 is located, that is, the edge of the first electrode 210 extends into a range of the second spacing L1, and a thickness of the light-emitting functional layer 220 is uneven (gradually thinning) within the range of the second spacing L1. In this way, it can be ensured that the first electrode 210 has a larger area, and it can be better ensured that the first electrode 210 exists in a region (for example, the effective functional region 202 above-mentioned) with a uniform film thickness of the light-emitting functional layer 220, thereby improving an area of a uniform light-emitting region (with the uniform film thickness of the light-emitting functional layer 220) of the light-emitting device 200, to increase an aperture ratio of the display panel; furthermore, the design provides sufficient margin for an alignment precision of the first electrode 210 and the isolation structure 300, and even if there is position offsets of the first electrode 210 and the isolation structure 300, it can also be ensured that area and position of the uniform light-emitting region of the light-emitting device 200 are not affected.

For example, in some other designs, as shown in FIG. 21A and FIG. 21C, in a regular cross-section of the light-emitting device 200, a product L1 of a cotangent value of an acute angel (set as Θ) formed by intersecting a connecting line between an edge of a light-emitting functional layer 220 and the edge of the second end portion 320 with the plane where the substrate 100 is located and a distance between an intermediate portion of a lower surface of the light-emitting functional layer 220 and the edge of the second end portion 320 in a direction perpendicular to the plane where the substrate 100 is located is less than or equal to: a distance L0 between the orthographic projection, on the plane where the substrate 100 is located, of the edge of the first electrode 210 and the orthographic projection, on the plane where the substrate 100 is located, of the edge of the second end portion 320. And, in a region where the first electrode 210 is distributed in the light-emitting device 200, a film thickness of the light-emitting functional layer 220 is uniform, thereby ensuring that wavelengths of light emitted by a light-emitting region of the light-emitting device 200 are consistent, to eliminate a problem of stray light with different colors in the light-emitting device 200.

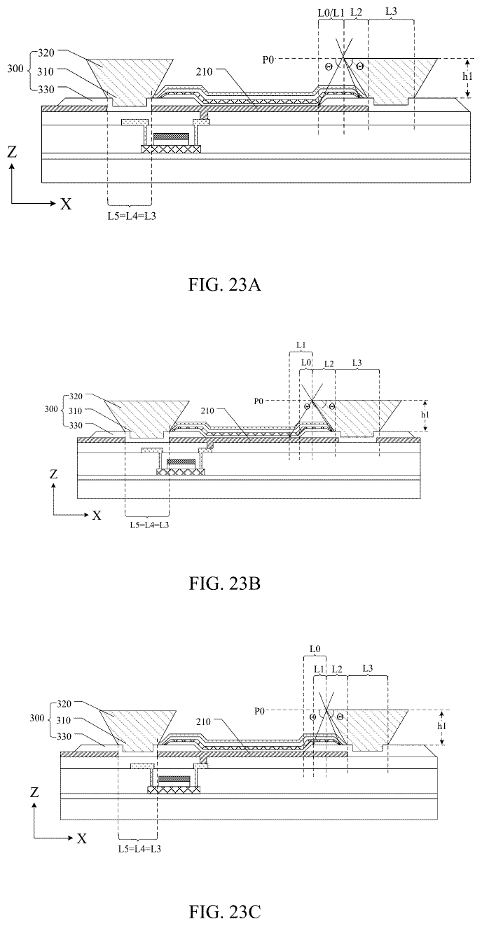

In an embodiment of the present application, a partition portion of an isolation structure 300 may be as shown in FIG. 21A, and includes a supporting portion 310 and a blocking portion 320, or may be shown in FIG. 22 and FIG. 23A, a portion of the isolation structure 300 located between two adjacent sub-pixels is generally in an inverted trapezoid shape, and for a specific design of the isolation structure 300 in the two forms, reference may be made to related descriptions in the foregoing embodiments, and details are not described herein again.

For example, as shown in FIG. 20 and FIG. 21A, when the partition portion of the isolation structure 300 is designed to include the supporting portion 310 and the blocking portion 320, between two adjacent first openings, a width L5 of a surface, facing the blocking portion 320, of the supporting portion 310 is not less than a safety width. Along a direction from any first opening to another adjacent first opening, a width of the isolation structure 300 is not less than a sum of twice the first width L2, twice a distance between an orthographic projection, on a plane where a substrate is located, of an edge of a top surface of the supporting portion 310 and an orthographic projection, on the plane where the substrate is located, of an edge of a bottom surface of the supporting portion 310 (a difference between L6 and L2) and a safety width (a minimum value of L5). It should be noted that the difference between L6 and L2 may be determined according to an inclination degree of a sidewall of the supporting portion 310, and the larger the difference between L6 and L2 is, the more convenient an edge of a second electrode 320 is attached to the sidewall of the supporting portion 310; furthermore, the smaller the difference between L6 and L2, the smaller a width of the isolation structure 300 between two first openings, which helps to improve a pixel density of the display panel. The safety width refers to the width of the surface, facing the blocking portion 320, of the supporting portion 310 that meets a functional requirement, and the safety width may be obtained according to a test. When the safety width is determined, in a case when it is determined that a value of Z meets the functional requirement and there is no value less than the value of Z and meets the functional requirement, it should be determined that the value of Z is the safety width; and when it is determined that a plurality of values can meet the functional requirements, a minimum value may be used as the safety width.

For example, as shown in FIG. 21A, the partition portion of the isolation structure 300 includes a supporting portion 310 and a blocking portion 320 stacked on the substrate 100, the blocking portion 320 has an inclined sidewall 321 on a regular cross-section of a light-emitting device, a difference between an acute angle Theta 1 at which a connecting line between an edge of a second electrode 230 and an edge of the blocking portion 320 intersects the plane where the substrate 100 is located and an acute angle A at which a sidewall of the blocking portion 320 intersects the plane where the substrate 100 is located is not less than a preset angle; that is, the acute angle A at which the sidewall of the blocking portion 320 intersects the plane where the substrate 100 is located is less than the acute angle Theta 1 at which the connecting line between the edge of the second electrode 230 and the edge of the blocking portion 320 intersects the plane where the substrate 100 is located, and in a vapor deposition process, unwanted excessive shielding of a vapor deposition material on a surface, facing away from the substrate 100, of the blocking portion 320 is avoided. For example, the sidewall of the blocking portion 320 is a surface determined by an edge of a surface, facing the supporting portion 310, of the blocking portion 320 and an edge of a surface, facing away from the supporting portion 310, of the blocking portion 320. Further, in the embodiments of the present application, the preset angle should be satisfied: in the vapor deposition process of completing all the vapor deposition layers, a fact that the vapor deposition material above-mentioned being attached on the sidewall will not lead to more blocking of normal vapor deposition material to reach a corresponding position, and a specific numerical range of the preset angle is not further limited under the above conditions.

For example, as shown in FIG. 22 and FIG. 23A, in a case that the portion of the isolation structure 300 located between the two adjacent sub-pixels is generally in the inverted trapezoid shape, a width L5 of a surface, facing a substrate 100, of a first end portion 310 may be designed to be not less than a safety width, and a width of the isolation structure 300 is not less than a sum of twice of a first width L2 and the safety width along a direction from any first opening to another adjacent first opening. A minimum value of the safety width may be designed according to a process of preparing the isolation structure 300 (for example, a precision of processes such as photolithography). Similarly, the safety width refers to a width that satisfies a functional requirement that can be obtained from a trial test or experience. When the safety width is determined, in a case when it is determined that a value of Z meets the functional requirement and there is no value less than the value of Z and meets the functional requirement, it should be determined that the value of Z is the safety width; and when it is determined that a plurality of values can meet the functional requirements, a minimum value may be used as the safety width.

In the embodiment of the present application, the partition portion of the isolation structure 300 may be directly disposed on the substrate 100 as shown in FIG. 21A and FIG. 22, or as shown in FIG. 23A, the partition portion of the isolation structure 300 may be separated from the substrate 100 by another structure (for example, a pixel defining layer), and under different designs, a calculation manner of the width of the isolation structure 300 between the two first openings is different, which is specifically as follows.

In some embodiments of the present application, as shown in FIGS. 21A to 21 C and 22, the partition portion of the isolation structure 300 may be directly disposed on the substrate 100, that is, the partition portion is in direct contact with the substrate 100.

For example, in a specific example, as shown in FIG. 21B, when a partition portion of an isolation structure 300 is in direct contact with a substrate 100 (for example, the pixel defining layer is not provided), on a regular cross-section of a light-emitting device, a distance between an orthographic projection, on a plane where the substrate is located, of an edge of a first electrode and an orthographic projection, on the plane where the substrate is located, of an edge of a second end portion is less than: a product of a cotangent value of an acute angle at which a connecting line between an edge of a light-emitting functional layer and the edge of the second end portion intersects the plane where the substrate is located and a distance between an intermediate portion of a lower surface of the light-emitting functional layer and the edge of the second end portion in a direction perpendicular to the plane where the substrate is located, that is, a first spacing L0 and a second spacing L1 are not overlapped, and a size of the first spacing L0 is less than a size of the second spacing L. Specifically, the first distance L0 between the orthographic projection, on the plane where the substrate 100 is located, of the edge of the first electrode 210 and the orthographic projection, on the plane where the substrate 100 is located, of the edge of the second end portion 320 is less than: the product of the cotangent value of the acute angle at which the connecting line between the edge of the light-emitting functional layer 220 and the edge of the second end portion 320 intersects the plane where the substrate 100 is located and a difference between a first height h1 and a thickness of the first electrode.

For example, in another specific example, as shown in FIG. 21A and FIG. 21C, in the case that the partition portion of the isolation structure 300 is in direct contact with the substrate 100, on the regular cross-section of the light-emitting device, a product of a cotangent value of an acute angle at which a connecting line between an edge of a light-emitting functional layer and an edge of a second end portion intersects a plane where the substrate is located and a distance between an intermediate portion of a lower surface of the light-emitting functional layer and the edge of the second end portion in a direction perpendicular to the plane where the substrate is located is less than or equal to: a distance between an orthographic projection, on the plane where the substrate is located, of an edge of a first electrode and an orthographic projection, on the plane where the substrate is located, of the edge of the second end portion. It should be noted that, under a relationship that a first spacing L0 and a second spacing L1 are equal to each other, the first spacing L0 and the second spacing L1 coincide with each other as shown in FIG. 21A or FIG. 22; correspondingly, under a “less” relationship, the first spacing L0 is not overlapped with the second spacing L1, and a size of the first spacing L0 is greater than a size of the second spacing L1.

Specifically, under the relationship that a first spacing L0 and a second spacing L1 are equal to each other (the first spacing L0 coincides with the second spacing L1), the first spacing L0 between the orthographic projection, on the plane where the substrate is located, of the edge of the first electrode 210 and the orthographic projection, on the plane where the substrate is located, of the edge of the second end portion 320 is equal to: the product of the cotangent value of the acute angle formed by intersecting the connecting line between the edge of the light-emitting functional layer 220 and the edge of the second end portion 320 with the plane where the substrate is located and the difference between the first height h1 and the thickness of the first electrode.

Specifically, under the “less” relationship (the size of the first spacing L0 is greater than the size of the second spacing L1), the product of the cotangent value of the acute angle formed by intersecting the connecting line between the edge of the light-emitting functional layer 220 and the edge of the second end portion 320 with the plane where the substrate is located and the first height h1, is less than: the first spacing L0 between the orthographic projection, on the plane where the substrate is located, of the edge of the first electrode 210 and the orthographic projection, on the plane where the substrate is located, of the edge of the second end portion 320.

In some other embodiments of the present application, as shown in FIG. 23A, the display panel may further include a pixel defining layer 330, the pixel defining layer 330 is located on a first electrode 210 and located on a side, facing a substrate 100, of a partition portion and defines a plurality of second opening 302, the first electrode 210 is exposed from each second opening 302 of the plurality of second openings 302, and an edge of a first end portion 310 is located in an upper surface, facing away from the substrate 100, of the pixel defining layer 330.

For example, as shown in FIG. 23B, on a regular cross-section of a light-emitting device 200, a distance L0 between an orthographic projection, on a plane where a substrate 100 is located, of an edge of a portion, exposed from a second opening 320, of a first electrode 210 and an orthographic projection, on the plane where the substrate 100 is located, of an edge of a second end portion 320 is less than: a product L1 of a cotangent value of an acute angle at which a connecting line between an edge of a light-emitting functional layer 220 and the edge of the second end portion 320 intersects the plane where the substrate 100 is located and a distance between an intermediate portion of a lower surface of the light-emitting functional layer 220 and the edge of the second end portion 320 in a direction perpendicular to the plane where the substrate 100 is located. And in a region with uniform film thickness of the light-emitting functional layer 220 (for example, the effective functional region 202 above-mentioned), the first electrode 210 may exist, thereby increasing an area of a light-emitting region (with uniform film thickness of the light-emitting functional layer 220) of the light-emitting device 200, to increase an aperture ratio of the display panel.

For the above relationship, in a case that the display panel is provided with the pixel defining layer 330, the first electrode 210 may extend below the isolation structure 300, and correspondingly, the isolation structure 300 is configured to cover a gap between adjacent first electrodes 210. In this case, a position of an edge of a first end portion 310 is increased by the first electrode 210 and the pixel defining layer 330, and the distance between the intermediate portion of the lower surface of the light-emitting functional layer 220 and the edge of the second end portion 320 in the direction perpendicular to the plane where the substrate 100 is located is equal to a sum of a first height h1 and a thickness of the pixel defining layer 330, that is, on the regular cross-section of the light-emitting device 200, the distance L0 between the orthographic projection, on the plane where the substrate 100 is located, of the edge of the portion, exposed from the second opening 320, of the first electrode 210 and the orthographic projection, on the plane where the substrate 100 is located, of the edge of the second end portion 320 is less than: the product L1 of the cotangent value of the acute angle at which the connecting line between the edge of the light-emitting functional layer 220 and the edge of the second end portion 320 intersects the plane where the substrate 100 is located and the sum of the first height h1 and the thickness of the pixel defining layer 330.

For example, as shown in FIG. 23A and FIG. 23C, on a regular cross-section of a light-emitting device 200, a product L1 of a cotangent value of an acute angle at which a connecting line between an edge of a light-emitting functional layer 220 and the edge of the second end portion 320 intersects the plane where the substrate 100 is located and a distance between an intermediate portion of a lower surface of the light-emitting functional layer 220 and the edge of the second end portion 320 in a direction perpendicular to the plane where the substrate 100 is located is less than or equal to: a distance L0 between an orthographic projection, on a plane where a substrate 100 is located, of an edge of a portion, exposed from a second opening 320, of a first electrode 210 and an orthographic projection, on the plane where the substrate 100 is located, of an edge of a second end portion 320. And in a region where the light-emitting device 200 is distributed with the first electrode 210, a film thickness of the light-emitting functional layer 220 is uniform, and wavelengths of light emitted from the light-emitting region of the light-emitting device 200 can be ensured to be consistent, to eliminate a problem of stray light with different colors in the light-emitting device 200.

For the above relationship, in a case that the display panel is provided with the pixel defining layer 330, the first electrode 210 may extend below the isolation structure 300, and correspondingly, the isolation structure 300 is configured to cover a gap between adjacent first electrodes 210. In this case, a position of an edge of a first end portion 310 is increased by the first electrode 210 and the pixel defining layer 330. In this way, the product L1 of the cotangent value of the acute angle at which the connecting line between the edge of the light-emitting functional layer 220220 and the edge of the second end portion 320 intersects the plane where the substrate 100 is located and a sum of a first height h1 and a thickness of the pixel defining layer 330 is less than or equal to the distance L0 between the orthographic projection, on the plane where the substrate 100 is located, of the edge of the portion, exposed from the second opening 320, of the first electrode 210 and the orthographic projection, on the plane where the substrate 100 is located, of the edge of the second end portion 320.

For example, the pixel defining layer 330 is an inorganic layer, a portion, covering a gap of the first electrode 210 disposed adjacently, of the pixel defining layer 330 has a groove conformal with the gap, and a surface, facing the substrate 100, of the first end portion 310 covers the groove. The inorganic pixel defining layer 330 may have a smaller thickness design, and there is a small segment difference at an edge of a pixel defining layer 330 to improve a continuity of the second electrode 230 at the edge; furthermore, the design may reduce a degree of increase of a height of the isolation structure 300 due to an arrangement of the pixel defining layer 330; furthermore, the first end portion 310 completely covers the groove, thereby eliminating an influence of the groove on the isolation structure 300, to ensure that heights of edges of the first end portion 310 are same.

For example, a distance between an intermediate portion of a lower surface of the light-emitting functional layer 220 and the edge of the second end portion 320 in the direction perpendicular to the plane where the substrate 100 is located is equal to: a sum of the first height h1 and a thickness of the pixel defining layer 330.

In the embodiment of the present application, a specific shape of the isolation structure and whether to set the pixel defining layer may be selected according to specific conditions.

For example, in some examples, referring to FIG. 22 again, the portion, located between two adjacent sub-pixels, of the partition portion of the isolation structure 300 is an inverted trapezoid, and may be directly disposed on the substrate 100 to be in direct contact with the substrate 100, where, for a manner of calculating a positional relationship between the isolation structure and the first electrode and the light-emitting functional layer, reference may be made to related descriptions in the foregoing embodiments, and details are not described herein again.

For example, in some other examples, as shown in FIG. 23A to FIG. 23C, the portion, located between two adjacent sub-pixels, of the partition portion of the isolation structure 300 is an inverted trapezoid, the display panel includes a pixel defining layer 330, and a partition portion of the isolation structure 300 is disposed on the pixel defining layer 330, where, for a manner of calculating a positional relationship between the partition portion and the first electrode, the light-emitting functional layer and the pixel defining layer, reference may be made to related descriptions in the foregoing embodiments, and details are not described herein again.

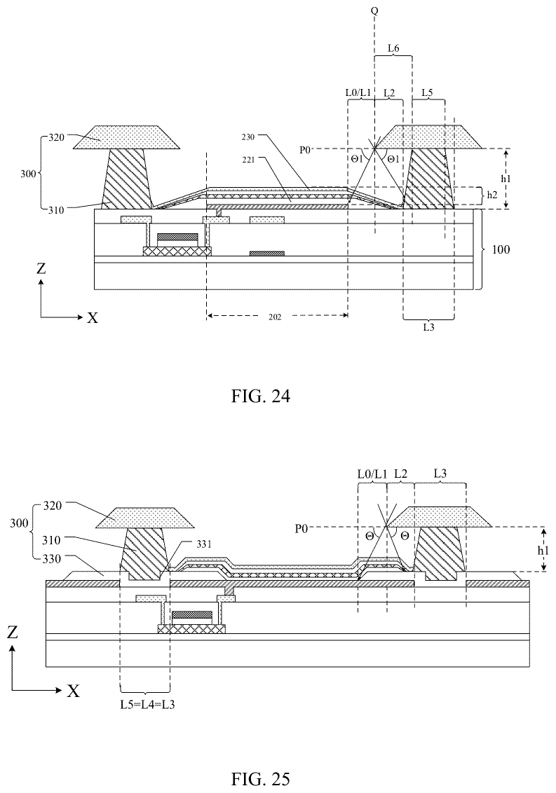

For example, in some other examples, as shown in FIG. 24, a partition portion of an isolation structure 300 is designed to include a supporting portion 310 and a blocking portion 320, and the partition portion of the isolation structure 300 may be directly disposed on a substrate 100 (that is, there is no pixel defining layer disposed between the partition portion and the substrate) to be in direct contact with the substrate 100, where, for a manner of calculating a positional relationship between the partition portion and a first electrode and a light-emitting functional layer, reference may be made to related descriptions in the foregoing embodiments, and details are not described herein again.

For example, in some other examples, as shown in FIG. 25, a partition portion of an isolation structure 300 is designed to include a supporting portion 310 and a blocking portion 320, the display panel includes a pixel defining layer 330, and the partition portion of the isolation structure 300 is disposed on the pixel defining layer 330, where, for a manner of calculating a positional relationship between the isolation structure and a first electrode, a light-emitting functional layer and the pixel defining layer, reference may be made to related descriptions in the foregoing embodiments, and details are not described herein again.

The manner of calculating a width of the isolation structure between adjacent first openings is described, and the first spacing L0 can be synchronously calculated in the calculation manner, and a distance between two sub-pixels, that is, a distance between effective functional regions, can be obtained, and a pixel density of the display panel can be calculated in combination with a specific pixel arrangement and widths of sub-pixels in each pixel, which is specifically as follows.

For example, in an example, the display panel includes a plurality of pixels, each pixel of the plurality of pixels includes a first sub-pixel, a second sub-pixel, and a third sub-pixel, where a wavelength of emergent light of the first sub-pixel, a wavelength of emergent light of the second sub-pixel, a wavelength of emergent light of the third sub-pixel are sequentially increased, the first sub-pixel, the second sub-pixel, and the third sub-pixel respectively include different light-emitting devices, the first sub-pixel, the second sub-pixel, and the third sub-pixel are arranged in a plurality of rows and a plurality of columns, in the each pixel, the first sub-pixel, the second sub-pixel, and the third sub-pixel are sequentially arranged along a row direction, a width direction of the first sub-pixel, a width direction of the second sub-pixel, a width direction of the third sub-pixel are all perpendicular to a column direction, a number of the first sub-pixel, a number of the second sub-pixels, and a number of the third sub-pixels are same. In other words, the display panel may include a plurality of pixels, and each pixel of the plurality of pixels includes a plurality of sub-pixels with different wavelengths of emergent light, the plurality of sub-pixels of the plurality of pixels include a first sub-pixel, a second sub-pixel and a third sub-pixel, and the first sub-pixel, the second sub-pixel and the third sub-pixel respectively include different light-emitting devices; a number ratio of the first sub-pixel, the second sub-pixel and the third sub-pixel is 1:1:1; and in the each pixel, the first sub-pixel, the second sub-pixel and the third sub-pixel are arranged in parallel, which referred to as a first pixel arrangement manner. Under this design, for an arrangement manner of the plurality of pixels of the display panel, refer to the foregoing related description in the embodiment of FIG. 14, and details are not described herein again. It should be noted that, for an adjustment of structural parameters of the isolation structure, a numerical range of a width of the isolation structure between adjacent first openings (see L in FIG. 5) is changed, and is not limited to the description related to FIG. 14, for details, refer to related descriptions of the pixel density of the display panel listed in the following embodiments and the calculation manner of the width of a corresponding isolation structure.

For example, in another example, the display panel includes a plurality of pixels, each pixel of the plurality of pixels includes a first sub-pixel, a second sub-pixel, and a third sub-pixel, where a wavelength of emergent light of the first sub-pixel, a wavelength of emergent light of the second sub-pixel, a wavelength of emergent light of the third sub-pixel are sequentially increased, the first sub-pixel, the second sub-pixel, and the third sub-pixel respectively include different light-emitting devices, the first sub-pixel, the second sub-pixel, and the third sub-pixel are arranged in a plurality of columns, a width direction of the first sub-pixel, a width direction of the second sub-pixel, a width direction of the third sub-pixel are all perpendicular to a column direction, a column where the second sub-pixel and the third sub-pixel are arranged is different with a column where the first sub-pixel is arranged, the second sub-pixel and the third sub-pixel are arranged alternately in the column where the second sub-pixel and the third sub-pixel are arranged, and a number of the first sub-pixel, a number of the second sub-pixels, and a number of the third sub-pixels are same. In other words, the display panel may include a plurality of pixels, and each pixel of the plurality of pixels includes a plurality of sub-pixels with different wavelengths of emergent light, the plurality of sub-pixels of the plurality of pixels include a first sub-pixel, a second sub-pixel and a third sub-pixel, and the first sub-pixel, the second sub-pixel and the third sub-pixel respectively include different light-emitting devices; a number ratio of the first sub-pixel, the second sub-pixel and the third sub-pixel is 1:1:1; and in the each pixel, the second sub-pixel and the third sub-pixel are arranged in a column/row and parallel to the first sub-pixel, which referred to as a second pixel arrangement manner. Under this design, for an arrangement manner of the plurality of pixels of the display panel, refer to the foregoing related description in the embodiment of FIG. 15, and details are not described herein again. It should be noted that, for an adjustment of structural parameters of the isolation structure, a numerical range of a width of the isolation structure between adjacent first openings (see L in FIG. 5) is changed, and is not limited to the description related to FIG. 15, for details, refer to related descriptions of the pixel density of the display panel listed in the following embodiments and the calculation manner of the width of a corresponding isolation structure.

Furthermore, for the display panel in different display modes and specific function requirements in the display panel, the isolation structure may be modified or other functional structures (such as the optical functional layer in the following embodiments) may be provided based on the isolation structure, in this case, a height, parameters, and the like of the isolation structure need to be adjusted, and when the functional structures are formed by means of the isolation structure, a manufacturing cost can be reduced, related errors are reduced, and the pixel density I of a product is improved.

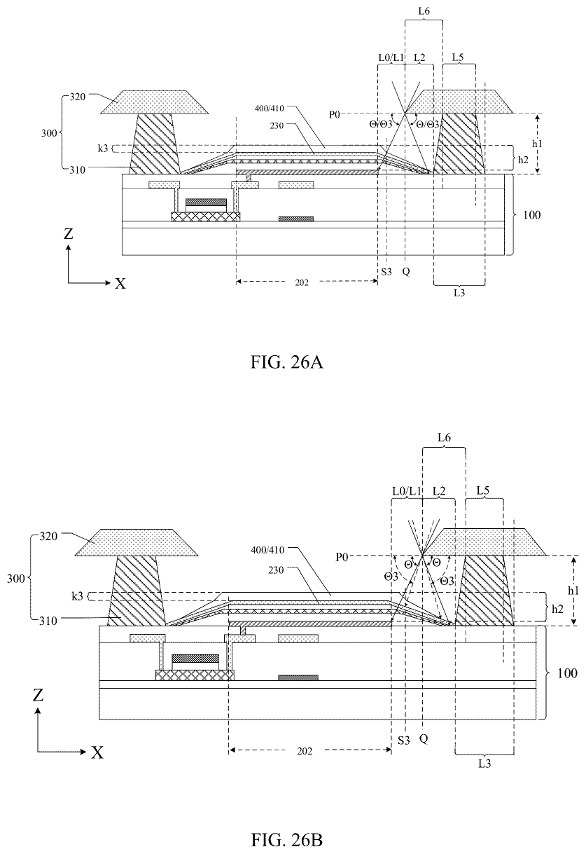

In at least one embodiment of the present application, as shown in FIG. 26A, the display panel may further include at least one optical functional layer (including a film layer corresponding to a mark 400), and the optical functional layer is located on a side, away from a substrate 100, of a light-emitting functional layer 220 and includes a plurality of optical functional units.

For example, as shown in FIG. 26A and FIG. 26B, on a regular cross-section of a light-emitting device, an acute angle Θ3 formed by intersecting a connecting line between an edge of a optical functional unit and an edge of a second end portion 320 with a plane where a substrate 100 is located is greater than or equal to acute angle Θ formed by intersecting a connecting line between an edge of a light-emitting functional layer and the edge of the second end portion 320 and the plane where the substrate 100 is located, FIG. 26A shows a positional relationship between the optical functional unit and the light-emitting functional layer under a “equal” relationship, and FIG. 26B shows a positional relationship between the optical functional unit and the light-emitting functional layer under a “greater” relationship. In this way, a portion of the optical functional unit that having a uniform thickness covers a portion of the light-emitting functional layer that having a uniform thickness, to make lights emitted by the light-emitting device pass through a portion of the optical functional unit that having a uniform thickness as much as possible, to improve display effect of the display panel. It should be noted that, even if under the “equal” relationship (Θ3 is equal to Θ), as shown in FIG. 26A, because the optical functional unit is located above the light-emitting functional layer, an area of a portion of the optical functional layer that having a uniform thickness is greater than an area of a portion of the light-emitting functional layer that having a uniform thickness, that is, an orthographic projection, on the plane where the substrate 100 is located, of the portion of the light-emitting functional layer that having a uniform thickness is located within an orthographic projection, on the plane where the substrate 100 is located, of the portion of the optical functional unit that having a uniform thickness, specifically, in a structure shown in FIG. 26A, a boundary of the portion of the light-emitting functional layer that having a uniform thickness coincides with an edge of a first electrode, and a boundary of the portion of the optical functional unit that having a uniform thickness is located at a position S3.

In a case that the optical functional layer is located below a first encapsulation layer, a thickness K3 of the optical functional layer may affect an encapsulation of the first encapsulation layer, that is, when specific parameters of the isolation structure is calculated, the thickness K3 of the optical functional layer needs to be added.

For example, the optical functional unit is located between the light-emitting functional layer 220 and the first packaging layer 510, at least a part of the first opening 301 is internally provided with the optical functional unit, and an orthographic projection, on the plane where the substrate 100 is located, of a part of an edge portion of the optical functional unit is located within an orthographic projection, on the plane where the substrate 100 is located, of the second end portion 320. For example, a thickness of the edge portion of the optical functional unit gradually decreases along a direction from a middle portion of the light-emitting device to a corresponding edge. Therefore, a thickness of at least one of film layers of the optical functional unit is gradually reduced, correspondingly, the film layers can be formed by vapor deposition through the isolation structure 300, and the isolation structure 300 can limit a vapor deposition range of a vapor deposition material, and at the edges of the film layers, as a distance from the isolation structure is closer, thicknesses of the film layers becomes smaller and smaller, accordingly, a thickness of the optical functional unit at an edge of the second end portion 320 is smaller than a thickness at a middle portion of the second end portion 320, accordingly, a height of the isolation structure 300 (for example, a first height described below) can be designed, and the isolation structure 300 has a relatively small height while ensuring an encapsulation effect of the first encapsulation layer 510, to further reduce a width of a portion, between adjacent first openings 301, of the isolation structure 300, thereby improving an aperture ratio, a pixel density, and the like of the display panel.

For example, in some embodiments of the present application, on the regular cross-section of the light-emitting device, a product of a cotangent value of an acute angle formed by intersecting a connecting line between the edge of the optical functional unit and the edge of the second end portion and the plane where the substrate is located and a distance between a middle portion of a lower surface of the optical functional unit and the edge of the second end portion in a direction perpendicular to the plane where the substrate is located is less than or equal to: a distance between an orthographic projection, on the plane where the substrate is located, of the edge of the first electrode and an orthographic projection, on the plane where the substrate is located, of the edge of the second end portion. For an arrangement manner of the optical functional unit in this solution, refer to related descriptions in the following embodiments (for example, embodiments of introducing a color conversion unit), details are not described here again.

For example, in some other embodiments of the present application, the display panel further includes a pixel defining layer, the pixel defining layer is located on the first electrode and located on a side, facing the substrate, of the partition portion and defines a plurality of second openings, the first electrode is exposed from the plurality of second openings, the edge of the first end portion is located in an upper surface of the pixel defining layer, and a distance between a middle portion of a lower surface of the optical functional unit and the edge of the second end portion in a direction perpendicular to the plane where the substrate is located is equal to: a difference between a sum of the first height and a thickness of the pixel defining layer and a distance between the middle portion of the lower surface of the optical functional unit and a middle portion of the first electrode in the direction perpendicular to the plane where the substrate is located. For an arrangement manner of the optical functional unit in this solution, refer to related descriptions in the following embodiments (for example, embodiments of introducing a color conversion unit), details are not described here again.

In the embodiment of the present application, a type of an optical functional unit is not limited, and can be designed according to actual needs, and the following describes several design choices of the optical functional unit.

For example, in at least one embodiment of the present application, as shown in FIG. 26A, an optical functional layer may include a color conversion layer 400, and an optical functional unit may include a color conversion unit 410, in a case that a light-emitting device of the display panel is set to be a same color light (which may be single primary color light or mixed light), the color conversion layer 400 is disposed in the display panel, and the display panel has a color conversion function to display a color image, and in this design, a light-emitting quality of the display panel may be higher.

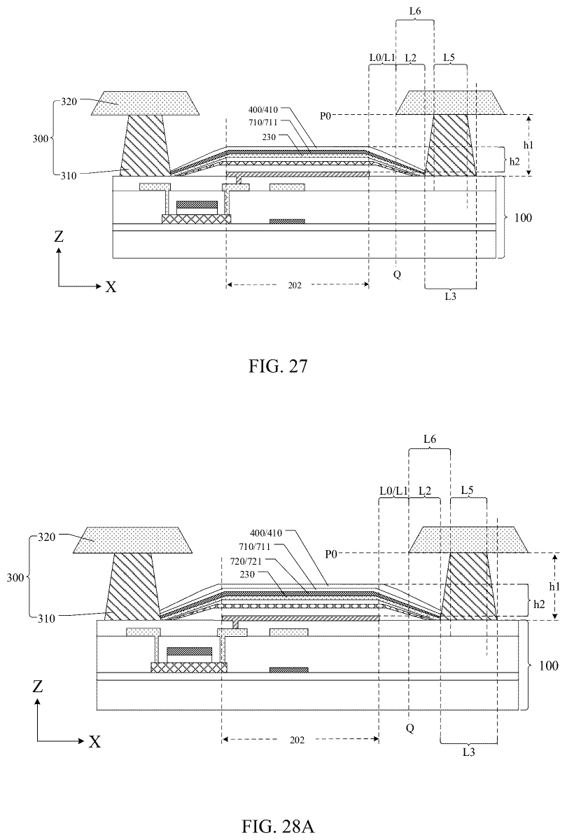

For example, in at least one embodiment of the present application, as shown in FIG. 27, the optical functional layer may further include an optical extraction layer 710, the optical extraction layer 710 includes a plurality of optical extraction units 711, each optical extraction unit 711 of the plurality of optical extraction units 711 respectively located in a first opening, the optical extraction unit is located between the light-emitting functional layer and the color conversion unit 410 in the first opening provided with the color conversion unit 410, by providing the optical extraction units 711, a light-emitting efficiency of a light-emitting device can be improved, to improve a brightness of a display image of the display panel.

The optical extraction layer can improve light extraction efficiency by suppressing optical losses such as internal reflection and absorption. In the display panel, light in the light-emitting device and the color conversion layer is reflected and absorbed, thereby affecting light extraction efficiency. By providing the optical extraction layer on a second electrode (for example, a cathode) of the light-emitting device, these losses can be reduced, and the light extraction efficiency can be improved, thereby increasing a brightness and light extraction efficiency of the display panel. Furthermore, the optical extraction layer may further improve a color purity of the display panel by selecting appropriate materials and structures. In a structure of exciting light by applying quantum dots, a polarization state of light can affect the extraction efficiency and color purity of light, and by selecting an appropriate material and structure of the optical extraction layer, the polarization state of light can be adjusted, and the color purity can be improved.

Exemplary, the optical extraction layer may be made of a low-molecular organic material or a polymer material, such as polyethylene terephthalate (PEDOT:PSS), polyaniline (PANI), poly (3,4-ethylenedioxythiophene) (PEDOT), poly (3,4-ethylenedioxythiophene-2,5-dimethoxyphenyl) (PProDOT-MeO2), and the like. These materials have good conductivity and transparency, and a uniform film can be formed on a surface of the second electrode. Furthermore, a polymer material may also be used as an optical extraction layer, for example, polymethyl acrylate (PMMA), polyvinyl alcohol (PVA), and the like. These polymer materials can form an optically transparent film, and have high optical refractive index and surface roughness, which can help reduce reflection and scattering of light and improve light extraction efficiency.

For example, the optical extraction unit 711 includes a first extraction sub-layer to form a single-layer structure, or the optical extraction unit 711 may be of a multi-layer structure, that is, the optical extraction unit 711 includes a first extraction sub-layer, a second extraction sub-layer located on a side, facing the substrate 100, of the first extraction sub-layer, and a third extraction sub-layer located on a side, facing away from the substrate 100, of the first extraction sub-layer, where a refractive index of the second extraction sub-layer and a refractive index of the third extraction sub-layer are both less than a refractive index of the first extraction sub-layer.

For example, the refractive index of the first extraction sub-layer is 2.0 to 2.3, and for further example, the refractive index of the first extraction sub-layer is 2.1 to 2.2.

For example, a thickness of the first extraction sub-layer is 45 to 75 nanometers, and for further example, the thickness of the first extraction sub-layer is 55 to 65 nanometers.

For example, the refractive index of the second extraction sub-layer and/or the refractive index of the third extraction sub-layer is 1.4 to 1.8, and for further example, the refractive index of the second extraction sub-layer and/or the refractive index of the third extraction sub-layer is 1.5 to 1.6.

For example, a thickness of the second extraction sub-layer and/or a thickness of the third extraction sub-layer is 7 to 30 nanometers, and for further example, the thickness of the second extraction sub-layer and/or the thickness of the third extraction sub-layer is 10 to 20 nanometers.

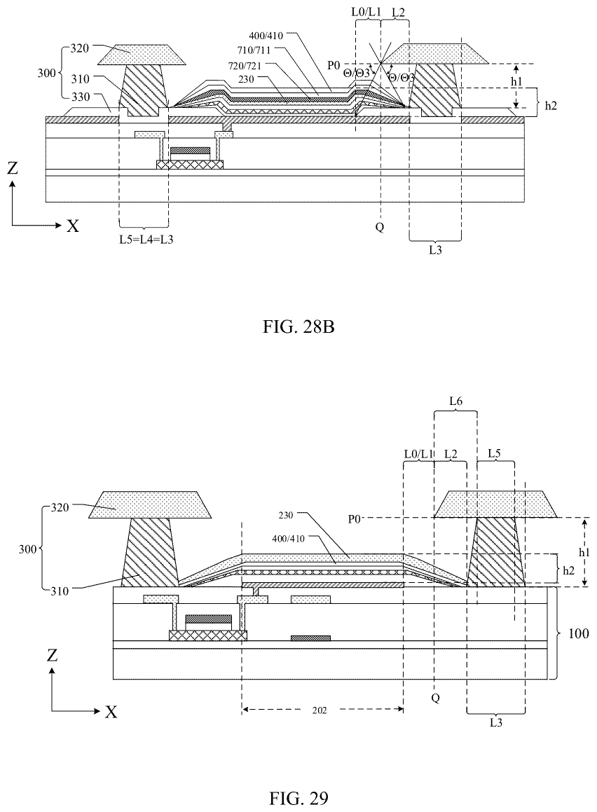

For example, in at least one embodiment of the present application, as shown in FIG. 28A, the optical functional layer may further include an optical regulating layer 720, the optical regulating layer 720 includes a plurality of optical regulating units 721 respectively located in the plurality of first openings, and the optical regulating unit 721 is located between the light-emitting functional layer and the optical extraction unit 711 in a first opening provided with the color conversion unit 410. For example, the optical regulating unit 721 may be a lithium fluoride unit, that is, the optical regulating unit 721 includes a lithium fluoride material to adjust a refractive index of adjacent film layers, and the light emitted by the light-emitting device is more easily derived.

For example, a thickness of the optical regulating unit 721 is 65 to100 nanometers, for further example, the thickness of the optical regulating unit 721 is 75 to 85 nanometers.

It should be noted that, in at least one embodiment of the present application, a type of the optical functional unit is configured to include at least one type of a color conversion unit 410, an optical extraction unit 711, an optical regulating unit 721, a filling unit, and a filter unit (see related descriptions in related embodiments); or, the type of the optical functional unit is configured to include at least two different types of the color conversion unit 410, the optical extraction unit 711, the optical regulating unit 721, the filling unit, and the filter unit 820. In this way, when the optical functional unit includes the color conversion unit 410, the light-emitting device 200 of the display panel may be configured to emit light of same color, and each light-emitting device 200 may be synchronously prepared, and an overall light-emitting quality of the display panel may be improved.

The following describes a calculation manner between structural parameters of the isolation structure, the light-emitting device, and the optical functional unit in combination with several design combinations of the optical functional unit, where it should be noted that the color conversion unit may be designed according to requirements of an actual process as long as the color conversion unit is located on a light-emitting side of the light-emitting functional layer.

In at least one embodiment of the present application, referring to FIG. 26A, in a case that an optical functional layer includes a color conversion layer, an orthographic projection, on a plane where a substrate 100 is located, of a portion of an edge portion of the color conversion unit 410 is located within an orthographic projection, on the plane where the substrate 100 is located, of a second end portion 320, and a thickness of the edge portion of the color conversion unit 410 gradually decreases along a direction from a middle portion of a light-emitting device to a corresponding edge. The color conversion unit 410 may be formed by vapor deposition by means of the isolation structure 300, and therefore, a change rule of a thickness of a film layer of the color conversion unit 410 is substantially the same as that of a film layer of a light-emitting functional layer, which affects an encapsulation effect of a first encapsulation layer.

For example, in a case that an isolation structure 300 is directly disposed on a substrate 100, as shown in FIG. 26A to FIG. 28A, a partition portion of the isolation structure 300 is in direct contact with a surface of the substrate 100, and a product of a cotangent value of an acute angle Θ3 formed by intersecting a connecting line between an edge of a color conversion unit 410 and an edge of a second end portion 320 with a plane where the substrate 100 is located and a difference between a first height h1 and a distance between a middle portion of a surface, facing the substrate 100, of the color conversion unit 410 and an edge of a first end portion 310 in a direction perpendicular to the plane where the substrate 100 is located is equal to or less than (shown in the figure): a product L1 of a cotangent value of an acute angle Θ formed by intersecting a connecting line between an edge of a light-emitting functional layer and the edge of the second end portion 320 with the plane where the substrate 100 is located and a difference between the first height h1 and a distance between a middle portion of a surface, facing the substrate 100, of the light-emitting functional layer and an edge of the first end portion 310 in the direction perpendicular to the plane where the substrate 100 is located. In this way, it can be ensured that in a uniform light-emitting region of the light-emitting device, the color conversion unit 410 having a uniform film thickness.

For example, as shown in FIG. 28B, when a pixel defining layer 330 is provided on the display panel, a difference between a sum of a first height h1 and a thickness of the pixel defining layer 330 and a distance between a middle portion of a surface, facing a substrate 100, of the color conversion unit 410 and an edge of a first end portion 310 in a direction perpendicular to the plane where the substrate 100 is located is a design value, and a product of a cotangent value of an acute angle Θ3 formed by intersecting a connecting line between an edge of the color conversion unit 410 and an edge of a second end portion 320 with the plane where the substrate 100 is located and the design value is equal to or less than: a product L1 of a cotangent value of an acute angle Θ formed by intersecting a connecting line between an edge of a light-emitting functional layer and the edge of the second end portion 320 with the plane where the substrate 100 is located and a difference between the first height h1 and a distance between a middle portion of a surface, facing the substrate 100, of the light-emitting functional layer and an edge of the first end portion 310 in the direction perpendicular to the plane where the substrate 100 is located. In this way, it can be ensured that in a uniform light-emitting region of the light-emitting device, the color conversion unit 410 having a uniform film thickness.

For example, a thickness of the pixel defining layer may be a thickness of a portion, covering the first electrode, of the pixel defining layer.

A calculation manner of a structure of the display panel and structural parameters between the isolation structure, the light-emitting device, and the optical functional unit is described below with respect to several different positional relationships between the optical functional layer and the light-emitting device.

In some embodiments of the present application, as shown in FIG. 26A to FIG. 28A, the color conversion layer 400 is located on the second electrode 230 of the light-emitting device, that is, located on a side, facing away from the substrate 100, of the second electrode 230, and under this case, the second height h2 includes a thickness of a portion, corresponding to an intermediate position of the light-emitting device, of the color conversion unit 410.

For example, there is a gap between an edge of the color conversion unit 410 and the isolation structure 300, and in the uniform light-emitting region of the light-emitting device, the color conversion unit 410 having a uniform film thickness; furthermore, it can be avoided that the edge of the color conversion unit 410 extends to a sidewall of the isolation structure to affect an encapsulation effect of the first encapsulation layer.

For example, as shown in FIG. 28A and FIG. 28B, the optical functional layer includes an optical extraction layer 710, the optical extraction layer 710 includes a plurality of optical extraction units 711, each optical extraction unit 711 of the plurality of optical extraction units 711 respectively corresponds to the light-emitting device, and the optical extraction unit 711 is located in the first opening, and under this case, the second height h2 includes a thickness of a portion, corresponding to the intermediate position of the light-emitting device, of the optical extraction unit 711. For example, the optical extraction unit 711 is located between the light-emitting device and the color conversion unit 410.

For example, as shown in FIG. 28A, in a case that the isolation structure 300 is directly disposed on the substrate 100, a product of a cotangent value of the acute angle Θ3 formed by intersecting a connecting line between an edge of the optical extraction unit 711 and the edge of the second end portion 320 with the plane where the substrate 100 is located and a difference between the first height h1 and a distance between a middle portion of a surface, facing the substrate 100, of the optical extraction unit 711 and the edge of the first end portion 310 in the direction perpendicular to the plane where the substrate 100 is located is equal to or less than: the product L1 of the cotangent value of the acute angle Θ formed by intersecting the connecting line between the edge of the light-emitting functional layer and the edge of the second end portion 320 with the plane where the substrate 100 is located and the difference between the first height h1 and the distance between the middle portion of the surface, facing the substrate 100, of the light-emitting functional layer and the edge of the first end portion 310 in the direction perpendicular to the plane where the substrate 100 is located. In this way, it can be ensured that in a uniform light-emitting region of the light-emitting device, the optical extraction unit 711 having a uniform film thickness.

For example, as shown in FIG. 28B, when the pixel defining layer 330 is provided on the display panel, a difference between the sum of the first height h1 and the thickness of the pixel defining layer 330 and a distance between a middle portion of a surface, facing a substrate 100, of the optical extraction unit 711 and the edge of the first end portion 310 in the direction perpendicular to the plane where the substrate 100 is located is a design value, and a product of a cotangent value of an acute angle Θ3 formed by intersecting a connecting line between an edge of the optical extraction unit 711 and the edge of the second end portion 320 with the plane where the substrate 100 is located and the design value is equal to or less than: the product L1 of the cotangent value of the acute angle Θ formed by intersecting the connecting line between the edge of the light-emitting functional layer and the edge of the second end portion 320 with the plane where the substrate 100 is located and the difference between the first height h1 and the distance between the middle portion of the surface, facing the substrate 100, of the light-emitting functional layer and the edge of the first end portion 310 in the direction perpendicular to the plane where the substrate 100 is located. In this way, it can be ensured that in a uniform light-emitting region of the light-emitting device, the optical extraction unit 711 having a uniform film thickness.

For example, as shown in FIG. 28A and FIG. 28B, the optical functional layer includes an optical regulating layer 720, the optical regulating layer 720 includes a plurality of optical regulating units 721, each optical regulating unit 721 of the plurality of optical regulating units 721 is located between the optical extraction unit 711 and the light-emitting device, and the second height h2 includes a thickness of a portion, corresponding to the intermediate position of the light-emitting device, of the optical extraction unit 711 and the optical regulating unit 721. For example, the optical regulating unit 721 is a lithium fluoride unit.

For example, as shown in FIG. 28A, in a case that the isolation structure 300 is directly disposed on the substrate 100, a product of a cotangent value of the acute angle Θ3 formed by intersecting a connecting line between an edge of the optical regulating unit 721 and the edge of the second end portion 320 with the plane where the substrate 100 is located and a difference between the first height h1 and a distance between a middle portion of a surface, facing the substrate 100, of the optical regulating unit 721 and the edge of the first end portion 310 in the direction perpendicular to the plane where the substrate 100 is located is equal to or less than: the product L1 of the cotangent value of the acute angle Θ formed by intersecting the connecting line between the edge of the light-emitting functional layer and the edge of the second end portion 320 with the plane where the substrate 100 is located and the difference between the first height h1 and the distance between the middle portion of the surface, facing the substrate 100, of the light-emitting functional layer and the edge of the first end portion 310 in the direction perpendicular to the plane where the substrate 100 is located. In this way, it can be ensured that in a uniform light-emitting region of the light-emitting device, the optical regulating unit 721 having a uniform film thickness.

For example, as shown in FIG. 28B, when the pixel defining layer 330 is provided on the display panel, a difference between the sum of the first height h1 and the thickness of the pixel defining layer 330 and a distance between a middle portion of a surface, facing a substrate 100, of optical regulating unit 721 and the edge of the first end portion 310 in the direction perpendicular to the plane where the substrate 100 is located is a design value, and a product of a cotangent value of an acute angle Θ3 formed by intersecting a connecting line between an edge of optical regulating unit 721 and the edge of the second end portion 320 with the plane where the substrate 100 is located and the design value is equal to or less than: the product L1 of the cotangent value of the acute angle Θ formed by intersecting the connecting line between the edge of the light-emitting functional layer and the edge of the second end portion 320 with the plane where the substrate 100 is located and the difference between the first height h1 and the distance between the middle portion of the surface, facing the substrate 100, of the light-emitting functional layer and the edge of the first end portion 310 in the direction perpendicular to the plane where the substrate 100 is located. In this way, it can be ensured that in a uniform light-emitting region of the light-emitting device, the optical regulating unit 721 having a uniform film thickness.

In some other embodiments of the present application, as shown in FIG. 29 to FIG. 31, a color conversion unit 410 is located between a second electrode 230 and a light-emitting functional layer, and a second height h2 includes a thickness of a portion, corresponding to an intermediate position of a light-emitting device, of the color conversion unit 410.

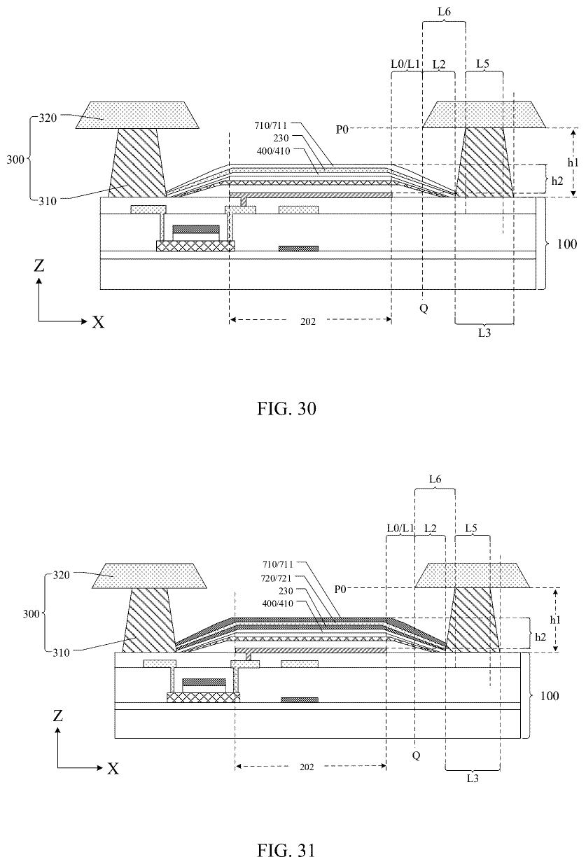

For example, as shown in FIG. 30, an optical functional layer includes an optical extraction layer, the optical extraction layer includes a plurality of optical extraction units 711, each optical extraction units 711 of the plurality of optical extraction units 711 respectively corresponds to the light-emitting device, the optical extraction unit 711 is located in a first opening, and the second height h2 includes a thickness of a portion, corresponding to the intermediate position of the light-emitting device, of the optical extraction units 711. For example, the optical extraction unit 711 is located between the light-emitting device and the color conversion unit.

For example, in a case that an isolation structure 300 is directly disposed on a substrate 100, a product of a cotangent value of an acute angle formed by intersecting a connecting line between an edge of the optical extraction unit 711 and an edge of a second end portion 320 with a plane where the substrate 100 is located and a difference between a first height h1 and a distance between an intermediate portion of a surface, facing the substrate 100, of the optical extraction unit 711 and an edge of a first end portion 310 in a direction perpendicular to the plane where the substrate 100 is located is equal to or less than: a product of a cotangent value of an acute angle formed by interesting a connecting line between an edge of a light-emitting functional layer and the edge of the second end portion 320 with the plane where the substrate 100 is located and a difference between the first height h1 and a distance between an intermediate portion of a surface, facing the substrate 100, of the light-emitting functional layer and the edge of the first end portion 310 in the direction perpendicular to the plane where the substrate 100 is located. In this way, it can be ensured that in a uniform light-emitting region of the light-emitting device, the optical extraction unit 711 having a uniform film thickness.

For example, in a case that a pixel defining layer is provided on the display panel, a difference between a sum of the first height h1 and a thickness of the pixel defining layer and a distance between the intermediate portion of the surface, facing the substrate 100, of the optical extraction unit 711 and the edge of the first end portion 310 in the direction perpendicular to the plane where the substrate 100 is located is a design value, and a product of the cotangent value of the acute angle formed by intersecting the connecting line between the edge of the optical extraction unit 711 and the edge of the second end portion 320 with the plane where the substrate 100 is located and the design value is equal to or less than: the product of the cotangent value of the acute angle formed by interesting the connecting line between the edge of the light-emitting functional layer and the edge of the second end portion 320 with the plane where the substrate 100 is located and the difference between the first height h1 and the distance between the intermediate portion of the surface, facing the substrate 100, of the light-emitting functional layer and the edge of the first end portion 310 in the direction perpendicular to the plane where the substrate 100 is located. In this way, it can be ensured that in a uniform light-emitting region of the light-emitting device, the optical extraction unit 711 having a uniform film thickness.

For example, as shown in FIG. 31, an optical functional layer includes an optical regulating layer, the optical regulating layer includes a plurality of optical regulating units 721, and each optical regulating unit 721 of the optical regulating units 721 is located between an optical extraction unit 711 and a light-emitting device. A second height h2 includes a thickness of a portion, corresponding to an intermediate position of the light-emitting device, of the optical extraction unit 711 and a lithium fluoride unit. For example, the optical regulating unit 721 is the lithium fluoride unit.

For example, in a case that an isolation structure 300 is directly disposed on a substrate 100, a product of a cotangent value of an acute angle formed by intersecting a connecting line between an edge of the optical regulating unit 721 and an edge of a second end portion 320 with a plane where the substrate 100 is located and a difference between a first height h1 and an intermediate portion of a surface, facing the substrate 100, of the optical regulating unit 721 and an edge of a first end portion 310 in a direction perpendicular to the plane where the substrate 100 is located is equal to or less than: a product of a cotangent value of an acute angle formed by interesting a connecting line between an edge of a light-emitting functional layer and the edge of the second end portion 320 with the plane where the substrate 100 is located and a difference between the first height h1 and a distance between an intermediate portion of a surface, facing the substrate 100, of the light-emitting functional layer and the edge of the first end portion 310 in the direction perpendicular to the plane where the substrate 100 is located. In this way, it can be ensured that in a uniform light-emitting region of a light-emitting device, the optical regulating unit 721 having a uniform film thickness.

For example, in a case that a pixel defining layer is provided on the display panel, a difference between a sum of the first height h1 and a thickness of the pixel defining layer and a distance between the intermediate portion of the surface, facing the substrate 100, of the optical regulating unit 721 and the edge of the first end portion 310 in the direction perpendicular to the plane where the substrate 100 is located is a design value, and a product of the cotangent value of the acute angle formed by intersecting the connecting line between the edge of the optical regulating unit 721 and the edge of the second end portion 320 with the plane where the substrate 100 is located and the design value is equal to or less than: the product of the cotangent value of the acute angle formed by interesting the connecting line between the edge of the light-emitting functional layer and the edge of the second end portion 320 with the plane where the substrate 100 is located and the difference between the first height h1 and the distance between the intermediate portion of the surface, facing the substrate 100, of the light-emitting functional layer and the edge of the first end portion 310 in the direction perpendicular to the plane where the substrate 100 is located. In this way, it can be ensured that in a uniform light-emitting region of the light-emitting device, the optical regulating unit 721 having a uniform film thickness.

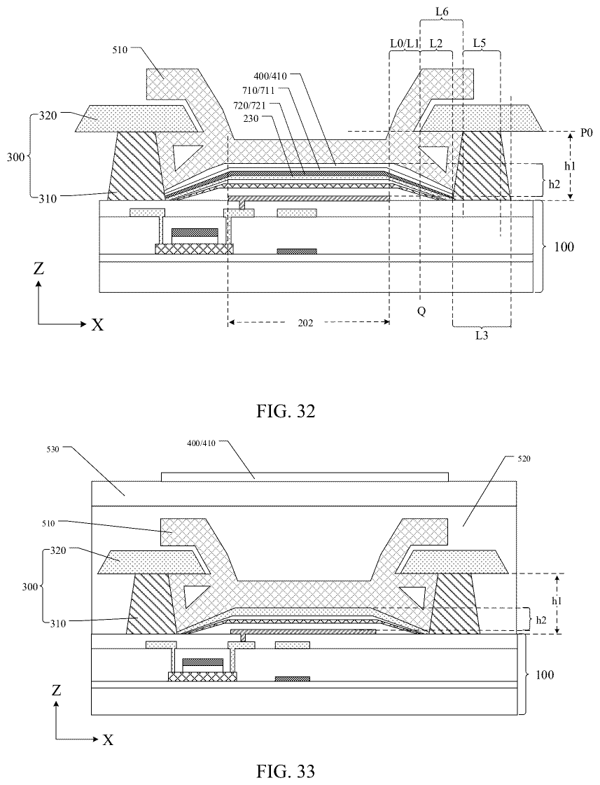

For example, in the foregoing embodiment, as shown in FIG. 32, an optical functional unit may be located below a first encapsulation layer 510, and in this design, a design of a first height needs to consider a thickness of the optical functional unit, that is, a distance between the first encapsulation layer and a first electrode includes a thickness of a light-emitting functional layer, a second electrode, and the optical functional unit.

In some other embodiments of the present application, as shown in FIG. 33, a color conversion layer 400 may be located on a first encapsulation layer 510, that is, the color conversion layer is located on a side, facing away from a substrate 100, of the first encapsulation layer 510. In this way, a problem that a height of an isolation structure is increased due to an arrangement of the color conversion layer can be eliminated. It should be noted that, in this design, an optical functional layer may be all disposed on a side, facing away from the substrate 100, of the first encapsulation layer (or an entire encapsulation layer represented by the identifiers 510 to 530).

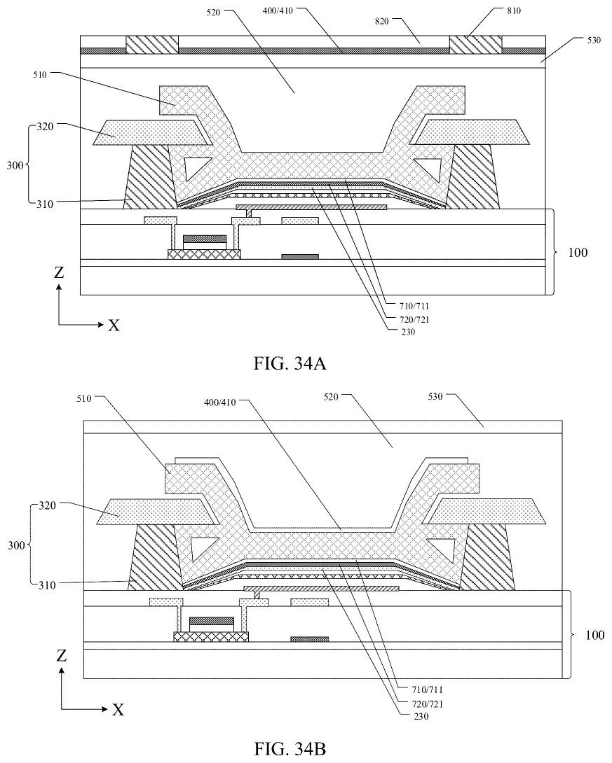

In the embodiment of the present application, in the case that the color conversion layer is located on the side, facing away from the substrate, of the first encapsulation layer, arrangement positions of other optical functional units such as an optical regulating layer, an optical extraction layer, and the like are not limited. For example, in some embodiments, as shown in FIG. 34A, a color conversion layer 400 may be located on a side, facing away from a substrate 100, of a first encapsulation layer 510, and an optical regulating layer 720 and an optical extraction layer 710 are located between the first encapsulation layer 510 and a light-emitting device for improving an optical extraction efficiency of the light-emitting device, for related designs in this case, reference may be made to related descriptions in the foregoing embodiments, and details are not described herein again.

For example, in some other embodiments of the present application, some structures located on a first encapsulation layer 510 may be designed to include a color conversion material to be multiplexed as a color conversion unit. For example, as shown in FIG. 34B, a second encapsulation layer 520 (see related descriptions in the following embodiments, which may be an organic film layer) is provided on the first encapsulation layer 510, where the second encapsulation layer 520 may be designed to include a plurality of multiplexing units, and each multiplexing unit of the plurality of multiplexing units includes a color conversion material to serve as the color conversion unit 410, thereby facilitating a light-weight and thin design of the display panel.

For example, in some other embodiments of the present application, the display panel includes a second encapsulation layer 520 that located on a side, away from a substrate, of a first encapsulation layer 510, the second encapsulation layer 520 is an organic encapsulation layer, a color conversion unit may be a structure that located between the first encapsulation layer 510 and the second encapsulation layer 520.

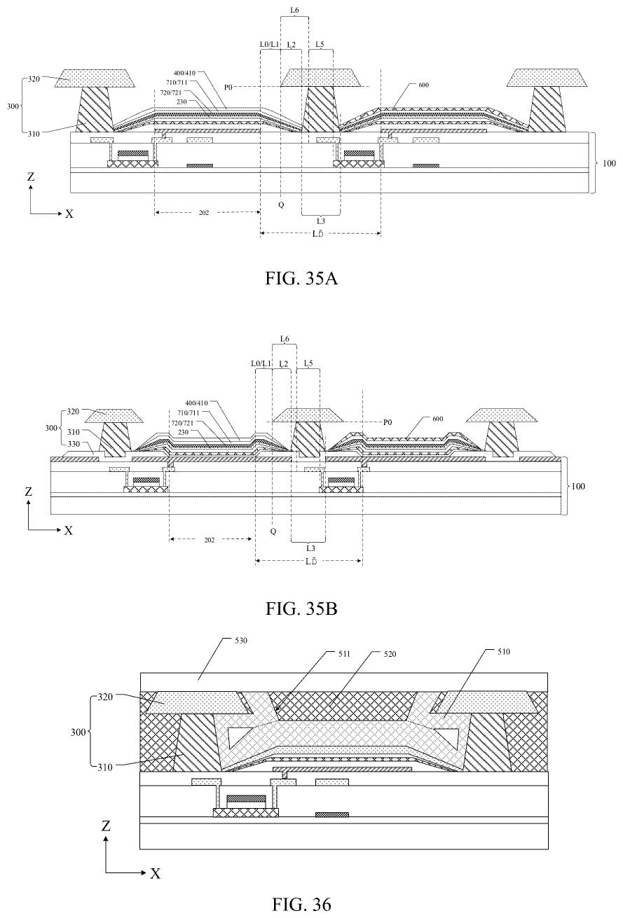

In at least one embodiment of the present application, as shown in FIG. 35A, in a case that a color conversion layer 400 is provided, colors of emergent lights of a light-emitting device are same, a color conversion unit 410 is configured to convert an emergent light of the light-emitting device into target color light, a wavelength of the target color light is greater than a wavelength of the emergent light of the light-emitting device.

For example, in one design, a light-emitting functional layer of the light-emitting device includes at least one light-emitting layer, the at least one light-emitting layer are all configured to emit a first color light, a color conversion unit is at least include a first color conversion unit and a second color conversion unit, the first color conversion unit is configured to convert a first color light into a second color light, and the second color conversion unit is configured to convert the first color light into a third color light. For example, the first color light, the second color light, and the third color light are sequentially blue light, green light, and red light.

For example, in another design, a light-emitting functional layer of the light-emitting device includes at least two light-emitting layers, at least one light-emitting layer of the at least two light-emitting layers is configured to emit a first color light and at least one light-emitting layer of the at least two light-emitting layers is configured to emit a second color light, a color conversion unit 410 is at least include a first color conversion unit and a second color conversion unit, the first color conversion unit is configured to convert the first color light into the second color light, and the second color conversion unit is configured to convert the first color light into a third color light, where wavelengths of the first color light, the second color light, and the third color light are sequentially increased, for example, the first color light, the second color light, and the third color light are sequentially blue light, green light, and red light; or the wavelengths of the first color light, the third color light, and the second color light are sequentially increased. For example, the first color light, the second color light, and the third color light are sequentially blue light, red light, and green light.

For example, the color conversion unit 410 includes a quantum dot material. For example, the quantum dot material may absorb blue light to excite red light (which may be referred to as an R-quantum dot material) or green light (which may be referred to as a G-quantum dot material). For example, the quantum dot material includes perovskite quantum dots and/or II-VI group semiconductor quantum dots; in one embodiment, the perovskite quantum dot includes at least one of CsPbX₃ and CH₃NH₃PbX₃, where X is a halogen atom, and further in one embodiment, the halogen atom includes at least one of F, Cl, Br, and I; in one embodiment, the II-VI Group semiconductor quantum dots include at least one of CdSe/ZnS, ZnCdSe/ZnSe/ZnS, CdZnSe/CdZnS/ZnS, CdSe/CdZnSe/ZnS, CdZnSe/ZnS, InP@ZnSeS, ZnSe/ZnS, InP/ZnSe/ZnS, ZnSeTe/ZnSe/ZnSeS/ZnS, ZnSeTe/ZnSe/ZnS, and ZnSe/ZnS.

For example, a thickness of a film layer of the color conversion unit 410 is 500 to 10000 nanometers, for example, furthermore, the thickness of the film layer of the color conversion unit 410 is 600 to 3000 nanometers, for example, still further, the thickness of the film layer of the color conversion unit 410 may be 800 to 1200 nanometers.

For example, as shown in FIG. 35A and FIG. 35B, the display panel further includes a filling layer 600, the filling layer 600 includes a plurality of filling units, and each filling unit of the plurality of filling units is located in the first opening not provided with the color conversion unit 410. For example, the color conversion unit is disposed in the first opening corresponding to sub-pixels R and G, and the color conversion unit does not need to be arranged in the first opening corresponding to sub-pixel B, and there is a large segment difference in the first opening corresponding to the sub-pixel B, and the segment difference may increase a probability of breakage of the first encapsulation layer 510 when structures such as the first encapsulation layer 510 and the like are formed, that is, in above design, the segment difference at the first opening not provided with the color conversion unit 410 may be reduced by setting the filling layer 600, to reduce a risk of the breakage of the first encapsulation layer 510, thereby improving an encapsulation effect of the first encapsulation layer 510.

In at least one embodiment of the present application, the first end portion 310 and the second end portion 320 of the isolation structure 300 are of an integral structure, and in the direction perpendicular to the plane where the substrate 100 is located, a cross-sectional profile of a portion, located between two adjacent sub-pixels, of the partition portion is an inverted trapezoid, an edge of a bottom of the inverted trapezoidal is the edge of the second end portion 320, and an edge of a top of the inverted trapezoidal is the edge of the first end portion 310.

In at least one embodiment of the present application, the optical function unit is configured to at least include a filter unit 820 and a color conversion unit 410, the filter unit 820 is located on a side, away from the substrate 100, of the color conversion unit 410 corresponding to the filter unit 820, and a shielding portion 810 is disposed between adjacent filter units 820.

For example, the filter unit 820 is located between the color conversion unit 410 corresponding to the filter unit 820 and the first encapsulation layer 510, and a part of the isolation structure 300 is multiplexed as the shielding portion 810. In at least one embodiment of the present application, as shown in FIG. 34A, the display panel may further include a filter layer, the filter layer is located on a side, facing away from a substrate 100, of an isolation structure 300 and a color conversion layer 400, the filter layer includes a shielding portion 810 and a plurality of filter units 820, where each filter unit 820 respectively corresponds to a light-emitting device. The shielding portion 810 defines a plurality of filter openings, the filter unit 820 is located in each filter opening of the plurality of filter openings, and an orthographic projection, on a plane where a substrate 100 is located, of the shielding portion 810 is located within an orthographic projection, on the plane where the substrate 100 is located, of the isolation structure. The filter unit 820 may filter out a light that is not converted by a color conversion unit, and may filter part of ambient light to filter out stray light, thereby improving a display effect of a display image.

In the embodiment of the present application, the blocking portion of the isolation structure may be designed as a conductive structure, to reduce an impedance when driving the second electrode and an uneven voltage distribution caused by a voltage drop; or the blocking portion of the isolation structure may be designed as an inorganic film layer or the like that may have a good bonding strength with the first encapsulation layer, which specifically as follows.

In at least one embodiment of the present application, as shown in FIG. 36, a first encapsulation layer 510 is in contact with a surface of the blocking portion, and materials of the first encapsulation layer 510 and the blocking portion 320 are same. In this way, a reliable bonding strength can be ensured to exist directly between the first encapsulation layer 510 and the blocking portion 320 to reduce a risk of the first encapsulation layer 510 falling off and cracking and leading to encapsulation failure.

For example, in some embodiments, as shown in FIG. 36, the first encapsulation layer 510 is composed of a plurality of first encapsulation units, each first encapsulation unit of the plurality of first encapsulation units respectively covers a first opening, the first encapsulation layer 510 and the first opening are conformal to form an encapsulation groove 511, the display panel further includes a second encapsulation layer 520 and a third encapsulation layer 530, the second encapsulation layer 520 is located on a side, facing away from a substrate, of the first encapsulation layer 510 and includes a plurality of second encapsulation unit, each second encapsulation unit of the plurality of second encapsulation unit fills the encapsulation groove 511, a distance from a surface, facing away from the substrate, of the second encapsulation unit to the substrate is not greater than a distance from a surface, facing away from the substrate, of the blocking portion 320 to the substrate, and the third encapsulation layer 530 is located on a side, facing away from the substrate, of the second encapsulation layer 520 and covers the first opening and the isolation structure. For example, the second encapsulation layer 520 is an organic layer, and the third encapsulation layer 530 is an inorganic layer.

For example, in some other embodiments, the structure shown in FIG. 36 may be modified, where the first encapsulation layer 510 is composed of a plurality of first encapsulation units, each first encapsulation unit of the plurality of first encapsulation units respectively covers a first opening, the first encapsulation layer 510 and the first opening are conformal to form an encapsulation groove 511, the display panel further includes a second encapsulation layer 520 and a third encapsulation layer 530. The second encapsulation layer 520 is located on a side, facing away from a substrate, of the first encapsulation layer 510 and includes a plurality of second encapsulation unit, each second encapsulation unit of the plurality of second encapsulation unit fills the encapsulation groove 511, a distance from a surface, facing away from the substrate, of the second encapsulation unit to the substrate is less than a distance from a surface, facing away from the substrate, of the blocking portion 320 to the substrate. The third encapsulation layer 530 is located on a side, facing away from the substrate, of the second encapsulation layer 520 and includes a plurality of third encapsulation units, the third encapsulation unit fills the encapsulation groove 511, and a distance from a surface, facing away from the substrate, of the third encapsulation unit to the substrate is not greater than the distance from the surface, facing away from the substrate, of the blocking portion 320 to the substrate. For example, the second encapsulation layer 520 is an organic layer, and the third encapsulation layer 530 is an inorganic layer.

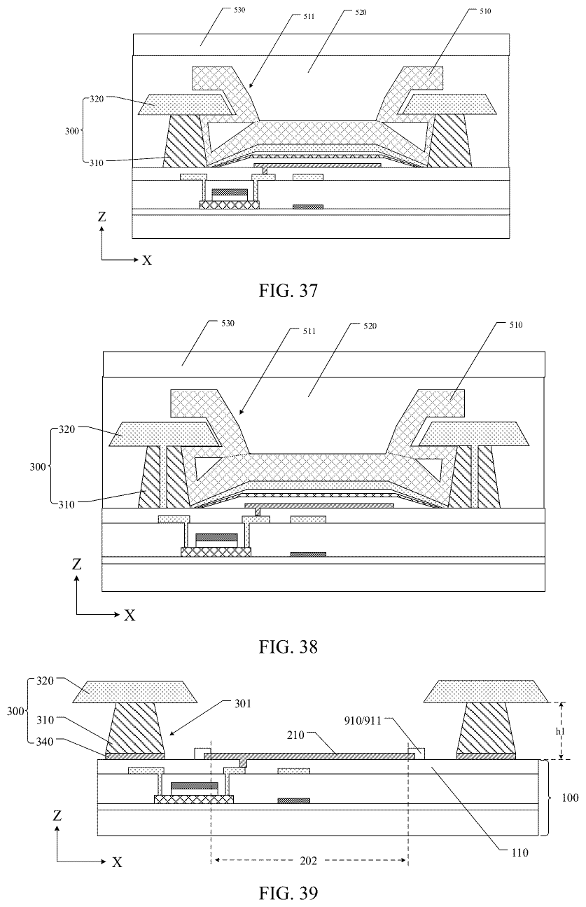

For example, in some still other embodiments, as shown in FIG. 37, a first encapsulation layer 510 is composed of a plurality of first encapsulation units, each first encapsulation unit of the plurality of first encapsulation units respectively covers a first opening, the first encapsulation layer 510 and the first opening are conformal to form an encapsulation groove 511, the display panel further includes a second encapsulation layer 520 and a third encapsulation layer 530. The second encapsulation layer 520 is located on a side, facing away from a substrate, of the first encapsulation layer 510 and covers the first opening and an isolation structure. The third encapsulation layer 530 is located on a side, facing away from the substrate, of the second encapsulation layer 520 and covers the first opening and the isolation structure. For example, the second encapsulation layer 520 is an organic layer, and the third encapsulation layer 530 is an inorganic layer.

For example, in a case that the first encapsulation layer 510 and the third encapsulation layer 530 are inorganic layers, materials of the first encapsulation layer 510 and the third encapsulation layer 530 may be silicon oxide, silicon nitride, silicon oxynitride, or the like.

For example, in an embodiment of the present application, the first encapsulation unit may be completely located in the first opening as shown in FIG. 36, or a portion of the first encapsulation unit extends out of the first opening as shown in FIG. 37. For a manner of forming the first encapsulation unit under this case, refer to related descriptions of the preparation method of the display panel in the foregoing embodiments.

It should be noted that, in the embodiments of the present application, if the color conversion layer is provided in the display panel, the light-emitting device may not need to be prepared in batches, that is, the first encapsulation layer may be formed as a whole layer of a continuous structure.

In at least one embodiment of the present application, as shown in FIG. 38, a dividing hole with a grid shape is provided in a supporting portion 310, the dividing hole divides the supporting portion 310 into a plurality of sub-supporting portions 311, an insulating blocking portion 320 (for example, an inorganic layer) covers and fills the dividing hole, the supporting portion is of a conductive structure, the blocking portion is of an insulating structure, and a second electrode 230 is connected to a sub-supporting portion 311 corresponding to the second electrode 230. In this way, a conductive portion of a partition portion is divided into the sub-supporting portion through the dividing hole, and second electrodes 230 of the light-emitting device 200 are independent of each other, and the second electrode of each light-emitting device 200 can be independently driven. For example, the second electrode 230 may be connected to a driving circuit in a substrate 100 through a conductive sub-supporting portion 311.

It should be noted that, in a case that a first end portion 310 is designed to include the sub-supporting portion 311 spaced apart, a width of the dividing hole formed in the first end portion 310 and a minimum width of the sub-supporting portion 311 need to be considered to determine a minimum width of one end, facing the substrate, of the supporting portion under the current design (the minimum value of L3 mentioned above). For example, in a case that the first end portion 310 is not provided with the dividing hole, if a minimum design width of L3 is 2 micrometers, the minimum width of the sub-supporting portion 311 may also be set to 2 micrometers after the first end portion 310 is provided with the dividing hole.

In the present application, an arrangement of the isolation structure shields part of light (for example, light at a large viewing angle) obliquely emitted by the light-emitting device, thereby reducing the viewing angle of the display panel; furthermore, when a height of the isolation structure is designed too high, it is not beneficial to reduce a minimum design width of the gap (for example, the L3 above-mentioned) of the light-emitting device, which is not beneficial to improving the pixel density of the display panel.

In at least one embodiment of the present application, an overall height of the isolation structure is reduced by cancelling the pixel defining layer, in this case, the protective layer is provided to protect the sidewall of the first electrode to solve above problems. This design is described in detail below with reference to specific embodiments.

In at least one embodiment of the present application, as shown in FIG. 39, the display panel may further include a protective layer 910, the protective layer 910 is an insulating layer, the protective layer 910 includes a plurality of protective units 911, and each protective unit 911 of the plurality of protective units 911 is located between a first electrode 210 and a first end portion 310 to cover at least a sidewall of the first electrode 210. In this way, in a process of preparing an isolation structure 300, the sidewall of the first electrode 210 may be protected by the protective layer 910, to prevent the first electrode 210 from side etching, thereby improving a yield of a light-emitting device 200.

It should be noted that, on a basis that it is ensured that the protective unit 911 may cover the sidewall of the first electrode 210, a shape of the protective unit 911 and a positional relationship with other structures may be further designed according to requirements of an actual process, which is not limited in the embodiments of the present application. For example, several specific designs of the protective unit 911 are as follows.

For example, in a specific example, as shown in FIG. 39, the protective unit 911 covers a sidewall of the first electrode 210 and covers an edge portion of an upper surface of the first electrode 210, and there is an interval between the protective unit 911 and the first end portion 310 of the isolation structure 300, that is, the protective unit 911 defines a plurality of openings, each opening of the plurality of openings exposes a portion of an upper surface of the first electrode 210, and an orthographic projection, on a plane where a substrate 100 is located, of an edge of the first electrode 210 is located within an orthographic projection, on the plane where the substrate 100 is located, of the protective unit 911.

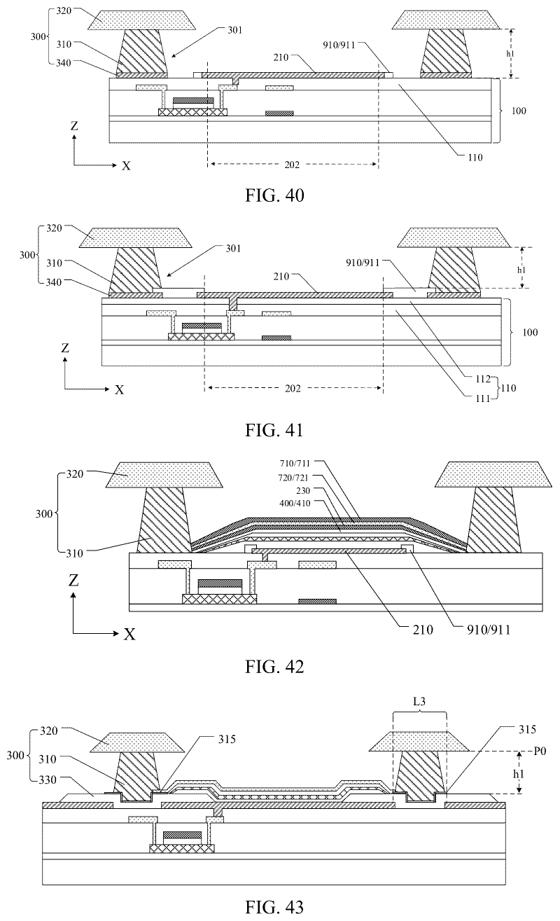

For example, in another specific example, as shown in FIG. 40, a protective unit 911 and a first electrode 210 are in same layer to cover only a sidewall of the first electrode 210, that is, an orthographic projection, on a plane where a substrate 100 is located, of the protective unit 911 is located outside an orthographic projection, on the plane where the substrate 100 is located, of an edge of the first electrode 210 and adjacent to the orthographic projection, on the plane where the substrate 100 is located, of the edge of the first electrode 210. Under this case, the protective unit 911 may be spaced from an isolation structure 300 as shown in FIG. 40, or may be adjacent to the isolation structure 300, that is, the protective unit 911 fills a gap between the first electrode 210 and a first end portion 310 of the isolation structure 300.

For example, in another specific example, as shown in FIG. 41, a protective unit 911 covers a sidewall of a first electrode 210 and a sidewall of a first end portion 310. In this way, a bonding strength between the protective unit 911 and a substrate 100 is higher, and the first electrode 210 is sandwiched between the protective unit 911 and the substrate 100, thereby further reducing the risk that the first electrode 210 falls off the substrate 100.

For example, the first end portion 310 includes a connecting portion 340 facing one side of the substrate 100, and the connecting portion 340 and the first electrode 210 are in same layer and made of same material. In this design, the connecting portion 340 may be synchronously prepared in a process of preparing the first electrode 210, to reduce a thickness requirement of the isolation structure; furthermore, the connecting portion 340 is disposed between the isolation structure and the substrate 100, and a risk that the isolation structure 300 falls off the substrate 100 can be reduced.

For example, a straight line perpendicular to the plane where the substrate 100 is located and passing through an edge of the second end portion 320 passes through the protective unit 911. In this way, when a thickness of the first height h1 and a thickness of the first encapsulation layer are designed, an influence caused by a thickness of the protective unit 911 needs to be considered, details are as follows.

In some embodiments of the present application, as shown in FIG. 39 and FIG. 40, when the interval is provided between the protective unit 911 and the first end portion 310 of the isolation structure 300, a distance between an edge of a second end portion 320 and an edge of the first end portion 310 is a first height h1 along a direction perpendicular to the plane where the substrate 100 is located, a distance between a first encapsulation layer and the first electrode 210 is a second height h2 at an intermediate position of the light-emitting device, a product of the second height h2 and a first thickness coefficient is a first numerical value, a sum of the first numerical value and a thickness of the protective unit 911 is a second numerical value, and a difference between the first height h1 and the second numerical value is not less than an encapsulation safety margin.

In some other embodiments of the present application, as shown in FIG. 41, when a protective layer 910 (which includes the protective unit 911) covers the sidewall of the first electrode 210 and a portion of the sidewall of the first end portion 310, a distance between an edge of a second end portion 320 and an edge of the first end portion 310 is a first height h1 along a direction perpendicular to the plane where the substrate 100 is located. In a regular cross-section of the light-emitting device, a distance between a position of a surface, facing the substrate 100, of a first encapsulation layer 510 that located on a straight line passing through the edge of the second end portion 320 and perpendicular to the plane where the substrate 100 is located and the edge of the first end portion 310 in the direction perpendicular to the plane where the substrate 100 is located is a partition association height, and a difference between the first height h1 and a first numerical value is not less than an encapsulation safety margin.

The distance between the first encapsulation layer and the first electrode 210 is the second height h2 at the intermediate position of the light-emitting device, the product of the second height and the first thickness coefficient is the first numerical value (the partition association height is equal to the first numerical value), the distance between the edge of the second end portion 320 and the edge of the first end portion 310 is the first height h1 along the direction perpendicular to the plane where the substrate 100 is located, the difference between the first height h1 and the first numerical value is not less than the encapsulation safety margin.

In one embodiment, the first thickness coefficient is greater than or equal to M and less than 1 and M∈[0.3, 0.5) or M∈[0.5, 0.7], further in one embodiment, M is a ratio of the partition association height to the second height h1, and further in one embodiment, the first thickness coefficient is equal to M.

It should be noted that a theoretical value of M is 0.5, and due to an influence of factors such as a static electricity, an adsorption performance of an adopted material, a strength of a related material and the like in a vapor deposition process of related film layers by means of the isolation structure, the partition association height h3 may deviate from the theoretical value; correspondingly, according to an actual situation, a value of M may be changed within a range of 0.5±0.2, and a specific value may be obtained through experiments or reference experience.

For example, the first thickness coefficient may be equal to 0.5, to facilitate the first height h1 to be taken to a small value, thereby facilitating an improvement of the pixel density of the display panel.

For example, the thickness of the protective unit 911 may be a thickness of a portion between the first electrode 210 and the isolation structure 300.

For example, in one design, on the regular cross-section of the light-emitting device, a distance between an orthographic projection, on the plane where the substrate 100 is located, of an edge of a portion, exposed from the protective layer 910, of the first electrode 210 and the orthographic projection, on the plane where the substrate 100 is located, of the edge of the second end portion 320 is less than: a product of a cotangent value of an acute angle at which a connecting line of an edge of a light-emitting functional layer and the edge of the second end portion 320 intersects the plane where the substrate 100 is located and a distance between an intermediate portion of a lower surface of the light-emitting functional layer and the edge of the second end portion 320 in the direction perpendicular to the plane where the substrate 100 is located. In this way, by adjusting a coverage area of the protective unit 911 of the protective layer 910 to the first electrode 210, it can be better ensured that the first electrode 210 exists in a region (for example, the effective functional region 202 above-mentioned) with a uniform film thickness of the light-emitting functional layer, thereby improving an area of a uniform light-emitting region (with the uniform film thickness of the light-emitting functional layer) of the light-emitting device 200, to increase an aperture ratio of the display panel; furthermore, the design provides sufficient margin for an alignment precision of the first electrode 210 and the isolation structure 300, and even if there is position offsets of the first electrode 210 and the isolation structure 300, it can also be ensured that area and position of the uniform light-emitting region of the light-emitting device 200 are not affected.

For the above relationship, in a case that the protective unit 911 and the isolation structure 300 are spaced as shown in FIG. 39, it may be further defined in combination with the first height h1, the distance between the orthographic projection, on the plane where the substrate 100 is located, of the edge of the portion, exposed from the protective layer 910, of the first electrode 210 and the orthographic projection, on the plane where the substrate 100 is located, of the edge of the second end portion 320 is less than: a product of the cotangent value of the acute angle at which the connecting line of the edge of the light-emitting functional layer and the edge of the second end portion intersects the plane where the substrate 100 is located and a distance between the first height h1 and a thickness of the first electrode 210.

For the above relationship, in a case that the protective unit 911 covers the gap between the isolation structure 300 and the first electrode 210 as shown in FIG. 41, it may be further defined in combination with the first height h1, that is, the distance between the orthographic projection, on the plane where the substrate 100 is located, of the edge of the portion, exposed from the protective layer 910, of the first electrode 210 and the orthographic projection, on the plane where the substrate 100 is located, of the edge of the second end portion 320 is less than: a product of the cotangent value of the acute angle at which the connecting line of the edge of the light-emitting functional layer and the edge of the second end portion 320 intersects the plane where the substrate 100 is located and a sum between the first height h1 and the thickness of the protective unit 911.

For example, in another design, on a regular cross-section of the light-emitting device 200, the product of the cotangent value of the acute angle at which the connecting line of the edge of the light-emitting functional layer and the edge of the second end portion 320 intersects the plane where the substrate 100 is located and the distance between the intermediate portion of the lower surface of the light-emitting functional layer and the edge of the second end portion 320 in the direction perpendicular to the plane where the substrate 100 is located is less than or equal to: the distance between the orthographic projection, on the plane where the substrate 100 is located, of the edge of the portion, exposed from the protective layer 910, of the first electrode 210 and the orthographic projection, on the plane where the substrate 100 is located, of the edge of the second end portion 320. In this way, by adjusting the coverage area of the protective unit 911 of the protective layer 910 to the first electrode 210, the film thickness of the light-emitting functional layer is uniform in a region of the light-emitting device 200 where the first electrode is distributed, and wavelengths of light emitted from the light-emitting region of the light-emitting device 200 can be ensured to be consistent, to eliminate a problem of stray light with different colors in the light-emitting device 200.

For the above relationship, in the case that the protective unit 911 and the isolation structure 300 are spaced as shown in FIG. 39, it may be further defined in combination with the first height h1, that is, the distance between the orthographic projection, on the plane where the substrate 100 is located, of the edge of the portion, exposed from the protective layer 910, of the first electrode 210 and the orthographic projection, on the plane where the substrate 100 is located, of the edge of the second end portion 320 is greater than or equal to: a product of the cotangent value of the acute angle at which the connecting line of the edge of the light-emitting functional layer and the edge of the second end portion 320 intersects the plane where the substrate 100 is located and a difference between the first height h1 and a thickness of the first electrode 210 and a thickness of the protective unit 911.

For the above relationship, in the case that the protective unit 911 covers the gap between the isolation structure 300 and the first electrode 210 as shown in FIG. 41, it may be further defined in combination with the first height h1, that is, the distance between the orthographic projection, on the plane where the substrate 100 is located, of the edge of the portion, exposed from the protective layer 910, of the first electrode 210 and the orthographic projection, on the plane where the substrate 100 is located, of the edge of the second end portion 320 is greater than or equal to: a product of the cotangent value of the acute angle at which the connecting line of the edge of the light-emitting functional layer and the edge of the second end portion 320 intersects the plane where the substrate 100 is located and the first height h1.

For the above relationship, if a structure shown in FIG. 41 is modified to remove the connecting portion, in the case that the protective unit 911 covers the gap between the isolation structure 300 and the first electrode 210, it may be further defined in combination with the first height h1, that is, the distance between the orthographic projection, on the plane where the substrate 100 is located, of the edge of the portion, exposed from the protective layer 910, of the first electrode 210 and the orthographic projection, on the plane where the substrate 100 is located, of the edge of the second end portion 320 is greater than or equal to: a product of the cotangent value of the acute angle at which the connecting line of the edge of the light-emitting functional layer and the edge of the second end portion 320 intersects the plane where the substrate 100 is located and a difference between a thickness of the first height h1 and a thickness of the first electrode 210.

For example, the substrate 100 includes a planarization layer 110 facing a side of the isolation structure 300, the planarization layer 110 includes a first planarization layer 111 and a second planarization layer 112, the second planarization layer 112 is located between the first planarization layer 111 and the isolation structure 300, and is located between the first planarization layer 111 and the first electrode 210, the first planarization layer 111 is an organic layer, and the second planarization layer 112 is an inorganic layer. In this design, by designing the second planarization layer 112 as the inorganic layer, a bonding strength of the substrate 100 and the isolation structure 300 and the first electrode 210 may be increased, thereby reducing a risk that the first electrode 210 and the isolation structure 300 fall off the substrate 100.

It should be noted that, in at least one embodiment of the present application, as shown in FIG. 42, in a case that the display panel is provided with a protective unit 911, the display panel may further include an optical functional unit, and for a type of the optical functional unit and a specific setting mode, refer to related descriptions in the foregoing embodiments.

It should be noted that, in combination with the above description of the edge of the first end portion and the edge of the second end portion of the isolation structure corresponding to different specific structures, it can be understood that the edge of the first end portion corresponds to an edge of a lowermost side of a position of a vapor deposition layer formed by the isolation structure in contact with the first end portion is an edge of a lowermost side of an outer leakage of the first end portion before the vapor deposition layer is formed; for example, as shown in FIG. 43, a first end portion 310 includes an overlapping portion 315 facing a side of a substrate 100, and an edge of the overlapping portion 315 extends outward relative to a portion, located on the overlapping portion 315, of the first end portion 310, and a second electrode 230 is better electrically connected to a supporting portion 310; material of a second end portion 320 may include titanium, and material of the portion, located on the lap joint portion 315, of the first end portion 310 may include aluminum; and material of the lap joint portion 315 may include molybdenum. In this structure, the edge of the overlapping portion 315 is an edge of the first end portion. The edge of the second end portion is an outermost outline edge corresponding to the second end portion, and corresponds to an outermost position where the second end portion shields a vapor deposition material when forming the vapor deposition layer.

For the specific design of the display panel mentioned above, the following describes the pixel pitch between light-emitting devices, width parameters of each part of the isolation structure under different pixel pitches, and specific design parameters of each structure in the display panel under different pixel pitch requirements. It should be noted that, a pixel pitch is a distance between an edge of a portion that a first electrode of one light-emitting device in contact with a corresponding light-emitting functional layer and an edge of a portion that a first electrode of another adjacent light-emitting device in contact with a corresponding light-emitting functional layer in every two adjacent light-emitting devices.

At least one embodiment of the present application provides a display panel. The display panel includes a substrate, and an isolation structure and a display function layer located on the substrate. The isolation structure has a first end portion and a second end portion. The second end portion is located on a side, away from the substrate, of the first end portion, The isolation structure defines a plurality of first openings, the display functional layer includes a plurality of light-emitting devices, where the plurality of light-emitting devices correspond to the plurality of first openings respectively, each light-emitting device of the plurality of light-emitting devices is located in a first opening, corresponding to the light-emitting device, of the plurality of first openings, the light-emitting device includes a first electrode, a light-emitting functional layer and a second electrode stacked on the substrate, an orthographic projection, on a plane where the substrate is located, of an edge of the first functional layer is located outside an orthographic projection, on the plane where the substrate is located, of the first end portion, and is located within an orthographic projection, on the plane where the substrate is located, of the second end portion. A distance between edges of portions that the first electrode contact with the light-emitting functional layer corresponding to the first electrode of adjacent light-emitting devices is a pixel pitch, the pixel pitch is 2000 to 18000 nanometers.

It should be noted that, in this case, the pixel pitch is not calculated at the second distance L1 as shown in FIG. 5, but is calculated by replacing the second distance L1 with the first distance L0 as shown in FIG. 35A and FIG. 35B, it should be noted that there is a situation that the first distance L0 and the second distance L1 may be overlap, for details, refer to related descriptions in the foregoing embodiments, and details are not described herein again.

In some embodiments of the present application, on a regular cross-section of the light-emitting device, a cross-sectional profile of a portion, located between two adjacent sub-pixels, of a partition portion, is an inverted trapezoid, an edge of a bottom of the inverted trapezoid is the edge of the second end portion, and an edge of a top of the inverted trapezoid is the edge of the first end portion, and a width of a top of the inverted trapezoid is 1500 to 16000 nanometers. For a specific design of the partition portion in this case, reference may be made to related descriptions in the foregoing embodiments, and details are not described herein again.

In some other embodiments of the present application, the partition portion includes a supporting portion and a blocking portion stacked on the substrate, the supporting portion forms the first end portion, the blocking portion forms the second end portion, on the regular cross-section of the light-emitting device, a cross-sectional profile of the supporting portion and the blocking portion is a regular trapezoid, the edge of the second end portion is an edge, facing a surface of the substrate, of the blocking portion, the edge of the first end portion is an edge, facing a surface of the substrate, of the supporting portion, where a width of a bottom of the regular trapezoid corresponding to the supporting portion is 1258 to 17000 nanometers, and a width of a top of the regular trapezoid corresponding to the supporting portion is 880 to 15000 nanometers. For a specific design of the partition portion in this case, refer to related descriptions in the foregoing embodiments, and details are not described herein again.

In at least one embodiment of the present application, the display panel may include a plurality of pixels, each pixel of the plurality of pixels includes a plurality of sub-pixels with different wavelengths of emergent light, the plurality of sub-pixels of the plurality of pixels includes a first sub-pixel, a second sub-pixel and a third sub-pixel, and the first sub-pixel, the second sub-pixel and the third sub-pixel respectively include different light-emitting devices.

In one embodiment, a number ratio of the first sub-pixel, the second sub-pixel and the third sub-pixel is 1:1:1.

In one embodiment, each pixel is arranged in a first pixel arrangement manner in which the first sub-pixel, the second sub-pixel, and the third sub-pixel are arranged in parallel; or, each pixel is arranged in a second pixel arrangement manner in which the second sub-pixel and the third sub-pixel are arranged in a column/row and are arranged parallel to the first sub-pixel. For the first pixel arrangement manner and the second pixel arrangement manner, reference may be made to related descriptions in the foregoing embodiments, and details are not described herein again.

In one embodiment, the larger a pixel density, the smaller a pixel pitch, and/or the smaller an average width of the plurality of sub-pixels.

In some embodiments of the present application, the partition portion of the isolation structure is in direct contact with the substrate, an edge of a first spacing is the edge of the portion of the first electrode in contact with the light-emitting functional layer in a same light-emitting device, a distance between an orthographic projection, on the surface where the substrate is located, of the edge of the second end portion and an orthographic projection, on the surface where the substrate is located, of the edge of the first end portion is a first width, and a distance between the edge of the portion of the first electrode in contact with the light-emitting functional layer in the same light-emitting device and the orthographic projection, on the plane where the substrate is located, of the edge of the second end portion is a first spacing. In this case, the pixel pitch is 2000 to 2200 nanometers, the first spacing is 0 to 1017 nanometers, and the first width is 148 to 417 nanometers; or the pixel pitch is 2200 to 2500 nanometers, the first spacing is 0 to 1050 nanometers, and the first width is 166 to 450 nanometers; or the pixel spacing is 2500 to 3200 nanometers, the first spacing is 0 to 1090 nanometers, and the first width is 185 to 490 nanometers; or the pixel spacing is 3200 to 4000 nanometers, the first spacing is 0 to 1130 nanometers, and the first width is 203 to 530 nanometers; or the pixel spacing is 4000 to 6000 nanometers, the first spacing is 0 to 1170 nanometers, and the first width is 221 to 570 nanometers; or the pixel pitch is 6000 to 9000 nanometers, the first spacing is 0 to 1210 nanometers, and the first width is 240 to 610 nanometers; or the pixel pitch is 9000 to 13000 nanometers, the first spacing is 0 to 1300 nanometers, and the first width is 259 to 700 nanometers; or the pixel pitch is 13000 to 18000 nanometers, the first spacing is 0 to 1410 nanometers, and the first width is 277 to 810 nanometers.

For example, in a first case that the partition portion is in direct contact with the substrate, on the regular cross-section of the light-emitting device, a product of a cotangent value of an acute angle at which a connecting line of an edge of the light-emitting functional layer and the edge of the second end portion intersects the plane where the substrate is located and a distance between an intermediate portion of a lower surface of the light-emitting functional layer and the edge of the second end portion in a direction perpendicular to the plane where the substrate is located is less than or equal to: a distance between an orthographic projection, on the plane where the substrate is located, of an edge of the first electrode and the orthographic projection, on the plane where the substrate is located, of the edge of the second end portion. For example, the pixel pitch is 2000 to 2200 nanometers, and the first spacing is 148 to 567 nanometers; or the pixel pitch is 2200 to 2500 nanometers, and the first spacing is 166 to 650 nanometers; or the pixel pitch is 2500 to 3200 nanometers, and the first spacing is 185 to 740 nanometers; or the pixel pitch is 3200 to 4000 nanometers, and the first spacing is 203 to 830 nanometers; or the pixel pitch is 4000 to 6000 nanometers, and the first spacing is 221 to 920 nanometers; or the pixel pitch is 6000 to 9000 nanometers, and the first spacing is 240 to 1010 nanometers; or the pixel pitch is 9000 to 13000 nanometers, and the first spacing is 259 to 1150 nanometers; or the pixel pitch is 13000 to 18000 nanometers, and the first spacing is 277 to 1310 nanometers.

In one embodiment, in the first case that the partition portion is in direct contact with the substrate, a distance from the edge of the second end portion to the edge of the first end portion is a first height along the direction perpendicular to the plane where the substrate is located, and the first height is 400 to 2200 nanometers. In one embodiment, the pixel pitch is 2000 to 2200 nanometers, and the first height is 400 to 800 nanometers; or the pixel pitch is 2200 to 2500 nanometers, and the first height is 450 to 850 nanometers; or the pixel pitch is 2500 to 3200 nanometers, and the first height is 500 to 900 nanometers; or the pixel pitch is 3200 to 4000 nanometers, and the first height is 550 to 950 nanometers; or the pixel pitch is 4000 to 6000 nanometers, and the first height is 600 to 1000 nanometers; or the pixel pitch is 6000 to 9000 nanometers, and the first height is 650 to 1100 nanometers; or the pixel pitch is 9000 to 13000 nanometers, and the first height is 700 to 1200 nanometers; or the pixel pitch is 13000 to 18000 nanometers, and the first height is 750 to 2200 nanometers.

For example, in a second case that the partition portion is in direct contact with the substrate, on the regular cross-section of the light-emitting device, a distance between an orthographic projection, on the plane where the substrate is located, of an edge of the first electrode and the orthographic projection, on the plane where the substrate is located, of the edge of the second end portion is less than: a product of a cotangent value of an acute angle at which a connecting line of an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located. Under this case, the pixel pitch is 2000 to 2200 nanometers, the first spacing is 0 to 415 nanometers, and the first width is 148 to 417 nanometers; or the pixel pitch is 2200 to 2500 nanometers, the first spacing is 0 to 446 nanometers, and the first width is 166 to 450 nanometers; or the pixel pitch is 2500 to 3200 nanometers, the first spacing is 0 to 484 nanometers, and the first width is 185 to 490 nanometers; or the pixel pitch is 3200 to 4000 nanometers, the first spacing is 0 to 522 nanometers, and the first width is 203 to 530 nanometers; or the pixel pitch is 4000 to 6000 nanometers, the first spacing is 0 to 560 nanometers, and the first width is 221 to 570 nanometers; or the pixel pitch is 6000 to 9000 nanometers, the first spacing is 0 to 598 nanometers, and the first width is 240 to 610 nanometers; or the pixel pitch is 9000 to 13000 nanometers, the first spacing is 0 to 685 nanometers, and the first width is 259 to 700 nanometers; or the pixel pitch is 13000 to 18000 nanometers, the first spacing is 0 to 790 nanometers, and the first width is 277 to 810 nanometers.

For example, in a case that the partition portion is in direct contact with the substrate, the display panel further includes at least one optical functional layer, where the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases. For example, for every two adjacent first electrodes, a pixel pitch between edges of a portion of the first electrode in contact with the light-emitting functional layer in a same light-emitting device is 2074 to 18000 nanometers. For a specific type and a setting manner of the optical functional layer, refer to related descriptions in the foregoing embodiments, and details are not described herein again.

In some other embodiments of the present application, the display panel further includes a pixel defining layer, the pixel defining layer is located on the first electrode and located on a side, facing the substrate, of the partition portion and defines a second opening, the pixel defining layer covers an edge of the first electrode, the second opening exposes the first electrode, and an edge of the second opening coincides with an edge of a portion of the first electrode in contact with the light-emitting functional layer in a same light-emitting device, where a distance between an orthographic projection, on the plane where the substrate is located, of the edge of the second end portion and an orthographic projection, on the plane where the substrate is located, of the edge of the first end portion is a first width, a distance between an edge of a portion of the first electrode in contact with the light-emitting functional layer in the same light-emitting device and an orthographic projection, on the plane where the substrate is located, of the edge of the second end portion is a first spacing. For example the pixel pitch is 2200 to 2500 nanometers, the first spacing is 0 to 1050 nanometers, and the first width is 148 to 450 nanometers; or the pixel pitch is 2500 to 3200 nanometers, the first spacing is 0 to 1090 nanometers, and the first width is 185 to 490 nanometers; or the pixel pitch is 3200 to 4000 nanometers, the first spacing is 0 to 1130 nanometers, and the first width is 203 to 530 nanometers; or the pixel pitch is 4000 to 6000 nanometers, the first spacing is 0 to 1170 nanometers, and the first width is 221 to 570 nanometers; or the pixel pitch is 6000 to 9000 nanometers, the first spacing is 0 to 1210 nanometers, and the first width is 240 to 610 nanometers; or the pixel pitch is 9000 to 13000 nanometers, the first spacing is 0 to 1300 nanometers, and the first width is 259 to 700 nanometers; or the pixel pitch is 13000 to 18000 nanometers, the first spacing is 0 to 1410 nanometers, and the first width is 277 to 810 nanometers.

For example, in a third case that the partition portion is in direct contact with the substrate, on the regular cross-section of the light-emitting device, a product of a cotangent value of an acute angle at which a connecting line of an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located is less than or equal to: a distance between an orthographic projection, on the plane where the substrate is located, of an edge of a portion, exposed from the plurality of second openings, of the first electrode and the orthographic projection, on the plane where the substrate is located, of the edge of the second end portion. For example, the pixel pitch is 2200 to 2500 nanometers, the first spacing is 148 to 650 nanometers, and the first width is 148 to 450 nanometers; or the pixel pitch is 2500 to 3200 nanometers, the first spacing is 185 to 740 nanometers, and the first width is 185 to 490 nanometers; or the pixel pitch is 3200 to 4000 nanometers, the first spacing is 203 to 830 nanometers, and the first width is 203 to 530 nanometers; or the pixel pitch is 4000 to 6000 nanometers, the first spacing is 221 to 920 nanometers, and the first width is 221 to 570 nanometers; or the pixel pitch is 6000 to 9000 nanometers, the first spacing is 240 to 1010 nanometers, and the first width is 240 to 610 nanometers; or the pixel pitch is 9000 to 13000 nanometers, the first spacing is 259 to 1150 nanometers, and the first width is 259 to 700 nanometers; or the pixel pitch is 13000 to 18000 nanometers, the first spacing is 277 to 1310 nanometers, and the first width is 277 to 810 nanometers.

In one embodiment, in the third case that the display panel includes the pixel defining layer, a distance from the edge of the second end portion to the edge of the first end portion is a first height along the direction perpendicular to the plane where the substrate is located, and the first height is 400 to 2200 nanometers. In one embodiment, the pixel pitch is 2200 to 2500 nanometers, and the first height is 400 to 850 nanometers; or the pixel pitch is 2500 to 3200 nanometers, and the first height is 500 to 900 nanometers; or the pixel pitch is 3200 to 4000 nanometers, and the first height is 550 to 950 nanometers; or the pixel pitch is 4000 to 6000 nanometers, and the first height is 600 to 1000 nanometers; or the pixel pitch is 6000 to 9000 nanometers, and the first height is 650 to 1100 nanometers; or the pixel pitch is 9000 to 13000 nanometers, and the first height is 700 to 1200 nanometers; or the pixel pitch is 13000 to 18000 nanometers, and the first height is 750 to 2200 nanometers.

In one embodiment, in a fourth case that the display panel includes the pixel defining layer, on the regular cross-section of the light-emitting device, a distance between an orthographic projection, on the plane where the substrate is located, of an edge of a portion, exposed from the plurality of second openings, of the first electrode and the orthographic projection, on the plane where the substrate is located, of the edge of the second end portion is less than: a product of a cotangent value of an acute angle at which a connecting line of an edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located. For example, the pixel pitch is 2200 to 2500 nanometers, the first spacing is 0 to 446 nanometers, and the first width is 148 to 450 nanometers; or the pixel pitch is 2500 to 3200 nanometers, the first spacing is 0 to 484 nanometers, and the first width is 185 to 490 nanometers; or the pixel pitch is 3200 to 4000 nanometers, the first spacing is 0 to 522 nanometers, and the first width is 203 to 530 nanometers; or the pixel pitch is 4000 to 6000 nanometers, the first spacing is 0 to 560 nanometers, and the first width is 221 to 570 nanometers; or the pixel pitch is 6000 to 9000 nanometers, the first spacing is 0 to 598 nanometers, and the first width is 240 to 610 nanometers; or the pixel pitch is 9000 to 13000 nanometers, the first spacing is 0 to 685 nanometers, and the first width is 259 to 700 nanometers; or the pixel pitch is 13000 to 18000 nanometers, the first spacing is 0 to 790 nanometers, and the first width is 277 to 810 nanometers.

For example, in a case that the display panel includes the pixel defining layer, the display panel may further includes at least one optical functional layer, the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases, and for every two adjacent first electrodes, a pixel pitch between edges of a portion of the first electrode in contact with the light-emitting functional layer in a same light-emitting device is 2274 to 18000 nanometers. For a specific type and a setting manner of the optical functional layer, refer to related descriptions in the foregoing embodiments, and details are not described herein again.

The pixel pitch of the display panel under different structures is described above, and a pixel density of the display panel is described below in combination with different structures of the display panel and corresponding pixel pitches.

At least one embodiment of the present application provides a display panel, the display panel includes a substrate, an isolation structure and a display functional layer, where the isolation structure and the display functional layer are located on the substrate, where the isolation structure includes a first end portion and a second end portion, the second end portion located on a side, away from the substrate, of the first end portion, the isolation structure defines a plurality of first openings, the display functional layer includes a plurality of light-emitting devices, each light-emitting device of the plurality of light-emitting devices is located in a first opening, corresponding to the light-emitting device, of the plurality of first openings, an orthographic projection, on a plane where the substrate is located, of the light-emitting functional layer is located outside an orthographic projection, on the plane where the substrate is located, of the first end portion, and located within an orthographic projection, on the plane where the substrate is located, of the second end portion, the light-emitting device includes a first electrode, a light-emitting functional layer and a second electrode stacked on the substrate, and a pixel density of the display panel is 90 PPI to 7400 PPI. For a specific structure of the display panel, refer to related descriptions in the foregoing embodiments, and details are not described herein again.

In at least one embodiment of the present application, a thickness of an edge portion of each of at least one of the film layers of the light-emitting device gradually decreases along a direction from a middle portion of the light-emitting device to an edge of the light-emitting device. For a forming method and a specific setting manner of the light-emitting device, refer to related descriptions in the foregoing embodiments, and details are not described herein again.

In at least one embodiment of the present application, a pixel pitch between edges of portions that the first electrode in contact with a corresponding light-emitting functional layer of adjacent light-emitting devices is 2000 to 18000 nanometers.

In at least one embodiment of the present application, in a regular cross-section of the light-emitting device, a cross-sectional profile of a portion, located between two adjacent sub-pixels, of the partition portion is an inverted trapezoid, an edge of a bottom of the inverted trapezoid is an edge of the second end portion, and an edge of a top of the inverted trapezoid is an edge of the first end portion. For a specific design of the partition portion under this case, refer to related descriptions in the foregoing embodiments, and details are not described herein again.

In at least one embodiment of the present application, the partition portion includes a supporting portion and a blocking portion stacked on the substrate, the supporting portion forms the first end portion, the blocking portion forms the second end portion, on a regular cross-section of the light-emitting device, a cross-sectional profile of a portion, located between two adjacent sub-pixels, of the supporting portion and the blocking portion is a regular trapezoid, the edge of the second end portion is an edge of a surface, facing a surface of the substrate, of the blocking portion, and the edge of the first end portion is an edge of a surface, facing the surface of the substrate, of the supporting portion. For a specific design of the partition portion under this case, refer to related descriptions in the foregoing embodiments, and details are not described herein again.

In at least one embodiment of the present application, the display panel includes a plurality of pixels, each pixel of the plurality of pixels includes a plurality of sub-pixels with different wavelengths of emergent light, the plurality of sub-pixels of the plurality of pixels include a first sub-pixel, a second sub-pixel and a third sub-pixel, and the first sub-pixel, the second sub-pixel and the third sub-pixel respectively include different light-emitting devices.

In one embodiment, a number ratio of the first sub-pixel, the second sub-pixel and the third sub-pixel is 1:1:1.

In one embodiment, each pixel is arranged in a first pixel arrangement manner in which a first sub-pixel, a second sub-pixel, and a third sub-pixel are arranged in parallel; or, each pixel is arranged in a second pixel arrangement manner in which the second sub-pixel and the third sub-pixel are arranged in a column/row and are arranged parallel to the first sub-pixel. For the first pixel arrangement manner and the second pixel arrangement manner, reference may be made to related descriptions in the foregoing embodiments, and details are not described herein again.

In some embodiments of the present application, a pixel density of the display panel is 90 to 5200 PPI. In one embodiment, the pixel pitch is 2000 to 2200 nanometers, and the pixel density of the display panel is 117 to 5200 PPI; or the pixel pitch is 2200 to 2500 nanometers, and the pixel density of the display panel is 117 to 4792 PPI; or the pixel pitch is 2500 to 3200 nanometers, and the pixel density of the display panel is 115 to 4305 PPI; or the pixel pitch is 3200 to 4000 nanometers, and the pixel density of the display panel is 115 to 3479 PPI; or the pixel pitch is 4000 to 6000 nanometers, and the pixel density of the display panel is 111 to 2854 PPI; or the pixel pitch is 6000 to 9000 nanometers, and the pixel density of the display panel is 107 to 1969 PPI; or the pixel pitch is 9000 to 13000 nanometers, and the pixel density of the display panel is 102 to 1344 PPI; or the pixel pitch is 13000 to 18000 nanometers, and the pixel density of the display panel is 90 to 944 PPI.

In some embodiments of the present application, the plurality of sub-pixels in a pixel are arranged in the first pixel arrangement manner, and the pixel density of the display panel is 170 to 3456 PPI. In one embodiment, the pixel pitch is 2000 to 2200 nanometers, and the pixel density of the display panel is 2545 to 3456 PPI; or the pixel pitch is 2200 to 2500 nanometers, and the pixel density of the display panel is 2171 to 3143 PPI; or the pixel pitch is 2500 to 3200 nanometers, and the pixel density of the display panel is 1577 to 2765 PPI; or the pixel pitch is 3200 to 4000 nanometers, and the pixel density of the display panel is 1063 to 2160 PPI; or the pixel pitch is 4000 to 6000 nanometers, and the pixel density of the display panel is 529 to 1728 PPI; or the pixel pitch is 6000 to 9000 nanometers, and the pixel density of the display panel is 353 to 1152 PPI; or the pixel pitch is 9000 to 13000 nanometers, and the pixel density of the display panel is 244 to 768 PPI; or the pixel pitch is 13000 to 18000 nanometers, and the pixel density of the display panel is 170 to 531 PPI.

In some embodiments of the present application, under the first pixel arrangement manner, the pixel pitch is 2000-2200 nanometers, and the pixel density of the display panel may be 2600 PPI, 2800 PPI, 3000 PPI, or 3200 PPI; or, the pixel pitch is 2200 to 2500 nanometers, and the pixel density of the display panel may be 2200 PPI, 2600 PPI, or 3000 PPI; or, the pixel pitch is 2500 to 3200 nanometers, and the pixel density of the display panel may be 1600 PPI, 1800 PPI, 2100 PPI, 2200 PPI, or 2600 PPI; or, the pixel pitch is 3200 to 4000 nanometers, and the pixel density of the display panel may be 1200 PPI, 1500 PPI, 1600 PPI, 1700 PPI, 1800 PPI, or 2100 PPI; or, the pixel pitch is 4000 to 6000 nanometers, and the pixel density of the display panel may be 600 PPI, 700 PPI, 847 PPI, 941 PPI, 1000 PPI, 1150 PPI, 1200 PPI, 1500 PPI, 1700 PPI; or, the pixel pitch is 6000 to 9000 nanometers, and the pixel density of the display panel may be 400 PPI, 550 PPI, 600 PPI, 661 PPI, 700 PPI, 706 PPI, 847 PPI, 941 PPI, 1000 PPI, 1150 PPI; or, the pixel pitch is 9000 to 13000 nanometers, and the pixel density of the display panel may be 300 PPI, 400 PPI, 446 PPI, 504 PPI, 550 PPI, 661 PPI, 706 PPI; or the pixel pitch is 13000 to 18000 nanometers, and the pixel density of the display panel may be 200 PPI, 300 PPI, 370 PPI, 400 PPI.

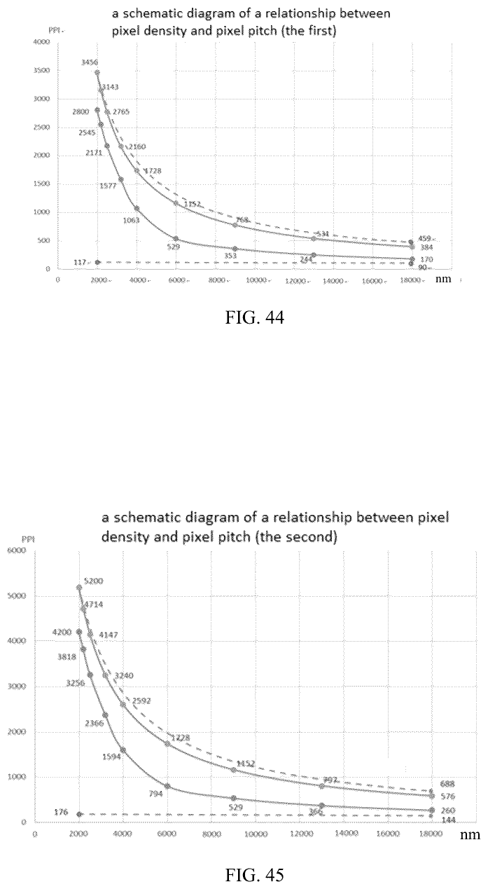

Corresponding to the first pixel arrangement manner, a parameter change rule of the pixel pitch and the pixel density may be referred to FIG. 44, and as shown in FIG. 44, it can be seen that generally, along with a pixel pitch decreases, a pixel density corresponding to the pixel pitch increases; in the FIG. 44, two dashed lines represent an upper limit and a lower limit of a design of the pixel density corresponding to different pixel pitches, and a region between two solid lines represents a more appropriate selection range between the pixel pitch and the pixel density. For example, in this selection range, if the pixel pitch is designed to be 2000 nanometers, an appropriate selection range of the pixel density is 2800 to 3456 PPI; if the pixel pitch is designed to be 18000 nanometers, the appropriate selection range of the pixel density may be 170 to 384 PPI. Furthermore, in FIG. 44, according to a below dashed line, when the pixel pitch is 2000 nanometers, the lower limit of the pixel density is 117 PPI, and when the pixel pitch is 2000 nanometers, the lower limit of the pixel density is 90 PPI; according to an above dashed line, when the pixel pitch is 2000 nanometers, the upper limit of the pixel density is 3456 PPI; and when the pixel pitch 18000 nanometers, the upper limit of the pixel density is 459 PPI.

In some other embodiments of the present application, the plurality of sub-pixels in a pixel are arranged in the second pixel arrangement manner, and the pixel density of the display panel is 260 to 5200 PPI. In one embodiment, the pixel pitch is 2000 to 2200 nanometers, and the pixel density of the display panel is 3818 to 5200 PPI; or the pixel pitch is 2200 to 2500 nanometers, and the pixel density of the display panel is 3256 to 4714 PPI; or the pixel pitch is 2500 to 3200 nanometers, and the pixel density of the display panel is 2366 to 4147 PPI; or the pixel pitch is 3200 to 4000 nanometers, and the pixel density of the display panel is 1594 to 3240 PPI; or the pixel pitch is 4000 to 6000 nanometers, and the pixel density of the display panel is 794 to 2592 PPI; or the pixel pitch is 6000 to 9000 nanometers, and the pixel density of the display panel is 529 to 1728 PPI; or the pixel pitch is 9000 to 13000 nanometers, and the pixel density of the display panel is 366 to 1152 PPI; or the pixel pitch is 13000 to 18000 nanometers, and the pixel density of the display panel is 260 to 797 PPI.

In some embodiments of the present application, under the second pixel arrangement manner, the pixel pitch is 2000 to 2200 nanometers, and the pixel density of the display panel may be 4000 PPI, 4600 PPI, 4800 PPI, or 5000 PPI; or, the pixel pitch is 2200 to 2500 nanometers, and the pixel density of the display panel may be 3300 PPI, 3500 PPI, 4000 PPI, or 4600 PPI; or, the pixel pitch is 2500 to 3200 nanometers, and the pixel density of the display panel may be 2600 PPI, 2800 PPI, 3000 PPI, 3200 PPI, 3300 PPI, 3500 PPI, or 4000 PPI; or, the pixel pitch is 3200-4000 nanometers, and the pixel density of the display panel may be 1600 PPI, 1800 PPI, 2200 PPI, 2500 PPI, 2600 PPI, 2800 PPI, 3000 PPI, or 3200 PPI; or, the pixel pitch is 4000 to 6000 nanometers, and the pixel density of the display panel may be 850 PPI, 992 PPI, 1000 PPI, 1025 PPI, 1270 PPI, 1300 PPI, 1411 PPI, 1500 PPI, 1600 PPI, 1800 PPI, 2200 PPI, or 2500 PPI; or, the pixel pitch is 6000 to 9000 nanometers, and the pixel density of the display panel may be 550 PPI, 668 PPI, 756 PPI, 800 PPI, 850 PPI, 992 PPI, 1000 PPI, 1025 PPI, 1270 PPI, 1300 PPI, 1411 PPI, or 1500 PPI; or, the pixel pitch is 9000 to 13000 nanometers, and the pixel density of the display panel may be 404 PPI, 550 PPI, 668 PPI, 706 PPI, 756 PPI, 800 PPI, 850 PPI, 992 PPI, 1000 PPI, or 1025 PPI; or the pixel pitch is 13000 to 18000 nanometers, and the pixel density of the display panel may be 404 PPI, 460 PPI, 500 PPI, 668 PPI, 706 PPI, or 756 PPI.

Corresponding to the second pixel arrangement manner, the parameter change rule of the pixel pitch and the pixel density may be referred to FIG. 45, and as shown in FIG. 45, it can be seen that generally, along with a pixel pitch decreases, a pixel density corresponding to the pixel pitch increases; in the FIG. 45, two dashed lines represent an upper limit and a lower limit of a design of the pixel density corresponding to different pixel pitches, and a region between two solid lines represents a more appropriate selection range between the pixel pitch and the pixel density. For example, in this selection range, if the pixel pitch is designed to be 2000 nanometers, an appropriate selection range of the pixel density is 4200 to 5200 PPI; if the pixel pitch is designed to be 18000 nanometers, the appropriate selection range of the pixel density may be 260 to 576 PPI. Furthermore, in FIG. 45, according to a below dashed line, when the pixel pitch is 2000 nanometers, the lower limit of the pixel density is 176 PPI, and when the pixel pitch is 2000 nanometers, the lower limit of the pixel density is 144 PPI; according to an above dashed line, when the pixel pitch is 2000 nanometers, the upper limit of the pixel density is 5200 PPI; and when the pixel pitch 18000 nanometers, the upper limit of the pixel density is 688 PPI.

In some embodiments of the present application, the display panel further includes a pixel defining layer, where the pixel defining layer is located on the first electrode and located on a side, facing the substrate, of the partition portion and defines a second opening, the pixel defining layer covers an edge of the first electrode, the second opening exposes the first electrode, and an edge of the second opening coincides with an edge of a portion of the first electrode in contact with the light-emitting functional layer in a same light-emitting device, a distance between an orthographic projection, on a plane where the substrate is located, of the edge of the second end portion and an orthographic projection, on the plane where the substrate is located, of the edge of the first end portion is a first width, a distance between the edge of the portion of the first electrode in contact with the light-emitting functional layer in the same light-emitting device and the orthographic projection, on the plane where the substrate is located, of the edge of the second end portion is a first spacing, the plurality of sub-pixels in a pixel are arranged in a first pixel arrangement manner, and the pixel density of the display panel is 170 to 3143 PPI. For example, the pixel pitch is 2200 to 2500 nanometers, and the pixel density of the display panel is 2171 to 3143 PPI; or the pixel pitch is 2500 to 3200 nanometers, and the pixel density of the display panel is 1577 to 2765 PPI; or the pixel pitch is 3200 to 4000 nanometers, and the pixel density of the display panel is 1063 to 2160 PPI; or the pixel pitch is 4000 to 6000 nanometers, and the pixel density of the display panel is 529 to 1728 PPI; or the pixel pitch is 6000 to 9000 nanometers, and the pixel density of the display panel is 353 to 1152 PPI; or the pixel pitch is 9000 to 13000 nanometers, and the pixel density of the display panel is 244 to 768 PPI; or the pixel pitch is 13000 to 18000 nanometers, and the pixel density of the display panel is 170 to 531 PPI. In some embodiments of the present application, under the first pixel arrangement manner, the pixel pitch is 2000 to 2200 nanometers, and the pixel density of the display panel may be 2200 PPI, 2600 PPI, or 3000 PPI; or, the pixel pitch is 2500 to 3200 nanometers, and the pixel density of the display panel may be 1600 PPI, 1800 PPI, 2100 PPI, 2200 PPI, or 2600 PPI; or, the pixel pitch is 3200 to 4000 nanometers, and the pixel density of the display panel may be 1200 PPI, 1500 PPI, 1600 PPI, 1700 PPI, 1800 PPI, or 2100 PPI; or, the pixel pitch is 4000 to 6000 nanometers, and the pixel density of the display panel may be 600 PPI, 700 PPI, 847 PPI, 941 PPI, 1000 PPI, 1150 PPI, 1200 PPI, 1500 PPI, 1700 PPI; or, the pixel pitch is 6000 to 9000 nanometers, and the pixel density of the display panel may be 400 PPI, 550 PPI, 600 PPI, 661 PPI, 700 PPI, 706 PPI, 847 PPI, 941 PPI, 1000 PPI, 1150 PPI; or, the pixel pitch is 9000 to 13000 nanometers, and the pixel density of the display panel may be 300 PPI, 400 PPI, 446 PPI, 504 PPI, 550 PPI, 661 PPI, 706 PPI; or the pixel pitch is 13000 to 18000 nanometers, and the pixel density of the display panel may be 200 PPI, 300 PPI, 370 PPI, 400 PPI.

In some embodiments of the present application, the display panel further includes a pixel defining layer, where the pixel defining layer is located on the first electrode and located on a side, facing the substrate, of the partition portion and defines a second opening, the pixel defining layer covers an edge of the first electrode, the second opening exposes the first electrode, and an edge of the second opening coincides with an edge of a portion of the first electrode in contact with the light-emitting functional layer in a same light-emitting device, a distance between an orthographic projection, on a plane where the substrate is located, of the edge of the second end portion and an orthographic projection, on the plane where the substrate is located, of the edge of the first end portion is a first width, a distance between the edge of the portion of the first electrode in contact with the light-emitting functional layer in the same light-emitting device and the orthographic projection, on the plane where the substrate is located, of the edge of the second end portion is a first spacing, the plurality of sub-pixels in a pixel are arranged in a second pixel arrangement manner. For example, the pixel pitch is 2200 to 2500 nanometers, and the pixel density of the display panel is 3256 to 4714 PPI; or the pixel pitch is 2500 to 3200 nanometers, and the pixel density of the display panel is 2366 to 4147 PPI; or the pixel pitch is 3200 to 4000 nanometers, and the pixel density of the display panel is 1594 to 3240 PPI; or the pixel pitch is 4000 to 6000 nanometers, and the pixel density of the display panel is 794 to 2592 PPI; or the pixel pitch is 6000 to 9000 nanometers, and the pixel density of the display panel is 529 to 1728 PPI; or the pixel pitch is 9000 to 13000 nanometers, and the pixel density of the display panel is 366 to 1152 PPI; or the pixel pitch is 13000 to 18000 nanometers, and the pixel density of the display panel is 260 to 797 PPI.

In some embodiments of the present application, under the second pixel arrangement manner, the pixel pitch is 2200 to 2500 nanometers, and the pixel density of the display panel may be 3300 PPI, 3500 PPI, 4000 PPI, or 4600 PPI; or, the pixel pitch is 2500 to 3200 nanometers, and the pixel density of the display panel may be 2600 PPI, 2800 PPI, 3000 PPI, 3200 PPI, 3300 PPI, 3500 PPI, or 4000 PPI; or, the pixel pitch is 3200 to 4000 nanometers, and the pixel density of the display panel may be 1600 PPI, 1800 PPI, 2200 PPI, 2500 PPI, 2600 PPI, 2800 PPI, 3000 PPI, or 3200 PPI; or, the pixel pitch is 4000 to 6000 nanometers, and the pixel density of the display panel may be 850 PPI, 992 PPI, 1000 PPI, 1025 PPI, 1270 PPI, 1300 PPI, 1411 PPI, 1500 PPI, 1600 PPI, 1800 PPI, 2200 PPI, or 2500 PPI; or, the pixel pitch is 6000 to 9000 nanometers, and the pixel density of the display panel may be 550 PPI, 668 PPI, 756 PPI, 800 PPI, 850 PPI, 992 PPI, 1000 PPI, 1025 PPI, 1270 PPI, 1300 PPI, 1411 PPI, or 1500 PPI; or, the pixel pitch is 9000 to 13000 nanometers, and the pixel density of the display panel may be 404 PPI, 550 PPI, 668 PPI, 706 PPI, 756 PPI, 800 PPI, 850 PPI, 992 PPI, 1000 PPI, or 1025 PPI; or the pixel pitch is 13000 to 18000 nanometers, and the pixel density of the display panel may be 404 PPI, 460 PPI, 500 PPI, 668 PPI, 706 PPI, or 756 PPI.

In some embodiments of the present application, the pixel defining layer may not be included, the pixel pitch is 2000 to 2200 nanometers, and an average value of a width of a first sub-pixel, a width of a second sub-pixel and a width of a third sub-pixel is 450 to 1326 nanometers; or the pixel pitch is 2200 to 2500 nanometers, and the average value of the width of the first sub-pixel, the width of the second sub-pixel and the width of the third sub-pixel is 494 to 1700 nanometers; or the pixel pitch is 2500 to 3200 nanometers, and the average value of the width of the first sub-pixel, the width of the second sub-pixel and the width of the third sub-pixel is 563 to 2868 nanometers; or the pixel pitch is 3200 to 4000 nanometers, and the average value of the width of the first sub-pixel, the width of the second sub-pixel and the width of the third sub-pixel is 720 to 4767 nanometers; or the pixel pitch is 4000 to 6000 nanometers, and the average value of the width of the first sub-pixel, the width of the second sub-pixel and the width of the third sub-pixel is 900 to 11995 nanometers; or the pixel pitch is 6000 to 9000 nanometers, and the average value of the width of the first sub-pixel, the width of the second sub-pixel and the width of the third sub-pixel is 1350 to 18008 nanometers; or the pixel pitch is 9000 to 13000 nanometers, and the average value of the width of the first sub-pixel, the width of the second sub-pixel and the width of the third sub-pixel is 2025 to 25699 nanometers; or the pixel pitch is 13000 to 18000 nanometers, and the average value of the width of the first sub-pixel, the width of the second sub-pixel, and the width of the third sub-pixel is 4050 to 35846 nanometers.

In one embodiment, the pixel defining layer may be included, the pixel pitch is 2200 to 2500 nanometers, an average value of a width of the first sub-pixel, a width of the second sub-pixel and a width of the third sub-pixel is 494 to 1700 nanometers; or, the pixel pitch is 2500 to 3200 nanometers, the average value of the width of the first sub-pixel, the width of the second sub-pixel and the width of the third sub-pixel is 563 to 2868 nanometers; or, the pixel pitch is 3200 to 4000 nanometers, the average value of the width of the first sub-pixel, the width of the second sub-pixel and the width of the third sub-pixel is 720 to 4767 nanometers; or, the pixel pitch is 4000 to 6000 nanometers, the average value of the width of the first sub-pixel, the width of the second sub-pixel and the width of the third sub-pixel is 900 to 11995 nanometers; or, the pixel pitch is 6000 to 9000 nanometers, the average value of the width of the first sub-pixel, the width of the second sub-pixel and the width of the third sub-pixel is 1350 to 18008 nanometers; or, the pixel pitch is 9000 to 13000 nanometers, and the average value of the width of the first sub-pixel, the width of the second sub-pixel and the width of the third sub-pixel is 2025 to 25699 nanometers; or, the pixel pitch is 13000 to 18000 nanometers, the average value of the width of the first sub-pixel, the width of the second sub-pixel and the width of the third sub-pixel is 4050 to 35846 nanometers.

In one embodiment, based on above data, an aperture ratio of the display is 6 to 60%.

For example, the display panel further includes at least one optical functional layer, where the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases.

In at least one embodiment of the present application, the display panel further includes at least one optical functional layer, the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases. Corresponding to an embodiment in which the display panel does not include the pixel defining layer, for every two adjacent first electrodes, a pixel pitch between edges of a portion of the first electrode in contact with the light-emitting functional layer in same light-emitting device is 2074 to 18000 nanometers, and a pixel density of the display panel is 90 to 5000 PPI. Specifically, corresponding to an embodiment that the plurality of sub-pixels in a pixel are arranged according to the first pixel arrangement manner, the pixel pitch is 2074 to 18000 nanometers, and the pixel density of the display panel may be 90 to 3333 PPI; corresponding to an embodiment that the plurality of sub-pixels in a pixel are arranged according to the second pixel arrangement manner, the pixel pitch is 2074 to 18000 nanometers, and the pixel density of the display panel may be 135 to 5000 PPI.

In at least one embodiment of the present application, the display panel further includes at least one optical functional layer, the optical functional layer is located on a side, away from the substrate, of the light-emitting functional layer and includes a plurality of optical functional units located in the first opening, a thickness of an edge portion of each of at least one of the film layers of each of the plurality of optical functional units gradually decreases. In a case that the display panel includes the pixel defining layer, for every two adjacent first electrodes, a pixel pitch between edges of a portion of the first electrode in contact with the light-emitting functional layer in same light-emitting device is 2274 to 18000 nanometers, and a pixel density of the display panel is 90 to 4560 PPI. Specifically, corresponding to an embodiment that the plurality of sub-pixels in a pixel are arranged according to the first pixel arrangement manner, the pixel pitch is 2274 to 18000 nanometers, and the pixel density of the display panel may be 90 to 3040 PPI; corresponding to an embodiment that the plurality of sub-pixels in a pixel are arranged according to the second pixel arrangement manner, the pixel pitch is 2274 to 18000 nanometers, and the pixel density of the display panel may be 135 to 4560 PPI.

It should be noted that, for a specific type and a setting manner of the optical functional layer, refer to related descriptions in the foregoing embodiments, and details are not described herein again.

In some embodiments of the present application, under a design that the display panel is provided with the optical functional layer, the isolation structure is in direct contact with the substrate, and an edge of the first electrode is a boundary of a portion of the first electrode in contact with the light-emitting functional layer in a same light-emitting device.

In one embodiment, in a solution that the display panel is provided with the optical functional layer and the isolation structure is in direct contact with the substrate, the pixel pitch is 2225 to 2700 nanometers, a distance between the orthographic projection, on the plane where the substrate is located, of the edge of the first electrode and the orthographic projection, on the plane where the substrate is located, of the edge of the second end portion is 181 to 520 nanometers, and a distance between the orthographic projection, on the plane where the substrate is located, of the edge of the first end portion and the orthographic projection, on the plane where the substrate is located, of the edge of the second end portion is 148 to 477 nanometers. In an embodiment, the distance between the orthographic projection, on the plane where the substrate is located, of the edge of the first electrode and the orthographic projection, on the plane where the substrate is located, of the edge of the second end portion is 181 nanometers, and the distance between the orthographic projection, on the plane where the substrate is located, of the edge of the first end portion and the orthographic projection, on the plane where the substrate is located, of the edge of the second end portion is 148 nanometers.

In one embodiment, in a solution that the display panel is provided with the optical functional layer and the isolation structure is in direct contact with the substrate, the pixel pitch is 2296 to 3600 nanometers, a distance between the orthographic projection, on the plane where the substrate is located, of the edge of the first electrode and the orthographic projection, on the plane where the substrate is located, of the edge of the second end portion is 199 to 483 nanometers, and a distance between the orthographic projection, on the plane where the substrate is located, of the edge of the first end portion and the orthographic projection, on the plane where the substrate is located, of the edge of the second end portion is 166 to 450 nanometers.

In one embodiment, in a solution that the display panel is provided with the optical functional layer and the isolation structure is in direct contact with the substrate, the pixel pitch is 2372 to 4985 nanometers, a distance between the orthographic projection, on the plane where the substrate is located, of the edge of the first electrode and the orthographic projection, on the plane where the substrate is located, of the edge of the second end portion is 218 to 533 nanometers, and a distance between the orthographic projection, on the plane where the substrate is located, of the edge of the first end portion and the orthographic projection, on the plane where the substrate is located, of the edge of the second end portion is 185 to 500 nanometers.

In one embodiment, in a solution that the display panel is provided with the optical functional layer and the isolation structure is in direct contact with the substrate, the pixel pitch is 2516 to 7623 nanometers, a distance between the orthographic projection, on the plane where the substrate is located, of the edge of the first electrode and the orthographic projection, on the plane where the substrate is located, of the edge of the second end portion is 254 to 633 nanometers, and a distance between the orthographic projection, on the plane where the substrate is located, of the edge of the first end portion and the orthographic projection, on the plane where the substrate is located, of the edge of the second end portion is 221 to 600 nanometers.

In one embodiment, in a solution that the display panel is provided with the optical functional layer and the isolation structure is in direct contact with the substrate, the pixel pitch is 3092 to 12960 nanometers, a distance between the orthographic projection, on the plane where the substrate is located, of the edge of the first electrode and the orthographic projection, on the plane where the substrate is located, of the edge of the second end portion is 273 to 683 nanometers, and a distance between the orthographic projection, on the plane where the substrate is located, of the edge of the first end portion and the orthographic projection, on the plane where the substrate is located, of the edge of the second end portion is 240 to 650 nanometers.

In one embodiment, in a solution that the display panel is provided with the optical functional layer and the isolation structure is in direct contact with the substrate, the pixel pitch is 3168 to 18000 nanometers, a distance between the orthographic projection, on the plane where the substrate is located, of the edge of the first electrode and the orthographic projection, on the plane where the substrate is located, of the edge of the second end portion is 292 to 843 nanometers, and a distance between the orthographic projection, on the plane where the substrate is located, of the edge of the first end portion and the orthographic projection, on the plane where the substrate is located, of the edge of the second end portion is 259 to 810 nanometers.

For example, in a case that the display panel is provided with the optical functional layer and the isolation structure is in direct contact with the substrate, along the direction perpendicular to the plane where the substrate is located, a distance between the edge of the second end portion and the edge of the first end portion is a first height, the first height is 400 to 2200 nanometers. In one embodiment, the pixel pitch is 2225 to 2700 nanometers, the first height is 400 to 800 nanometers; or the pixel pitch is 2296 to 3600 nanometers, the first height is 450 to 850 nanometers; or the pixel pitch is 2372 to 4985 nanometers, the first height is 500 to 900 nanometers; or the pixel pitch is 2516 to 7623 nanometers, the first height is 600 to 1000 nanometers; or the pixel pitch is 3092 to 12960 nanometers, the first height is 650 to 1200 nanometers; or the pixel pitch is 3168 to 18000 nanometers, the first height is 700 to 2200 nanometers.

For example, in a solution that the display panel is provided with the optical functional layer and the isolation structure is in direct contact with the substrate, the pixel pitch is 2225 to 2700 nanometers, a distance between the orthographic projection, on the plane where the substrate is located, of the edge of the first electrode and the orthographic projection, on the plane where the substrate is located, of the edge of the second end portion is 181 to 520 nanometers, and a distance between the orthographic projection, on the plane where the substrate is located, of the edge of the first end portion and the orthographic projection, on the plane where the substrate is located, of the edge of the second end portion is 148 to 477 nanometers, a first height is 400 to 800 nanometers.

For example, in a solution that the display panel is provided with the optical functional layer and the isolation structure is in direct contact with the substrate, the pixel pitch is 2296 to 3600 nanometers, a distance between the orthographic projection, on the plane where the substrate is located, of the edge of the first electrode and the orthographic projection, on the plane where the substrate is located, of the edge of the second end portion is 199 to 483 nanometers, and a distance between the orthographic projection, on the plane where the substrate is located, of the edge of the first end portion and the orthographic projection, on the plane where the substrate is located, of the edge of the second end portion is 166 to 450 nanometers, a first height is 450 to 850 nanometers.

For example, in a solution that the display panel is provided with the optical functional layer and the isolation structure is in direct contact with the substrate, the pixel pitch is 2372 to 4985 nanometers, a distance between the orthographic projection, on the plane where the substrate is located, of the edge of the first electrode and the orthographic projection, on the plane where the substrate is located, of the edge of the second end portion is 218 to 533 nanometers, and a distance between the orthographic projection, on the plane where the substrate is located, of the edge of the first end portion and the orthographic projection, on the plane where the substrate is located, of the edge of the second end portion is 185 to 500 nanometers, a first height is 500 to 900 nanometers.

For example, in a solution that the display panel is provided with the optical functional layer and the isolation structure is in direct contact with the substrate, the pixel pitch is 2516 to 7623 nanometers, a distance between the orthographic projection, on the plane where the substrate is located, of the edge of the first electrode and the orthographic projection, on the plane where the substrate is located, of the edge of the second end portion is 254 to 633 nanometers, and a distance between the orthographic projection, on the plane where the substrate is located, of the edge of the first end portion and the orthographic projection, on the plane where the substrate is located, of the edge of the second end portion is 221 to 600 nanometers, a first height is 600 to 1000 nanometers.

For example, in a solution that the display panel is provided with the optical functional layer and the isolation structure is in direct contact with the substrate, the pixel pitch is 3092 to 12960 nanometers, a distance between the orthographic projection, on the plane where the substrate is located, of the edge of the first electrode and the orthographic projection, on the plane where the substrate is located, of the edge of the second end portion is 273 to 683 nanometers, and a distance between the orthographic projection, on the plane where the substrate is located, of the edge of the first end portion and the orthographic projection, on the plane where the substrate is located, of the edge of the second end portion is 240 to 650 nanometers, a first height is 650 to 1200 nanometers.

For example, in a solution that the display panel is provided with the optical functional layer and the isolation structure is in direct contact with the substrate, the pixel pitch is 3168 to 18000 nanometers, a distance between the orthographic projection, on the plane where the substrate is located, of the edge of the first electrode and the orthographic projection, on the plane where the substrate is located, of the edge of the second end portion is 292 to 843 nanometers, and a distance between the orthographic projection, on the plane where the substrate is located, of the edge of the first end portion and the orthographic projection, on the plane where the substrate is located, of the edge of the second end portion is 259 to 810 nanometers, a first height is 700 to 2200 nanometers.

In one embodiment, in a solution that the display panel is provided with the optical functional layer and the isolation structure is in direct contact with the substrate, the pixel pitch is 2225 to 2700 nanometers, a distance between the orthographic projection, on the plane where the substrate is located, of the edge of the first electrode and the orthographic projection, on the plane where the substrate is located, of the edge of the second end portion is 181 to 520 nanometers, and a distance between the orthographic projection, on the plane where the substrate is located, of the edge of the first end portion and the orthographic projection, on the plane where the substrate is located, of the edge of the second end portion is 148 to 477 nanometers, a first height is 400 to 800 nanometers.

For example, in a solution that the display panel is provided with the optical functional layer and the isolation structure is in direct contact with the substrate, the pixel pitch is 2296 to 3600 nanometers, a distance between the orthographic projection, on the plane where the substrate is located, of the edge of the first electrode and the orthographic projection, on the plane where the substrate is located, of the edge of the second end portion is 199 to 483 nanometers, and a distance between the orthographic projection, on the plane where the substrate is located, of the edge of the first end portion and the orthographic projection, on the plane where the substrate is located, of the edge of the second end portion is 166 to 450 nanometers, a first height is 450 to 850 nanometers.

For example, in a solution that the display panel is provided with the optical functional layer and the isolation structure is in direct contact with the substrate, the pixel pitch is 2372 to 4985 nanometers, a distance between the orthographic projection, on the plane where the substrate is located, of the edge of the first electrode and the orthographic projection, on the plane where the substrate is located, of the edge of the second end portion is 218 to 533 nanometers, and a distance between the orthographic projection, on the plane where the substrate is located, of the edge of the first end portion and the orthographic projection, on the plane where the substrate is located, of the edge of the second end portion is 185 to 500 nanometers, a first height is 500 to 900 nanometers.

For example, in a solution that the display panel is provided with the optical functional layer and the isolation structure is in direct contact with the substrate, the pixel pitch is 2516 to 7623 nanometers, a distance between the orthographic projection, on the plane where the substrate is located, of the edge of the first electrode and the orthographic projection, on the plane where the substrate is located, of the edge of the second end portion is 254 to 633 nanometers, and a distance between the orthographic projection, on the plane where the substrate is located, of the edge of the first end portion and the orthographic projection, on the plane where the substrate is located, of the edge of the second end portion is 221 to 600 nanometers, a first height is 600 to 1000 nanometers.

For example, in a solution that the display panel is provided with the optical functional layer and the isolation structure is in direct contact with the substrate, the pixel pitch is 3092 to 12960 nanometers, a distance between the orthographic projection, on the plane where the substrate is located, of the edge of the first electrode and the orthographic projection, on the plane where the substrate is located, of the edge of the second end portion is 273 to 683 nanometers, and a distance between the orthographic projection, on the plane where the substrate is located, of the edge of the first end portion and the orthographic projection, on the plane where the substrate is located, of the edge of the second end portion is 240 to 650 nanometers, a first height is 650 to 1200 nanometers.

For example, in a solution that the display panel is provided with the optical functional layer and the isolation structure is in direct contact with the substrate, the pixel pitch is 3168 to 18000 nanometers, a distance between the orthographic projection, on the plane where the substrate is located, of the edge of the first electrode and the orthographic projection, on the plane where the substrate is located, of the edge of the second end portion is 292 to 843 nanometers, and a distance between the orthographic projection, on the plane where the substrate is located, of the edge of the first end portion and the orthographic projection, on the plane where the substrate is located, of the edge of the second end portion is 259 to 810 nanometers, a first height is 700 to 2200 nanometers.

In some other embodiments of the present application, there is another design under a solution that the display panel is provided with the optical functional layer, where, the display panel further includes a pixel defining layer, the pixel defining layer is located on the first electrode and located on a side, facing the substrate, of the partition portion and defines a second opening, the pixel defining layer covers an edge of the first electrode, the second opening exposes the first electrode, and an edge of the second opening coincides with an edge of a portion of the first electrode in contact with the light-emitting functional layer in a same light-emitting device.

In one embodiment, in a solution that the display panel is provided with the optical functional layer and the display panel further includes the pixel defining layer, the pixel pitch is 2576 to 2700 nanometers, a distance between an orthographic projection, on the plane where the substrate is located, of the edge of the second opening and the orthographic projection, on the plane where the substrate is located, of the edge of the second end portion is 292 to 659 nanometers, and a distance between the orthographic projection, on the plane where the substrate is located, of the edge of the first end portion and the orthographic projection, on the plane where the substrate is located, of the edge of the second end portion is 181 to 510 nanometers.

In one embodiment, in a solution that the display panel is provided with the optical functional layer and the display panel further includes the pixel defining layer, the pixel pitch is 2517 to 3600 nanometers, a distance between an orthographic projection, on the plane where the substrate is located, of the edge of the second opening and the orthographic projection, on the plane where the substrate is located, of the edge of the second end portion is 309 to 688 nanometers, and a distance between the orthographic projection, on the plane where the substrate is located, of the edge of the first end portion and the orthographic projection, on the plane where the substrate is located, of the edge of the second end portion is 199 to 483 nanometers.

In one embodiment, in a solution that the display panel is provided with the optical functional layer and the display panel further includes the pixel defining layer, the pixel pitch is 2592 to 4985 nanometers, a distance between an orthographic projection, on the plane where the substrate is located, of the edge of the second opening and the orthographic projection, on the plane where the substrate is located, of the edge of the second end portion is 328 to 718 nanometers, and a distance between the orthographic projection, on the plane where the substrate is located, of the edge of the first end portion and the orthographic projection, on the plane where the substrate is located, of the edge of the second end portion is 218 to 533 nanometers.

In one embodiment, in a solution that the display panel is provided with the optical functional layer and the display panel further includes the pixel defining layer, the pixel pitch is 3736 to 7623 nanometers, a distance between an orthographic projection, on the plane where the substrate is located, of the edge of the second opening and the orthographic projection, on the plane where the substrate is located, of the edge of the second end portion is 364 to 818 nanometers, and a distance between the orthographic projection, on the plane where the substrate is located, of the edge of the first end portion and the orthographic projection, on the plane where the substrate is located, of the edge of the second end portion is 254 to 633 nanometers.

In one embodiment, in a solution that the display panel is provided with the optical functional layer and the display panel further includes the pixel defining layer, the pixel pitch is 3312 to 12960 nanometers, a distance between an orthographic projection, on the plane where the substrate is located, of the edge of the second opening and the orthographic projection, on the plane where the substrate is located, of the edge of the second end portion is 383 to 858 nanometers, and a distance between the orthographic projection, on the plane where the substrate is located, of the edge of the first end portion and the orthographic projection, on the plane where the substrate is located, of the edge of the second end portion is 273 to 683 nanometers.

In one embodiment, in a solution that the display panel is provided with the optical functional layer and the display panel further includes the pixel defining layer, the pixel pitch is 3388 to 18000 nanometers, a distance between an orthographic projection, on the plane where the substrate is located, of the edge of the second opening and the orthographic projection, on the plane where the substrate is located, of the edge of the second end portion is 403 to 1028 nanometers, and a distance between the orthographic projection, on the plane where the substrate is located, of the edge of the first end portion and the orthographic projection, on the plane where the substrate is located, of the edge of the second end portion is 292 to 843 nanometers.

For example, in a case that the display panel is provided with the optical functional layer and the display panel further includes the pixel defining layer, along the direction perpendicular to the plane where the substrate is located, a distance between the edge of the second end portion and the edge of the first end portion is a first height, the first height is 400 to 2200 nanometers. In one embodiment, the pixel pitch is 2299 to 2700 nanometers, the first height is 450 to 800 nanometers; or, the pixel pitch is 2370 to 3600 nanometers, the first height is 500 to 850 nanometers; or, the pixel pitch is 2446 to 4985 nanometers, the first height is 550 to 900 nanometers; or, the pixel pitch is 2649 to 7623 nanometers, the first height is 690 to 1000 nanometers; or, the pixel pitch is 3270 to 12960 nanometers, the first height is 770 to 1200 nanometers; or, the pixel pitch is 3390 to 18000 nanometers, the first height is 850 to 2200 nanometers.

For example, in a solution that the display panel is provided with the optical functional layer and the display panel further includes the pixel defining layer, the pixel pitch is 2299 to 2700 nanometers, a distance between an orthographic projection, on the plane where the substrate is located, of the edge of the second opening and the orthographic projection, on the plane where the substrate is located, of the edge of the second end portion is 200 to 460 nanometers, and a distance between the orthographic projection, on the plane where the substrate is located, of the edge of the first end portion and the orthographic projection, on the plane where the substrate is located, of the edge of the second end portion is 167 to 417 nanometers.

For example, in a solution that the display panel is provided with the optical functional layer and the display panel further includes the pixel defining layer, the pixel pitch is 2370 to 3600 nanometers, a distance between an orthographic projection, on the plane where the substrate is located, of the edge of the second opening and the orthographic projection, on the plane where the substrate is located, of the edge of the second end portion is 218 to 483 nanometers, and a distance between the orthographic projection, on the plane where the substrate is located, of the edge of the first end portion and the orthographic projection, on the plane where the substrate is located, of the edge of the second end portion is 185 to 450 nanometers, a first height is 500 to 850 nanometers.

For example, in a solution that the display panel is provided with the optical functional layer and the display panel further includes the pixel defining layer, the pixel pitch is 2446 to 4985 nanometers, a distance between an orthographic projection, on the plane where the substrate is located, of the edge of the second opening and the orthographic projection, on the plane where the substrate is located, of the edge of the second end portion is 237 to 533 nanometers, and a distance between the orthographic projection, on the plane where the substrate is located, of the edge of the first end portion and the orthographic projection, on the plane where the substrate is located, of the edge of the second end portion is 204 to 500 nanometers, a first height is 550 to 900 nanometers.

For example, in a solution that the display panel is provided with the optical functional layer and the display panel further includes the pixel defining layer, the pixel pitch is 2649 to 7623 nanometers, a distance between an orthographic projection, on the plane where the substrate is located, of the edge of the second opening and the orthographic projection, on the plane where the substrate is located, of the edge of the second end portion is 287 to 633 nanometers, and a distance between the orthographic projection, on the plane where the substrate is located, of the edge of the first end portion and the orthographic projection, on the plane where the substrate is located, of the edge of the second end portion is 254 to 600 nanometers, a first height is 690 to 1000 nanometers.

For example, in a solution that the display panel is provided with the optical functional layer and the display panel further includes the pixel defining layer, the pixel pitch is 3270 to 12960 nanometers, a distance between an orthographic projection, on the plane where the substrate is located, of the edge of the second opening and the orthographic projection, on the plane where the substrate is located, of the edge of the second end portion is 317 to 683 nanometers, and a distance between the orthographic projection, on the plane where the substrate is located, of the edge of the first end portion and the orthographic projection, on the plane where the substrate is located, of the edge of the second end portion is 284 to 650 nanometers, a first height is 770 to 1200 nanometers.

For example, in a solution that the display panel is provided with the optical functional layer and the display panel further includes the pixel defining layer, the pixel pitch is 3390 to 18000 nanometers, a distance between an orthographic projection, on the plane where the substrate is located, of the edge of the second opening and the orthographic projection, on the plane where the substrate is located, of the edge of the second end portion is 348 to 843 nanometers, and a distance between the orthographic projection, on the plane where the substrate is located, of the edge of the first end portion and the orthographic projection, on the plane where the substrate is located, of the edge of the second end portion is 315 to 810 nanometers, a first height is 850 to 2200 nanometers.

For example, in a solution that the display panel is provided with the optical functional layer and the display panel further includes the pixel defining layer, the pixel pitch is 2299 to 2700 nanometers, a distance between an orthographic projection, on the plane where the substrate is located, of the edge of the second opening and the orthographic projection, on the plane where the substrate is located, of the edge of the second end portion is 200 to 460 nanometers, and a distance between the orthographic projection, on the plane where the substrate is located, of the edge of the first end portion and the orthographic projection, on the plane where the substrate is located, of the edge of the second end portion is 167 to 417 nanometers, a first height is 450 to 800 nanometers.

For example, in a solution that the display panel is provided with the optical functional layer and the display panel further includes the pixel defining layer, the pixel pitch is 2370 to 3600 nanometers, a distance between an orthographic projection, on the plane where the substrate is located, of the edge of the second opening and the orthographic projection, on the plane where the substrate is located, of the edge of the second end portion is 218 to 483 nanometers, and a distance between the orthographic projection, on the plane where the substrate is located, of the edge of the first end portion and the orthographic projection, on the plane where the substrate is located, of the edge of the second end portion is 185 to 450 nanometers, a first height is 500 to 850 nanometers.

For example, in a solution that the display panel is provided with the optical functional layer and the display panel further includes the pixel defining layer, the pixel pitch is 2446 to 4985 nanometers, a distance between an orthographic projection, on the plane where the substrate is located, of the edge of the second opening and the orthographic projection, on the plane where the substrate is located, of the edge of the second end portion is 237 to 533 nanometers, and a distance between the orthographic projection, on the plane where the substrate is located, of the edge of the first end portion and the orthographic projection, on the plane where the substrate is located, of the edge of the second end portion is 204 to 500 nanometers, a first height is 550 to 900 nanometers.

For example, in a solution that the display panel is provided with the optical functional layer and the display panel further includes the pixel defining layer, the pixel pitch is 2649 to 7623 nanometers, a distance between an orthographic projection, on the plane where the substrate is located, of the edge of the second opening and the orthographic projection, on the plane where the substrate is located, of the edge of the second end portion is 287 to 633 nanometers, and a distance between the orthographic projection, on the plane where the substrate is located, of the edge of the first end portion and the orthographic projection, on the plane where the substrate is located, of the edge of the second end portion is 254 to 600 nanometers, a first height is 690 to 1000 nanometers.

For example, in a solution that the display panel is provided with the optical functional layer and the display panel further includes the pixel defining layer, the pixel pitch is 3270 to 12960 nanometers, a distance between an orthographic projection, on the plane where the substrate is located, of the edge of the second opening and the orthographic projection, on the plane where the substrate is located, of the edge of the second end portion is 317 to 683 nanometers, and a distance between the orthographic projection, on the plane where the substrate is located, of the edge of the first end portion and the orthographic projection, on the plane where the substrate is located, of the edge of the second end portion is 284 to 650 nanometers, a first height is 770 to 1200 nanometers.

For example, in a solution that the display panel is provided with the optical functional layer and the display panel further includes the pixel defining layer, the pixel pitch is 3390 to 18000 nanometers, a distance between an orthographic projection, on the plane where the substrate is located, of the edge of the second opening and the orthographic projection, on the plane where the substrate is located, of the edge of the second end portion is 348 to 843 nanometers, and a distance between the orthographic projection, on the plane where the substrate is located, of the edge of the first end portion and the orthographic projection, on the plane where the substrate is located, of the edge of the second end portion is 315 to 810 nanometers, a first height is 850 to 2200 nanometers.

At least one embodiment of the present application provides a display panel, the display panel includes a substrate, an isolation structure and a display functional layer, the isolation structure includes a partition portion, the isolation structure defines a plurality of first openings, the display functional layer includes a plurality of light-emitting devices, each light-emitting device of the plurality of light-emitting devices is located in a first opening, corresponding to the light-emitting device, of the plurality of first openings, the light-emitting device includes a first electrode, a light-emitting functional layer and a second electrode stacked on the substrate, and a pixel density of the display panel is 200 PPI to 7400 PPI.

In one embodiment, the pixel pitch between edges of contact portions in adjacent light-emitting devices is 2000 to 18000 nanometers, where a contact portion is a portion that the first electrode in contact with a corresponding light-emitting functional layer.

In one embodiment, the pixel density of the display panel is 200 to 7400 PPI. In one embodiment, the pixel pitch is 2000 to 2200 nanometers, and the pixel density of the display panel is 249 to 7400 PPI; or, the pixel pitch is 2200 to 2500 nanometers, and the pixel density of the display panel is 248 to 6778 PPI; or, the pixel pitch is 2500 to 3200 nanometers, and the pixel density of the display panel is 245 to 6088 PPI; or, the pixel pitch is 3200 to 4000 nanometers, and the pixel density of the display panel is 243 to 4921 PPI; or, the pixel pitch is 4000 to 6000 nanometers, and the pixel density of the display panel is 236 to 4036 PPI; or, the pixel pitch is 6000 to 9000 nanometers, and the pixel density of the display panel is 227 to 2785 PPI; or the pixel pitch is 9000 to 13000 nanometers, and the pixel density of the display panel is 216 to 1901 PPI; or the pixel pitch is 13000 to 16500 nanometers, and the pixel density of the display panel is 208 to 1335 PPI; or the pixel pitch is 16500 to 18000 nanometers, and the pixel density of the display panel is 200 to 1060 PPI.

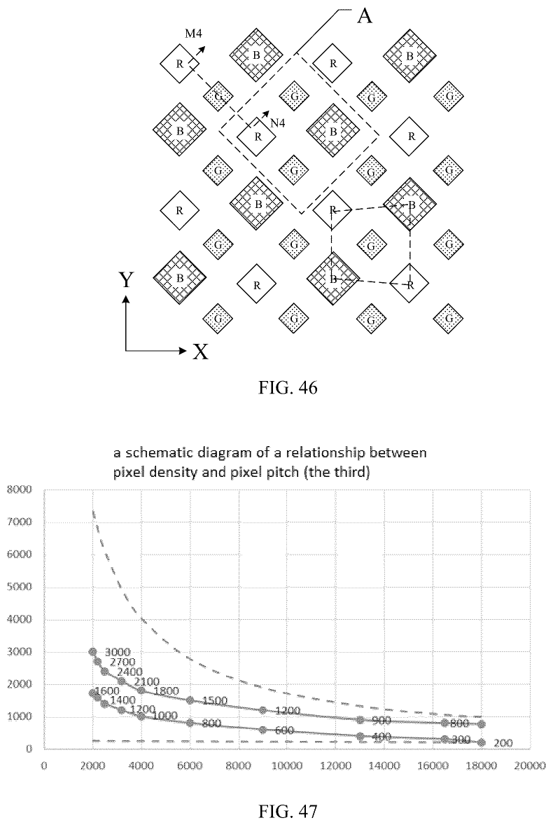

In one embodiment, as shown in FIG. 46, every two pixels form a repeating unit A, and the plurality of repeating units A are arranged in a plurality of rows and a plurality of columns to complete arrangement of all sub-pixels. In each repeating unit A, there is one first sub-pixel R, two second sub-pixels G and one third sub-pixel B, the two second sub-pixels G respectively belong to two pixels, and the two pixels share the first sub-pixel R and the one third sub-pixel B.

Corresponding to a pixel arrangement manner shown in FIG. 46, a change rule of parameters of the pixel pitch and the pixel density may be referred to FIG. 47, it can be seen that generally, along with the pixel pitch decreases, the pixel density corresponding to the pixel pitch increases; in the FIG. 47, two dashed lines represent an upper limit and a lower limit of a design of the pixel density corresponding to different pixel pitches, and a region between two solid lines represents a more appropriate selection range between the pixel pitch and the pixel density. For example, in this selection range, if the pixel pitch is designed to be 2000 nanometers, an appropriate selection range of the pixel density is 1700 to 3000 PPI; if the pixel pitch is designed to be 18000 nanometers, the appropriate selection range of the pixel density may be 200 to 750 PPI. Furthermore, in FIG. 47, according to a below dashed line, when the pixel pitch is 2000 nanometers, the lower limit of the pixel density is 249 PPI, and when the pixel pitch is 2000 nanometers, the lower limit of the pixel density is 249 PPI; according to an above dashed line, when the pixel pitch is 18000 nanometers, the upper limit of the pixel density is 7400 PPI; and when the pixel pitch 18000 nanometers, the upper limit of the pixel density is 973 PPI.

In one embodiment, for the pixel arrangement manner shown in FIG. 46, the pixel pitch is 2000 to 2200 nanometers, and the pixel density of the display panel is 1600 to 3000 PPI; or, the pixel pitch is 2200 to 2500 nanometers, and the pixel density of the display panel is 1400 to 2700 PPI; or, the pixel pitch is 2500 to 3200 nanometers, and the pixel density of the display panel is 1200 to 2400 PPI; or, the pixel pitch is 3200 to 4000 nanometers, and the pixel density of the display panel is 1000 to 2100 PPI; or, the pixel pitch is 4000 to 6000 nanometers, and the pixel density of the display panel is 800 to 1800 PPI; or, the pixel pitch is 6000 to 9000 nanometers, and the pixel density of the display panel is 600 to 1500 PPI; or the pixel pitch is 9000 to 13000 nanometers, and the pixel density of the display panel is 400 to 1200 PPI; or the pixel pitch is 13000 to 16500 nanometers, and the pixel density of the display panel is 300 to 900 PPI; or the pixel pitch is 16500 to 18000 nanometers, and the pixel density of the display panel is 200 to 800 PPI

In some embodiments of the present application, in the pixel arrangement manner shown in FIG. 46, the pixel pitch is 2000 to 2000 nanometers, and the pixel density of the display panel may be 1600 PPI, 2000 PPI, 2500 PPI, or 3000 PPI; or the pixel pitch is 2200 to 2500 nanometers, and the pixel density of the display panel may be 1500 PPI, 1800 PPI, 2200 PPI, or 2700 PPI; or, the pixel pitch is 2500 to 3200 nanometers, and the pixel density of the display panel may be 1200 PPI, 1800 PPI, or 2400 PPI; or the pixel pitch is 3200 to 4000 nanometers, and the pixel density of the display panel may be 1000 PPI, 1800 PPI, or 2100 PPI; or, the pixel pitch is 4000 to 6000 nanometers, and the pixel density of the display panel may be 850 PPI, 1000 PPI, 1300 PPI, 1500 PPI, 1600 PPI, or 1800 PPI; or, the pixel pitch is 6000 to 9000 nanometers, and the pixel density of the display panel may be 600 PPI, 800 PPI, 850 PPI, 1000 PPI, 1200 PPI, or 1500 PPI; or, the pixel pitch is 9000 to 13000 nanometers, and the pixel density of the display panel may be 404 PPI, 550 PPI, 668 PPI, 706 PPI, 756 PPI, 800 PPI, 850 PPI, 992 PPI, 1000 PPI, or 1200 PPI; or, the pixel pitch is 13000 to 16500 nanometers, and the pixel density of the display panel may be 404 PPI, 460 PPI, 500 PPI, 668 PPI, 706 PPI, or 900 PPI; or the pixel pitch is 16500 to 18000 nanometers, and the pixel density of the display panel may be 200 PPI, 300 PPI, 500 PPI, 668 PPI, 706 PPI, or 900 PPI.

In the embodiment of the present application above-mentioned, the pixel pitch may be reduced to increase the pixel density of the display panel based on the isolation structure. Furthermore, in the display panel, each sub-pixel needs to be provided with a pixel driving circuit at a corresponding position on the substrate to drive each sub-pixel to emit light, and in a case that the pixel driving circuit is relatively complex and a large area is required, it may cause the display panel to need to have a larger size, which limits an improvement of the pixel density.

For example, in some embodiments of the present application, an occupied area of each thin film transistor in the pixel driving circuit on a plane can be reduced to reduce an area required by the pixel driving circuit, for example, the occupied area of at least one of thin film transistors in the pixel driving circuit on the plane is reduced. If only a volume of the thin film transistor is reduced, which will cause the display panel has an abnormal display condition, a main reason of the abnormal display condition is that a pixel gray scale is not easy to switch, and a pixel gray scale switching is closely related to a sub-threshold slope (SS) value of the thin film transistor, and the larger the SS value is, the more easy to switch the gray scale of the pixel, where the SS value is also referred to as a sub-threshold swing, which is defined as a gate voltage that needs to be increased by increasing a drain current of the sub-threshold region by an order of magnitude, reflecting a conversion straightness of a current from an off state to an on state. The SS value is positively correlated with a channel length of the thin film transistor, if the SS value needs to be increased, the channel length needs to be increased and the occupied area of the thin film transistor on the plane is increased, which is not benefited to improve the pixel density of the display panel.

In some embodiments of the present application, for at least one of the thin film transistors in the pixel driving circuit, a channel of the thin film transistor may be designed as a non-linear shape to reduce the occupied area (for example, an area of an orthographic projection, on a plane where the substrate is located, of the channel) without changing or even increasing a total channel length, for example, the channel may be configured to include a protruding portion, and the protruding portion protrudes towards a defense line away from the substrate, and an overall formation of the channel is represented as a non-linear shape such as a bending shape, an arc shape, and the like.

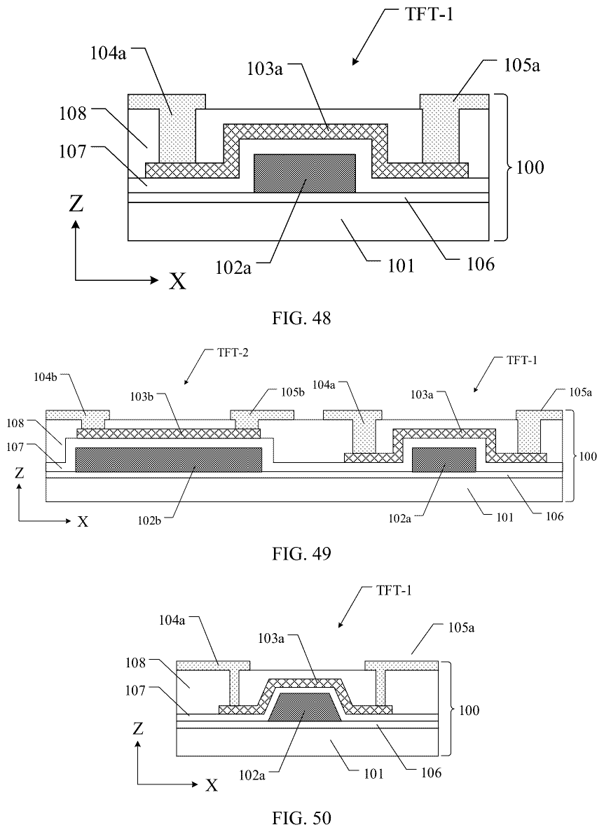

For example, as shown in FIG. 48, a pixel driving circuit of the display panel includes a first-type thin film transistor TFT-1, the first-type thin film transistor TFT-1 includes a first gate electrode 102a, a first semiconductor layer 103a, a first source electrode 104a, and a first drain electrode 105a disposed on a substrate 101. The first semiconductor layer 103a is located on a side, facing away from the substrate 101, of the first gate electrode 102a, a gate insulating layer 106 is disposed between the first semiconductor layer 103a and the first gate electrode 102a, limited by a thickness of the first gate electrode 102a, a portion, covering the first gate electrode 102a, of the gate insulating layer 106 is conformal with the first gate electrode 102a to form a convex surface, and the convex surface includes a top surface (conformal with a surface, facing away from the substrate 101, of the first gate electrode 102a) facing away from the substrate 101 and a side surface (conformal with a sidewall of the first gate electrode 102a) connected to the top surface. The first semiconductor layer 103a covers the convex surface to be conformal with the convex surface to form a protruding portion, and the protruding portion may increase an overall length of the first semiconductor layer 103a without changing a planar area occupied by the first semiconductor layer 103a, and correspondingly, the planar area occupied by the first semiconductor layer 103a may also be reduced while increasing or not changing the overall length of the first semiconductor layer 103a, thereby reducing a planar area of the first-type thin film transistor TFT-1.

It should be noted that the “planar area” may be an area of an orthographic projection, on the substrate or a plane where the substrate is located, of the target object.

As shown in FIG. 48, the first semiconductor layer 103a includes a first source region, a first drain region, and a first channel region located between the first source region and the first drain region, the first source region of the first semiconductor layer 103a is configured to be connected to the first source electrode 104a, a first drain region of the first semiconductor layer 103a is configured to be connected to the first drain electrode 105a, an orthographic projection, on the plane where the substrate 101 is located, of the first source region (or the first source electrode 104a) and an orthographic projection, on the plane where the substrate 101 is located, of the first drain region (or the first drain electrode 105a) are located outside an orthographic projection, on the plane where the substrate 101 is located, of the first gate electrode 102a, and the orthographic projection, on the plane where the substrate 101 is located, of the first gate electrode 102a is located between the orthographic projection, on the plane where the substrate 101 is located, of the first source region (or the first source electrode 104a) and the orthographic projection, on the plane where the substrate 101 is located, of the first drain region (or the first drain electrode 105a).

It should be noted that, in the embodiments of the present application, all the thin film transistors of the pixel driving circuit may be designed as the first-type thin film transistor TFT-1 above-described, or at least one of the thin film transistors of the pixel driving circuit may be designed as the first type thin film transistor TFT-1 above-described, while other thin film transistors are designed as thin film transistors with other types (denoted as a second-type thin film transistor).

For example, in some embodiments of the present application, as shown in FIG. 49, a second-type thin film transistor TFT-2 includes a second gate electrode 102b, a second semiconductor layer 103b, a second source electrode 104b, and a second drain electrode 105b disposed on a substrate 101. The second semiconductor layer 103b is located on a side, facing away from the substrate 101, of the second gate electrode 102b, limited by a thickness of the second gate electrode 102b, a portion, covering the second gate electrode 102b, of the gate insulating layer 106 is conformal with the second gate electrode 102b to form a convex surface, and the convex surface includes a top surface (conformal with a surface, facing away from the substrate 101, of the second gate electrode 102b) facing away from the substrate 101 and a side surface (conformal with a sidewall of the second gate electrode 102b) connected to the top surface, the second semiconductor layer 103b is located on the top surface. The second semiconductor layer 103b includes a second source region, a second drain region, and a second channel region located between the second source region and the second drain region, the second source region of the second semiconductor layer 103b is configured to be connected to the second source electrode 104b, the second drain region of the second semiconductor layer 103b is configured to be connected to the second drain electrode 105b, while an orthographic projection, on a plane where the substrate 101 is located, of the second source region (or the second source electrode 104b) and an orthographic projection, on the plane where the substrate 101 is located, of the second drain region (or the second drain electrode 105b) is located within an orthographic projection, on the plane where the substrate 101 is located, of the second gate electrode 102b, and an orthographic projection, on the plane where the substrate 101 is located, of the second semiconductor layer 103b coincides with the orthographic projection, on the plane where the substrate 101 is located, of the second gate electrode 102b, or located within the orthographic projection, on the plane where the substrate 101 is located, of the second gate electrode 102b.

As shown in FIG. 49, by comparing the first-type thin film transistor TFT-1 with the second-type thin film transistor TFT-2, it can be seen that, if a length of the first channel in the first-type thin film transistor TFT-1 equal to a length of the second channel in the second-type thin film transistor TFT-2, a spacing between the first source region and the first drain region in the first-type thin film transistor TFT-1 along a direction parallel to the plane where the substrate 101 is located is less than a spacing between the second source region and the second drain region in the second-type thin film transistor TFT-2 along the direction parallel to the plane where the substrate 101 is located, that is, an area of an orthographic projection, on the plane where the substrate 101 is located, of the first-type thin film transistor TFT-1 is smaller than an area of an orthographic projection, on the plane where the substrate 101 is located, of the second-type thin film transistor TFT-2.

It should be noted that, in at least one embodiment of the present application, the second-type thin film transistor TFT-2 may be designed as a bottom gate type thin film transistor shown in FIG. 49, or a position of the second gate electrode may be moved to an upper side of the second semiconductor layer to form a top gate type thin film transistor.

In at least one embodiment of the present application, in a case that the pixel driving circuit includes both the first-type thin film transistor and the second-type thin film transistor, and the second gate electrode in the second-type thin film transistor is located before the second semiconductor layer and the substrate, at least one of the film layers respectively included in the first-type thin film transistor and the second-type thin film transistor may be formed on same layer and made of same materials. For example, the first gate electrode 102a and the second gate electrode 102b are on same layer and made of same materials; and/or the first semiconductor layer 103a and the second semiconductor layer 103b are on same layer and made of same material; and/or the first source electrode 104a and the second source electrode 104b are in same layer and made of same material; and the first drain electrode 105a and the second drain electrode 105b are in the same layer and made of the same material.

It should be noted that a shape of the channel region of the first semiconductor layer is affected by a shape of the first gate electrode, and in the embodiments of the present application, the shape of the first gate electrode is not limited and may be designed according to the requirements of the actual process. For example, in some embodiments of the present application, a cross-sectional profile of the first gate electrode 102a is rectangular in a direction perpendicular to the plane where the substrate 100 is located and along an extension direction of the first semiconductor layer 103a (for example, a direction from the first source electrode 104a to the first drain electrode 105a). For example, in some other embodiments of the present application, as shown in FIG. 50, a cross-sectional profile of the first gate electrode 102a is a regular trapezoid in a direction perpendicular to the plane where the substrate 100 is located and along an extension direction of the first semiconductor layer 103a (for example, a direction from the first source electrode 104a to the first drain electrode 105a), and a top edge of the regular trapezoid facing the substrate 101, and a portion, covering a side edge of the first gate electrode 102a (a waist of the regular trapezoid), of a gate insulating layer 106 may have a certain slope, thereby facilitating an extension of the first semiconductor layer 103a in this region.

In the embodiment of the present application, a type of the sub-pixel in the pixel, a number of sub-pixels of each type, and a specific arrangement manner are not limited in the embodiment of the present application, and a pixel density of the display panel may be calculated according to above different choices.

In some embodiments of the present application, each pixel may include three types of sub-pixels, such as the sub-pixels R, G, B mentioned in the foregoing embodiment, and the type of the sub-pixels and the pixel arrangement manner in this case may refer to the related descriptions in the foregoing embodiments, and details are not described herein again.

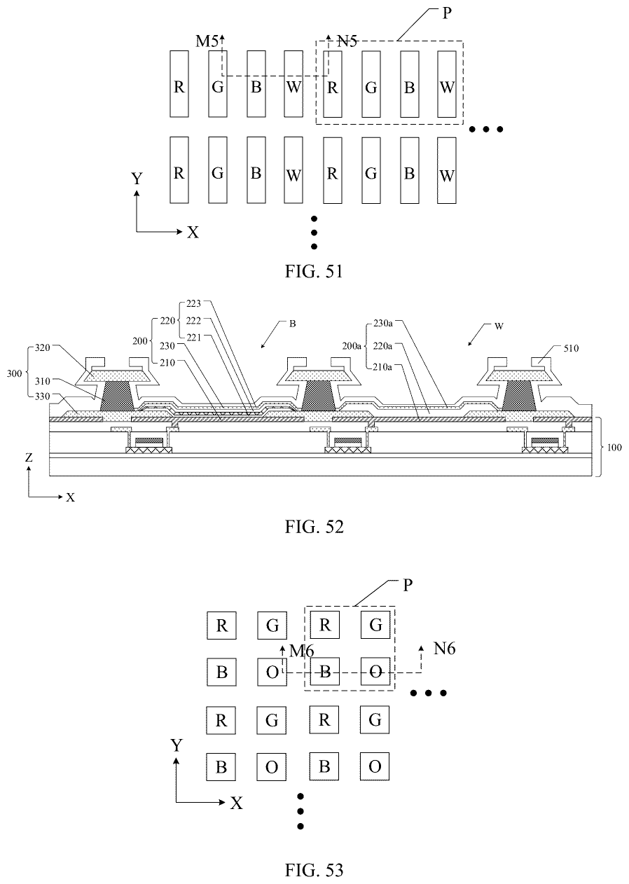

In some other embodiments of the present application, at least one of the pixels may include four types of sub-pixels, one of which is used to compensate for a brightness of an entire pixel. For example, as shown in FIG. 51 and FIG. 52, the pixel includes sub-pixels emitting red light (R), green light (G), blue light (B), and white light (W) respectively, and white light emitted by sub-pixel W may be used to compensate the brightness of the entire pixel to improve a display effect of the display panel. It should be noted that, in the embodiments, the sub-pixel W may be replaced with other mixed light (non-primary color light), for example, it may be configured to emit a combined light of green light and blue light, a combined light of green light and red light, a combined light of red light and blue light, and the like.

The light-emitting layer included in the light-emitting device of the sub-pixel is used for exciting light, and a type of the light-emitting layer determines a light color. In the sub-pixel W for compensation, one light-emitting layer emitting white light may be provided, or a plurality of different types of light-emitting layers respectively exciting light of different colors may be provided. For example, in the display panel shown in FIG. 52, a light-emitting device 200a corresponding to the sub-pixel W for compensation includes a first electrode 210a, a light-emitting functional layer 220a and a second electrode 230a sequentially stacked on a substrate 100, the light-emitting functional layer 220a is different from the light-emitting functional layer 220 of the light-emitting device 200 respectively corresponding to the sub-pixels R, G and B, there are three types of light-emitting layers in the light-emitting functional layer 220a, which is same as the light-emitting layer 222 included in the sub-pixels R, G and B, respectively, and the light-emitting functional layer 220a can emit white light.

In a case that the pixels of the display panel include the sub-pixels for compensating the brightness, the pixel arrangement manner of the display panel is not limited, and may be designed according to actual display requirements. For example, as shown in FIG. 51, four types of the sub-pixels in each pixel P are sequentially arranged in a row, and a direction of the row may be same as a direction of a row that the pixel P arranged.

It should be noted that, in at least one embodiment of the present application, the display panel may be provided with a sensing function, for the sensing function used for some special requirements, a sensor for sensing a signal, such as an optical signal, needs to be provided in the pixel, and the sensor may be located in same layer as the light-emitting device of the sub-pixel, for example, an electrode of the sensor may be prepared in same layer as the first electrode and the second electrode of the light-emitting device.

In the embodiment of the present application, a type of the sensor is related to a required sensing function, and the type of the sensor is not limited, and the sensor can be selected according to requirements of an actual process. In the following, for several different sensing requirements, a structure of the display panel having different types of sensors is exemplarily described.

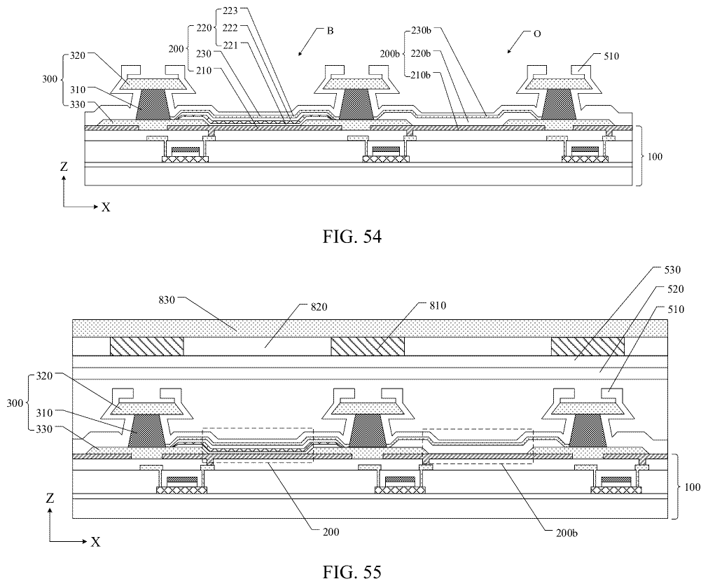

In at least one embodiment of the present application, as shown in FIG. 53 and FIG. 54, an optical sensing unit O is provided in at least one pixel of the display panel, an optical sensor 200b corresponding to the optical sensing unit O includes a first sensing electrode 210b, an optical sensing layer 220b, and a second sensing electrode 230b sequentially stacked on the substrate 100. The first sensing electrode 210b and the second sensing electrode 230b may be in a same layer as the first electrode 210 and the second electrode 230, respectively, and, the optical sensor 200b can be prepared using the isolation structure 300 as the light-emitting device 200.

For example, material of the optical sensing layer 220b is composed of a donor (Donor, D) and an acceptor (Acceptor, A). In one embodiment, material of a first optical sensor 112a is DMQA (D)/DCV3T (A), or DMQA (D)/SubPc (A), or SubPC (D)/C60 (A).

In some embodiments of the present application, the optical sensing unit O may be configured to detect visible light, and the optical sensing unit O may be configured to perform biometric authentication or biological signal monitoring, for example, fingerprint recognition may be performed. For example, the visible light may be a light ray emitted by the light-emitting device 200, after the light ray is emitted, the light ray is reflected into the optical sensing unit O by a fingerprint for fingerprint detection.

In some other embodiments of the present application, as shown in FIG. 53 and FIG. 55, an optical sensing unit O in the display panel may detect an invisible light, and on this basis, a stress light-emitting material layer 830 may be disposed on a side, facing away from a substrate 100, of an optical sensor 200b, and the stress light-emitting material layer 830 may emit invisible light under a stress condition. For example, a stress may be a force of pressing the display panel by an input object (for example, a user of an electronic device or a stylus pen), or may be a force of pressing the display panel by a detecting device for detecting a performance of the display panel. The light ray emitted by the light-emitting device 200 can excite the stress light-emitting material layer 830 to maintain a light-emitting intensity of the stress light-emitting material layer 830, which is beneficial to improving a stability of a pressure-sensitive function of the display panel and a service life.

For example, the stress light-emitting material layer 830 includes a transparent optical adhesive and stress light-emitting particles dispersed in the transparent optical adhesive. By dispersing the stress light-emitting particles in the transparent optical adhesive, a distribution of the stress light-emitting particles is more dispersed, and an entire lightening and thinning of the display panel is not affected while a touch input function and a pressure detection function are realized. For example, a stress light-emitting particle has a particle size of 0.1 μm to 1 μm; and/or, a mass percentage of the stress light-emitting particle in the stress light-emitting material layer 830 is 1% to 20%; and/or material of the stress light-emitting particle includes Sr3Sn2O7:Nd3+; and/or, a thickness of the stress light-emitting material layer 830 is 10 μm to 250 μm.

For example, the stress light-emitting material layer 830 may be a side, facing away from the substrate 100, of an encapsulation layer (for example, the third encapsulation layer 530), to ensure a flatness of the stress light-emitting material layer 830.

For example, a shielding portion 810 and a filter unit 820 may be disposed on a side, facing the substrate 100, of the stress light-emitting material layer 830, and the filter unit 820 corresponding to the optical sensing unit O is configured to block visible light and transmit invisible light to prevent the visible light from causing interference to the optical sensing unit O. For other arrangement manners of the shielding portion 810 and the filter unit 820, reference may be made to related descriptions in the foregoing embodiments, and details are not described herein again.

It should be noted that, in the embodiments of the present application, the display panel may include only the optical sensing unit O for detecting the visible light; or may include only the optical sensing unit O for detecting the invisible light; or both the optical sensing unit O for detecting the visible light and the optical sensing unit O for detecting the invisible light may be included at a same time. Furthermore, in the embodiments of the present application, the optical sensing unit O may be disposed in each pixel P, or the optical sensing unit O may be disposed in at least one of the pixels P.

For example, at least one embodiment of the present application provides a display device, which may include the display panel in any one of the embodiments above-mentioned, and the display device may be any product or component having a display function, such as a television, a digital camera, a mobile phone, a watch, a tablet computer, a notebook computer, a navigator, or the like.

As described above, in a solution of at least one embodiment of the present application, on the one hand, it is not necessary to be limited by a high-cost FMM mask, and based on the solution of the embodiments of the present application, a width of the sub-pixel and/or a gap between adjacent sub-pixels can be further reduced according to a structural characteristics of a self-scheme and a rule itself, and the pixel density can be increased to be greater than 403 PPI to broken through a limitation that the pixel density in a current OLED display panel is difficult to be further improved, for example, a range of the pixel density suitable for manufacturing a product can be achieved as 404 PPI to 7400 PPI by a currently available equipment according to a related solution of the present application; and the display panel and the display device can be applied to scenes such as a television and a notebook computer; in particular, the range of the pixel density suitable for manufacturing the product can be achieved as a higher PPI (such as 2000 to 7400 PPI), and the product can be suitable for usage scenarios of micro-display products (such as AR and VR). On the other hand, based on the solutions of the embodiments of the present application, the solutions of the present application are also suitable for manufacturing products with low pixel density (for example, 90 to 403 PPI, specifically such as 117 PPI, 144 PPI, 176 PPI, 260 PPI, and the like), and avoids problems of poor product quality and cost-prohibitive of a mask plate caused by factors such as stretching and fixing the mask plate and sagging at middle of the mask plate in the prior art.

The above is only the some embodiments of the present application and is not intended to limit the present application, and any modification, equivalent replacement, and the like made within the spirit and principle of the present application shall fall within the protection scope of the present application.

What is claimed is:

1. A display panel, comprising:
a substrate;
an isolation structure, located on the substrate and comprising a partition portion, wherein the partition portion comprises a first end portion and a second end portion, the second end portion is located on a side, away from the substrate, of the first end portion, an orthographic projection, on a plane where the substrate is located, of the first end portion is located within an orthographic projection, on the plane where the substrate is located, of the second end portion, and the isolation structure defines a plurality of first openings;
a display functional layer, located on the substrate and comprising a plurality of light-emitting devices, wherein the plurality of light-emitting devices correspond to the plurality of first openings respectively, each light-emitting device of the plurality of light-emitting devices is located in a first opening, corresponding to the light-emitting device, of the plurality of first openings, the light-emitting device comprises a first electrode, a light-emitting functional layer and a second electrode stacked on the substrate, and the first opening is configured to limit the light-emitting device corresponding to the first opening; and
a first encapsulation layer, located on a side, away from the substrate, of the display functional layer; a distance from an edge of the second end portion to an edge of the first end portion is a first height along a direction perpendicular to a plane where the substrate is located;
wherein, in a regular cross-section of the light-emitting device, a distance between a position of a surface, facing the substrate, of the first encapsulation layer that located on a straight line passing through the edge of the second end portion and perpendicular to the plane where the substrate is located and the edge of the first end portion in the direction perpendicular to the plane where the substrate is located is a partition association height, and a difference between the first height and the partition association height is not less than an encapsulation safety margin.

2. The display panel according to claim 1, wherein a distance between the first encapsulation layer and the first electrode is a second height at an intermediate position of the light-emitting device, a product of the second height and a first thickness coefficient is a first numerical value, and a difference between the first height and the first numerical value is not less than the encapsulation safety margin.

3. The display panel according to claim 2, wherein the first thickness coefficient is greater than or equal to M and less than 1, and M∈[0.3, 0.5) or M∈[0.5, 0.7]; and
M is a ratio of the partition association height to the second height.

4. The display panel according to claim 1, wherein at the intermediate position of the light-emitting device, the first encapsulation layer has a second thickness, and
the first encapsulation layer covers the light-emitting device and a side surface of a part of the second end portion, the encapsulation safety margin is equal to a product of the second thickness and the second thickness coefficient, and the second thickness coefficient is 0.2 to 2.

5. The display panel according to claim 1, wherein a distance between an orthographic projection, on the plane where the substrate is located, of the edge of the second end portion and an orthographic projection, on the plane where the substrate is located, of the edge of the first end portion is a first width, and
in the regular cross-section of the light-emitting device, an acute angle formed by intersecting a straight line passing through an edge of the second electrode and the edge of the second end portion with the plane where the substrate is located is a first inclination angle, and the first width is less than a product of the first height and a cotangent value of the first inclination angle.

6. The display panel according to claim 5, wherein in the regular cross-section of the light-emitting device, an acute angle formed by intersecting a straight line of an edge of the light-emitting functional layer and the edge of the second end portion with the plane where the substrate is located is an inclination angle of the light-emitting functional layer, and the inclination angle of the light-emitting functional layer is greater than the first inclination angle.

7. The display panel according to claim 6, wherein the first width is greater than a product of the first height and a cotangent value of the inclination angle of the light-emitting functional layer.

8. The display panel according to claim 6, wherein the light-emitting functional layer comprises a first functional layer, in the regular cross-section of the light-emitting device, an acute angle formed by intersecting a straight line passing through an edge of the first functional layer and the edge of the second end portion with the plane where the substrate is located is a second inclination angle, and the second inclination angle is greater than the inclination angle of the light-emitting functional layer.

9. The display panel according to claim 1, wherein the orthographic projection, on the plane where the substrate is located, of the edge of the second end portion is located between an orthographic projection, on the plane where the substrate is located, of an edge of the first electrode and the orthographic projection, on the plane where the substrate is located, of the edge of the first end portion.

10. The display panel according to claim 1, wherein on the regular cross-section of the light-emitting device, a distance between the orthographic projection, on the plane where the substrate is located, of the edge of the first electrode and the orthographic projection, on the plane where the substrate is located, of the edge of the second end portion is less than: a product of a cotangent value of an acute angle at which a connecting line of the edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located; and
on the regular cross-section of the light-emitting device, a product of a cotangent value of an acute angle at which a connecting line of the edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located is less than or equal to: a distance between the orthographic projection, on the plane where the substrate is located, of the edge of the first electrode and the orthographic projection, on the plane where the substrate is located, of the edge of the second end portion.

11. The display panel according to claim 1, further comprising a pixel defining layer, wherein the pixel defining layer is located on the first electrode and located on a side, facing the substrate, of the partition portion, the pixel defining layer defines a plurality of second openings, the first electrode is exposed from the plurality of second openings, and the edge of the first end portion is located in an upper surface of the pixel defining layer.

12. The display panel according to claim 11, wherein on the regular cross-section of the light-emitting device, a distance between an orthographic projection, on the plane where the substrate is located, of an edge of a portion, exposed from the plurality of second openings, of the first electrode and the orthographic projection, on the plane where the substrate is located, of the edge of the second end portion is less than: a product of a cotangent value of an acute angle at which a connecting line of the edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located; and
on the regular cross-section of the light-emitting device, a product of a cotangent value of an acute angle at which a connecting line of the edge of the light-emitting functional layer and the edge of the second end portion intersects the plane where the substrate is located and a distance between an intermediate portion of a lower surface of the light-emitting functional layer and the edge of the second end portion in the direction perpendicular to the plane where the substrate is located is less than or equal to: a distance between an orthographic projection, on the plane where the substrate is located, of an edge of a portion, exposed from the plurality of second openings, of the first electrode and the orthographic projection, on the plane where the substrate is located, of the edge of the second end portion.

13. The display panel according to claim 12, wherein the pixel defining layer is an inorganic layer, a portion, covering a gap of the first electrode disposed adjacently, of the pixel defining layer comprises a groove conformal with the gap, and a surface, facing the substrate, of the first end portion covers the groove.

14. The display panel according to claim 12, wherein a distance between an intermediate portion of a lower surface of the light-emitting functional layer and the edge of the second end portion in the direction perpendicular to the plane where the substrate is located is equal to: a sum of the first height and a thickness of the pixel defining layer.

15. The display panel according to claim 12, wherein the partition portion comprises a supporting portion and a blocking portion stacked on the substrate, the supporting portion forms the first end portion, and the blocking portion forms the second end portion.

16. The display panel according to claim 15, wherein the first encapsulation layer is in contact with a surface of the blocking portion, and material of the first encapsulation layer is same as material of a barrier portion.

17. The display panel according to claim 15, wherein a dividing hole with a grid shape is provided in the supporting portion, the dividing hole divides the supporting portion into a plurality of sub-supporting portions, the blocking portion covers and fills the dividing hole, the supporting portion is of a conductive structure, the blocking portion is of an insulating structure, and the second electrode is connected with a sub-supporting portion corresponding to the second electrode.

18. The display panel according to claim 1, wherein the partition portion comprises a supporting portion and a blocking portion stacked on the substrate, on the regular cross-section of the light-emitting device, the blocking portion comprises an inclined sidewall, a difference between an acute angle at which a connecting line of the edge of the second electrode and the edge of the second end portion intersects the plane where the substrate is located and an acute angle at which a sidewall of the blocking portion intersects the plane where the substrate is located is not less than a preset angle.

19. The display panel according to claim 1, wherein the first end portion and the second end portion of the partition portion are of an integral structure, and in the direction perpendicular to the plane where the substrate is located, a cross-sectional profile of a portion, located between two adjacent sub-pixels, of the partition portion is an inverted trapezoid, an edge of a bottom of the inverted trapezoidal is the edge of the second end portion, and an edge of a top of the inverted trapezoidal is the edge of the first end portion.

20. The display panel according to claim 1, wherein a distance between edges of portions that the first electrode contact with the light-emitting functional layer corresponding to the first electrode of adjacent light-emitting devices is a pixel pitch, the pixel pitch is 2000 to 18000 nanometers, and a pixel density of the display panel is 90 PPI to 7400 PPI.
